(19) United States
(12) Patent Application Publication
(10) Pub. No.: US 2025/0318355 A1
(43) Pub. Date: Oct. 9, 2025

(54) ORGANIC COMPOUND, ELECTRONIC ELEMENT AND ELECTRONIC APPARATUS USING SAME

(71) Applicant: SHAANXI LIGHTE OPTOELECTRONICS MATERIAL CO., LTD., Xi'an, Shaanxi (CN)

(72) Inventors: Yiyi ZHENG, Xi'an, Shaanxi (CN); Cheng WEI, Xi'an, Shaanxi (CN); Youngkook KIM, Xi'an, Shaanxi (CN)

(21) Appl. No.: 18/865,025

(22) PCT Filed: Sep. 15, 2023
(86) PCT No.: PCT/CN2023/119244

§ 371 Date: Nov. 12, 2024

(30) Foreign Application Priority Data
Mar. 29, 2023 (CN) 202310324591.7

(51) Int. Cl. H10K 50/11; C07F 7/08; C09K 11/06; H10K 85/40; H10K 85/60

(52) U.S. Cl. CPC H10K 50/11; C07F 7/0816; C09K 11/06; H10K 85/40; H10K 85/622; H10K 85/626; H10K 85/6572; H10K 85/6574; H10K 85/6576; C09K 2211/1096

(57) ABSTRACT

The present application relates to an organic compound, and an electronic element and an electronic apparatus using the same. The organic compound of the present application has a structure shown in Formula I. The organic compound of the present application is applied to the electronic element, such as an organic electroluminescent device, so that the performance of the device can be significantly improved.

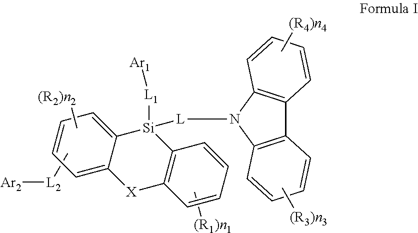

### CROSS-REFERENCE TO RELATED APPLICATIONS

The present application claims the priority of Chinese patent application No. 202310324591.7 filed on Mar. 29, 2023, which is incorporated herein by reference in its entirety as a part of the present application.

### FIELD OF THE INVENTION

The present application relates to the technical field of organic electroluminescence, and specifically to an organic compound, an electronic element and an electronic apparatus using the same.

### BACKGROUND OF THE INVENTION

With the development of electronic technology and the progress of material science, the application range of electronic devices used to realize electroluminescence or photoelectric conversion is increasingly extensive. This type of electronic device, for example an organic electroluminescent device, usually comprises a cathode and an anode disposed opposite to each other, and a functional layer disposed between the cathode and the anode. The functional layer is composed of multiple organic or inorganic film layers, and generally includes an organic light-emitting layer, a hole transport layer, and an electron transport layer, etc. When a voltage is applied to the anode and cathode, an electric field is generated between the two electrodes. Under the influence of the electric field, electrons on the cathode side move towards the organic light-emitting layer, and holes on the anode side also move towards the organic light-emitting layer. Electrons and holes combine in the organic light-emitting layer to form excitons, which are in an excited state and release energy outward, thereby causing the organic light-emitting layer to emit light externally.

Generally speaking, the selection of a host material in a host material/dopant system is critical, as it exerts a significant influence on the efficiency and lifetime of a luminescent device. A host material with superior performance should be characterized by an appropriate molecular weight, a higher glass transition temperature and thermal decomposition temperature, high electrochemical stability, and good interfacial contact between adjacent functional layer materials. For the host material in blue light, it is requisite that the material possesses good carrier transport capabilities and an appropriate triplet energy level, ensuring that energy can be efficiently transferred from the host material to the guest material during the luminescence process, thereby achieving a higher device efficiency.

In existing organic electroluminescent devices, the primary problems are lifetime and efficiency. With the large-area display trend, the driving voltage has been correspondingly increased, necessitating the enhancement of both luminous and electrical efficiencies. Consequently, there is a necessity for the continued development of new materials to further improve the performance of organic electroluminescent devices.

### SUMMARY OF THE INVENTION

The objective of the present application is to provide an organic compound, an electronic element and an electronic apparatus using the same. Using the organic compound in organic electroluminescent devices can improve the performance of the devices.

A first aspect of the present application provides an organic compound having a structure shown in a Formula I.

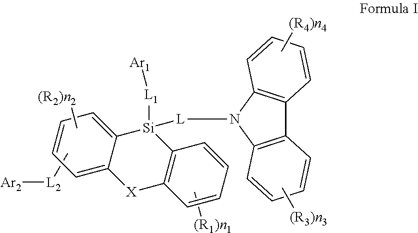

Wherein, X is selected from O or S;
Ar₁ and Ar₂ are the same or different, and are each independently selected from a substituted or unsubstituted aryl having 6 to 40 carbon atoms, or a substituted or unsubstituted heteroaryl having 3 to 40 carbon atoms;
L₁ and L₂ are the same or different, and are each independently selected from a single bond, a substituted or unsubstituted arylene having 6 to 30 carbon atoms, or a substituted or unsubstituted heteroarylene having 3 to 30 carbon atoms;
L is selected from a substituted or unsubstituted arylene having 6 to 30 carbon atoms, or a substituted or unsubstituted heteroarylene having 3 to 30 carbon atoms;
the substituent(s) of Ar₁, Ar₂, L₁, L₂ and L are the same or different, and are each independently selected from a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, an aryl having 6 to 20 carbon atoms, or a heteroaryl having 3 to 20 carbon atoms;
R₁, R₂, R₃ and R₄ are the same or different, and are each independently selected from a hydrogen, a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, a substituted or unsubstituted aryl having 6 to 20 carbon atoms, or a substituted or unsubstituted heteroaryl having 3 to 20 carbon atoms;
n₁ represents the number of R₁, and n₁ is selected from 1, 2, 3, or 4; when n₁ is greater than 1, any two R₁ are the same or different;
n₂ represents the number of R₂, and n₂ is selected from 1, 2, or 3; when n₂ is greater than 1, any two R₂ are the same or different;
n₃ represents the number of R₃, and n₃ is selected from 1, 2, 3, or 4; when n₃ is greater than 1, any two R₃ are the same or different;
n₄ represents the number of R₄, and n₄ is selected from 1, 2, 3, or 4; when n₄ is greater than 1, any two R₄ are the same or different;
the substituent(s) of R₁, R₂, R₃ and R₄ are the same or different, and are each independently selected from a deuterium, a halogen group, a cyano, an alkyl having 1 to 5 carbon atoms, an aryl having 6 to 12 carbon atoms, or a heteroaryl having 3 to 12 carbon atoms.

A second aspect of the present application provides an electronic element, comprising an anode and a cathode disposed opposite to each other, and a functional layer disposed between the anode and the cathode; the functional layer contains the organic compound described in the first aspect.

A third aspect of the present application provides an electronic apparatus, comprising the electronic element described in the second aspect.

The structure of the organic compound of the present application comprises a parent core of dibenzoxa(thia)silacycle, in which the silicon atom in the parent core is linked to N-carbazole through an aromatic linking group, and the benzene ring in the parent core of dibenzoxa(thia)silacycle is linked with at least one substituent; the two substituents on the silicon atom at position 10 of the parent core of dibenzoxa(thia)silacycle are on different planes, resulting in a relatively large molecular distortion, which endows the compound with a higher glass transition temperature, enabling the compound to form a better amorphous film; especially when the dibenzoxa(thia)silacycle is linked to N-carbazole through an aromatic group, the overall compound has strong hole transport capability. When the organic compound of the present application is used as a hole transport material in a hybrid blue light host material, on one hand, the high hole transport capability of the compound can improve the efficiency of energy transfer from the host material to the blue light doping material, thereby enhancing the efficiency of the device; on the other hand, the high glass transition temperature of the compound can ensure that the light-emitting layer forms a good amorphous thin film, and the film morphology does not change during the long-term operation of the device, thus improving the lifetime of the device.

The other features and advantages of the present application will be described in detail in the following Detailed Description of the Embodiments section.

### BRIEF DESCRIPTION OF THE DRAWINGS

The drawings are used for a further understanding of the present application and constitute a part of the specification and are used to explain the present application together with the following specific embodiments, but do not constitute a limitation of the present application.

FIG. 1 is a schematic structural diagram of an organic electroluminescent device according to one embodiment of the present application.

FIG. 2 is a schematic diagram of an electronic apparatus according to one embodiment of the present application.

### LIST OF REFERENCE SIGNS

100: Anode; 200: Cathode; 300: Functional layer; 310: Hole injection layer 321: Hole transport layer; 322: Electron blocking layer; 330: Organic light-emitting layer 340: Electron transport layer; 350: Electron injection layer; 400: Electronic apparatus

### DETAILED DESCRIPTION OF THE EMBODIMENTS

Exemplary embodiments will now be described more comprehensively with reference to the accompanying drawings. The exemplary embodiments, however, can be implemented in a variety of forms and should not be interpreted as being limited to the examples set forth herein. On the contrary, these embodiments are provided to make the present application more comprehensive and complete, and to convey the concepts of these exemplary embodiments fully to those skill in the art. Features, structures, or characteristics described herein can be combined in one or more embodiment(s) in any suitable manner. In the following description, many specific details are provided to give a full understanding of the examples of the present application.

In a first aspect, the present application provides an organic compound having a structure shown in a Formula I:

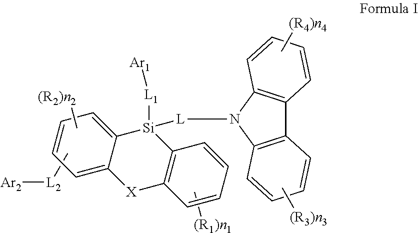

Wherein, X is selected from O or S;
Ar₁ and Ar₂ are the same or different, and are each independently selected from a substituted or unsubstituted aryl having 6 to 40 carbon atoms, or a substituted or unsubstituted heteroaryl having 3 to 40 carbon atoms;
L₁ and L₂ are the same or different, and are each independently selected from a single bond, a substituted or unsubstituted arylene having 6 to 30 carbon atoms, or a substituted or unsubstituted heteroarylene having 3 to 30 carbon atoms;
L is selected from a substituted or unsubstituted arylene having 6 to 30 carbon atoms, or a substituted or unsubstituted heteroarylene having 3 to 30 carbon atoms;
the substituent(s) of Ar₁, Ar₂, L₁, L₂ and L are the same or different, and are each independently selected from a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, an aryl having 6 to 20 carbon atoms, or a heteroaryl having 3 to 20 carbon atoms;
R₁, R₂, R₃ and R₄ are the same or different, and are each independently selected from a hydrogen, a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, a substituted or unsubstituted aryl having 6 to 20 carbon atoms, or a substituted or unsubstituted heteroaryl having 3 to 20 carbon atoms;
n₁ represents the number of R₁, and n₁ is selected from 1, 2, 3, or 4; when n₁ is greater than 1, any two R₁ are the same or different;
n₂ represents the number of R₂, and n₂ is selected from 1, 2, or 3; when n₂ is greater than 1, any two R₂ are the same or different;
n₃ represents the number of R₃, and n₃ is selected from 1, 2, 3, or 4; when n₃ is greater than 1, any two R₃ are the same or different;
n₄ represents the number of R₄, and n₄ is selected from 1, 2, 3, or 4; when n₄ is greater than 1, any two R₄ are the same or different;
the substituent(s) of R₁, R₂, R₃ and R₄ are the same or different, and are each independently selected from a deuterium, a halogen group, a cyano, an alkyl having 1 to 5 carbon atoms, an aryl having 6 to 12 carbon atoms, or a heteroaryl having 3 to 12 carbon atoms.

In the present application, the descriptive expressions “ . . . each independently selected from” and “each . . . independently selected from” can be interchanged and all these expressions should be interpreted in a broad sense. They can both refer to specific options expressed by the same symbols in different groups are mutually non-influential, and to specific options expressed by the same symbol within the same group are mutually non-influential. The groups each may be the same or different. For example,

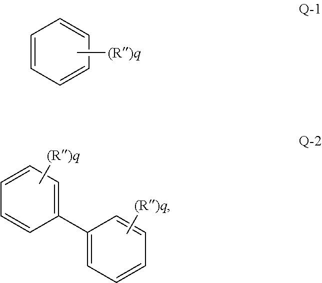

in which each q is independently 0, 1, 2, and 3, and each R″ is independently selected from a hydrogen, a deuterium, a fluorine, and a chlorine” means that Formula Q-1 represents that there are q substituents R″ on the benzene ring, and each R″ can be the same or different, with mutual non-influence between the options for each R″; Formula Q-2 represents that there are q substituents R″ on each benzene ring of biphenyl, and the number q of R″ substituents on the two benzene rings can be the same or different, with mutual non-influence between the options for each R″.

In the present application, the term “substituted or unsubstituted” means that the functional group defined by the term may or may not have a substituent (hereinafter referred to as Rc for ease of description). For example, “a substituted or unsubstituted aryl” refers to an aryl having a substituent Rc or an unsubstituted aryl. Among them, the above substituent, i.e., Rc, may be, for example, a deuterium, a halogen group, a cyano, an alkyl, a trialkylsilyl, a haloalkyl, a cycloalkyl, an aryl, or a heteroaryl.

In the present application, the number of carbon atoms of a substituted or unsubstituted functional group refers to the total number of carbon atoms. For example, if L₁ is a substituted arylene having 12 carbon atoms, the total number of carbon atoms in the arylene and its substituents is 12.

In the present application, an aryl refers to an optional functional group or a substituent derived from an aromatic carbon ring. An aryl may be a monocyclic aryl (e.g., phenyl) or a polycyclic aryl. In other words, an aryl may be a monocyclic aryl, a fused aryl, two or more monocyclic aryls linked by carbon-carbon bond conjugation, a monocyclic aryl and a fused aryl linked by carbon-carbon bond conjugation, or two or more fused aryls linked by carbon-carbon bond conjugation. That is, unless otherwise specified, two or more aromatic groups linked by carbon-carbon bond conjugation may also be regarded as an aryl in the present application. Among them, fused aryl may include, for example, a bicyclic fused aryl (e.g., naphthyl), a tricyclic fused aryl (e.g., phenanthryl, fluorenyl, anthryl), etc. For example, in the present application, biphenyl, terphenyl and the like belong to an aryl. Examples of an aryl include, but are not limited to, a phenyl, a naphthyl, a fluorenyl, a spirobifluorenyl an anthryl, a phenanthryl, a biphenyl, a terphenyl, a benzo[9,10]phenanthryl, a pyrenyl, a benzofluoranthryl, a chrysenyl, etc. In the present application, “an arylene” involved refers to a divalent group formed by further removing one hydrogen atom from an aryl.

In the present application, a substituted aryl may mean that one or more hydrogen atom(s) in the aryl are replace by a group such as a deuterium atom, a halogen group, a cyano, an aryl, a heteroaryl, a trialkylsilyl, an alkyl, a cycloalkyl, a haloalkyl, and a deuterated alkyl. Specific examples of an aryl substituted with a heteroaryl include, but are not limited to a phenyl substituted with a dibenzofuranyl, a phenyl substituted with a dibenzothienyl, a phenyl substituted with a pyridyl, etc. It should be understood that the number of carbon atoms in a substituted aryl refers to the total number of carbon atoms of an aryl and the substituents on the aryl. For example, a substituted aryl having 18 carbon atoms, refers to the total number of carbon atoms of the aryl and the substituents thereof is 18.

In the present application, “a heteroaryl” refers to a monovalent aromatic ring containing at least one heteroatom or a derivative thereof. The heteroatom may be at least one of B, O, N, P, Si, Se, and S. A heteroaryl may be a monocyclic heteroaryl or a polycyclic heteroaryl. In other words, a heteroaryl may be a single aromatic ring system, or multiple aromatic ring systems linked by carbon-carbon bond conjugation, with any of the aromatic ring systems being an aromatic monocyclic ring or an aromatic fused ring. For example, a heteroaryl may include, thienyl, furyl, pyrrolyl, imidazolyl, thiazolyl, oxazolyl, oxadiazolyl, triazolyl, pyridyl, dipyridyl, pyrimidinyl, triazinyl, acridinyl, pyridazinyl, pyrazinyl, quinolyl, quinazolinyl, quinoxalinyl, phenoxazinyl, phthalazinyl, pyridopyrimidinyl, pyridopyrazinyl, pyrazinopyrazinyl, isoquinolyl, indolyl, carbazolyl, benzoxazolyl, benzimidazolyl, benzothiazolyl, benzocarbazolyl, benzothienyl, dibenzothienyl, thienothienyl, benzofuranyl, phenanthrolinyl, isoxazolyl, thiadiazolyl, phenothiazinyl, silafluorenyl, and dibenzofuranyl, etc, but not limited thereto. In the present application, “a heteroarylene” involved refers to a divalent group formed by further removing one hydrogen atom from a heteroaryl.

In the present application, a substituted heteroaryl may mean that one or more hydrogen atom(s) in the heteroaryl are replaced by a group such as a deuterium atom, a halogen group, a cyano, an aryl, a heteroaryl, a trialkylsilyl, an alkyl, a cycloalkyl, a haloalkyl, and a deuterated alkyl. Specific examples of a heteroaryl substituted with an aryl include, but are not limited to a dibenzofuranyl substituted with a phenyl, a dibenzothienyl substituted with a phenyl, a pyridyl substituted with a phenyl, etc. It should be understood that the number of carbon atoms in the substituted heteroaryl refers to the total number of carbon atoms in the heteroaryl and the substituents thereon.

In the present application, the number of the carbon atoms of an aryl as a substituent may be 6 to 20. For example, the number of carbon atoms may be 6, 7, 8, 9, 10, 11, 12, 13, 14, 15, 16, 17, 18, 19, or 20. The specific examples of an aryl as substituent include, but are not limited to a phenyl, a biphenyl, a naphthyl, an anthryl, and a chrysenyl.

In the present application, the number of the carbon atoms of a heteroaryl as a substituent may be 3 to 20. For example, the number of carbon atoms may be 3, 4, 5, 6, 7, 8, 9, 10, 11, 12, 13, 14, 15, 16, 17, 18, 19, or 20. The specific examples of a heteroaryl as a substituent include, but are not limited to a pyridyl, a pyrimidinyl, a carbazolyl, a dibenzofuranyl, a dibenzothienyl, a quinolyl, a quinazolinyl, a quinoxalinyl, and an isoquinolyl.

In the present application, the number of carbon atoms in an alkyl having 1 to 10 carbon atoms may be, for example, 1, 2, 3, 4, 5, 6, 7, 8, 9, or 10. Specific examples of an alkyl include, but are not limited to a methyl, an ethyl, a n-propyl, an isopropyl, a n-butyl, an isobutyl, a tert-butyl, a n-pentyl, an isopentyl, a neopentyl, a n-hexyl, a n-heptyl, a n-octyl, a 2-ethylhexyl, a nonyl, a decyl, and a 3,7-dimethyloctyl, etc.

In the present application, a halogen group may be for example, a fluorine, a chlorine, a bromine, and an iodine.

In the present application, specific examples of a trialkylsilyl include, but are not limited to, a trimethylsilyl, a triethylsilyl, etc.

In the present application, specific examples of a haloalkyl include, but are not limited to, a trifluoromethyl.

In the present application, specific examples of a cycloalkyl include, but are not limited to, a cyclopentane, a cyclohexane, and an adamantane, etc.

In the present application, a non-positional bond refers to a single bond

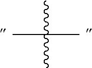

extending from the ring system, which represents that one end of the linkage bond can link to any position in the ring system through which the bond passes, and the other end links to the rest of the compound molecule. For example, as shown in Formula (f) below, the naphthyl represented by Formula (f) is linked to other positions of the molecule through two non-positional bonds passing through the two rings, which indicates any of possible linkages forms shown in Formulae (f-1) to (f-10):

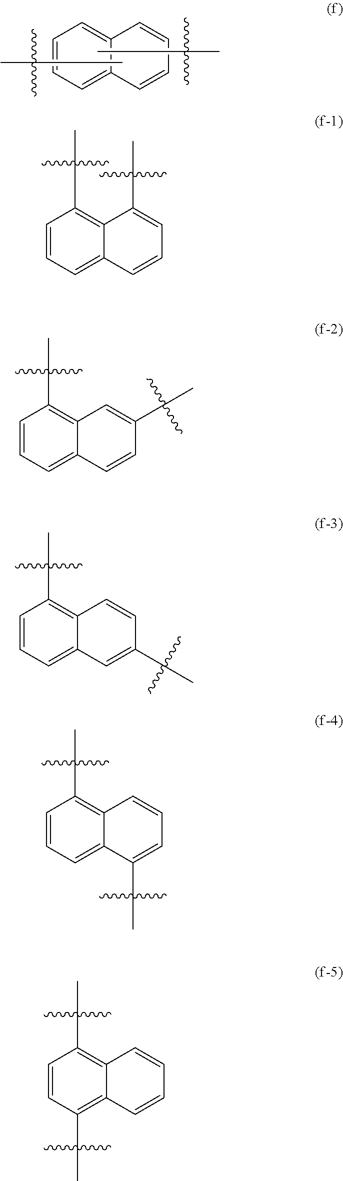

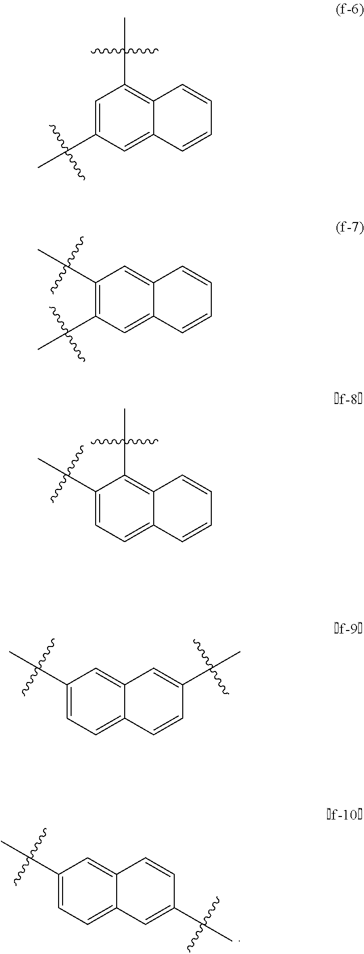

As another example, as shown in Formula (X′) below, the dibenzofuranyl represented by Formula (X′) is linked to other positions of the molecule via a non-positional bond extending from the center of benzene ring on one side, which indicates any of possible linkages forms shown in Formulae (X′-1) to (X′-4):

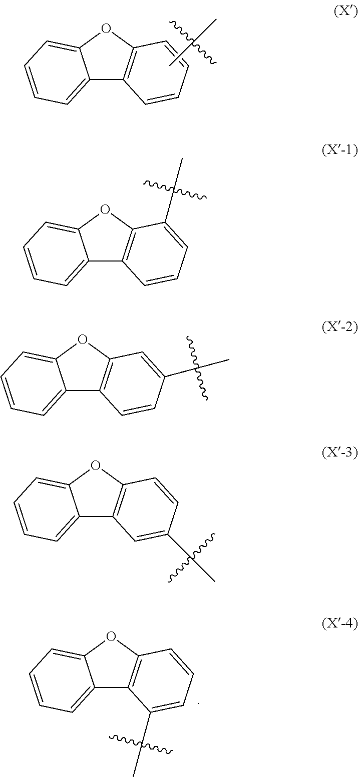

In some embodiments, the compound is selected from the structures represented by a Formula I-1, a Formula I-2, a Formula I-3, or a Formula I-4:

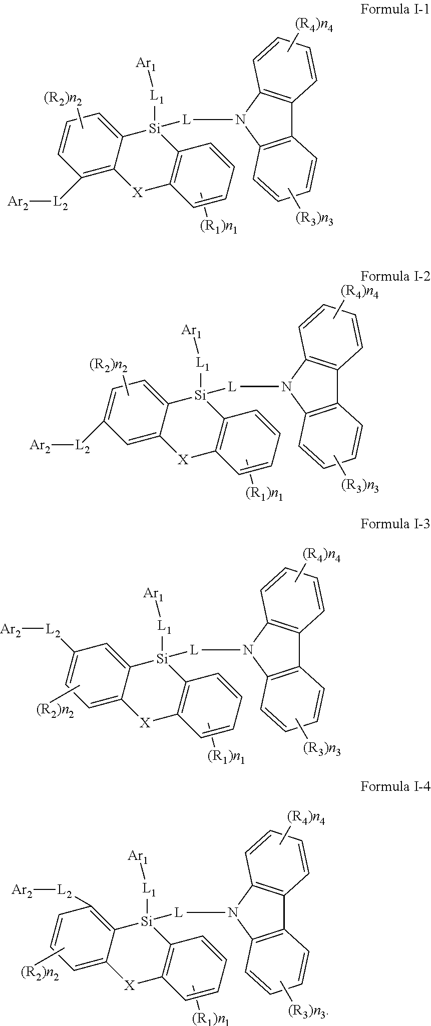

In some embodiments, L is selected from a substituted or unsubstituted arylene having 6 to 18 carbon atoms, or a substituted or unsubstituted heteroarylene having 5 to 18 carbon atoms. For example, L is selected from a substituted or unsubstituted arylene having 6, 7, 8, 9, 10, 11, 12, 13, 14, 15, 16, 17, or 18 carbon atoms, or a heteroarylene having 5, 6, 7, 8, 9, 10, 11, 12, 13, 14, 15, 16, 17, or 18 carbon atoms.

Optionally, the substituent(s) of L are each independently selected from a deuterium, a fluorine, a cyano, an alkyl having 1 to 5 carbon atoms, an aryl having 6 to 12 carbon atoms, or a heteroaryl having 5 to 12 carbon atoms.

Optionally, L is selected from a substituted or unsubstituted phenylene, a substituted or unsubstituted naphthylene, a substituted or unsubstituted biphenylene, a substituted or unsubstituted terphenylene, a substituted or unsubstituted fluorenylene, a substituted or unsubstituted phenanthrylene, a substituted or unsubstituted pyridylene, a substituted or unsubstituted dibenzofuranylene, or a substituted or unsubstituted dibenzothienylene.

Optionally, the substituent(s) of L are each independently selected from a deuterium, a fluorine, a cyano, a methyl, an ethyl, an isopropyl, a tert-butyl, a phenyl, a naphthyl, or a biphenyl.

Optionally, L is selected from the group consisting of the following groups:

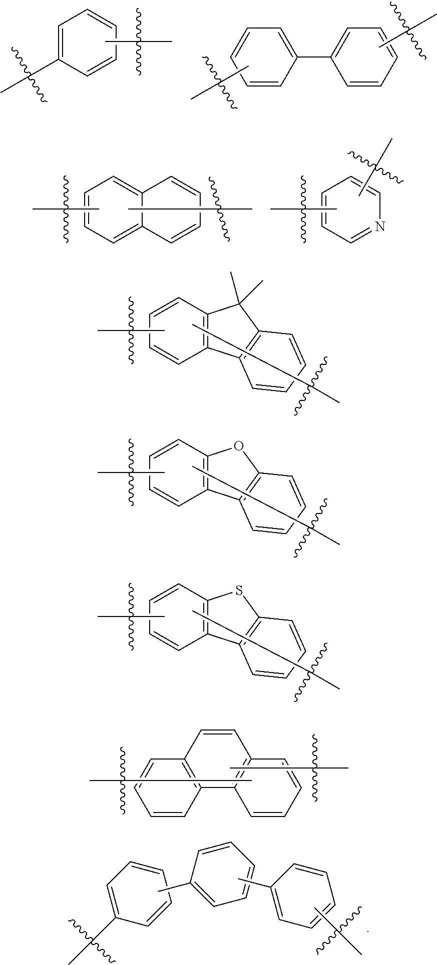

Optionally, L is selected from the group consisting of the following groups:

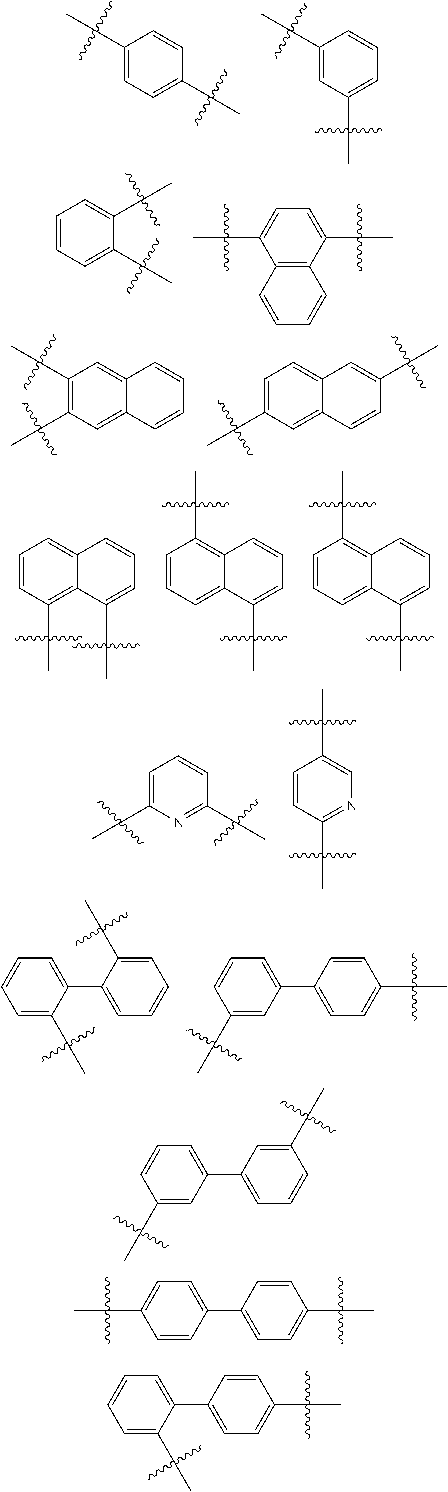

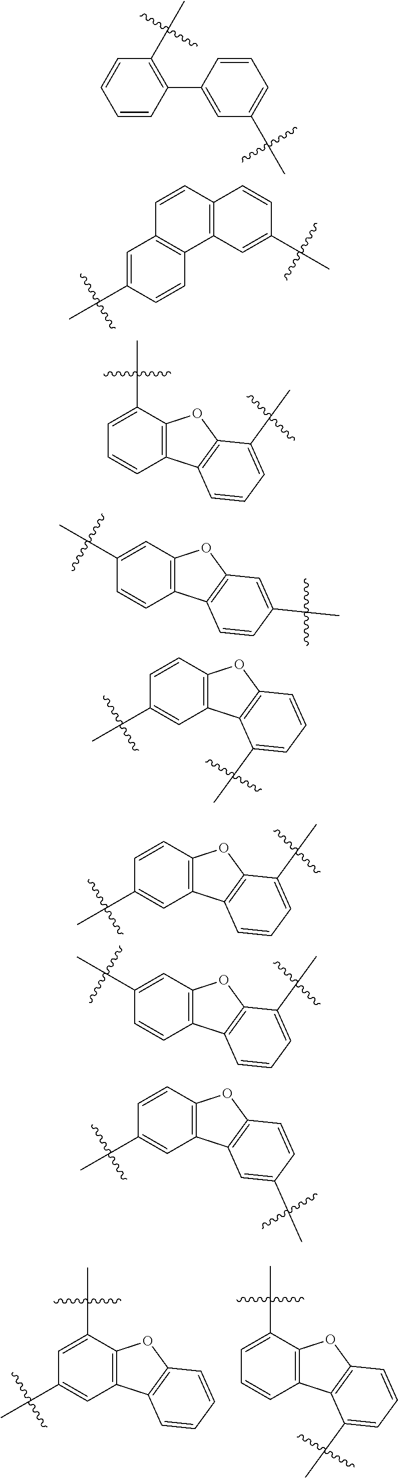

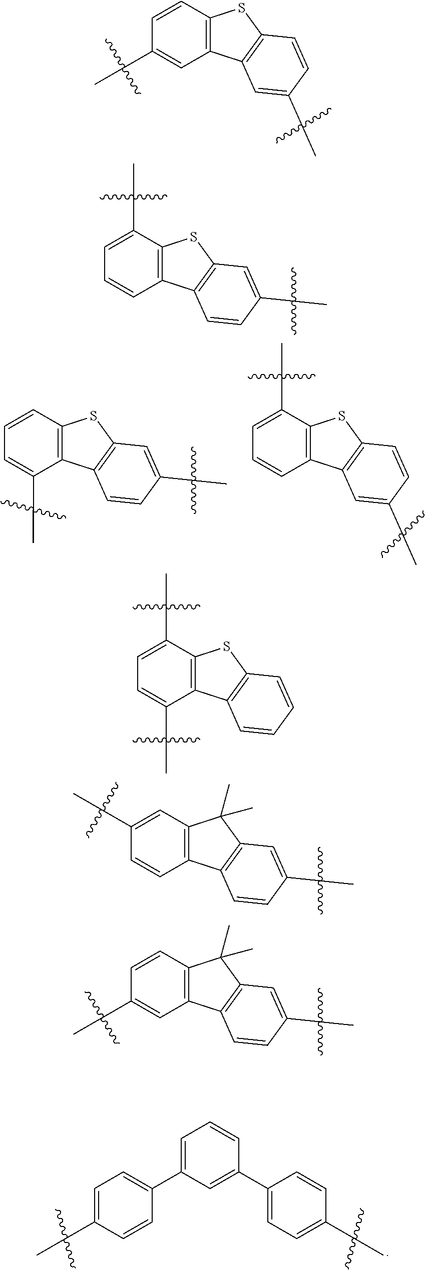

In some embodiments, Ar₁ and Ar₂ are each independently selected from aryl deuterium, a fluorine, a cyano, an alkyl having 1 to 5 carbon atoms, a trimethylsilyl, a haloalkyl having 1 to 5 carbon atoms, a cycloalkyl having 5 to 10 carbon atoms, an aryl having 6 to 12 carbon atoms, or a heteroaryl having 5 to 12 carbon atoms.

Optionally, Ar₁ and Ar₂ are each independently selected from a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted phenanthryl, a substituted or unsubstituted anthryl, a substituted or unsubstituted pyridyl, a substituted or unsubstituted quinolyl, a substituted or unsubstituted dibenzofuranyl, a substituted or unsubstituted dibenzothienyl, a substituted or unsubstituted carbazolyl, a substituted or unsubstituted spirobifluorenyl, a substituted or unsubstituted pyrenyl, or a substituted or unsubstituted triphenylene.

Optionally, the substituent(s) of Ar₁ and Ar₂ are each independently selected from a deuterium, a fluorine, a cyano, a methyl, an ethyl, an isopropyl, a tert-butyl, a trimethylsilyl, a trifluoromethyl, a cyclopentane, a cyclohexane, an adamantane, a phenyl, a naphthyl, a biphenyl, a dibenzofuranyl, a dibenzothienyl, or a carbazolyl.

In some embodiments, L₁ and L₂ are each independently selected from a single bond, a substituted or unsubstituted arylene having 6 to 18 carbon atoms, or a substituted or unsubstituted heteroarylene having 5 to 18 carbon atoms. For example, L₁ and L₂ are each independently selected from a substituted or unsubstituted arylene having 6, 7, 8, 9, 10, 11, 12, 13, 14, 15, 16, 17, or 18 carbon atoms, or a substituted or unsubstituted heteroarylene having 5, 6, 7, 8, 9, 10, 11, 12, 13, 14, 15, 16, 17, or 18 carbon atoms.

Optionally, the substituent(s) of L₁ and L₂ are each independently selected from a deuterium, a fluorine, a cyano, an alkyl having 1 to 5 carbon atoms, an aryl having 6 to 12 carbon atoms, or a heteroaryl having 5 to 12 carbon atoms.

In some embodiments, L₁ and L₂ are each independently a single bond, a substituted or unsubstituted phenylene, a substituted or unsubstituted naphthylene, a substituted or unsubstituted biphenylene, a substituted or unsubstituted anthrylene, a substituted or unsubstituted fluorenylene, a substituted or unsubstituted dibenzothienylene, a substituted or unsubstituted dibenzofuranylene, or a substituted or unsubstituted carbazolylene.

Optionally, the substituent(s) of L₁ and L₂ are each independently selected from a deuterium, a fluorine, a cyano, a trimethylsilyl, a trifluoromethyl, a methyl, an ethyl, an isopropyl, a tert-butyl, a phenyl, a naphthyl, or a biphenyl.

Optionally, Ar₁ is selected from a substituted or unsubstituted group W, wherein, the unsubstituted group W is selected from the group consisting of the following groups:

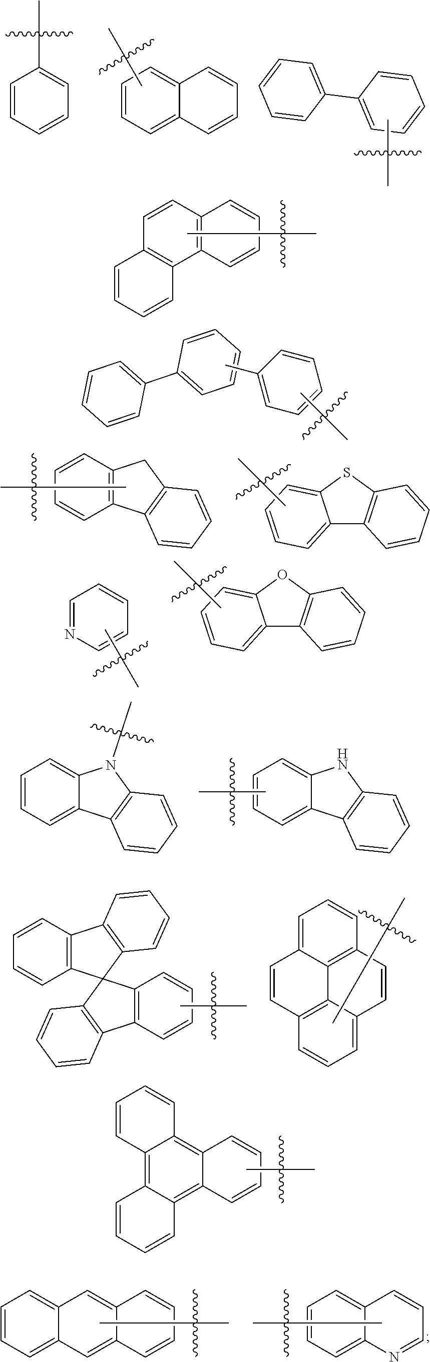

wherein, the substituted group W has one or more substituent(s), and the substituents are each independently selected from a deuterium, a fluorine, a cyano, a methyl, an ethyl, an isopropyl, a tert-butyl, a trimethylsilyl, a trifluoromethyl, a cyclopentane, a cyclohexane, an adamantane, a phenyl, a naphthyl, a biphenyl, a dibenzofuranyl, a dibenzothienyl or a carbazolyl, and when the number of the substituents is greater than 1, the substituents are each the same or different.

Optionally, Ar₁ is selected from the group consisting of the following groups:

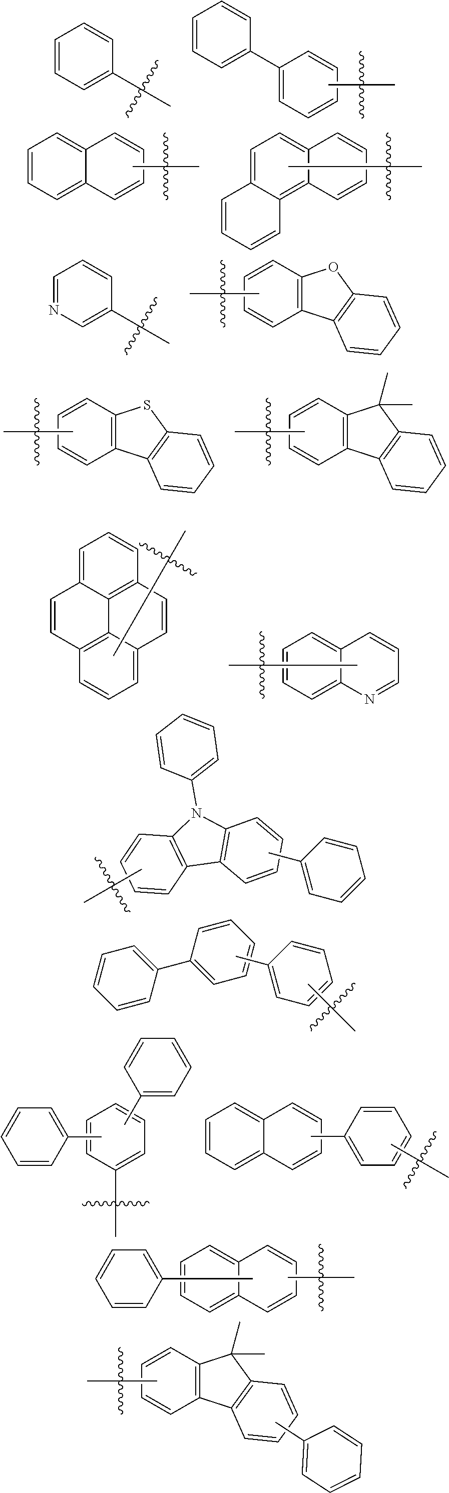

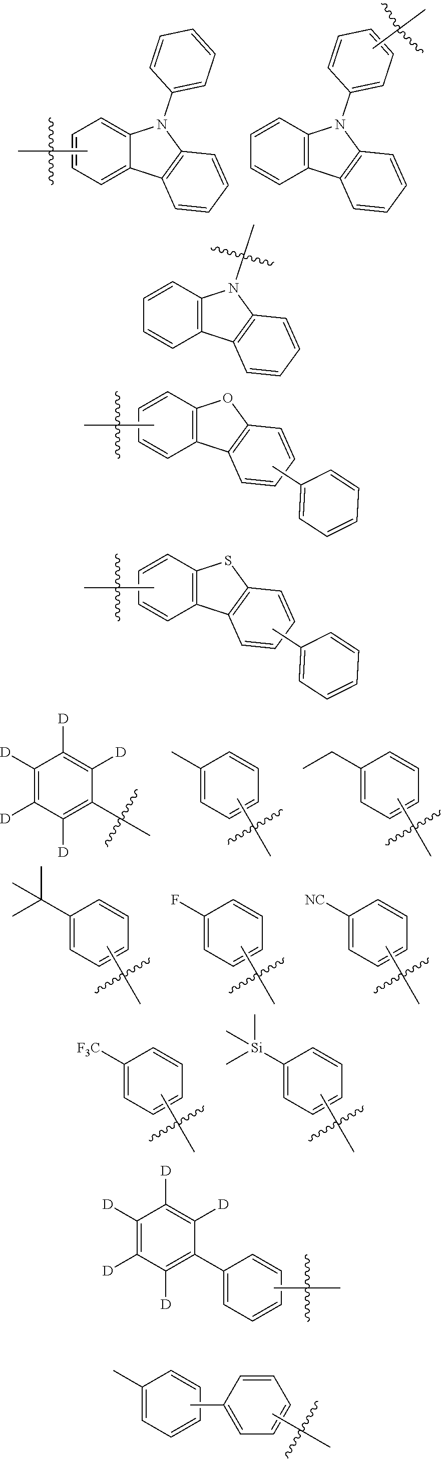

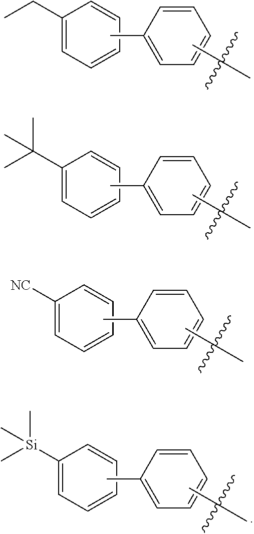

Optionally, Ar₁ is selected from the group consisting of the following groups:

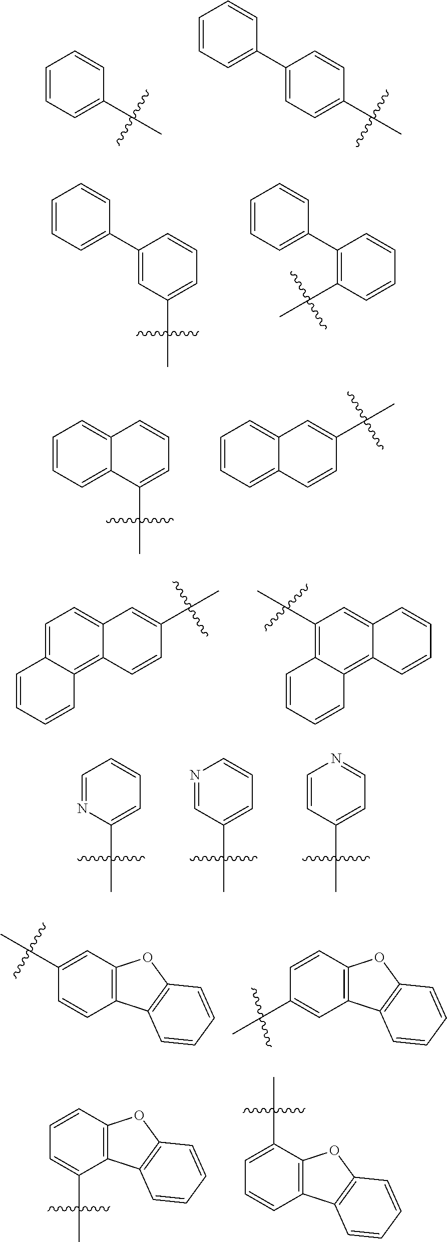

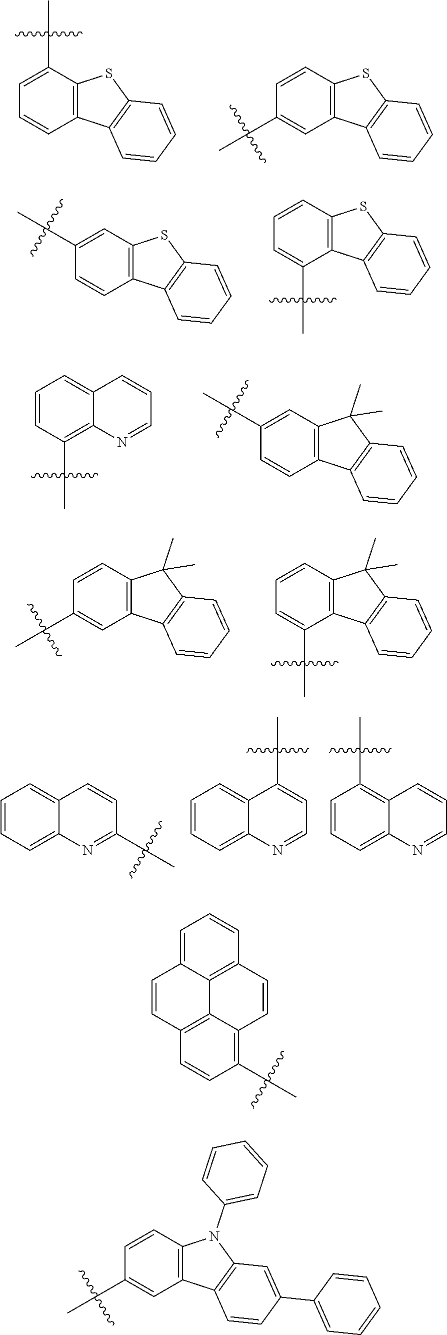

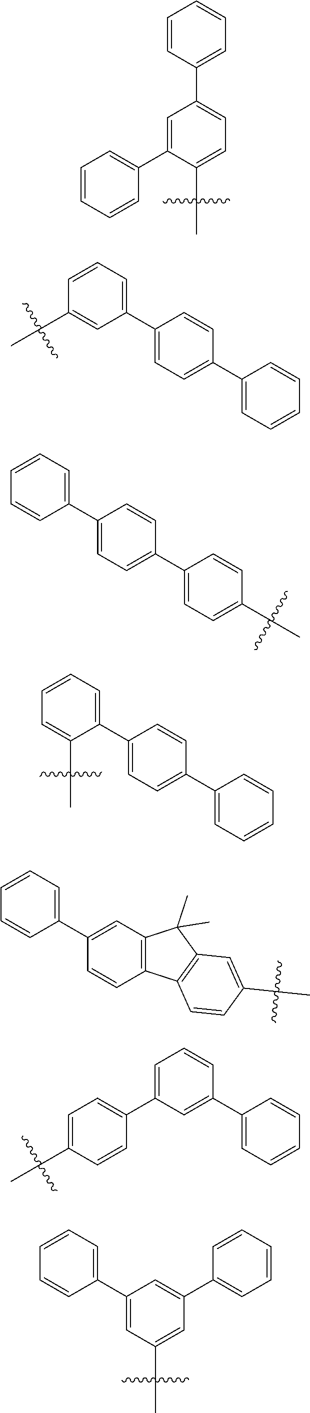

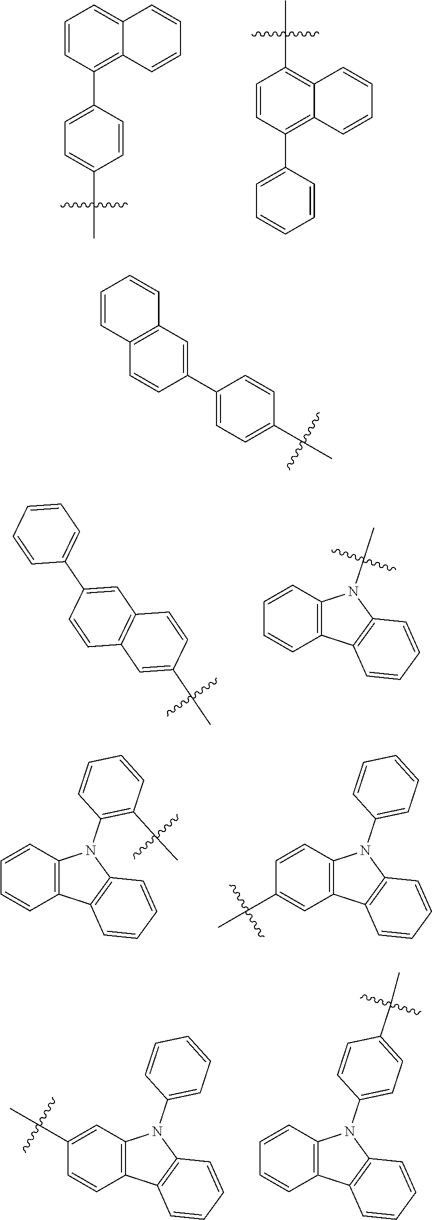

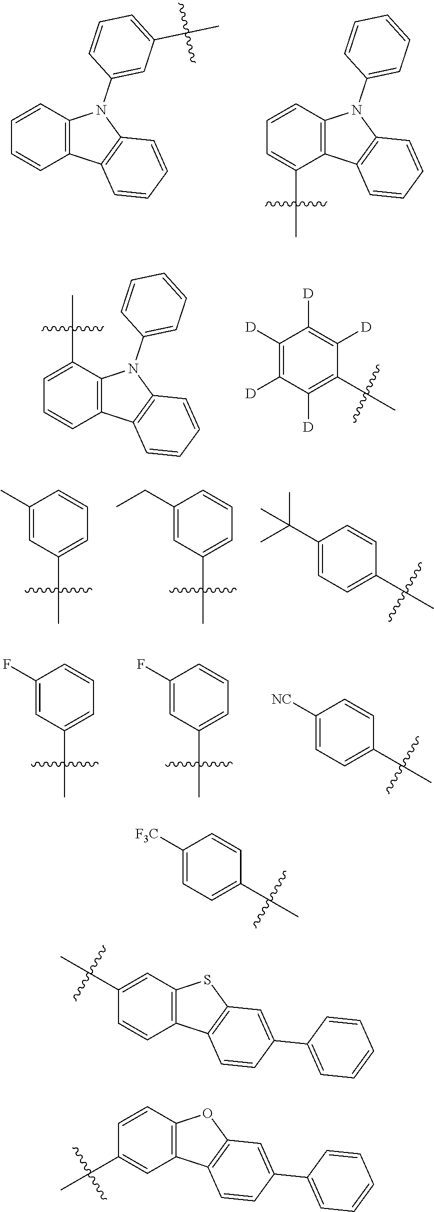

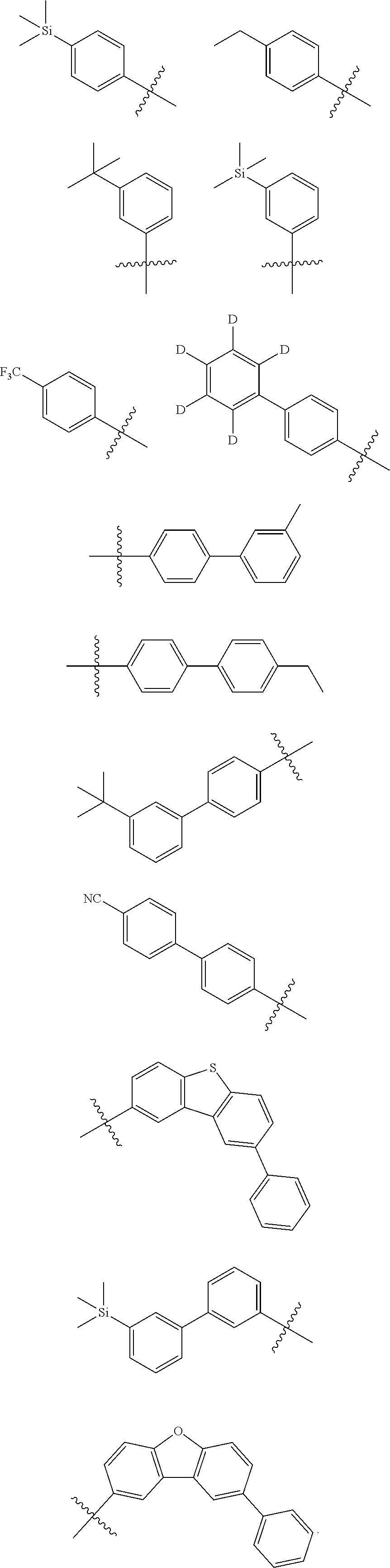

In some embodiments, L₁ is selected from a single bond, or the group consisting of the following groups:

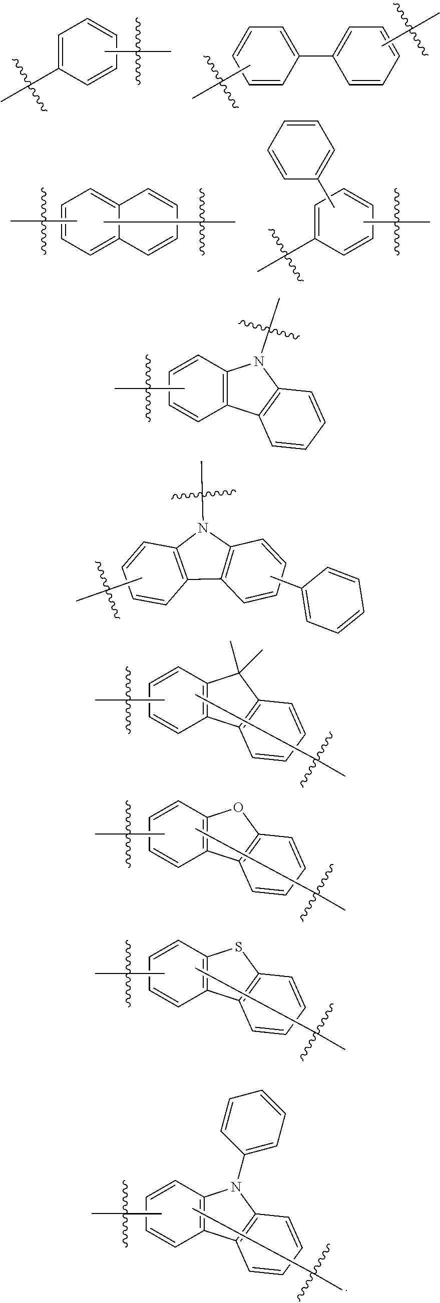

Optionally, L₁ is selected from a single bond, or the group consisting of the following groups:

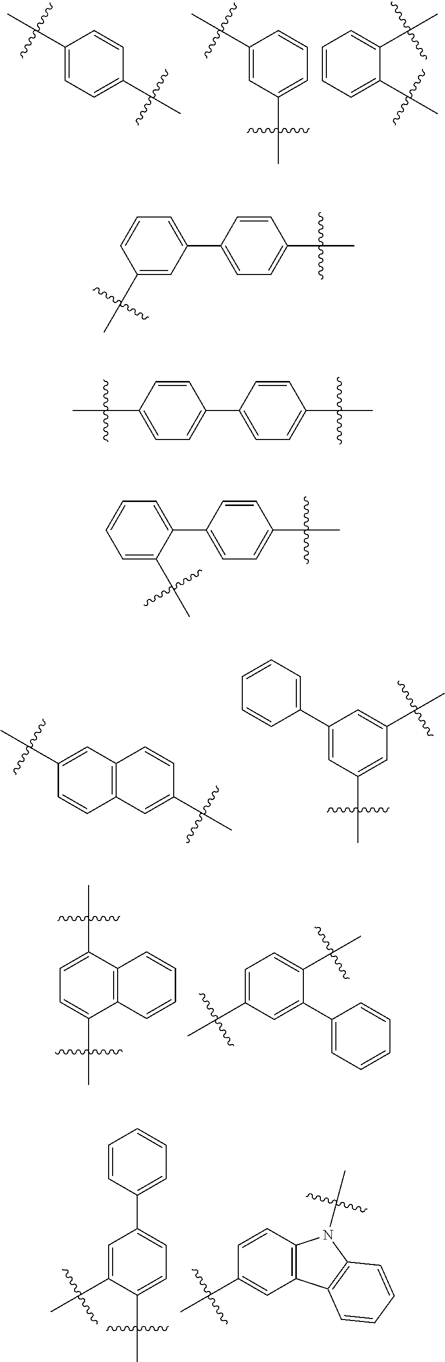

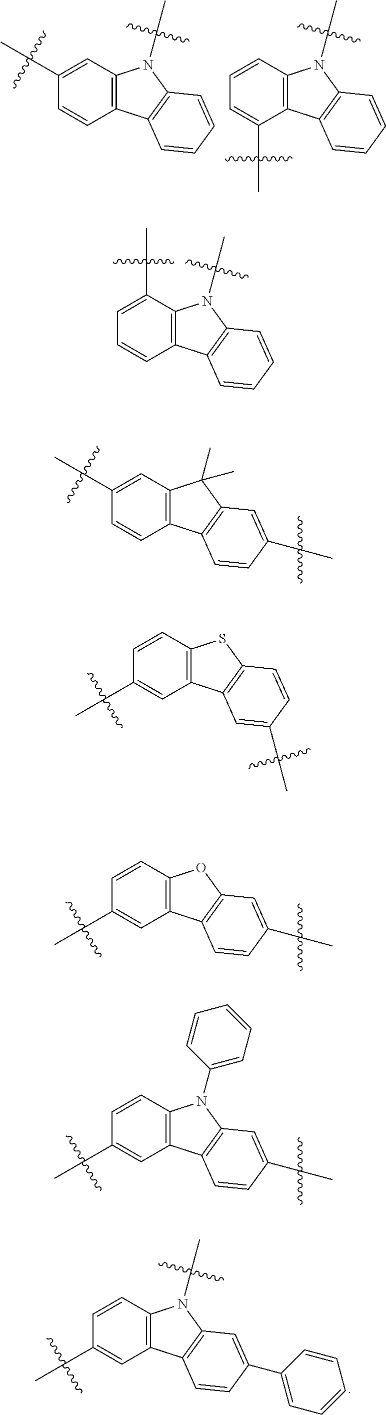

In some embodiments,

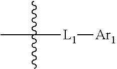

is selected from the group consisting of the following groups:

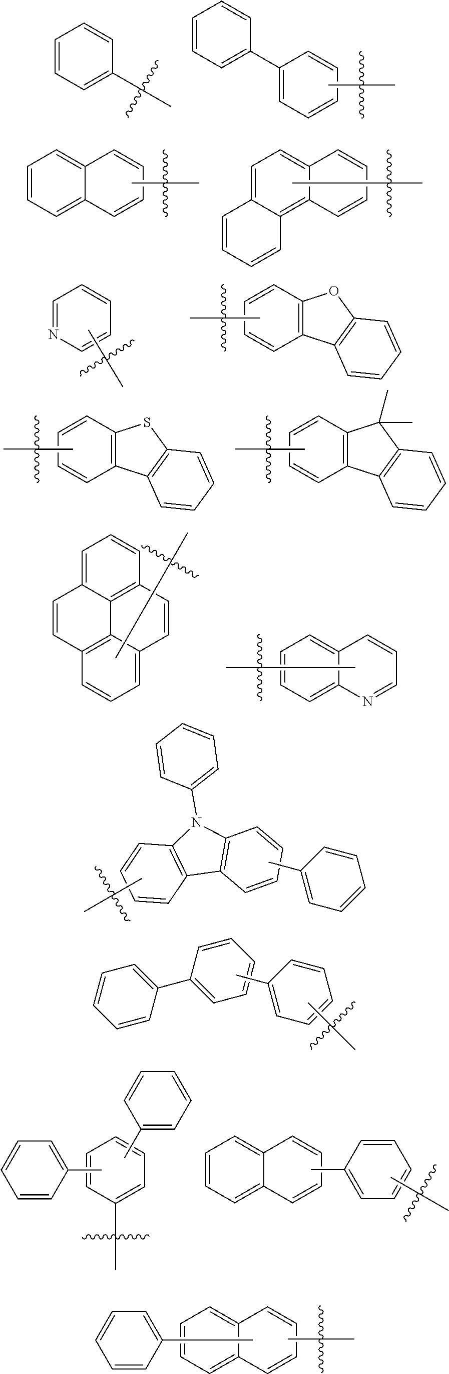

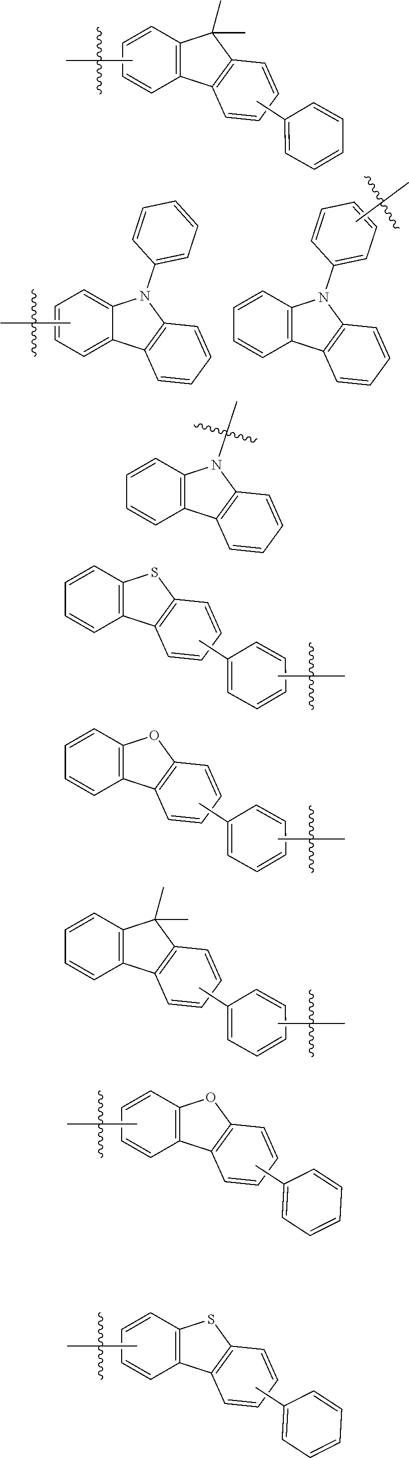

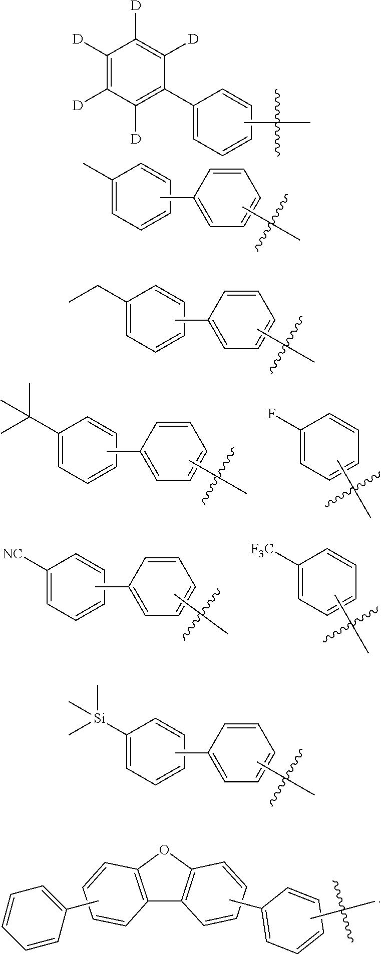

Optionally,

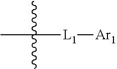

is selected from the group consisting of the following groups:

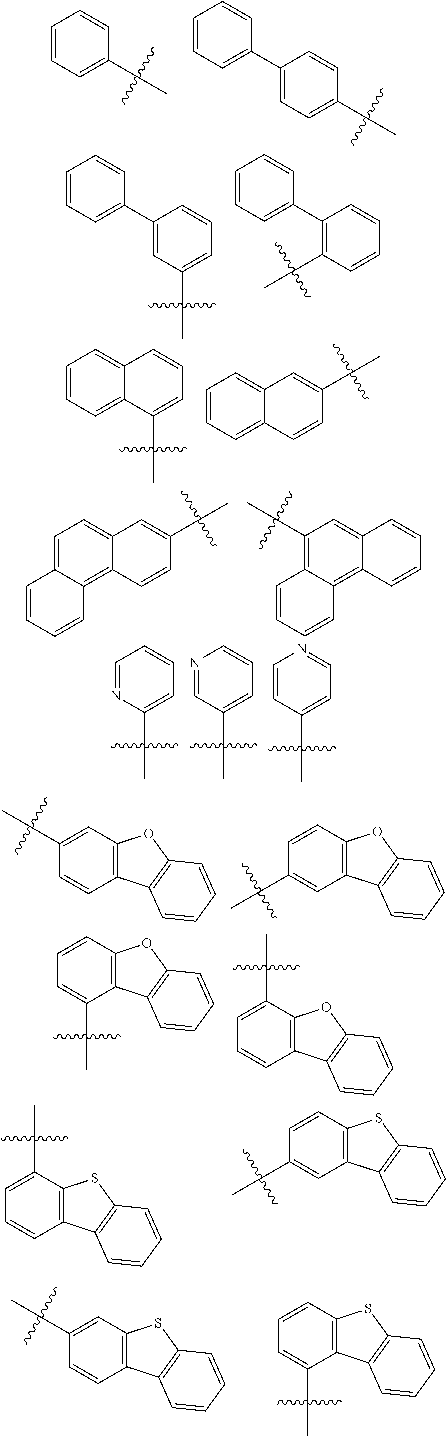

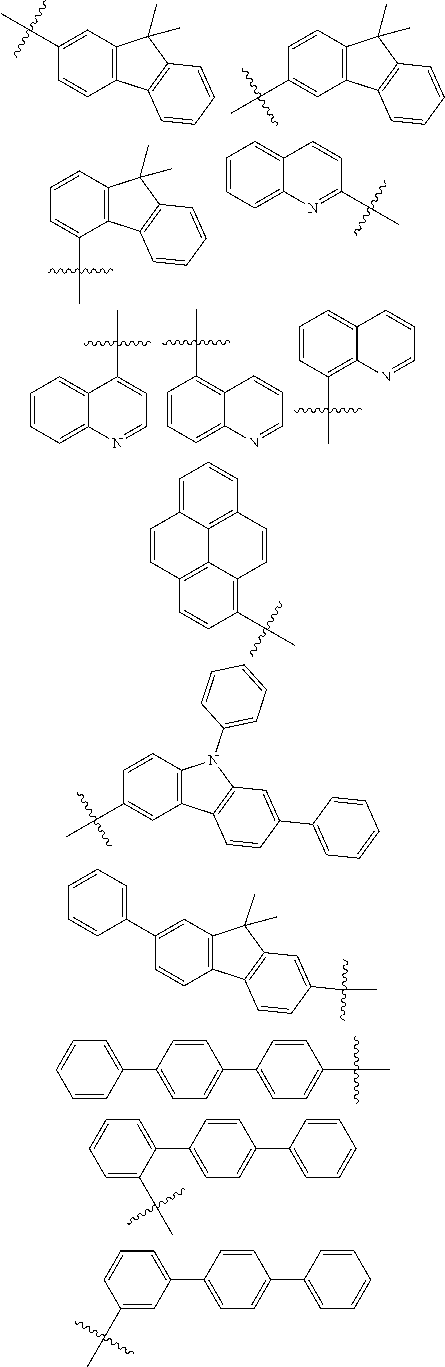

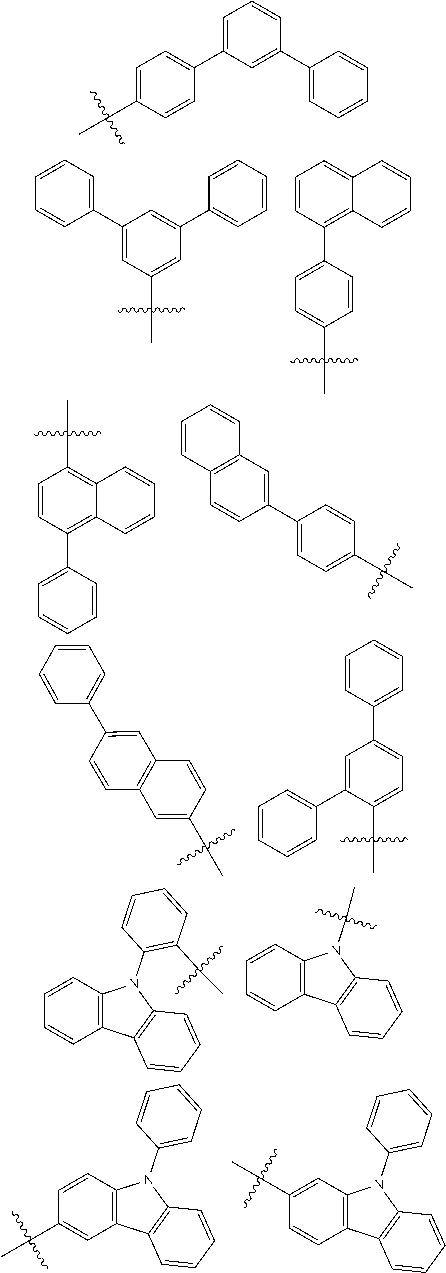

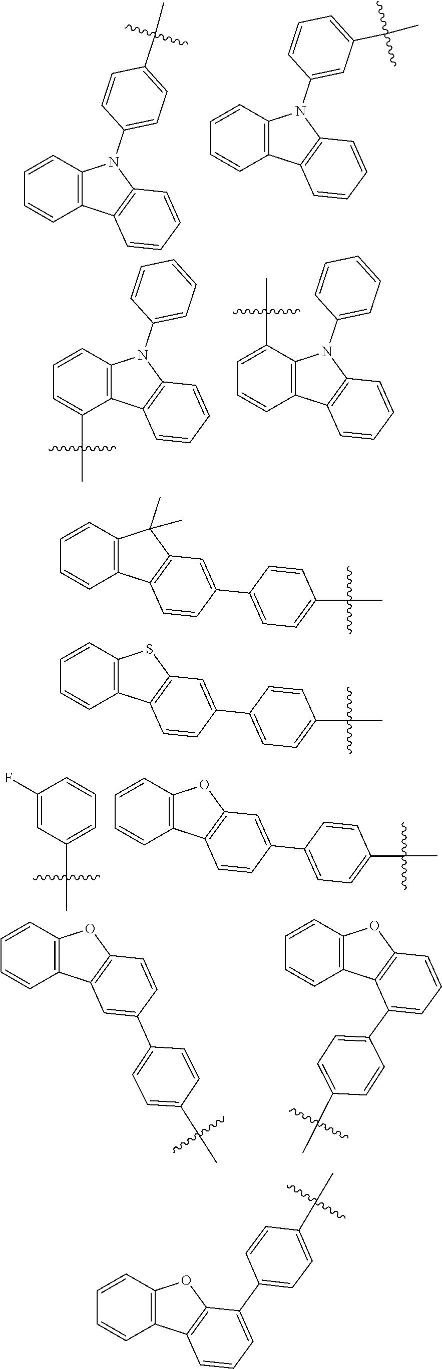

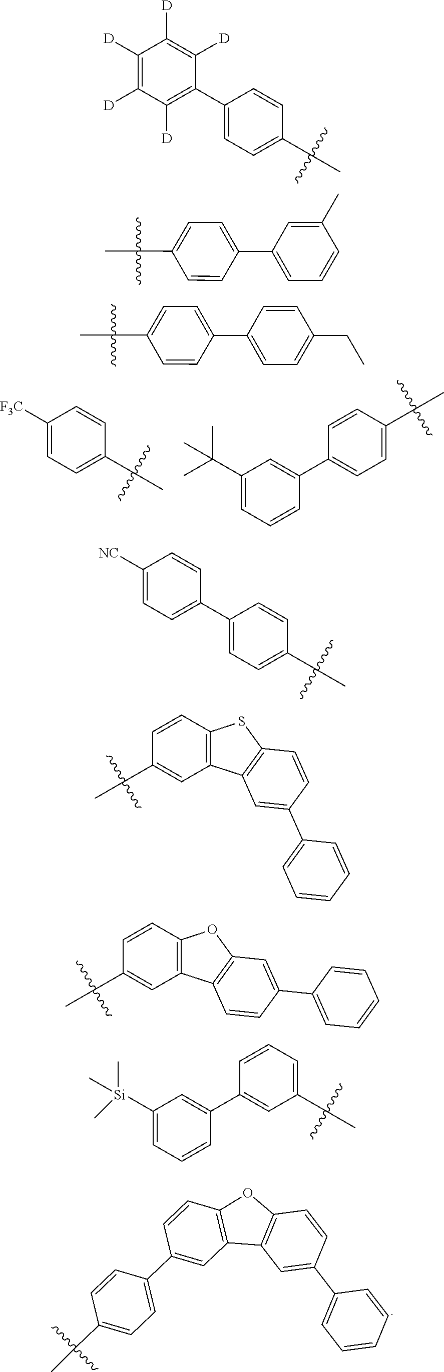

Optionally, Ar₂ is selected from a substituted or unsubstituted group V, wherein, the unsubstituted group V is selected from the group consisting of the following groups:

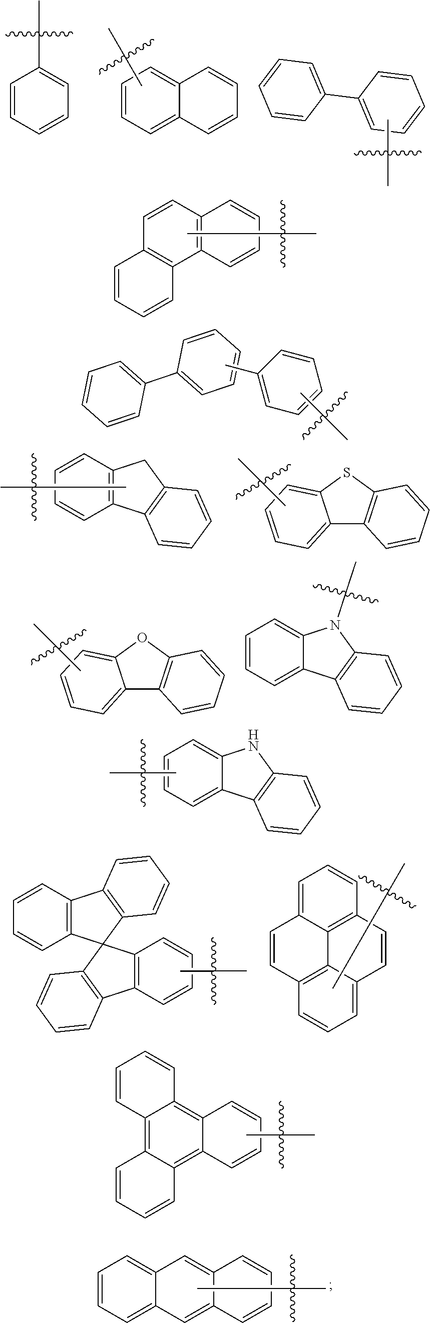

wherein, the substituted group V has one or more substituent(s), and the substituents are each independently selected from a deuterium, a fluorine, a cyano, a methyl, an ethyl, an isopropyl, a tert-butyl, a trimethylsilyl, a trifluormethyl, a cyclopentane, a cyclohexane, an adamantane, a phenyl, a napthyl, a biphenyl, a dibenzofuranyl, a dibenzothienyl or a carbazolyl, and when the number of substituents is greater than 1, the substituents are each the same or different.

Optionally, Ar₂ is selected from the group consisting of the following groups:

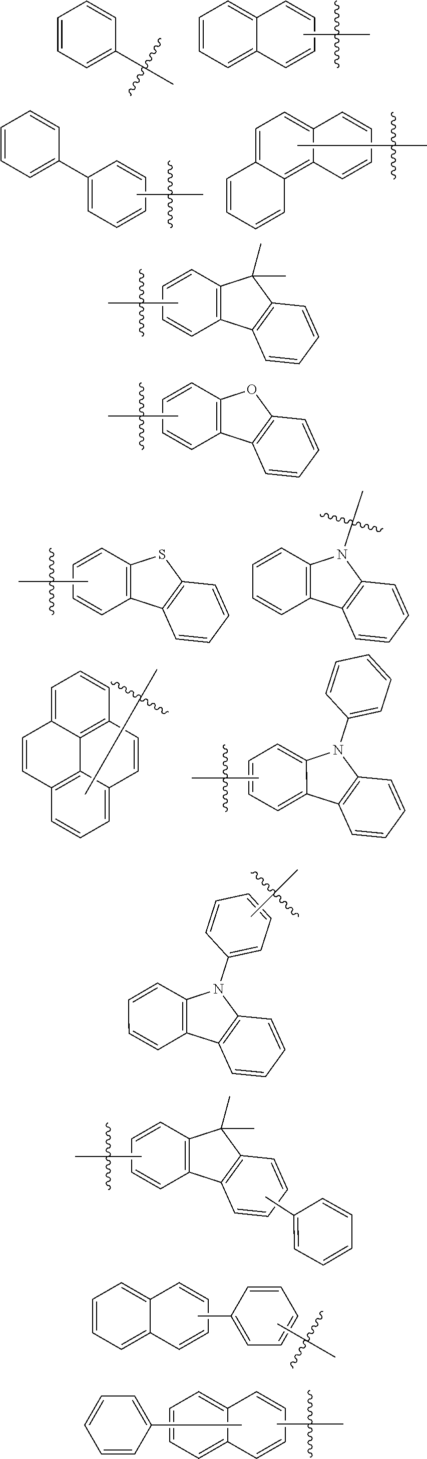

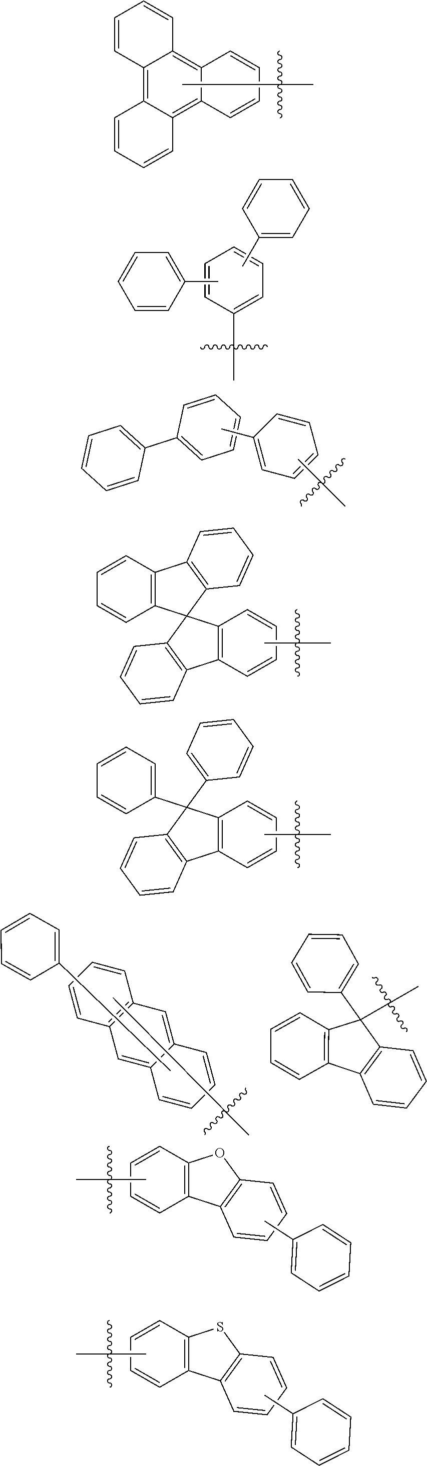

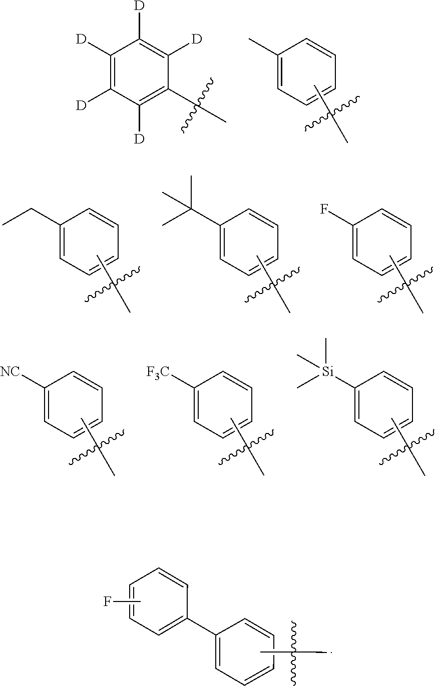

Optionally, Ar₂ is selected from the group consisting of the following groups:

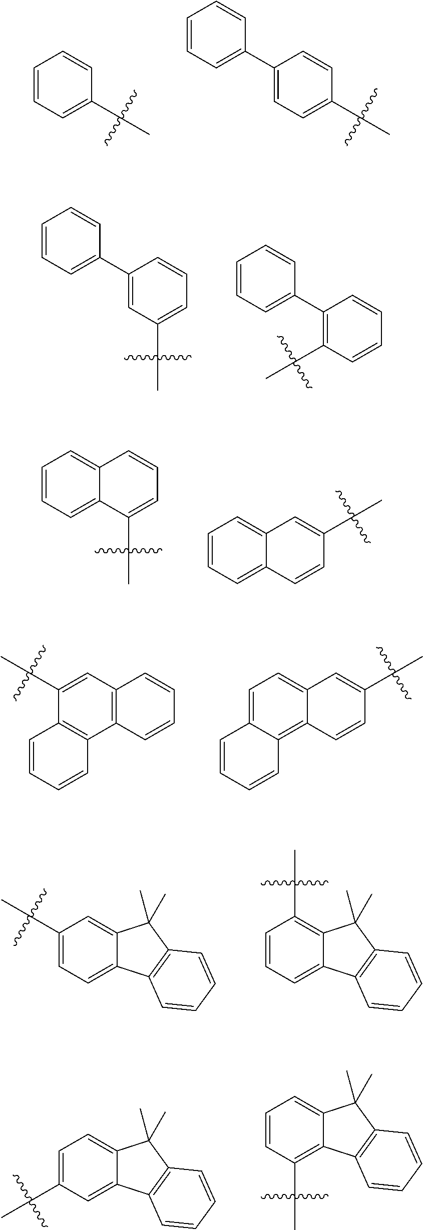

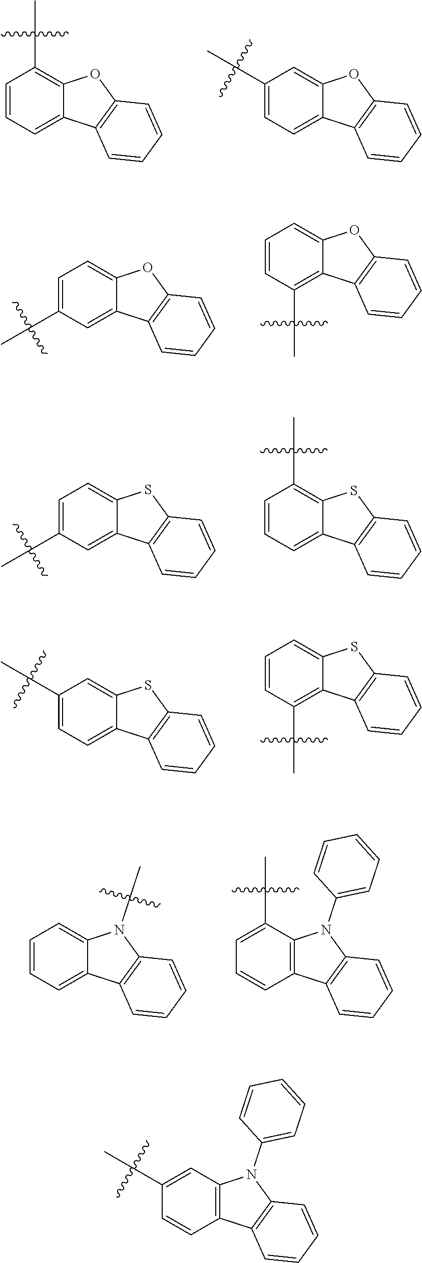

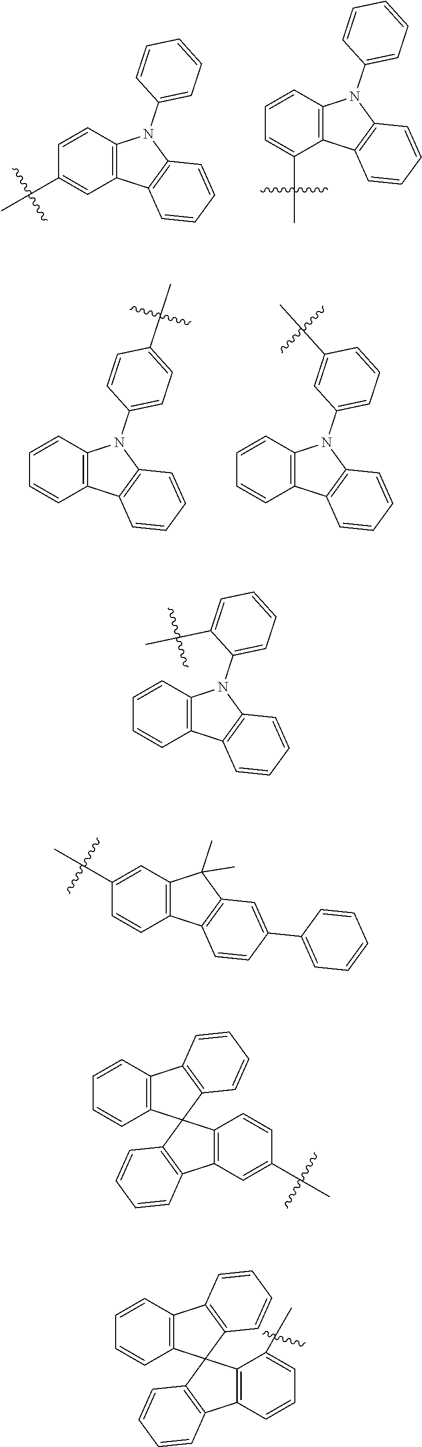

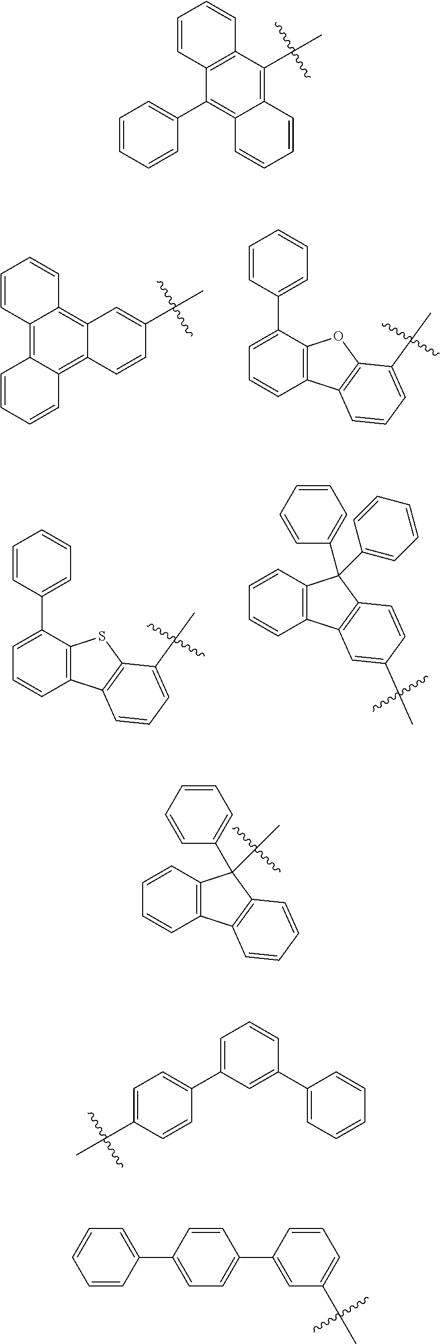

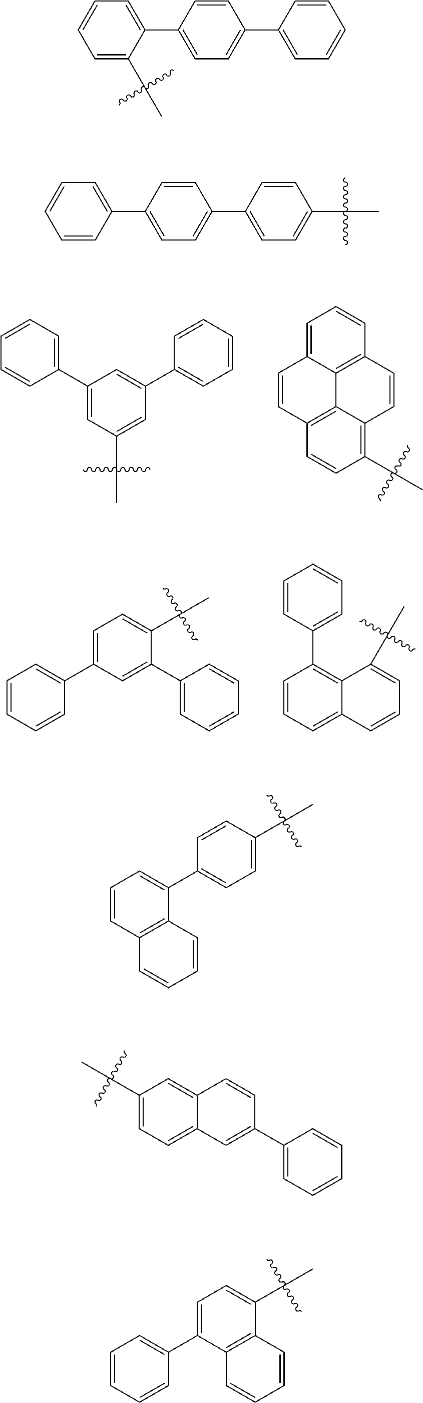

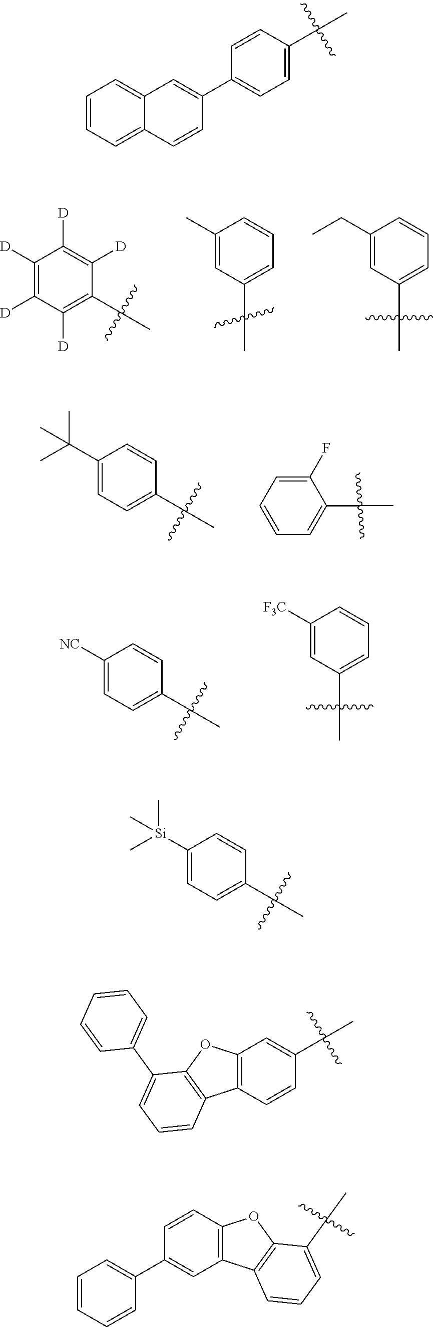

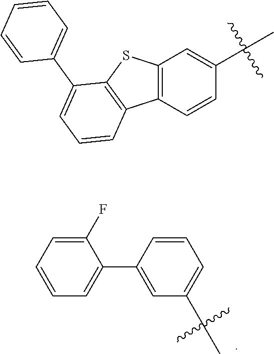 [SMILES: *c1ccc2c(c1)sc1c(-c3ccccc3)cccc12 ; *c1cccc(-c2ccccc2F)c1]

Optionally, L₂ is selected from a single bond, or the group consisting of the following groups:

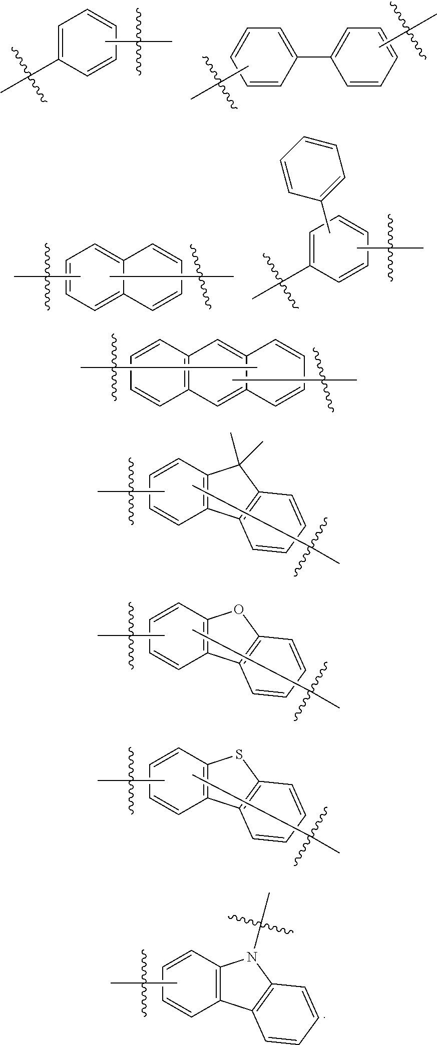

Optionally, L₂ is selected from a single bond, or the group consisting of the following groups:

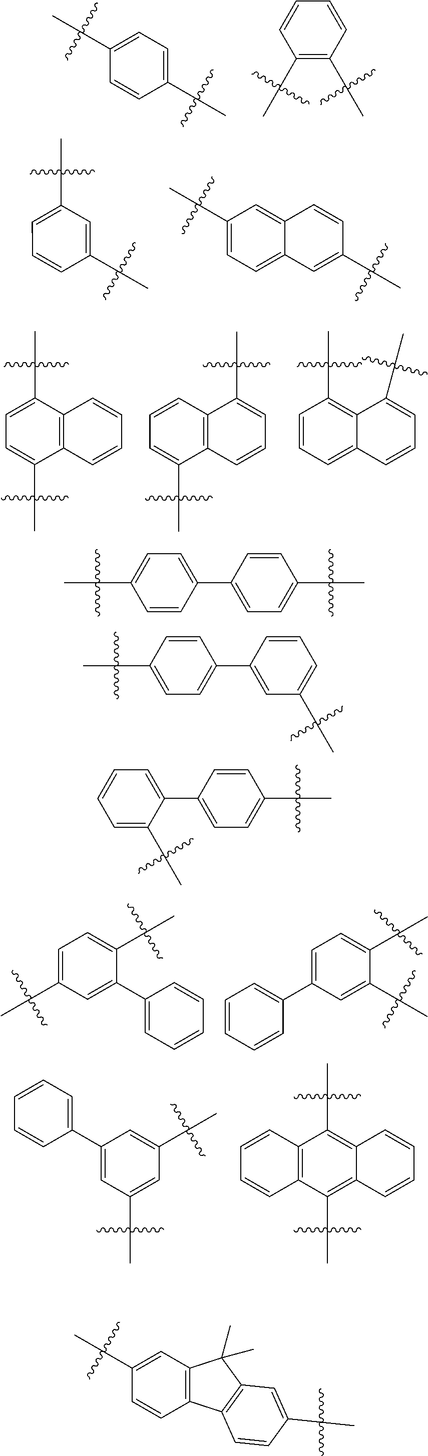

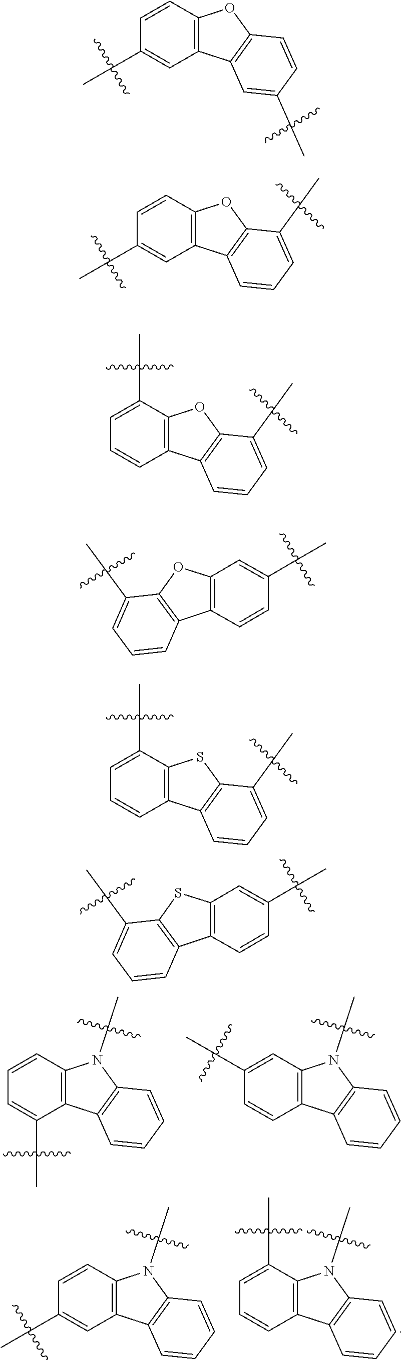

Optionally,

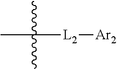

is selected from the group consisting of the following groups:

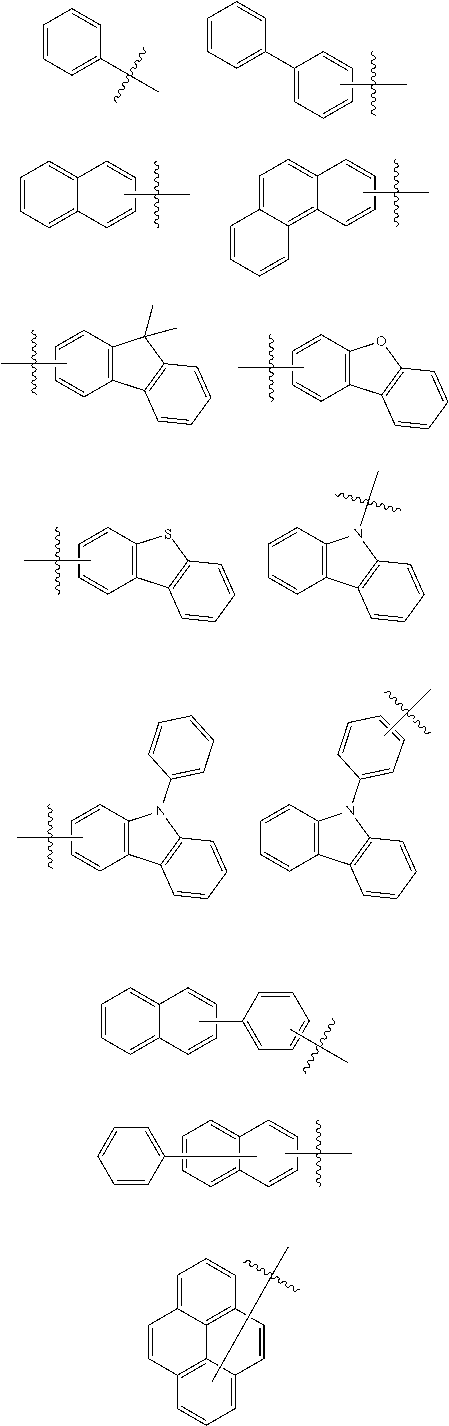

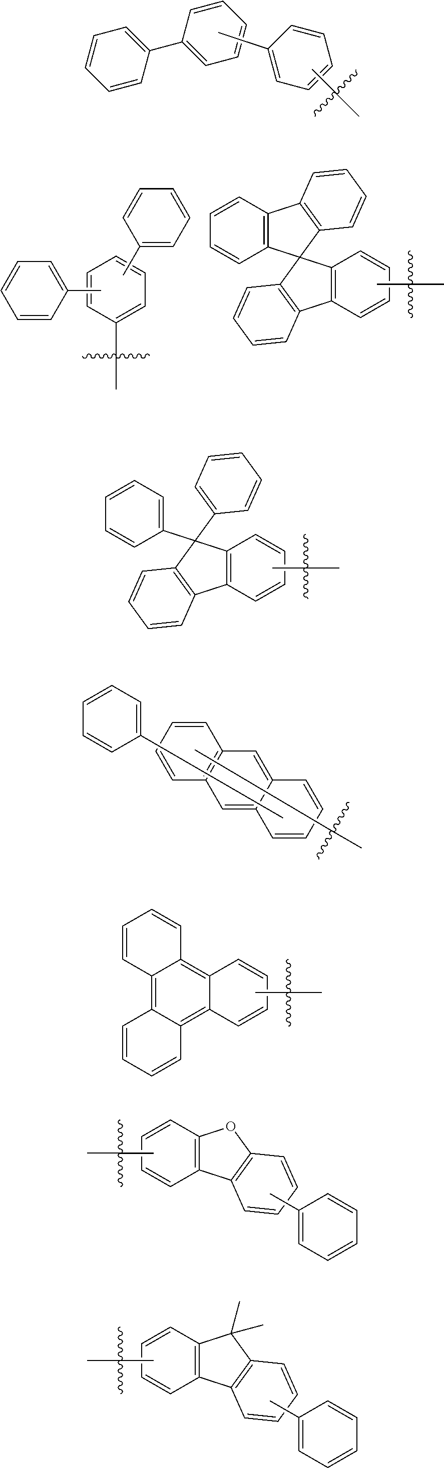

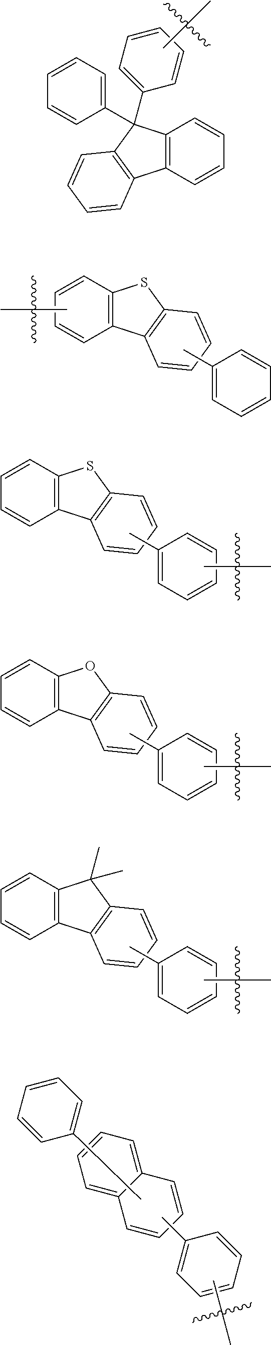

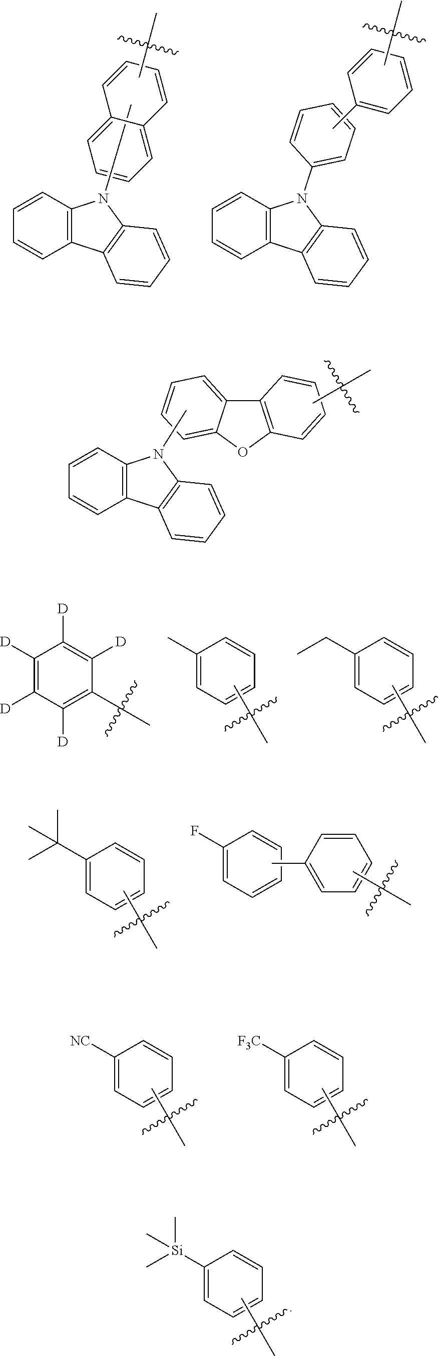

In some embodiments,

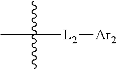

is selected from the group consisting of the following groups:

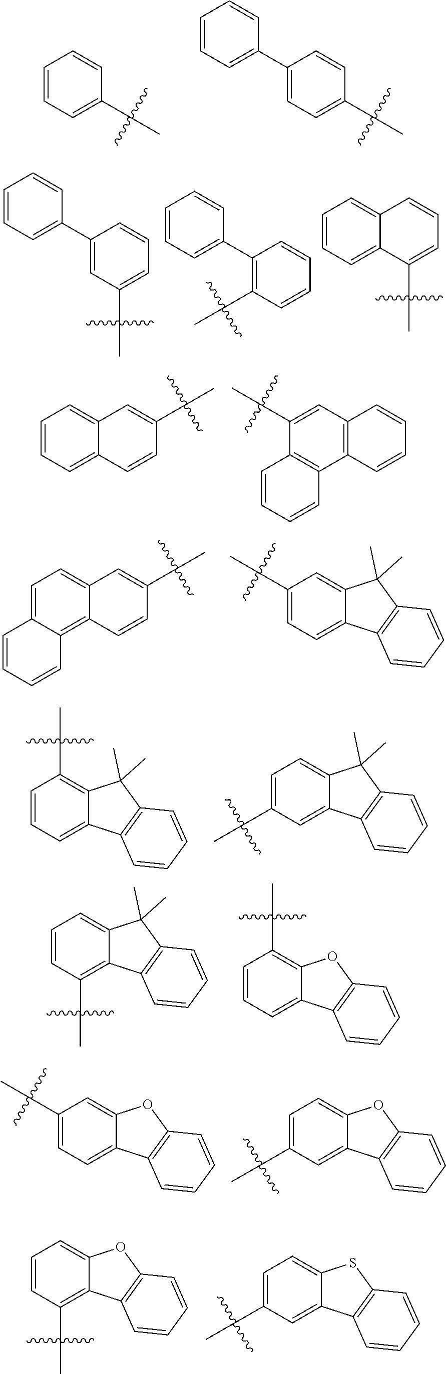

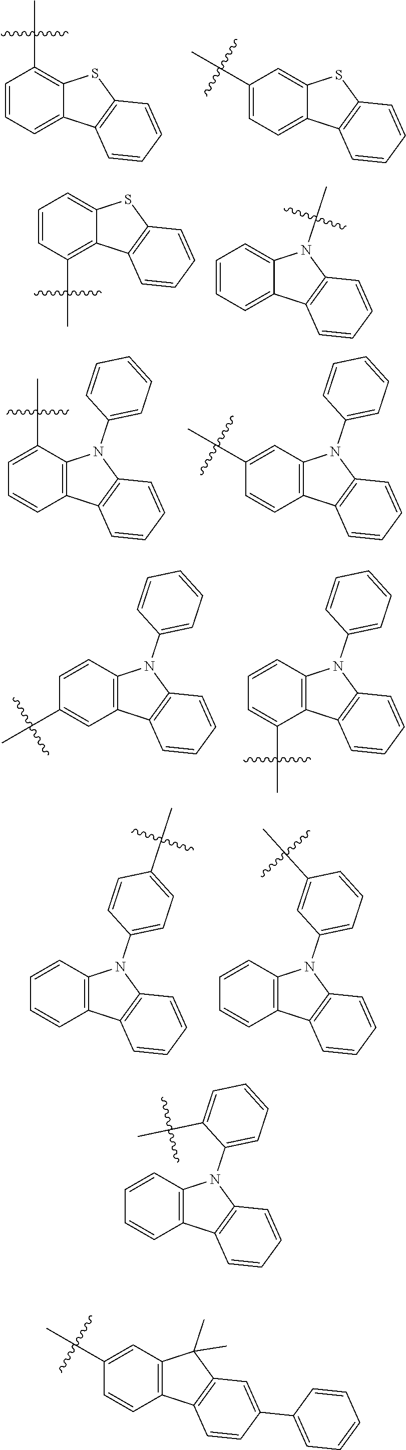

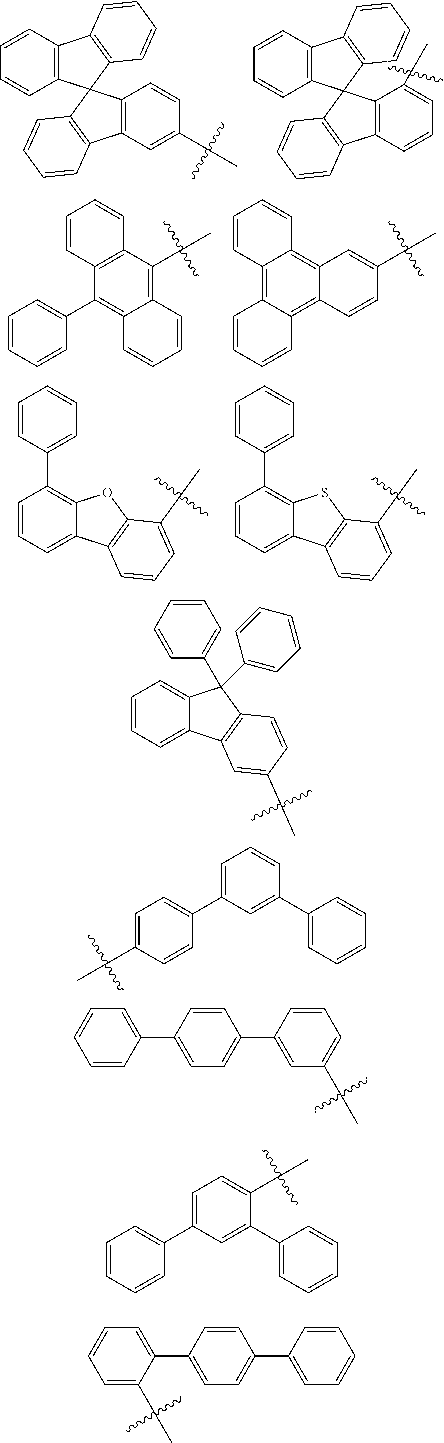

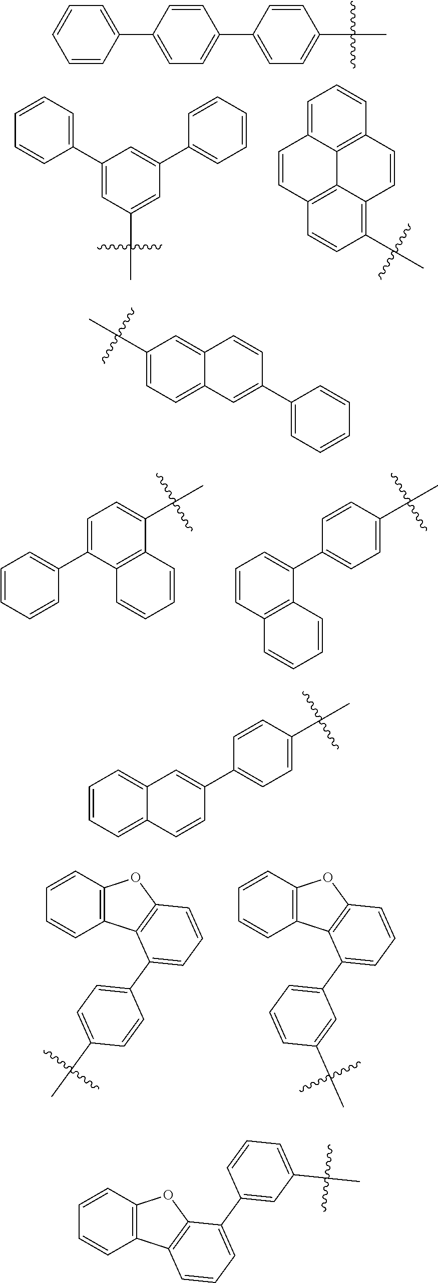

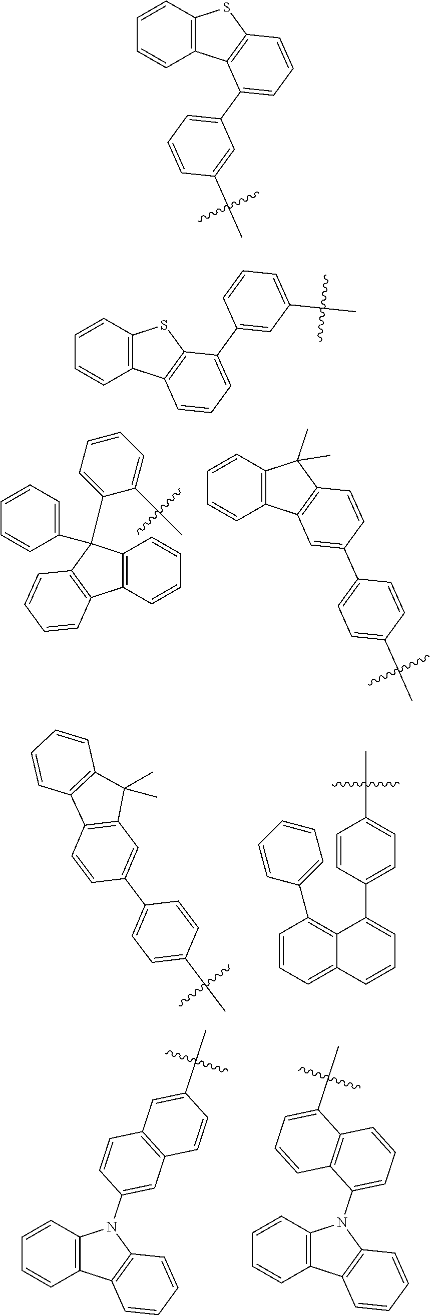

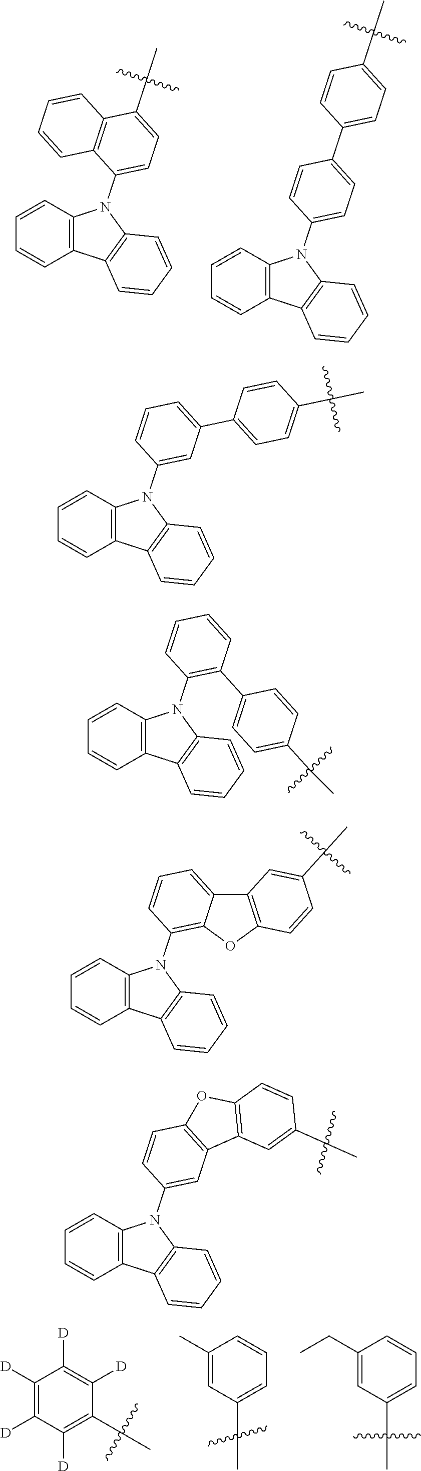

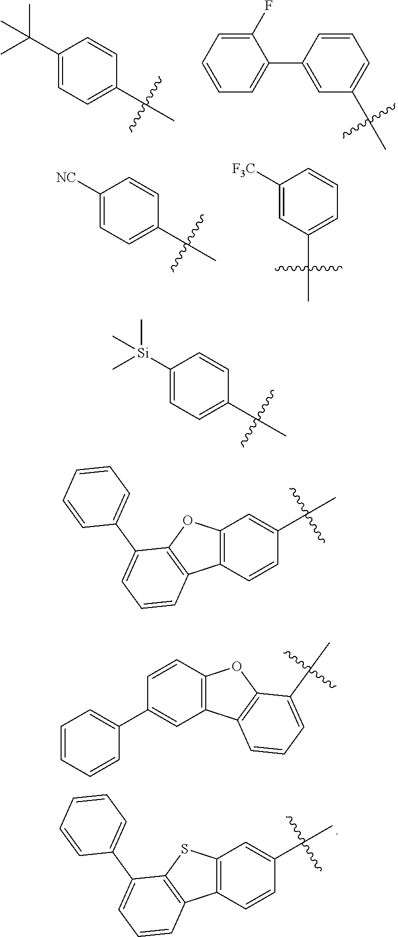

In some embodiments, R₁, R₂, R₃ and R₄ are each independently selected from a hydrogen, a deuterium, a fluorine, a cyano, a methyl, an ethyl, an isopropyl, a tert-butyl, a trimethylsilyl, a trifluoromethyl, a cyclopentane, a cyclohexane, an adamantane, a deuterated phenyl, a phenyl, a naphthyl, a biphenyl, a phenanthryl, a pyridyl, a quinolyl, 9,9-dimethylfluorenyl, a dibenzofuranyl, a dibenzothienyl, N-carbazolyl, or N-phenylcarbazolyl.

Optionally, the organic compound of the present application is selected from the group consisting of the following compounds:

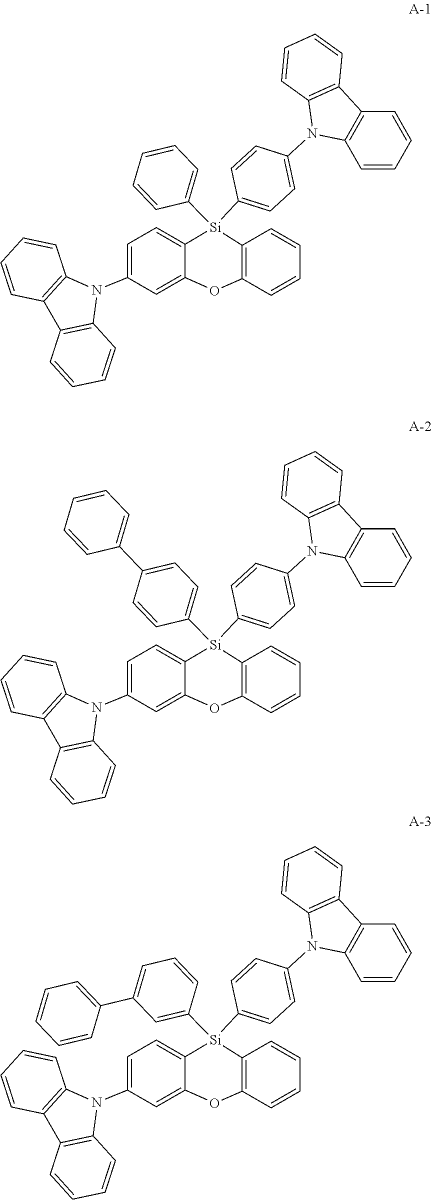 [SMILES: c1ccc([Si]2(c3ccc(-n4c5ccccc5c5ccccc54)cc3)c3ccccc3Oc3cc(-n4c5ccccc5c5ccccc54)ccc32)cc1 ; c1ccc(-c2ccc([Si]3(c4ccc(-n5c6ccccc6c6ccccc65)cc4)c4ccccc4Oc4cc(-n5c6ccccc6c6ccccc65)ccc43)cc2)cc1 ; c1ccc(-c2cccc([Si]3(c4ccc(-n5c6ccccc6c6ccccc65)cc4)c4ccccc4Oc4cc(-n5c6ccccc6c6ccccc65)ccc43)c2)cc1]

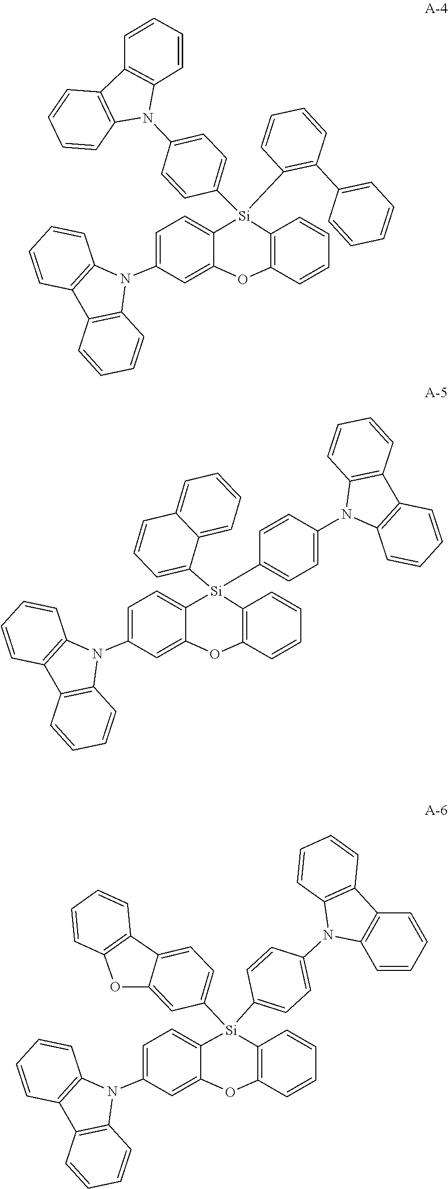 [SMILES: c1ccc(-c2ccccc2[Si]2(c3ccc(-n4c5ccccc5c5ccccc54)cc3)c3ccccc3Oc3cc(-n4c5ccccc5c5ccccc54)ccc32)cc1 ; c1ccc2c(c1)Oc1cc(-n3c4ccccc4c4ccccc43)ccc1[Si]2(c1ccc(-n2c3ccccc3c3ccccc32)cc1)c1cccc2ccccc12 ; c1ccc2c(c1)Oc1cc(-n3c4ccccc4c4ccccc43)ccc1[Si]2(c1ccc(-n2c3ccccc3c3ccccc32)cc1)c1ccc2c(c1)oc1ccccc12]

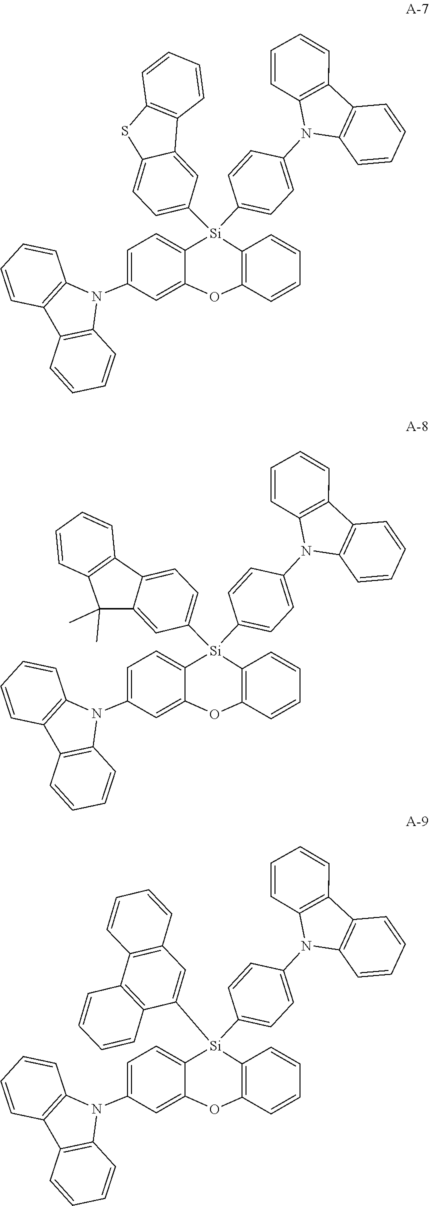 [SMILES: c1ccc2c(c1)Oc1cc(-n3c4ccccc4c4ccccc43)ccc1[Si]2(c1ccc(-n2c3ccccc3c3ccccc32)cc1)c1ccc2sc3ccccc3c2c1 ; CC1(C)c2ccccc2-c2ccc([Si]3(c4ccc(-n5c6ccccc6c6ccccc65)cc4)c4ccccc4Oc4cc(-n5c6ccccc6c6ccccc65)ccc43)cc21 ; c1ccc2c(c1)Oc1cc(-n3c4ccccc4c4ccccc43)ccc1[Si]2(c1ccc(-n2c3ccccc3c3ccccc32)cc1)c1cc2ccccc2c2ccccc12]

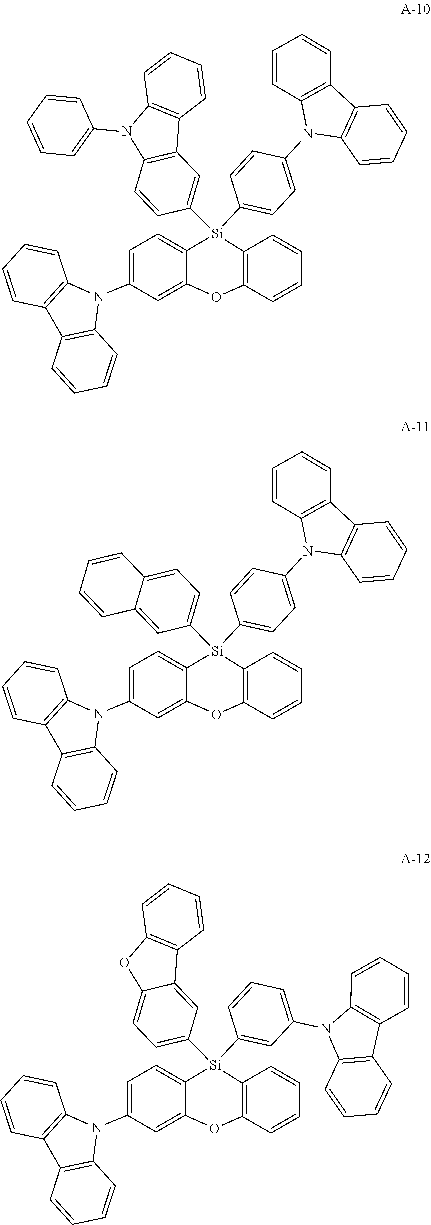 [SMILES: c1ccc(-n2c3ccccc3c3cc([Si]4(c5ccc(-n6c7ccccc7c7ccccc76)cc5)c5ccccc5Oc5cc(-n6c7ccccc7c7ccccc76)ccc54)ccc32)cc1 ; c1ccc2c(c1)Oc1cc(-n3c4ccccc4c4ccccc43)ccc1[Si]2(c1ccc(-n2c3ccccc3c3ccccc32)cc1)c1ccc2ccccc2c1 ; c1cc(-n2c3ccccc3c3ccccc32)cc([Si]2(c3ccc4oc5ccccc5c4c3)c3ccccc3Oc3cc(-n4c5ccccc5c5ccccc54)ccc32)c1]

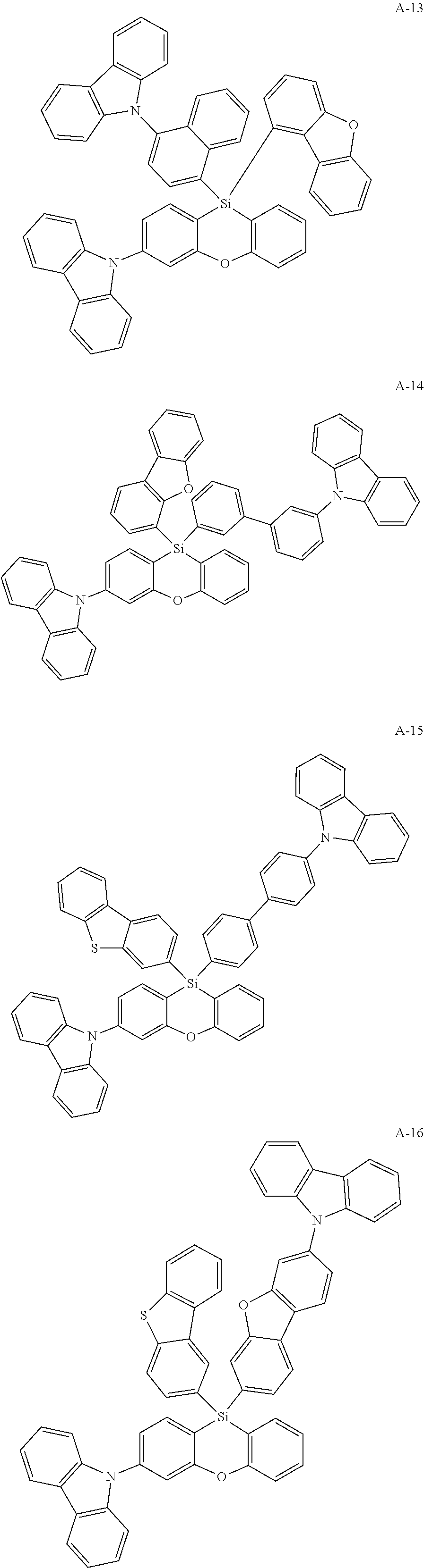 [SMILES: c1ccc2c(c1)Oc1cc(-n3c4ccccc4c4ccccc43)ccc1[Si]2(c1ccc(-n2c3ccccc3c3ccccc32)c2ccccc12)c1cccc2oc3ccccc3c12 ; c1cc(-c2cccc([Si]3(c4cccc5c4oc4ccccc45)c4ccccc4Oc4cc(-n5c6ccccc6c6ccccc65)ccc43)c2)cc(-n2c3ccccc3c3ccccc32)c1 ; c1ccc2c(c1)Oc1cc(-n3c4ccccc4c4ccccc43)ccc1[Si]2(c1ccc(-c2ccc(-n3c4ccccc4c4ccccc43)cc2)cc1)c1ccc2c(c1)sc1ccccc12 ; c1ccc2c(c1)Oc1cc(-n3c4ccccc4c4ccccc43)ccc1[Si]2(c1ccc2c(c1)oc1cc(-n3c4ccccc4c4ccccc43)ccc12)c1ccc2sc3ccccc3c2c1]

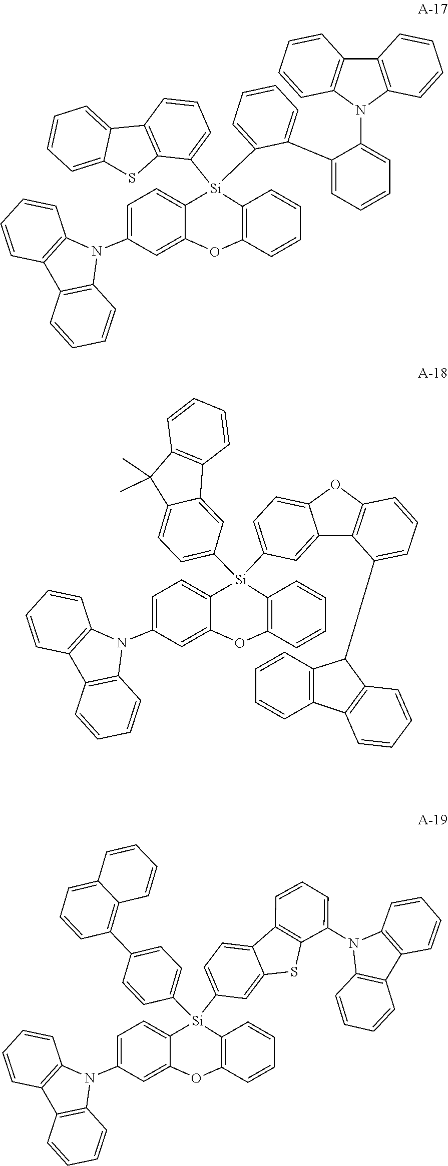 [SMILES: c1ccc2c(c1)Oc1cc(-n3c4ccccc4c4ccccc43)ccc1[Si]2(c1ccccc1-c1ccccc1-n1c2ccccc2c2ccccc21)c1cccc2c1sc1ccccc12 ; CC1(C)c2ccccc2-c2cc([Si]3(c4ccc5oc6cccc(C7c8ccccc8-c8ccccc87)c6c5c4)c4ccccc4Oc4cc(-n5c6ccccc6c6ccccc65)ccc43)ccc21 ; c1ccc2c(c1)Oc1cc(-n3c4ccccc4c4ccccc43)ccc1[Si]2(c1ccc(-c2cccc3ccccc23)cc1)c1ccc2c(c1)sc1c(-n3c4ccccc4c4ccccc43)cccc12]

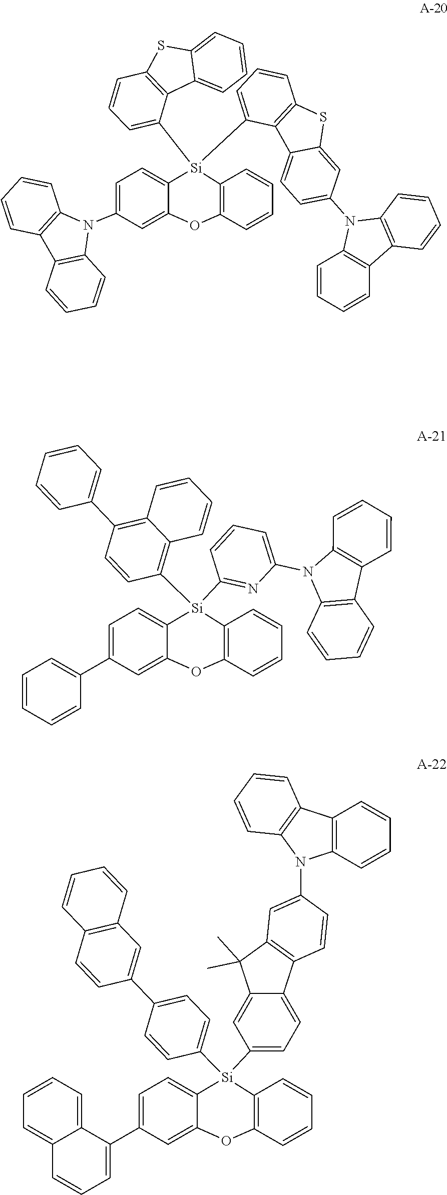 [SMILES: c1ccc2c(c1)Oc1cc(-n3c4ccccc4c4ccccc43)ccc1[Si]2(c1cccc2sc3ccccc3c12)c1cccc2sc3cc(-n4c5ccccc5c5ccccc54)ccc3c12 ; c1ccc(-c2ccc3c(c2)Oc2ccccc2[Si]3(c2cccc(-n3c4ccccc4c4ccccc43)n2)c2ccc(-c3ccccc3)c3ccccc23)cc1 ; CC1(C)c2cc(-n3c4ccccc4c4ccccc43)ccc2-c2ccc([Si]3(c4ccc(-c5ccc6ccccc6c5)cc4)c4ccccc4Oc4cc(-c5cccc6ccccc56)ccc43)cc21]

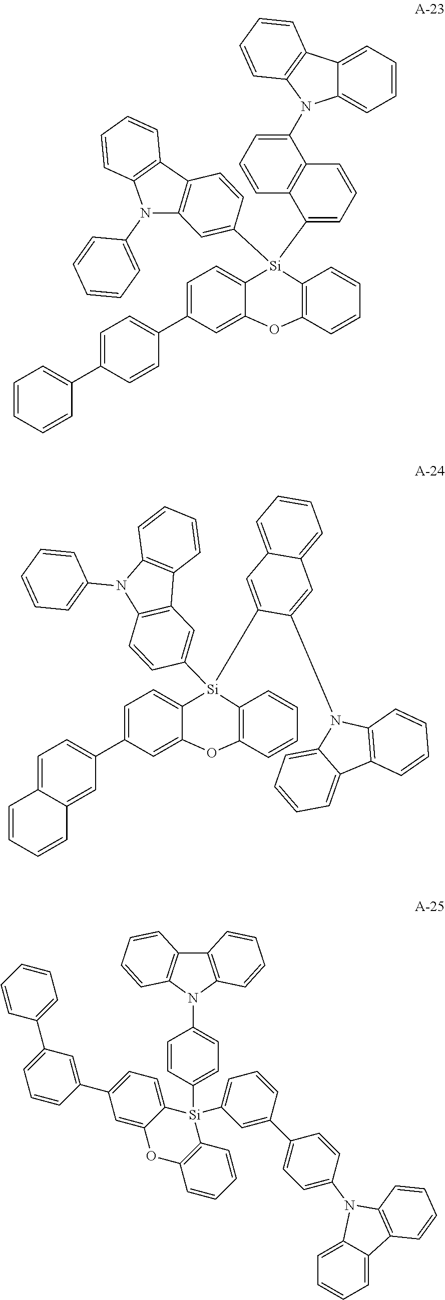 [SMILES: c1ccc(-c2ccc(-c3ccc4c(c3)Oc3ccccc3[Si]4(c3ccc4c5ccccc5n(-c5ccccc5)c4c3)c3cccc4c(-n5c6ccccc6c6ccccc65)cccc34)cc2)cc1 ; c1ccc(-n2c3ccccc3c3cc([Si]4(c5cc6ccccc6cc5-n5c6ccccc6c6ccccc65)c5ccccc5Oc5cc(-c6ccc7ccccc7c6)ccc54)ccc32)cc1 ; c1ccc(-c2cccc(-c3ccc4c(c3)Oc3ccccc3[Si]4(c3ccc(-n4c5ccccc5c5ccccc54)cc3)c3cccc(-c4ccc(-n5c6ccccc6c6ccccc65)cc4)c3)c2)cc1]

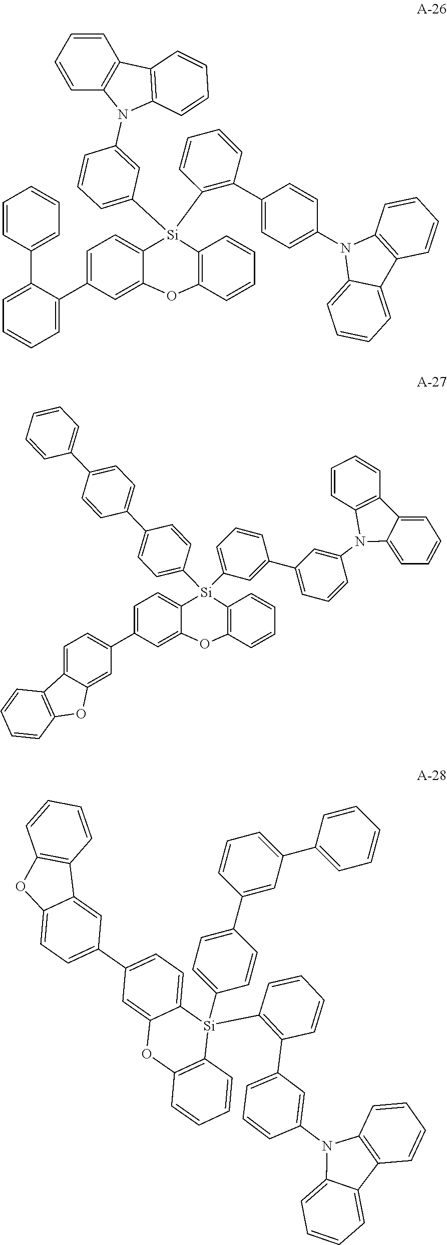 [SMILES: c1ccc(-c2ccccc2-c2ccc3c(c2)Oc2ccccc2[Si]3(c2cccc(-n3c4ccccc4c4ccccc43)c2)c2ccccc2-c2ccc(-n3c4ccccc4c4ccccc43)cc2)cc1 ; c1ccc(-c2ccc(-c3ccc([Si]4(c5cccc(-c6cccc(-n7c8ccccc8c8ccccc87)c6)c5)c5ccccc5Oc5cc(-c6ccc7c(c6)oc6ccccc67)ccc54)cc3)cc2)cc1 ; c1ccc(-c2cccc(-c3ccc([Si]4(c5ccccc5-c5cccc(-n6c7ccccc7c7ccccc76)c5)c5ccccc5Oc5cc(-c6ccc7oc8ccccc8c7c6)ccc54)cc3)c2)cc1]

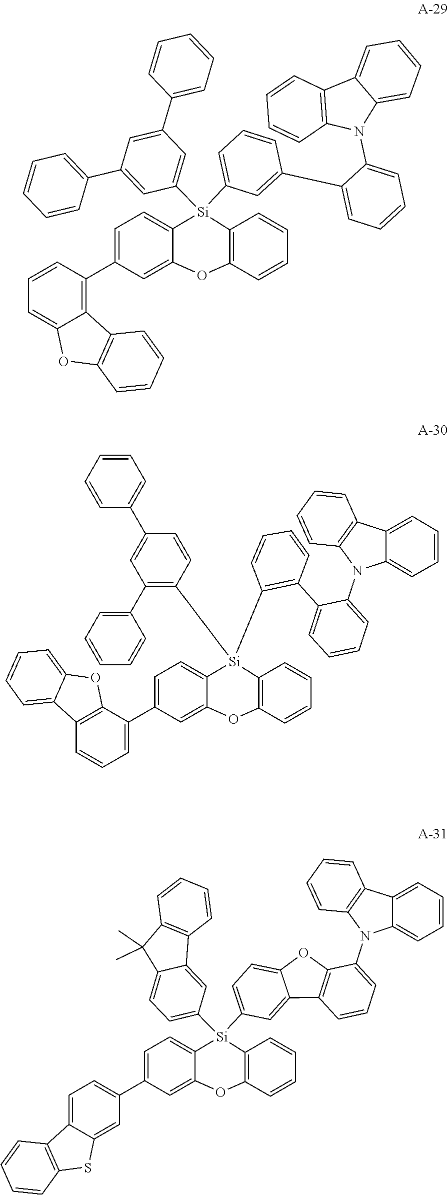 [SMILES: c1ccc(-c2cc(-c3ccccc3)cc([Si]3(c4cccc(-c5ccccc5-n5c6ccccc6c6ccccc65)c4)c4ccccc4Oc4cc(-c5cccc6oc7ccccc7c56)ccc43)c2)cc1 ; c1ccc(-c2ccc([Si]3(c4ccccc4-c4ccccc4-n4c5ccccc5c5ccccc54)c4ccccc4Oc4cc(-c5cccc6c5oc5ccccc56)ccc43)c(-c3ccccc3)c2)cc1 ; CC1(C)c2ccccc2-c2cc([Si]3(c4ccc5oc6c(-n7c8ccccc8c8ccccc87)cccc6c5c4)c4ccccc4Oc4cc(-c5ccc6c(c5)sc5ccccc56)ccc43)ccc21]

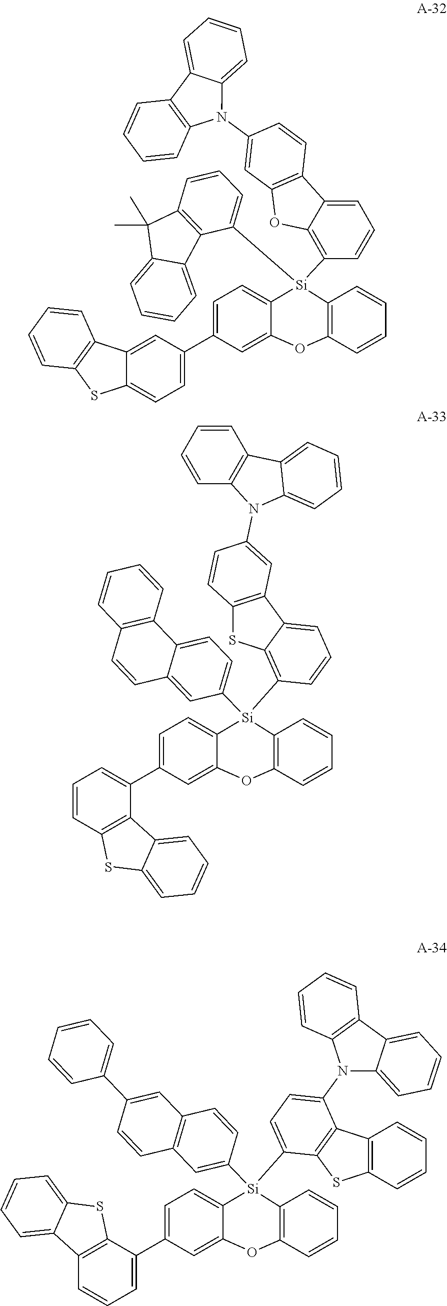

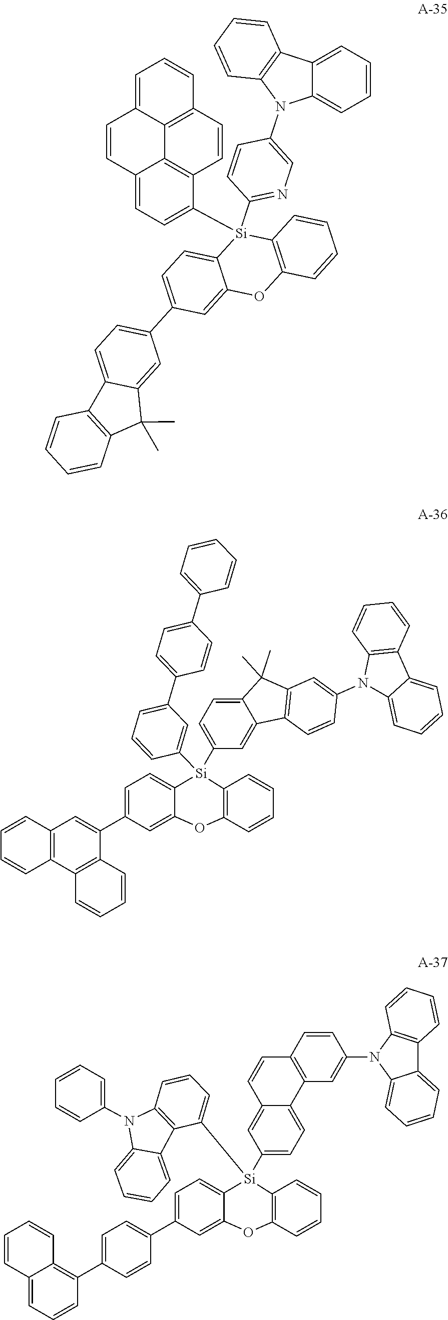 [SMILES: CC1(C)c2ccccc2-c2ccc(-c3ccc4c(c3)Oc3ccccc3[Si]4(c3ccc(-n4c5ccccc5c5ccccc54)cn3)c3ccc4ccc5cccc6ccc3c4c56)cc21 ; CC1(C)c2ccc([Si]3(c4cccc(-c5ccc(-c6ccccc6)cc5)c4)c4ccccc4Oc4cc(-c5cc6ccccc6c6ccccc56)ccc43)cc2-c2ccc(-n3c4ccccc4c4ccccc43)cc21 ; c1ccc(-n2c3ccccc3c3c([Si]4(c5ccc6c(ccc7ccc(-n8c9ccccc9c9ccccc98)cc76)c5)c5ccccc5Oc5cc(-c6ccc(-c7cccc8ccccc78)cc6)ccc54)cccc32)cc1]

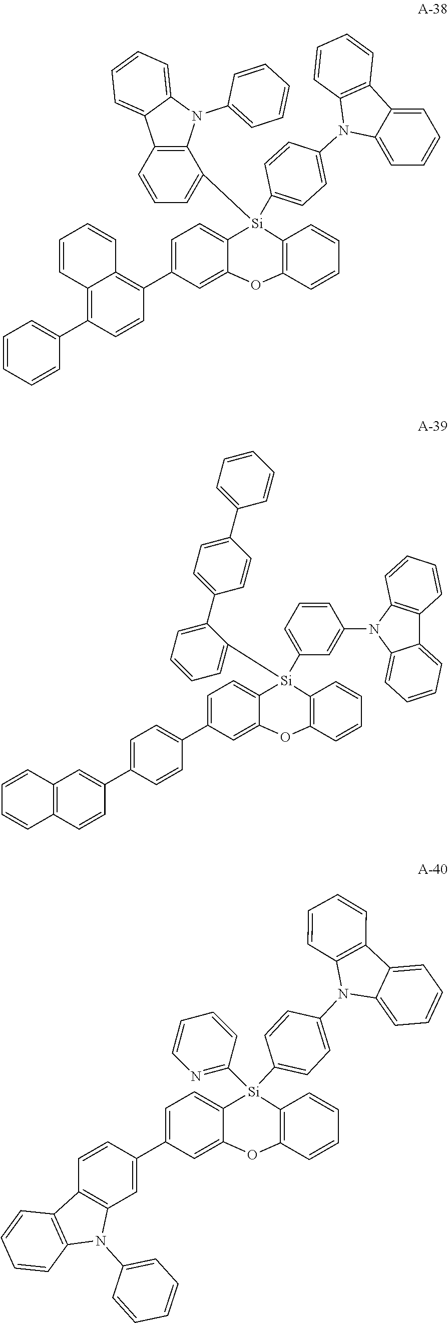 [SMILES: c1ccc(-c2ccc(-c3ccc4c(c3)Oc3ccccc3[Si]4(c3ccc(-n4c5ccccc5c5ccccc54)cc3)c3cccc4c5ccccc5n(-c5ccccc5)c34)c3ccccc23)cc1 ; c1ccc(-c2ccc(-c3ccccc3[Si]3(c4cccc(-n5c6ccccc6c6ccccc65)c4)c4ccccc4Oc4cc(-c5ccc(-c6ccc7ccccc7c6)cc5)ccc43)cc2)cc1 ; c1ccc(-n2c3ccccc3c3ccc(-c4ccc5c(c4)Oc4ccccc4[Si]5(c4ccc(-n5c6ccccc6c6ccccc65)cc4)c4ccccn4)cc32)cc1]

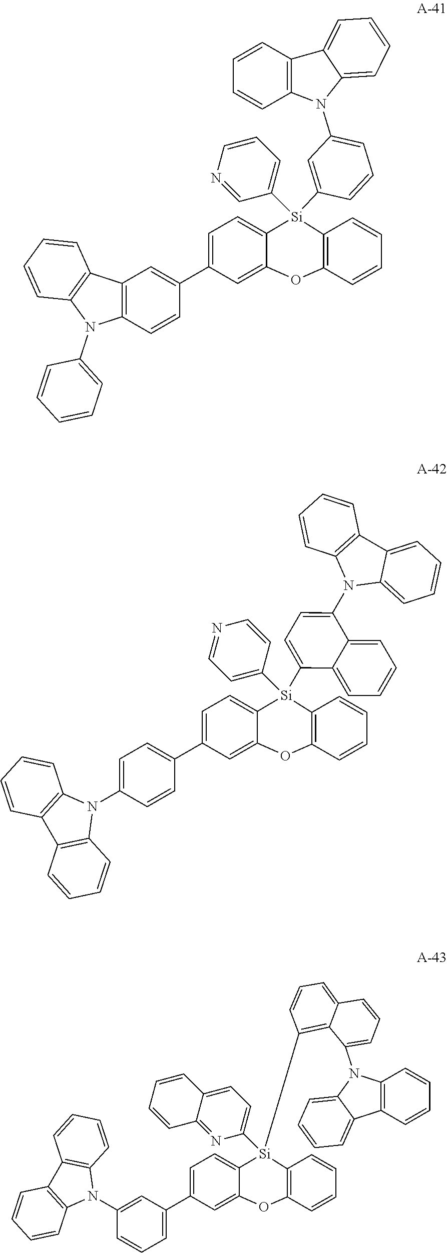

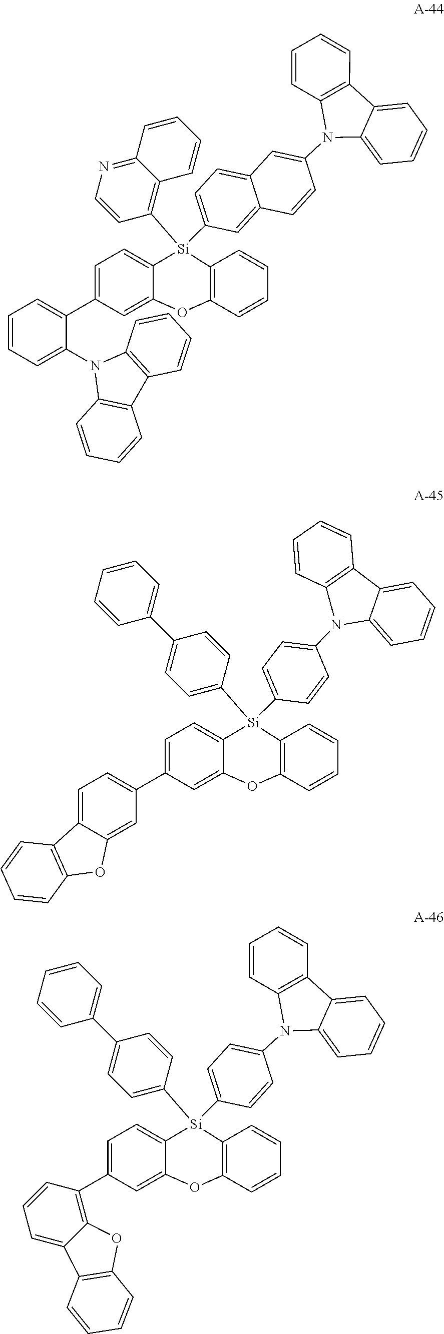 [SMILES: c1ccc2c(c1)Oc1cc(-c3ccccc3-n3c4ccccc4c4ccccc43)ccc1[Si]2(c1ccc2cc(-n3c4ccccc4c4ccccc43)ccc2c1)c1ccnc2ccccc12 ; c1ccc(-c2ccc([Si]3(c4ccc(-n5c6ccccc6c6ccccc65)cc4)c4ccccc4Oc4cc(-c5ccc6c(c5)oc5ccccc56)ccc43)cc2)cc1 ; c1ccc(-c2ccc([Si]3(c4ccc(-n5c6ccccc6c6ccccc65)cc4)c4ccccc4Oc4cc(-c5cccc6c5oc5ccccc56)ccc43)cc2)cc1]

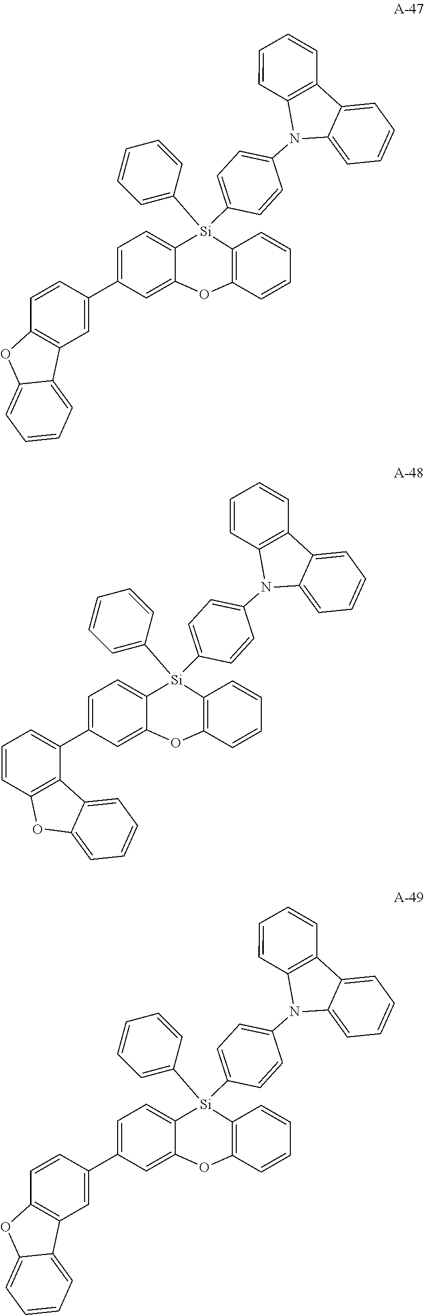 [SMILES: c1ccc([Si]2(c3ccc(-n4c5ccccc5c5ccccc54)cc3)c3ccccc3Oc3cc(-c4ccc5oc6ccccc6c5c4)ccc32)cc1 ; c1ccc([Si]2(c3ccc(-n4c5ccccc5c5ccccc54)cc3)c3ccccc3Oc3cc(-c4cccc5oc6ccccc6c45)ccc32)cc1 ; c1ccc([Si]2(c3ccc(-n4c5ccccc5c5ccccc54)cc3)c3ccccc3Oc3cc(-c4ccc5oc6ccccc6c5c4)ccc32)cc1]

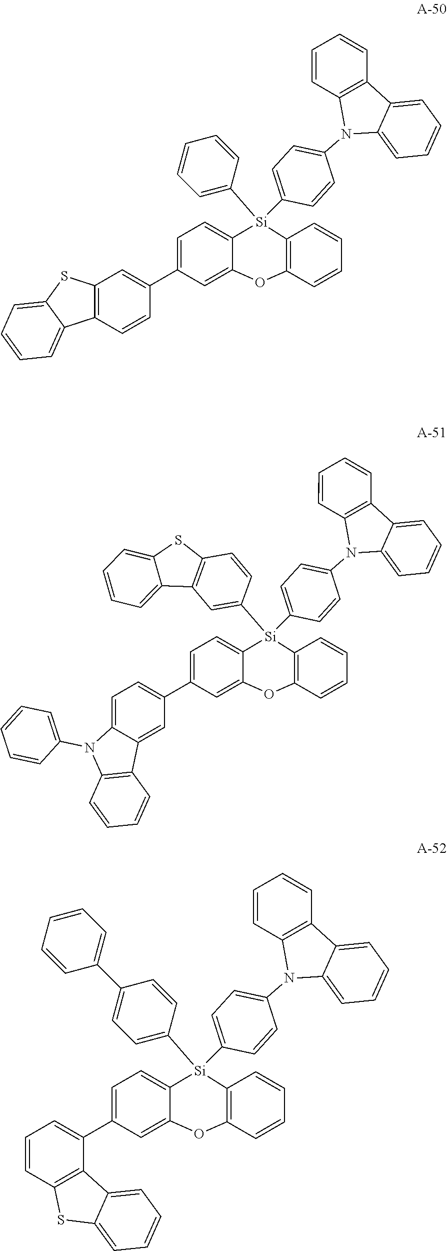 [SMILES: c1ccc([Si]2(c3ccc(-n4c5ccccc5c5ccccc54)cc3)c3ccccc3Oc3cc(-c4ccc5c(c4)sc4ccccc45)ccc32)cc1 ; c1ccc(-n2c3ccccc3c3cc(-c4ccc5c(c4)Oc4ccccc4[Si]5(c4ccc(-n5c6ccccc6c6ccccc65)cc4)c4ccc5sc6ccccc6c5c4)ccc32)cc1 ; c1ccc(-c2ccc([Si]3(c4ccc(-n5c6ccccc6c6ccccc65)cc4)c4ccccc4Oc4cc(-c5cccc6sc7ccccc7c56)ccc43)cc2)cc1]

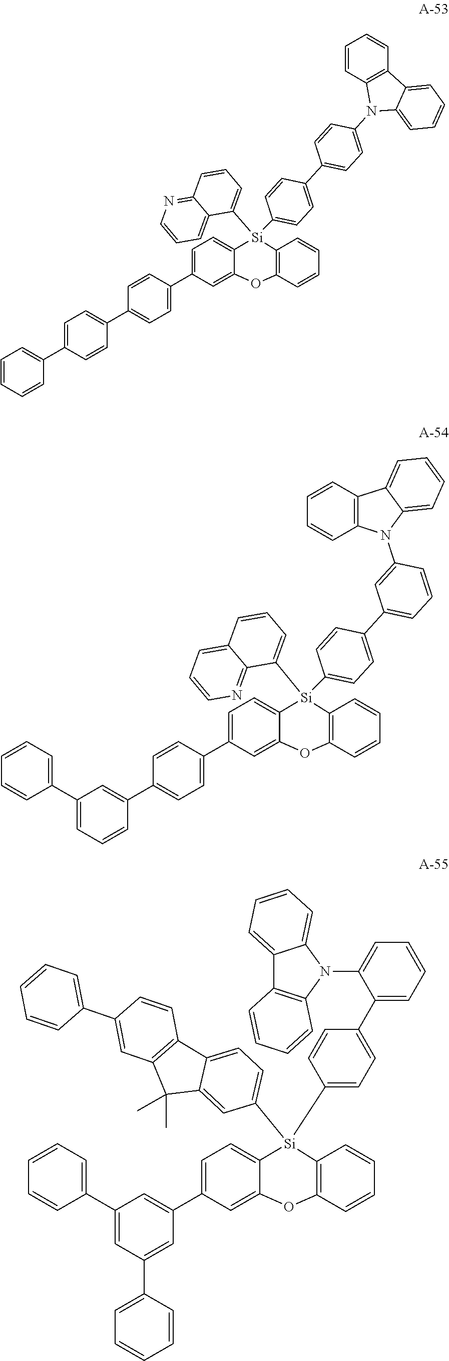 [SMILES: c1ccc(-c2ccc(-c3ccc(-c4ccc5c(c4)Oc4ccccc4[Si]5(c4ccc(-c5ccc(-n6c7ccccc7c7ccccc76)cc5)cc4)c4cccc5ncccc45)cc3)cc2)cc1 ; c1ccc(-c2cccc(-c3ccc(-c4ccc5c(c4)Oc4ccccc4[Si]5(c4ccc(-c5cccc(-n6c7ccccc7c7ccccc76)c5)cc4)c4cccc5cccnc45)cc3)c2)cc1 ; CC1(C)c2cc(-c3ccccc3)ccc2-c2ccc([Si]3(c4ccc(-c5ccccc5-n5c6ccccc6c6ccccc65)cc4)c4ccccc4Oc4cc(-c5cc(-c6ccccc6)cc(-c6ccccc6)c5)ccc43)cc21]

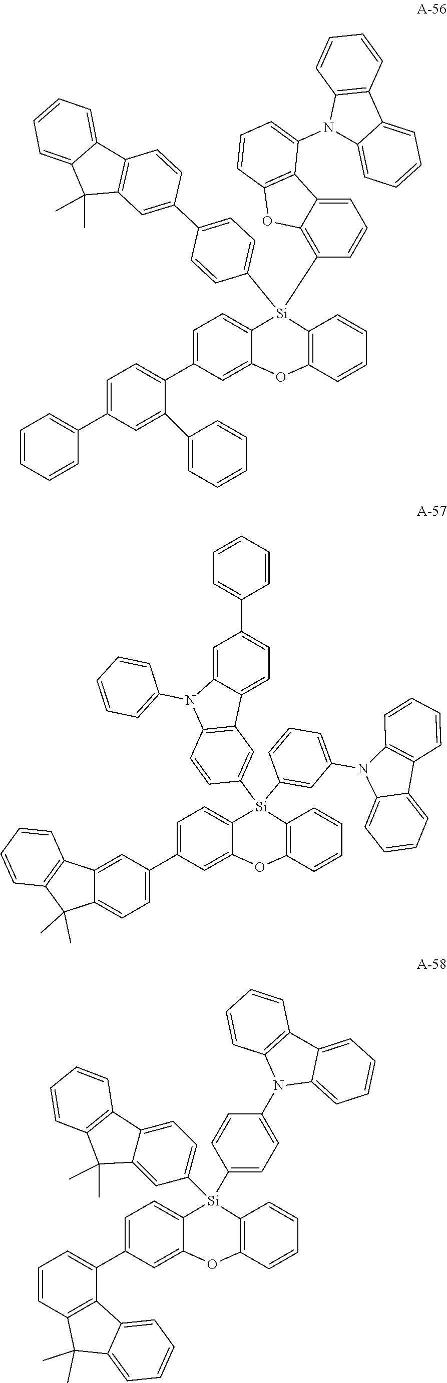 [SMILES: CC1(C)c2ccccc2-c2ccc(-c3ccc([Si]4(c5cccc6c5oc5cccc(-n7c8ccccc8c8ccccc87)c56)c5ccccc5Oc5cc(-c6ccc(-c7ccccc7)cc6-c6ccccc6)ccc54)cc3)cc21 ; CC1(C)c2ccccc2-c2cc(-c3ccc4c(c3)Oc3ccccc3[Si]4(c3cccc(-n4c5ccccc5c5ccccc54)c3)c3ccc4c(c3)c3ccc(-c5ccccc5)cc3n4-c3ccccc3)ccc21 ; CC1(C)c2ccccc2-c2ccc([Si]3(c4ccc(-n5c6ccccc6c6ccccc65)cc4)c4ccccc4Oc4cc(-c5cccc6c5-c5ccccc5C6(C)C)ccc43)cc21]

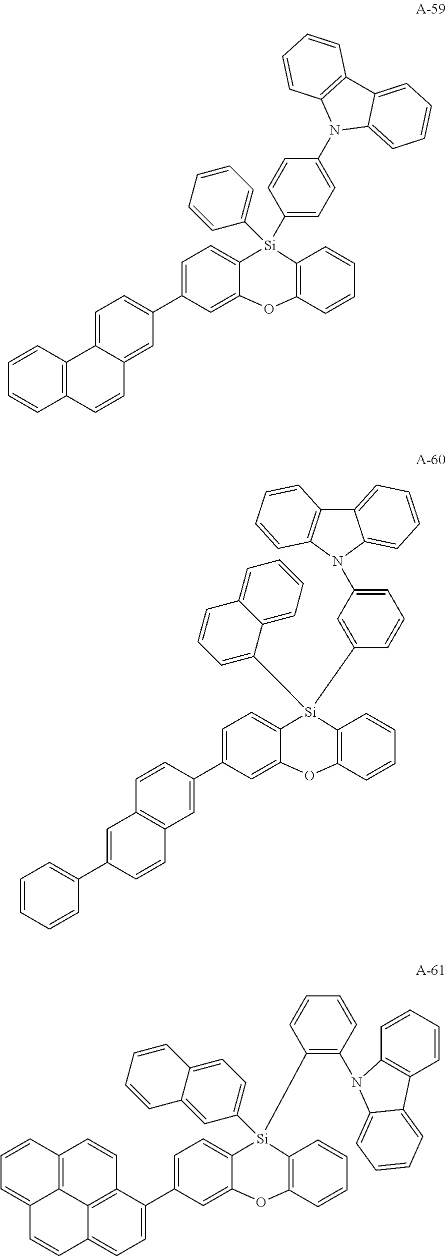 [SMILES: c1ccc([Si]2(c3ccc(-n4c5ccccc5c5ccccc54)cc3)c3ccccc3Oc3cc(-c4ccc5c(ccc6ccccc65)c4)ccc32)cc1 ; c1ccc(-c2ccc3cc(-c4ccc5c(c4)Oc4ccccc4[Si]5(c4cccc(-n5c6ccccc6c6ccccc65)c4)c4cccc5ccccc45)ccc3c2)cc1 ; c1ccc2c(c1)Oc1cc(-c3ccc4ccc5cccc6ccc3c4c56)ccc1[Si]2(c1ccc2ccccc2c1)c1ccccc1-n1c2ccccc2c2ccccc21]

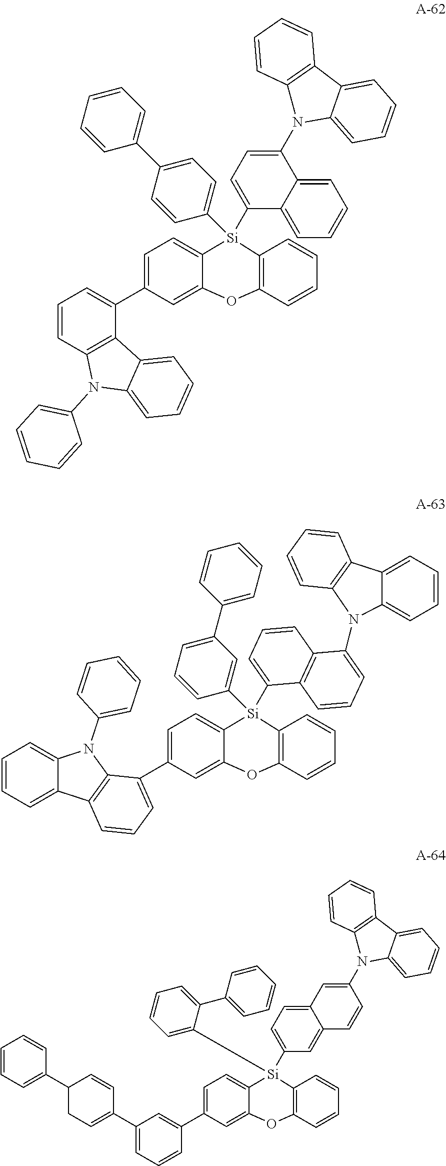 [SMILES: c1ccc(-c2ccc([Si]3(c4ccc(-n5c6ccccc6c6ccccc65)c5ccccc45)c4ccccc4Oc4cc(-c5cccc6c5c5ccccc5n6-c5ccccc5)ccc43)cc2)cc1 ; c1ccc(-c2cccc([Si]3(c4cccc5c(-n6c7ccccc7c7ccccc76)cccc45)c4ccccc4Oc4cc(-c5cccc6c7ccccc7n(-c7ccccc7)c56)ccc43)c2)cc1 ; C1=CC(c2ccccc2)CC=C1c1cccc(-c2ccc3c(c2)Oc2ccccc2[Si]3(c2ccc3cc(-n4c5ccccc5c5ccccc54)ccc3c2)c2ccccc2-c2ccccc2)c1]

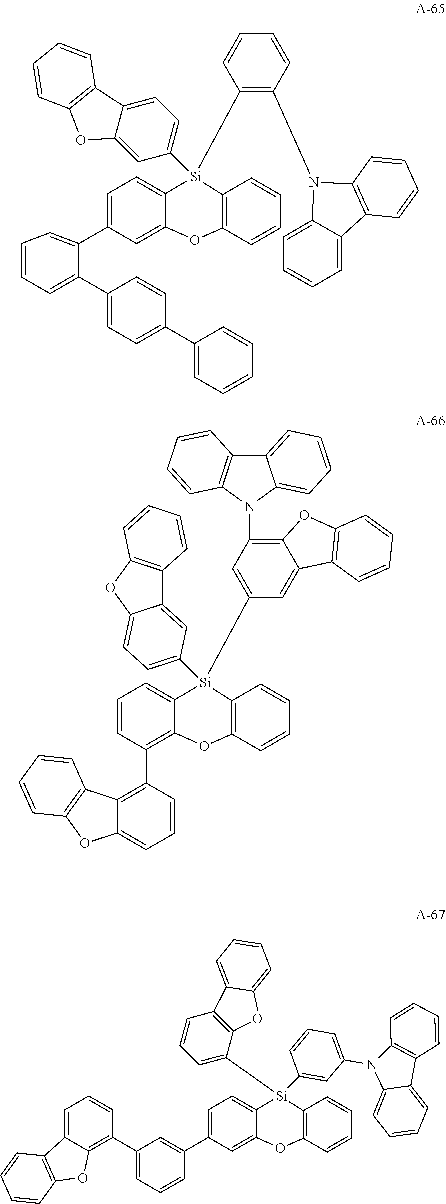

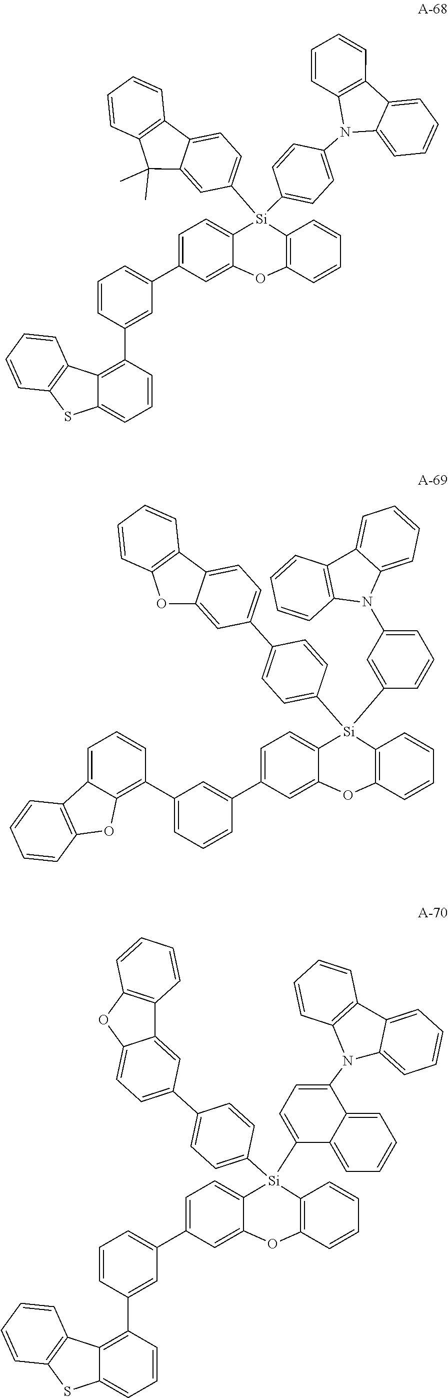 [SMILES: CC1(C)c2ccccc2-c2ccc([Si]3(c4ccc(-n5c6ccccc6c6ccccc65)cc4)c4ccccc4Oc4cc(-c5cccc(-c6cccc7sc8ccccc8c67)c5)ccc43)cc21 ; c1cc(-c2ccc3c(c2)Oc2ccccc2[Si]3(c2ccc(-c3ccc4c(c3)oc3ccccc34)cc2)c2cccc(-n3c4ccccc4c4ccccc43)c2)cc(-c2cccc3c2oc2ccccc23)c1 ; c1cc(-c2ccc3c(c2)Oc2ccccc2[Si]3(c2ccc(-c3ccc4oc5ccccc5c4c3)cc2)c2ccc(-n3c4ccccc4c4ccccc43)c3ccccc23)cc(-c2cccc3sc4ccccc4c23)c1]

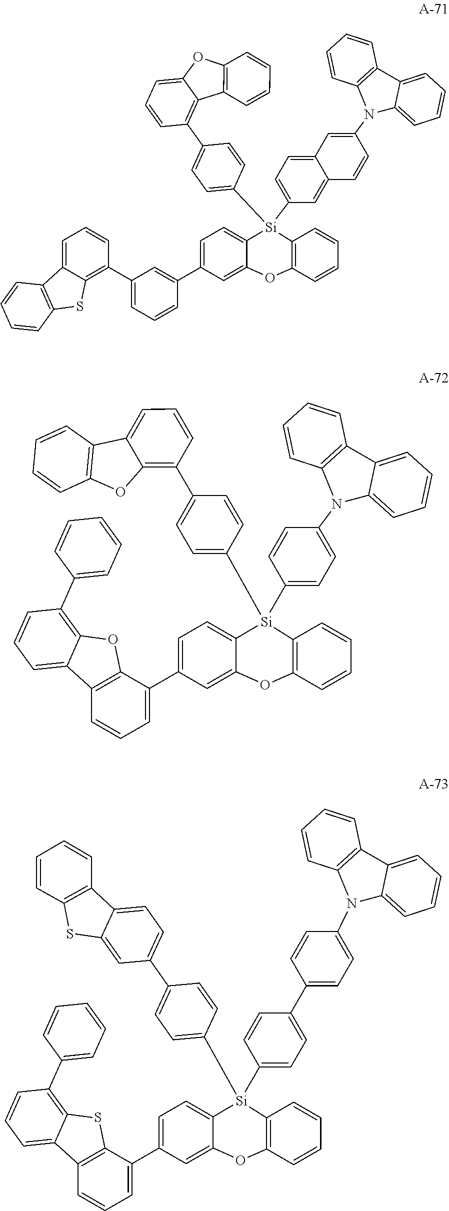 [SMILES: c1cc(-c2ccc3c(c2)Oc2ccccc2[Si]3(c2ccc(-c3cccc4oc5ccccc5c34)cc2)c2ccc3cc(-n4c5ccccc5c5ccccc54)ccc3c2)cc(-c2cccc3c2sc2ccccc23)c1 ; c1ccc(-c2cccc3c2oc2c(-c4ccc5c(c4)Oc4ccccc4[Si]5(c4ccc(-c5cccc6c5oc5ccccc56)cc4)c4ccc(-n5c6ccccc6c6ccccc65)cc4)cccc23)cc1 ; c1ccc(-c2cccc3c2sc2c(-c4ccc5c(c4)Oc4ccccc4[Si]5(c4ccc(-c5ccc(-n6c7ccccc7c7ccccc76)cc5)cc4)c4ccc(-c5ccc6c(c5)sc5ccccc56)cc4)cccc23)cc1]

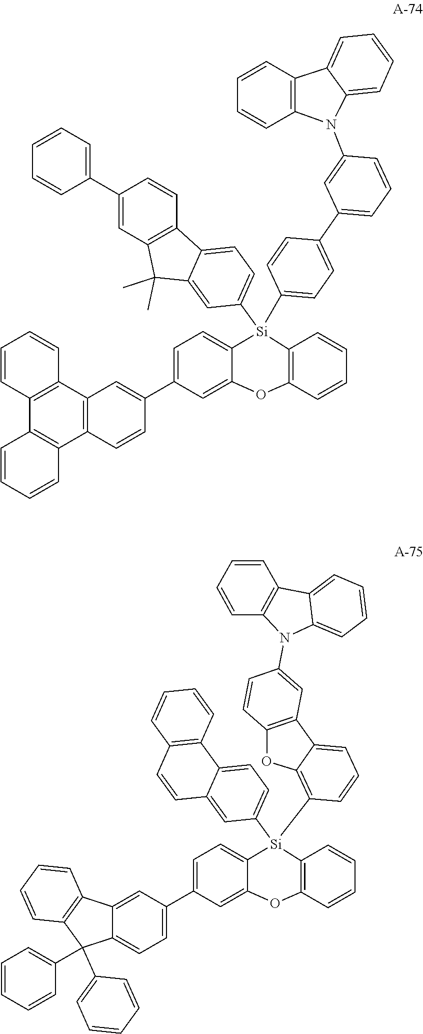 [SMILES: CC1(C)c2cc(-c3ccccc3)ccc2-c2ccc([Si]3(c4ccc(-c5cccc(-n6c7ccccc7c7ccccc76)c5)cc4)c4ccccc4Oc4cc(-c5ccc6c7ccccc7c7ccccc7c6c5)ccc43)cc21 ; c1ccc(C2(c3ccccc3)c3ccccc3-c3cc(-c4ccc5c(c4)Oc4ccccc4[Si]5(c4ccc5c(ccc6ccccc65)c4)c4cccc5c4oc4ccc(-n6c7ccccc7c7ccccc76)cc45)ccc32)cc1]

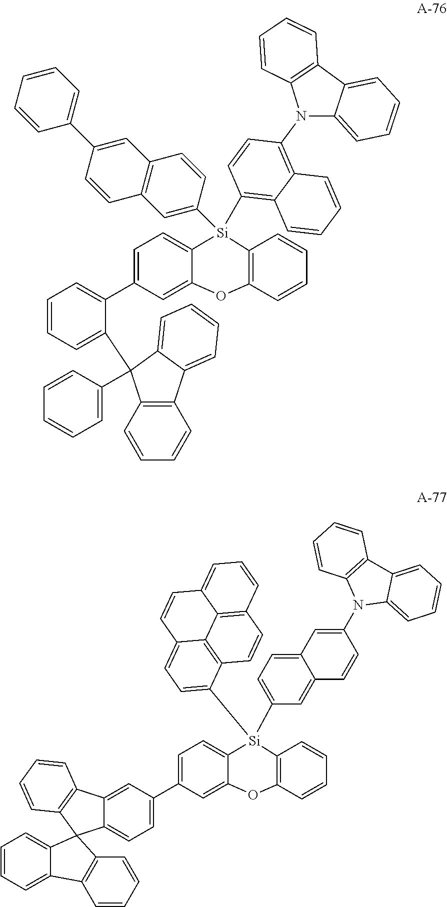 [SMILES: c1ccc(-c2ccc3cc([Si]4(c5ccc(-n6c7ccccc7c7ccccc76)c6ccccc56)c5ccccc5Oc5cc(-c6ccccc6C6(c7ccccc7)c7ccccc7-c7ccccc76)ccc54)ccc3c2)cc1 ; c1ccc2c(c1)Oc1cc(-c3ccc4c(c3)-c3ccccc3C43c4ccccc4-c4ccccc43)ccc1[Si]2(c1ccc2cc(-n3c4ccccc4c4ccccc43)ccc2c1)c1ccc2ccc3cccc4ccc1c2c34]

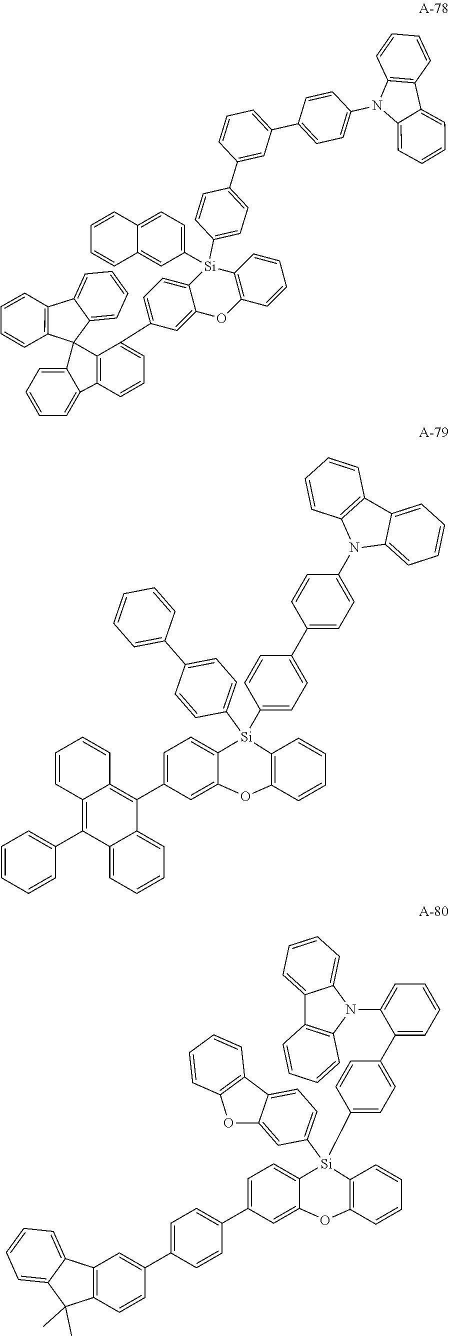 [SMILES: c1cc(-c2ccc(-n3c4ccccc4c4ccccc43)cc2)cc(-c2ccc([Si]3(c4ccc5ccccc5c4)c4ccccc4Oc4cc(-c5cccc6c5C5(c7ccccc7-c7ccccc75)c5ccccc5-6)ccc43)cc2)c1 ; c1ccc(-c2ccc([Si]3(c4ccc(-c5ccc(-n6c7ccccc7c7ccccc76)cc5)cc4)c4ccccc4Oc4cc(-c5c6ccccc6c(-c6ccccc6)c6ccccc56)ccc43)cc2)cc1 ; CC1(C)c2ccccc2-c2cc(-c3ccc(-c4ccc5c(c4)Oc4ccccc4[Si]5(c4ccc(-c5ccccc5-n5c6ccccc6c6ccccc65)cc4)c4ccc5c(c4)oc4ccccc45)cc3)ccc21]

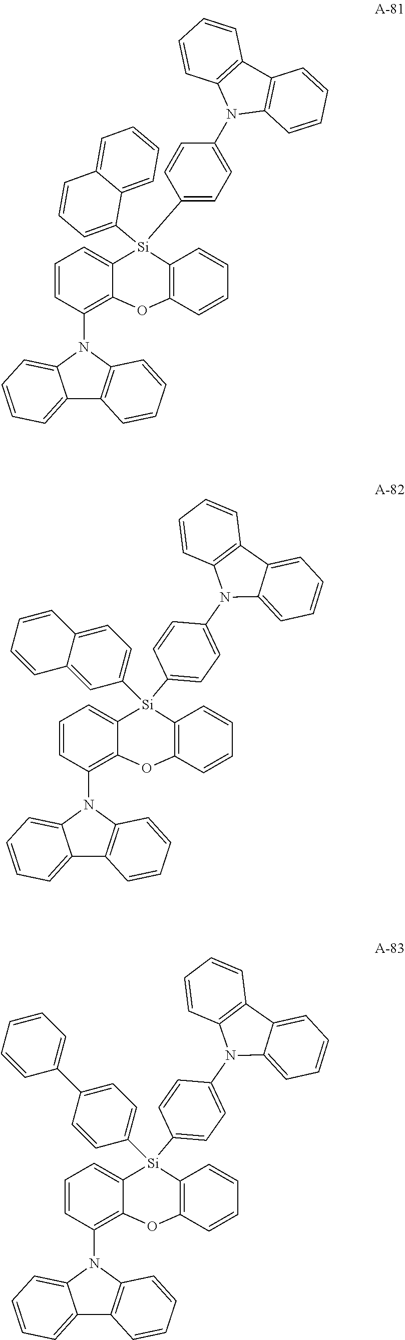 [SMILES: c1ccc2c(c1)Oc1c(-n3c4ccccc4c4ccccc43)cccc1[Si]2(c1ccc(-n2c3ccccc3c3ccccc32)cc1)c1cccc2ccccc12 ; c1ccc2c(c1)Oc1c(-n3c4ccccc4c4ccccc43)cccc1[Si]2(c1ccc(-n2c3ccccc3c3ccccc32)cc1)c1ccc2ccccc2c1 ; c1ccc(-c2ccc([Si]3(c4ccc(-n5c6ccccc6c6ccccc65)cc4)c4ccccc4Oc4c(-n5c6ccccc6c6ccccc65)cccc43)cc2)cc1]

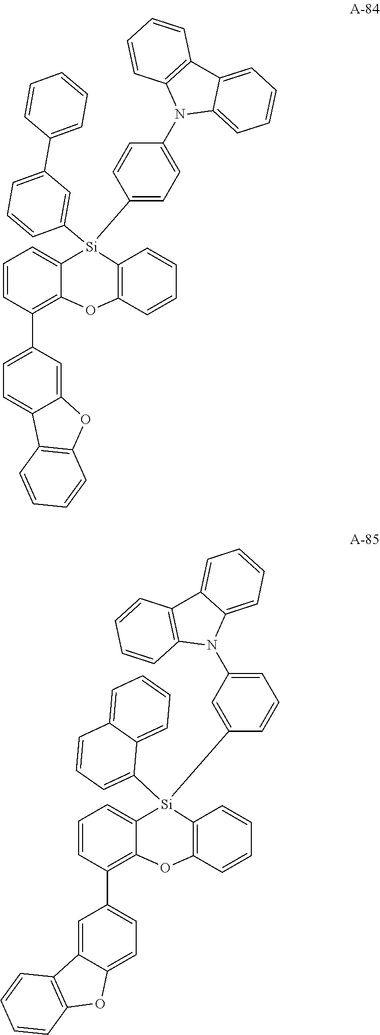 [SMILES: c1ccc(-c2cccc([Si]3(c4ccc(-n5c6ccccc6c6ccccc65)cc4)c4ccccc4Oc4c(-c5ccc6c(c5)oc5ccccc56)cccc43)c2)cc1 ; c1cc(-n2c3ccccc3c3ccccc32)cc([Si]2(c3cccc4ccccc34)c3ccccc3Oc3c(-c4ccc5oc6ccccc6c5c4)cccc32)c1]

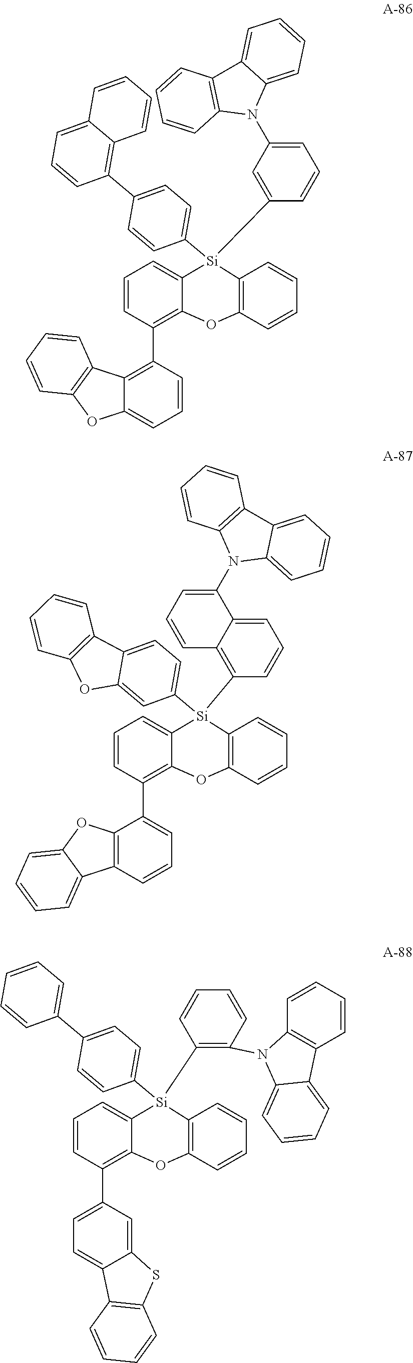 [SMILES: c1cc(-n2c3ccccc3c3ccccc32)cc([Si]2(c3ccc(-c4cccc5ccccc45)cc3)c3ccccc3Oc3c(-c4cccc5oc6ccccc6c45)cccc32)c1 ; c1ccc2c(c1)Oc1c(-c3cccc4c3oc3ccccc34)cccc1[Si]2(c1ccc2c(c1)oc1ccccc12)c1cccc2c(-n3c4ccccc4c4ccccc43)cccc12 ; c1ccc(-c2ccc([Si]3(c4ccccc4-n4c5ccccc5c5ccccc54)c4ccccc4Oc4c(-c5ccc6c(c5)sc5ccccc56)cccc43)cc2)cc1]

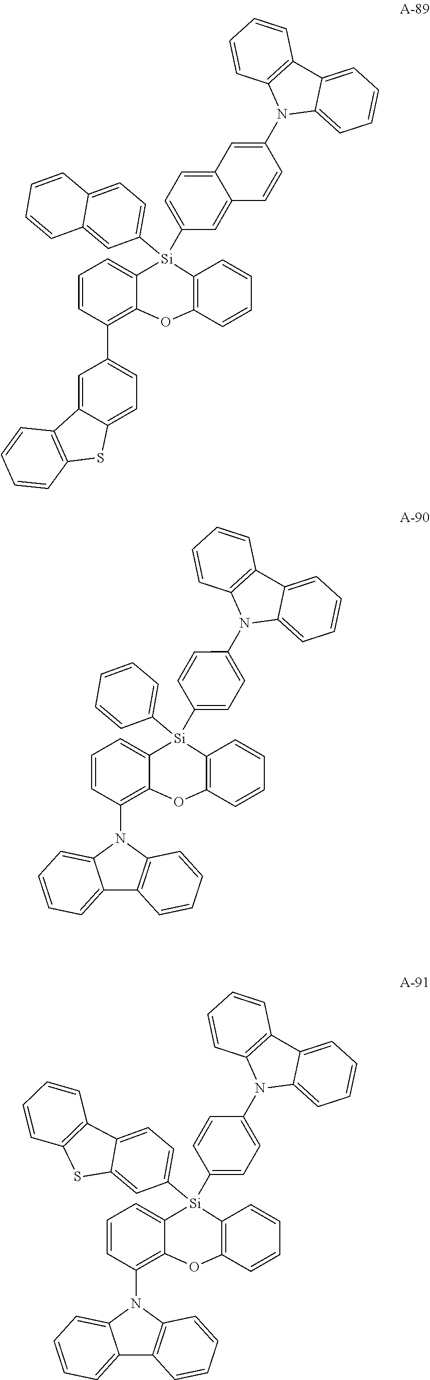 [SMILES: c1ccc2c(c1)Oc1c(-c3ccc4sc5ccccc5c4c3)cccc1[Si]2(c1ccc2ccccc2c1)c1ccc2cc(-n3c4ccccc4c4ccccc43)ccc2c1 ; c1ccc([Si]2(c3ccc(-n4c5ccccc5c5ccccc54)cc3)c3ccccc3Oc3c(-n4c5ccccc5c5ccccc54)cccc32)cc1 ; c1ccc2c(c1)Oc1c(-n3c4ccccc4c4ccccc43)cccc1[Si]2(c1ccc(-n2c3ccccc3c3ccccc32)cc1)c1ccc2c(c1)sc1ccccc12]

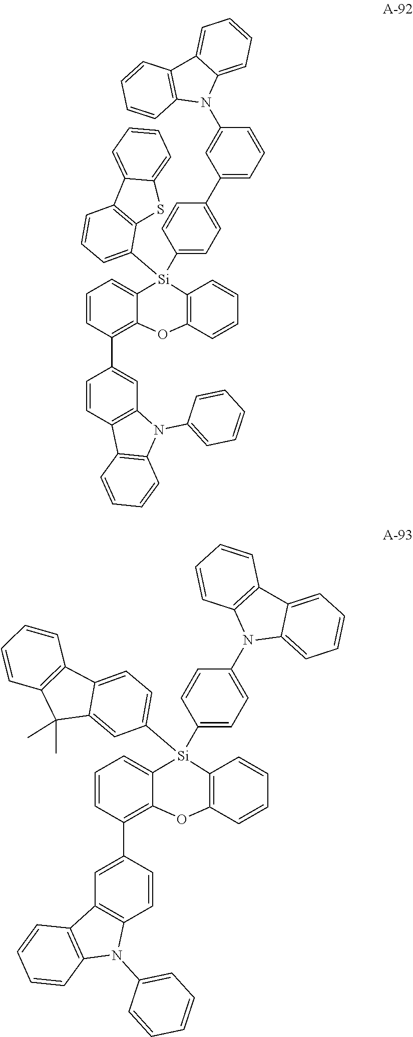 [SMILES: c1ccc(-n2c3ccccc3c3ccc(-c4cccc5c4Oc4ccccc4[Si]5(c4ccc(-c5cccc(-n6c7ccccc7c7ccccc76)c5)cc4)c4cccc5c4sc4ccccc45)cc32)cc1 ; CC1(C)c2ccccc2-c2ccc([Si]3(c4ccc(-n5c6ccccc6c6ccccc65)cc4)c4ccccc4Oc4c(-c5ccc6c(c5)c5ccccc5n6-c5ccccc5)cccc43)cc21]

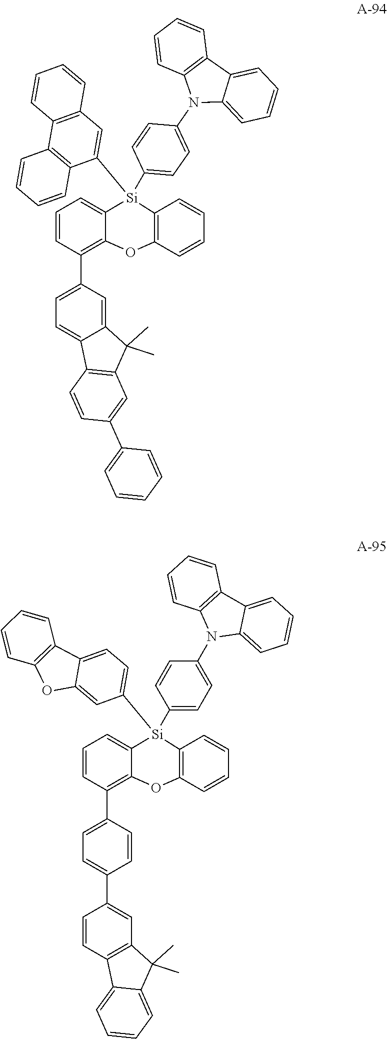 [SMILES: CC1(C)c2cc(-c3ccccc3)ccc2-c2ccc(-c3cccc4c3Oc3ccccc3[Si]4(c3ccc(-n4c5ccccc5c5ccccc54)cc3)c3cc4ccccc4c4ccccc34)cc21 ; CC1(C)c2ccccc2-c2ccc(-c3ccc(-c4cccc5c4Oc4ccccc4[Si]5(c4ccc(-n5c6ccccc6c6ccccc65)cc4)c4ccc5c(c4)oc4ccccc45)cc3)cc21]

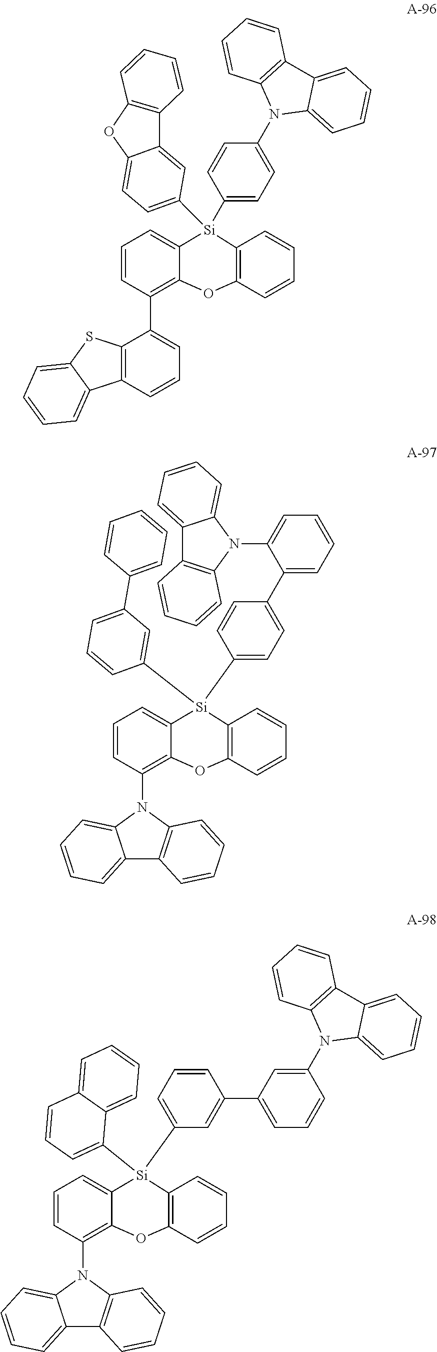 [SMILES: c1ccc2c(c1)Oc1c(-c3cccc4c3sc3ccccc34)cccc1[Si]2(c1ccc(-n2c3ccccc3c3ccccc32)cc1)c1ccc2oc3ccccc3c2c1 ; c1ccc(-c2cccc([Si]3(c4ccc(-c5ccccc5-n5c6ccccc6c6ccccc65)cc4)c4ccccc4Oc4c(-n5c6ccccc6c6ccccc65)cccc43)c2)cc1 ; c1cc(-c2cccc([Si]3(c4cccc5ccccc45)c4ccccc4Oc4c(-n5c6ccccc6c6ccccc65)cccc43)c2)cc(-n2c3ccccc3c3ccccc32)c1]

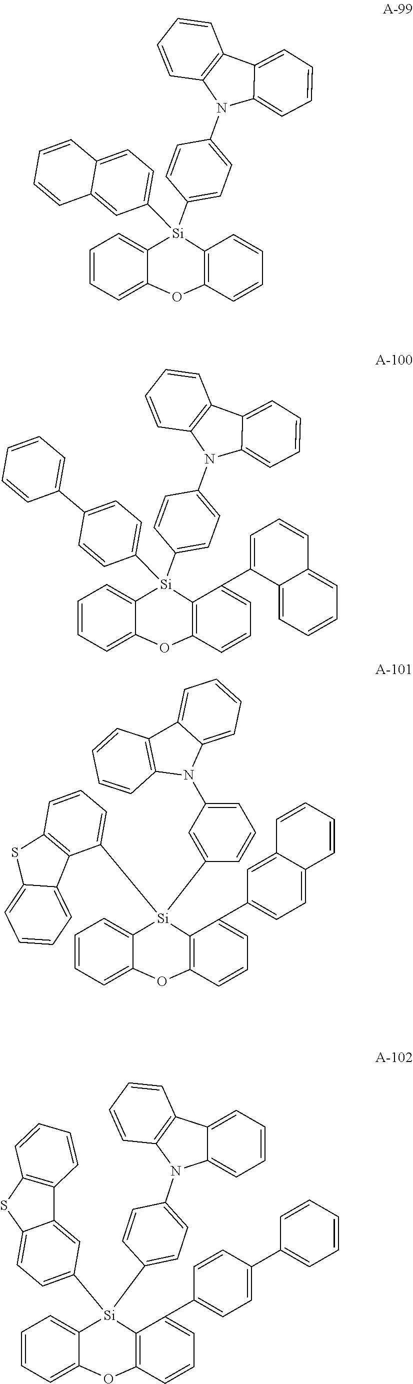

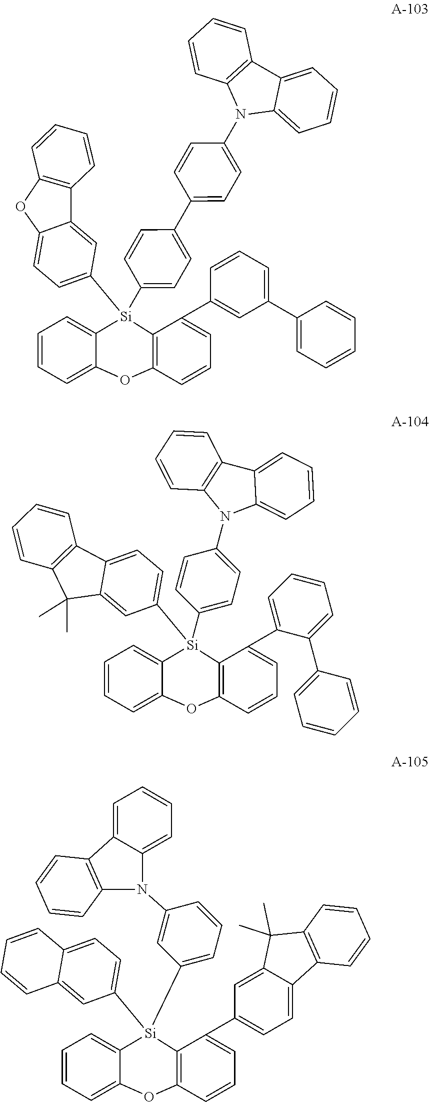 [SMILES: c1ccc(-c2cccc(-c3cccc4c3[Si](c3ccc(-c5ccc(-n6c7ccccc7c7ccccc76)cc5)cc3)(c3ccc5oc6ccccc6c5c3)c3ccccc3O4)c2)cc1 ; CC1(C)c2ccccc2-c2ccc([Si]3(c4ccc(-n5c6ccccc6c6ccccc65)cc4)c4ccccc4Oc4cccc(-c5ccccc5-c5ccccc5)c43)cc21 ; CC1(C)c2ccccc2-c2ccc(-c3cccc4c3[Si](c3cccc(-n5c6ccccc6c6ccccc65)c3)(c3ccc5ccccc5c3)c3ccccc3O4)cc21]

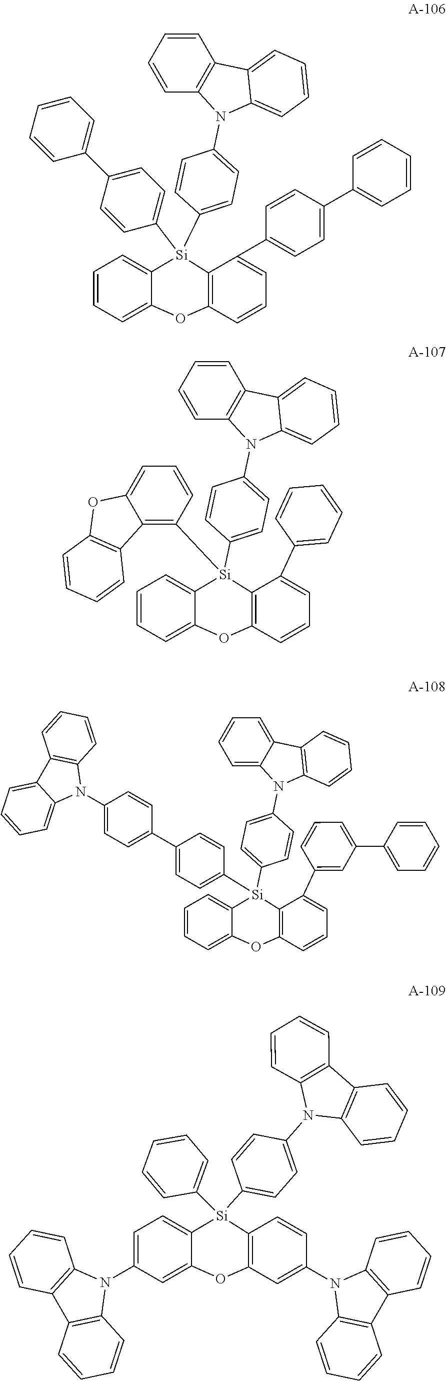

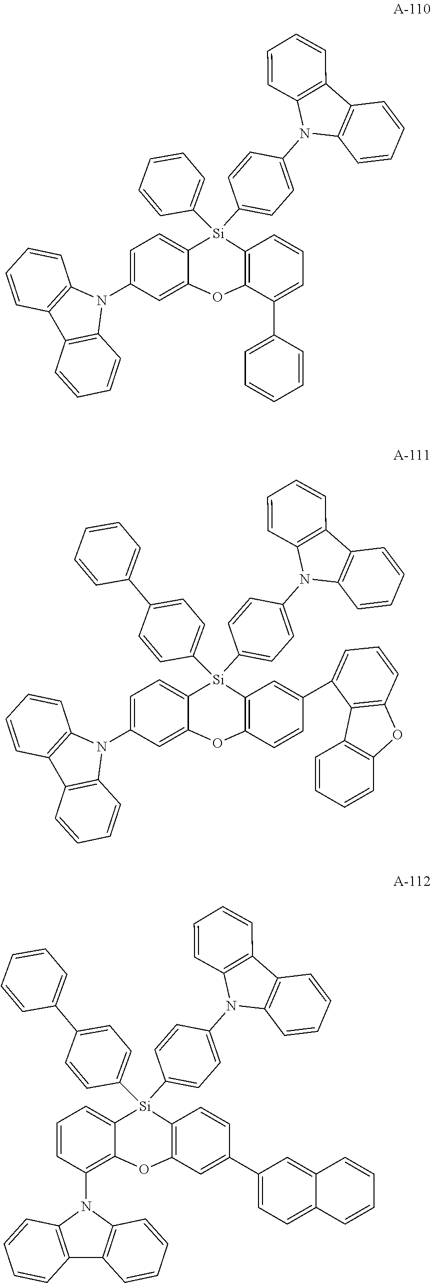 [SMILES: c1ccc(-c2cccc3c2Oc2cc(-n4c5ccccc5c5ccccc54)ccc2[Si]3(c2ccccc2)c2ccc(-n3c4ccccc4c4ccccc43)cc2)cc1 ; c1ccc(-c2ccc([Si]3(c4ccc(-n5c6ccccc6c6ccccc65)cc4)c4ccc(-n5c6ccccc6c6ccccc65)cc4Oc4ccc(-c5cccc6oc7ccccc7c56)cc43)cc2)cc1 ; c1ccc(-c2ccc([Si]3(c4ccc(-n5c6ccccc6c6ccccc65)cc4)c4ccc(-c5ccc6ccccc6c5)cc4Oc4c(-n5c6ccccc6c6ccccc65)cccc43)cc2)cc1]

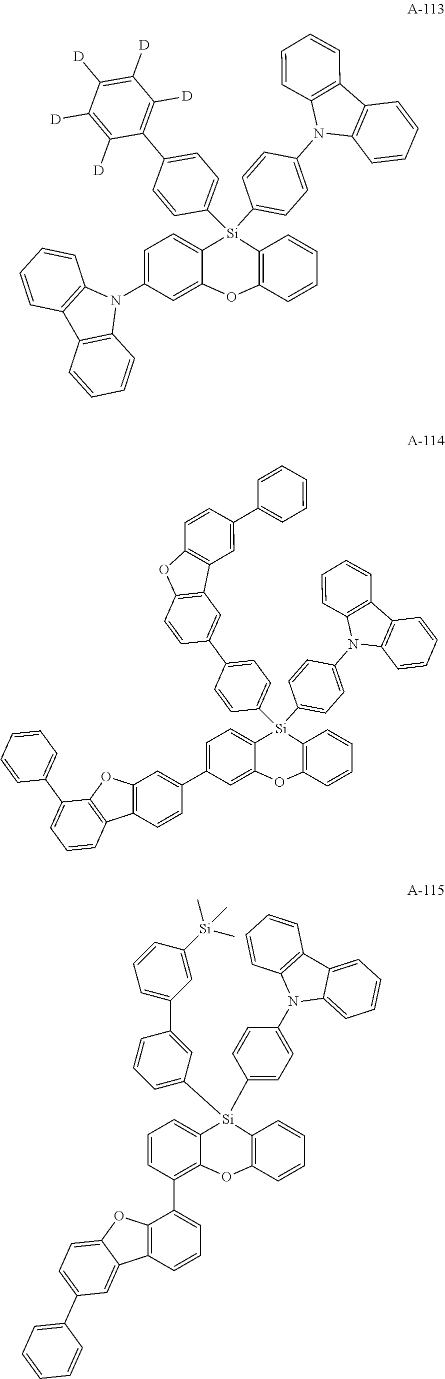 [SMILES: [2H]c1c([2H])c([2H])c(-c2ccc([Si]3(c4ccc(-n5c6ccccc6c6ccccc65)cc4)c4ccccc4Oc4cc(-n5c6ccccc6c6ccccc65)ccc43)cc2)c([2H])c1[2H] ; c1ccc(-c2ccc3oc4ccc(-c5ccc([Si]6(c7ccc(-n8c9ccccc9c9ccccc98)cc7)c7ccccc7Oc7cc(-c8ccc9c(c8)oc8c(-c%10ccccc%10)cccc89)ccc76)cc5)cc4c3c2)cc1 ; C[Si](C)(C)c1cccc(-c2cccc([Si]3(c4ccc(-n5c6ccccc6c6ccccc65)cc4)c4ccccc4Oc4c(-c5cccc6c5oc5ccc(-c7ccccc7)cc56)cccc43)c2)c1]

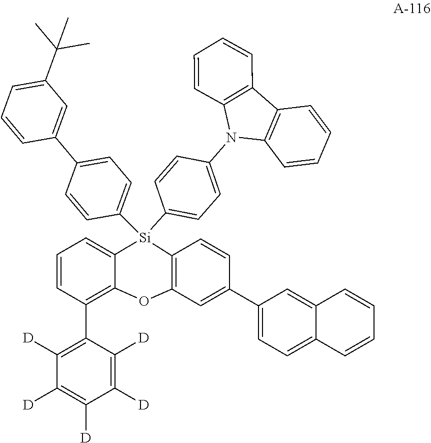 [SMILES: [2H]c1c([2H])c([2H])c(-c2cccc3c2Oc2cc(-c4ccc5ccccc5c4)ccc2[Si]3(c2ccc(-c3cccc(C(C)(C)C)c3)cc2)c2ccc(-n3c4ccccc4c4ccccc43)cc2)c([2H])c1[2H]]

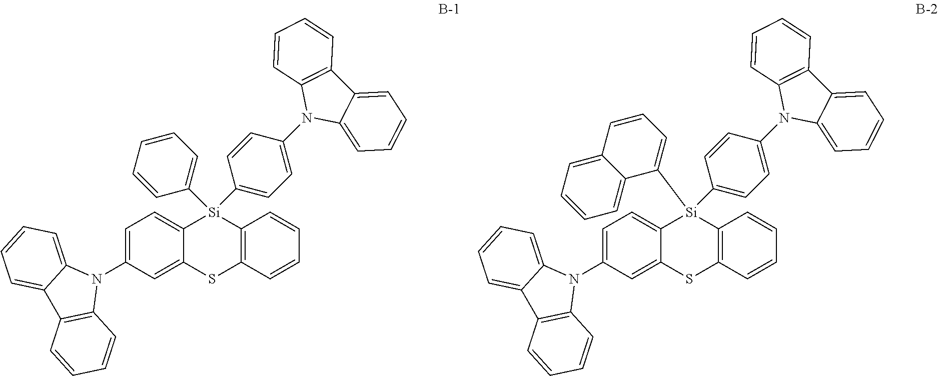 [SMILES: c1ccc([Si]2(c3ccc(-n4c5ccccc5c5ccccc54)cc3)c3ccccc3Sc3cc(-n4c5ccccc5c5ccccc54)ccc32)cc1 ; c1ccc2c(c1)Sc1cc(-n3c4ccccc4c4ccccc43)ccc1[Si]2(c1ccc(-n2c3ccccc3c3ccccc32)cc1)c1cccc2ccccc12]

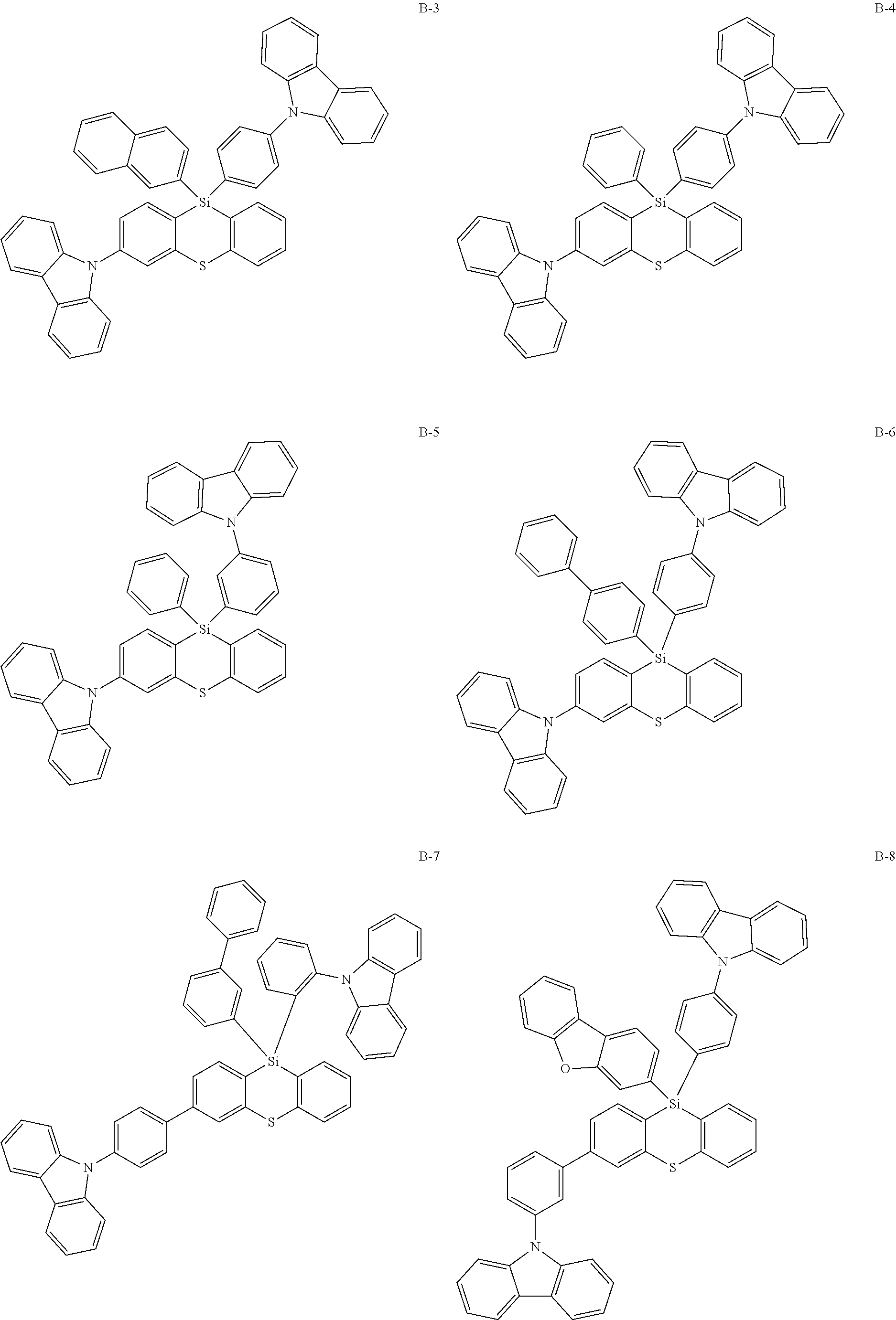

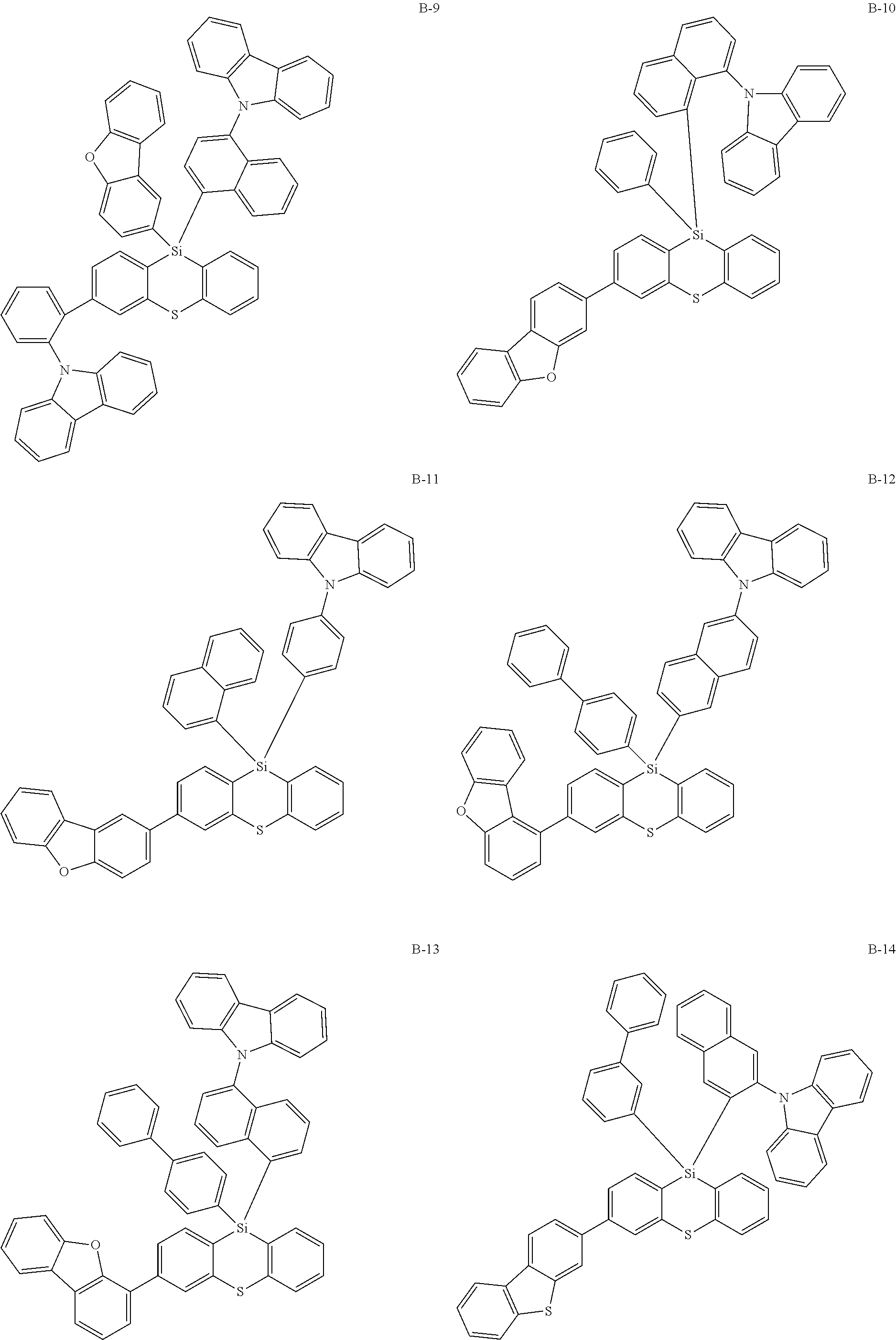

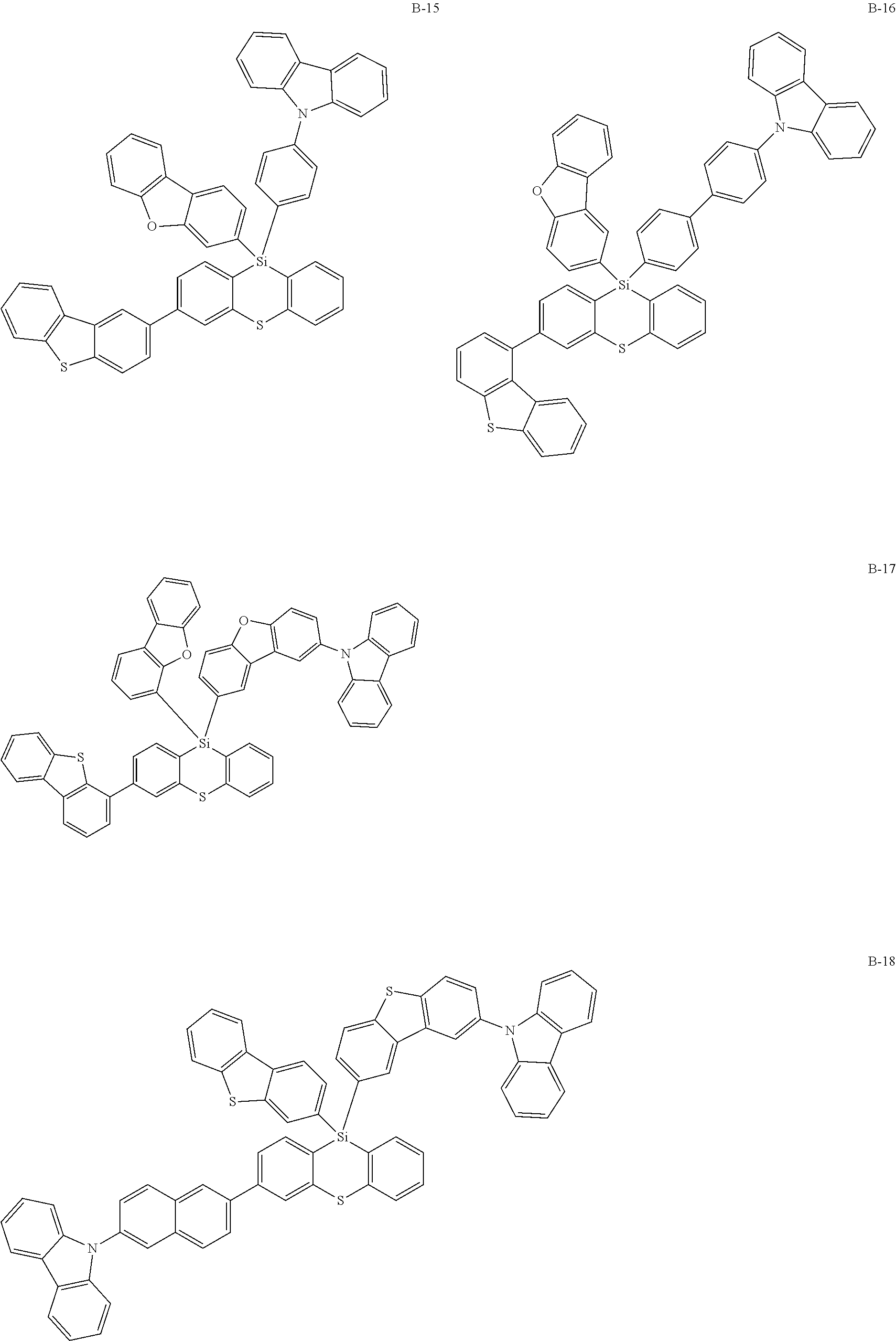 [SMILES: c1ccc2c(c1)Sc1cc(-c3ccc4sc5ccccc5c4c3)ccc1[Si]2(c1ccc(-n2c3ccccc3c3ccccc32)cc1)c1ccc2c(c1)oc1ccccc12 ; c1ccc2c(c1)Sc1cc(-c3cccc4sc5ccccc5c34)ccc1[Si]2(c1ccc(-c2ccc(-n3c4ccccc4c4ccccc43)cc2)cc1)c1ccc2oc3ccccc3c2c1 ; c1ccc2c(c1)Sc1cc(-c3cccc4c3sc3ccccc34)ccc1[Si]2(c1ccc2oc3ccc(-n4c5ccccc5c5ccccc54)cc3c2c1)c1cccc2c1oc1ccccc12 ; c1ccc2c(c1)Sc1cc(-c3ccc4cc(-n5c6ccccc6c6ccccc65)ccc4c3)ccc1[Si]2(c1ccc2c(c1)sc1ccccc12)c1ccc2sc3ccc(-n4c5ccccc5c5ccccc54)cc3c2c1]

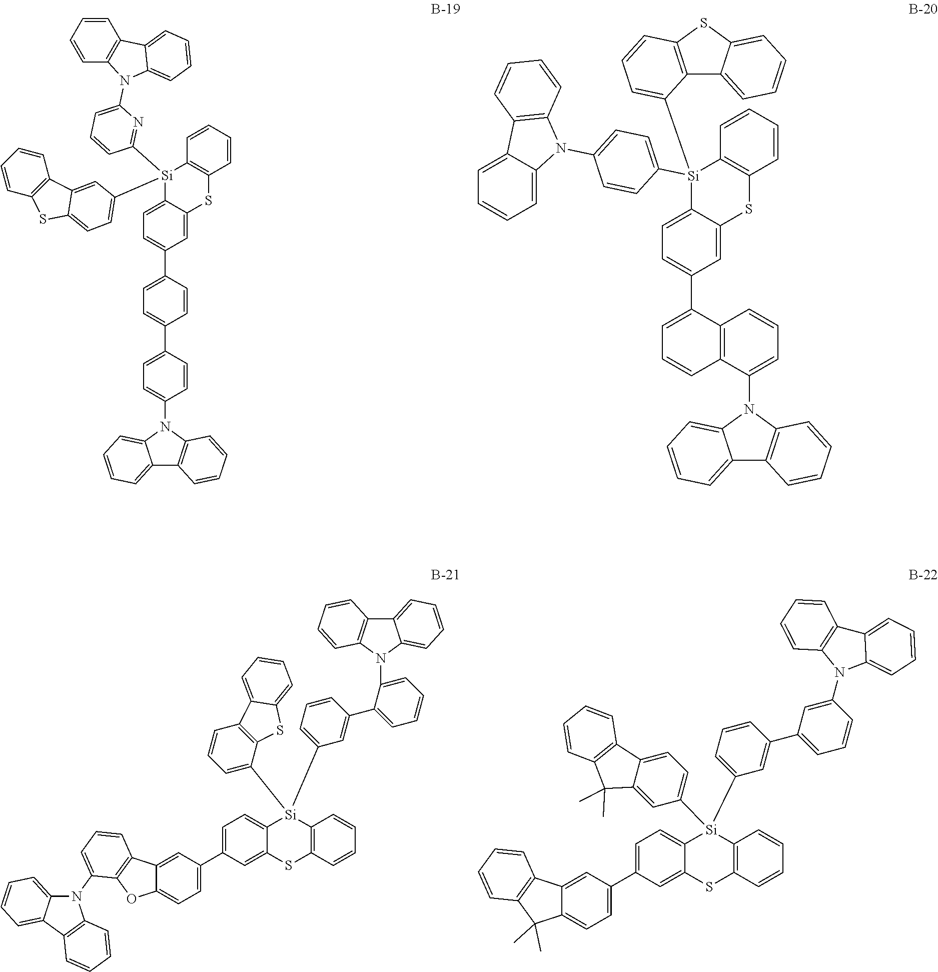 [SMILES: c1cc(-n2c3ccccc3c3ccccc32)nc([Si]2(c3ccc4sc5ccccc5c4c3)c3ccccc3Sc3cc(-c4ccc(-c5ccc(-n6c7ccccc7c7ccccc76)cc5)cc4)ccc32)c1 ; c1ccc2c(c1)Sc1cc(-c3cccc4c(-n5c6ccccc6c6ccccc65)cccc34)ccc1[Si]2(c1ccc(-n2c3ccccc3c3ccccc32)cc1)c1cccc2sc3ccccc3c12 ; c1cc(-c2ccccc2-n2c3ccccc3c3ccccc32)cc([Si]2(c3cccc4c3sc3ccccc34)c3ccccc3Sc3cc(-c4ccc5oc6c(-n7c8ccccc8c8ccccc87)cccc6c5c4)ccc32)c1 ; CC1(C)c2ccccc2-c2cc(-c3ccc4c(c3)Sc3ccccc3[Si]4(c3cccc(-c4cccc(-n5c6ccccc6c6ccccc65)c4)c3)c3ccc4c(c3)C(C)(C)c3ccccc3-4)ccc21]

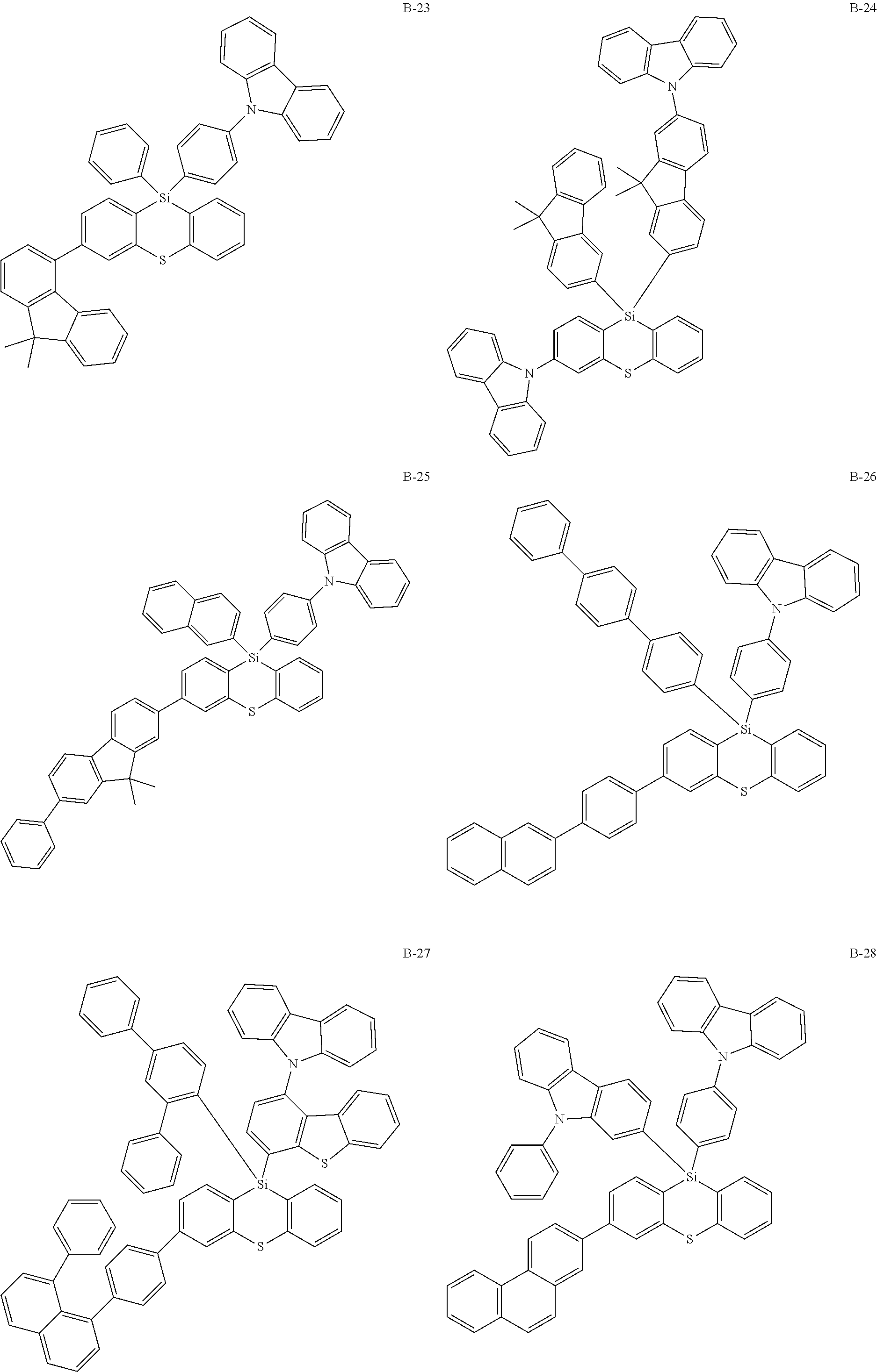

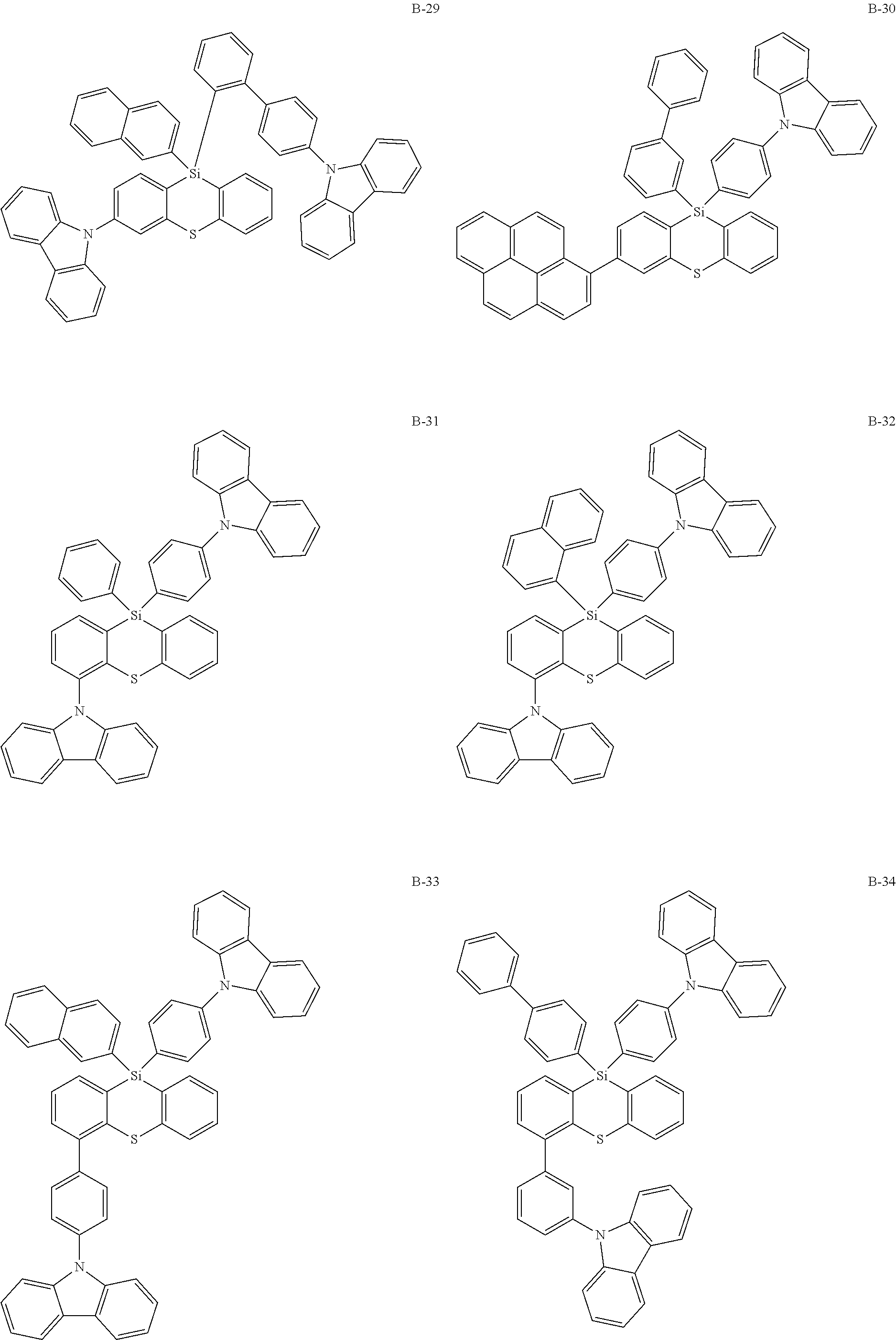

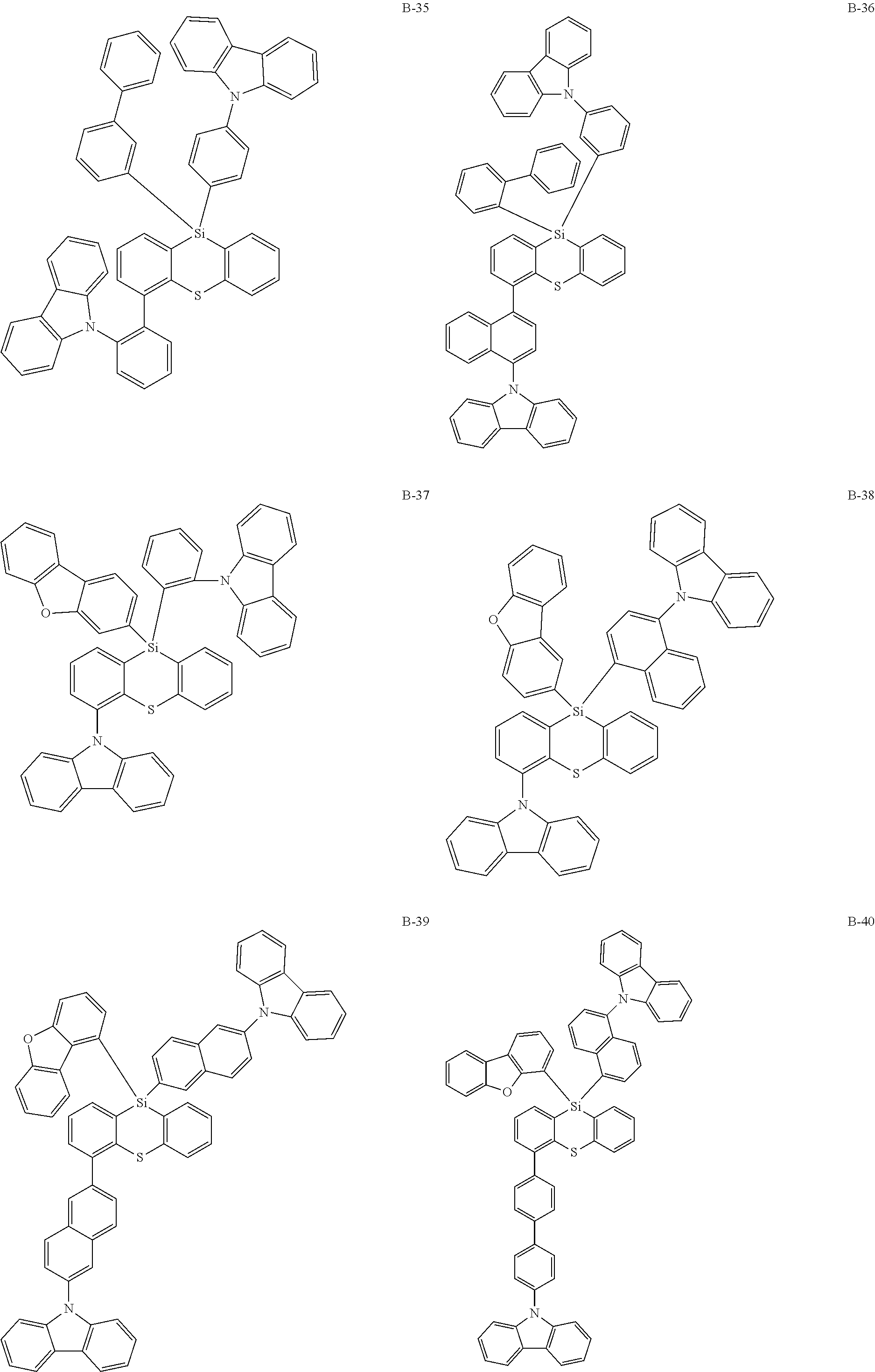

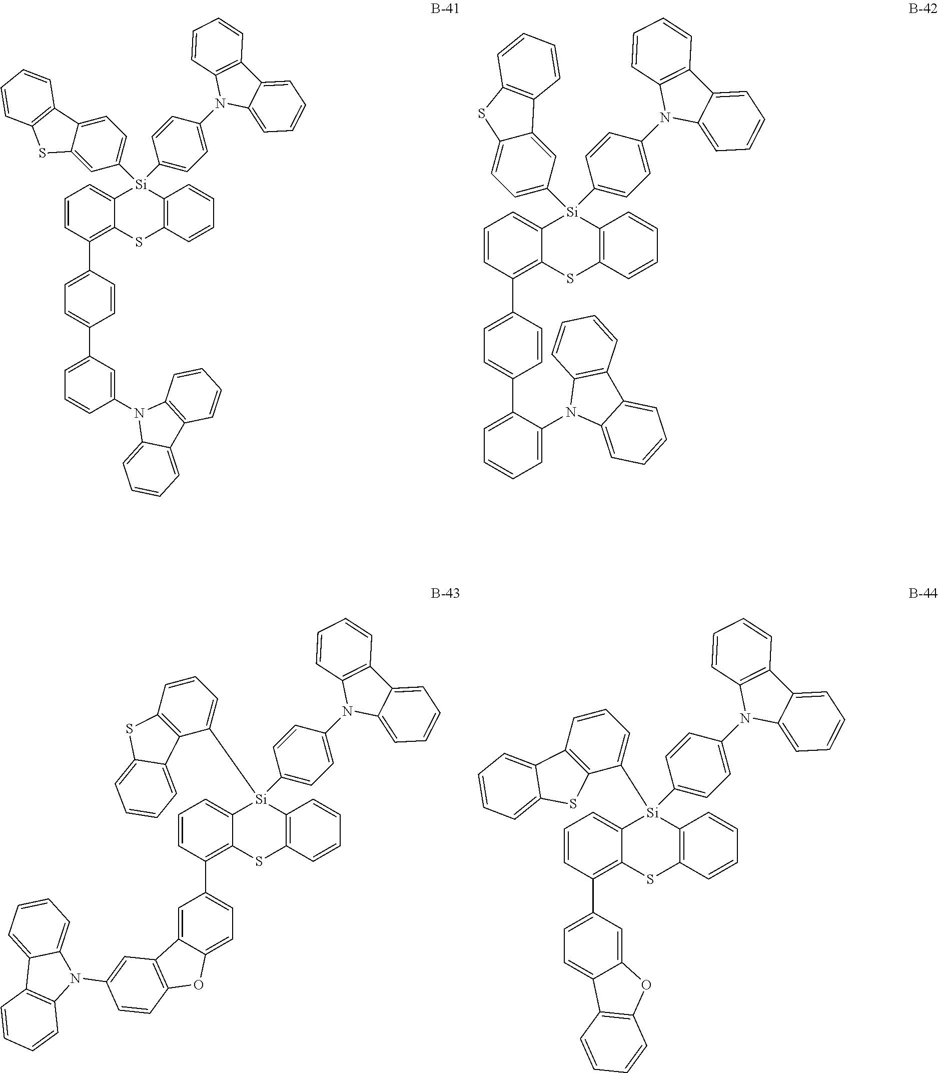 [SMILES: c1cc(-c2ccc(-c3cccc4c3Sc3ccccc3[Si]4(c3ccc(-n4c5ccccc5c5ccccc54)cc3)c3ccc4c(c3)sc3ccccc34)cc2)cc(-n2c3ccccc3c3ccccc32)c1 ; c1ccc2c(c1)Sc1c(-c3ccc(-c4ccccc4-n4c5ccccc5c5ccccc54)cc3)cccc1[Si]2(c1ccc(-n2c3ccccc3c3ccccc32)cc1)c1ccc2sc3ccccc3c2c1 ; c1ccc2c(c1)Sc1c(-c3ccc4oc5ccc(-n6c7ccccc7c7ccccc76)cc5c4c3)cccc1[Si]2(c1ccc(-n2c3ccccc3c3ccccc32)cc1)c1cccc2sc3ccccc3c12 ; c1ccc2c(c1)Sc1c(-c3ccc4c(c3)oc3ccccc34)cccc1[Si]2(c1ccc(-n2c3ccccc3c3ccccc32)cc1)c1cccc2c1sc1ccccc12]

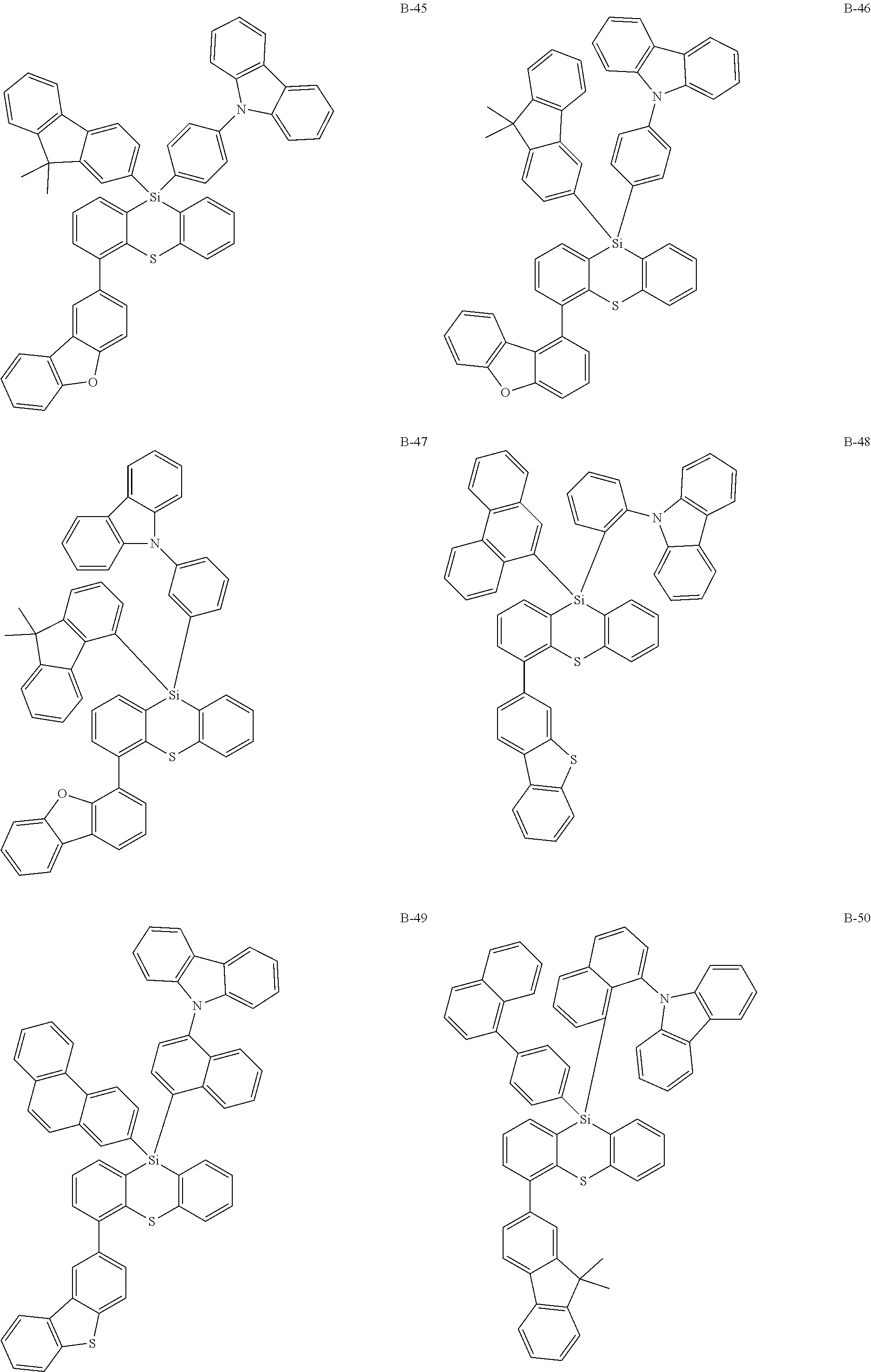

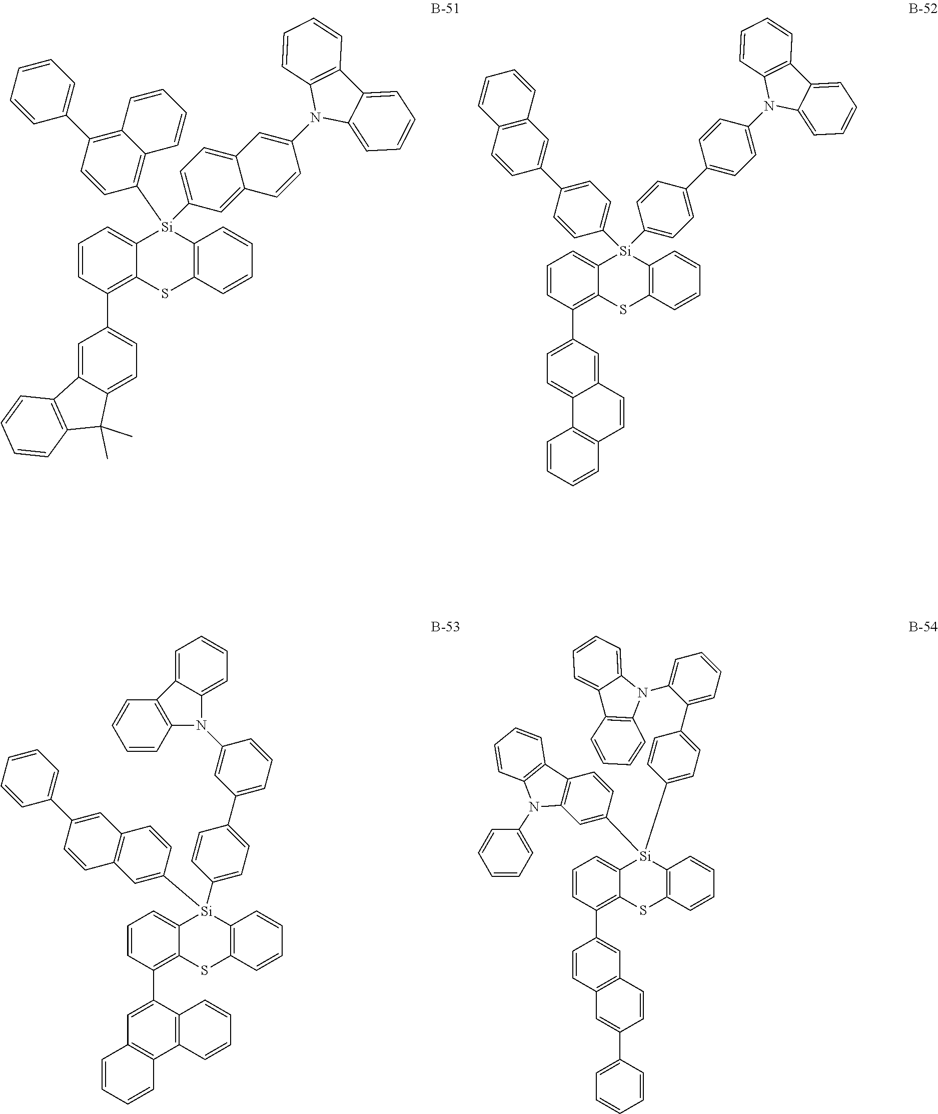 [SMILES: CC1(C)c2ccccc2-c2cc(-c3cccc4c3Sc3ccccc3[Si]4(c3ccc4cc(-n5c6ccccc6c6ccccc65)ccc4c3)c3ccc(-c4ccccc4)c4ccccc34)ccc21 ; c1ccc2c(c1)Sc1c(-c3ccc4c(ccc5ccccc54)c3)cccc1[Si]2(c1ccc(-c2ccc(-n3c4ccccc4c4ccccc43)cc2)cc1)c1ccc(-c2ccc3ccccc3c2)cc1 ; c1ccc(-c2ccc3cc([Si]4(c5ccc(-c6cccc(-n7c8ccccc8c8ccccc87)c6)cc5)c5ccccc5Sc5c(-c6cc7ccccc7c7ccccc67)cccc54)ccc3c2)cc1 ; c1ccc(-c2ccc3cc(-c4cccc5c4Sc4ccccc4[Si]5(c4ccc(-c5ccccc5-n5c6ccccc6c6ccccc65)cc4)c4ccc5c6ccccc6n(-c6ccccc6)c5c4)ccc3c2)cc1]

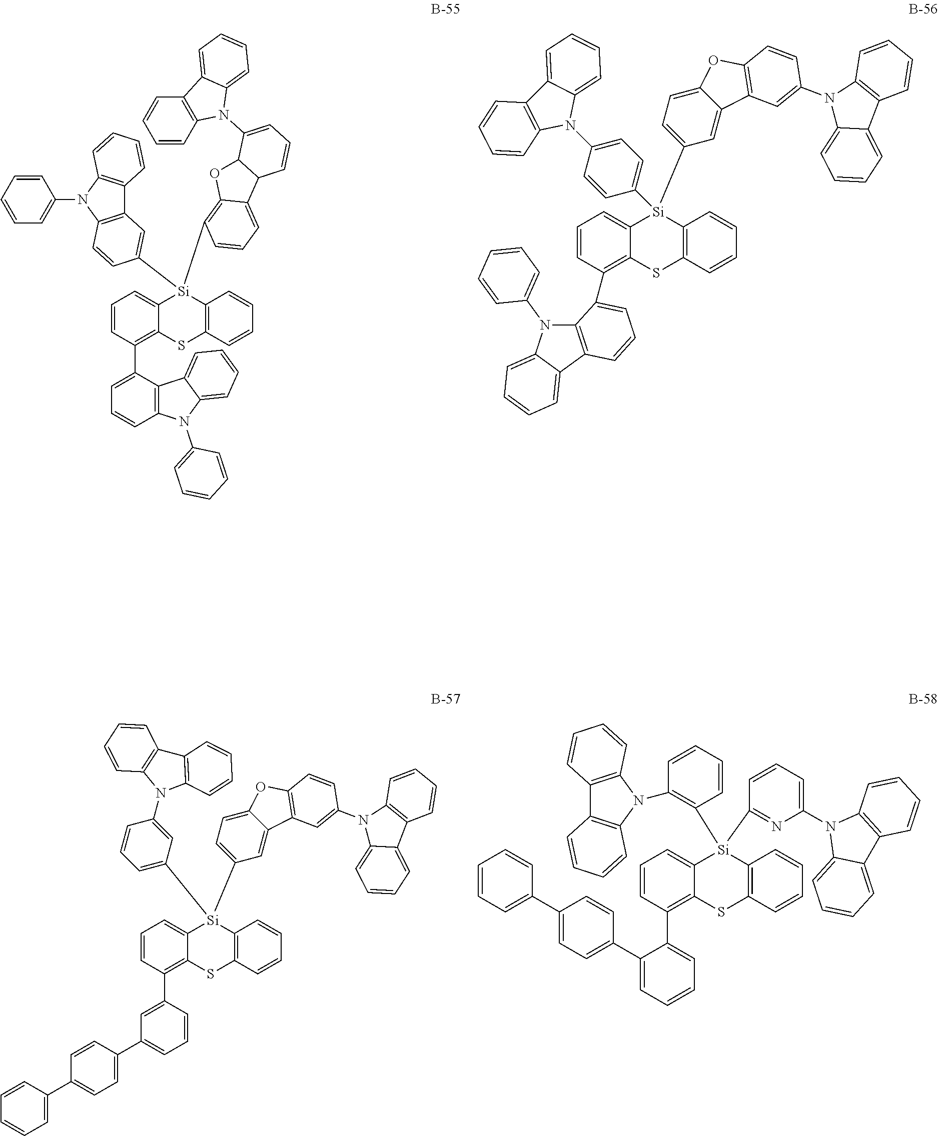

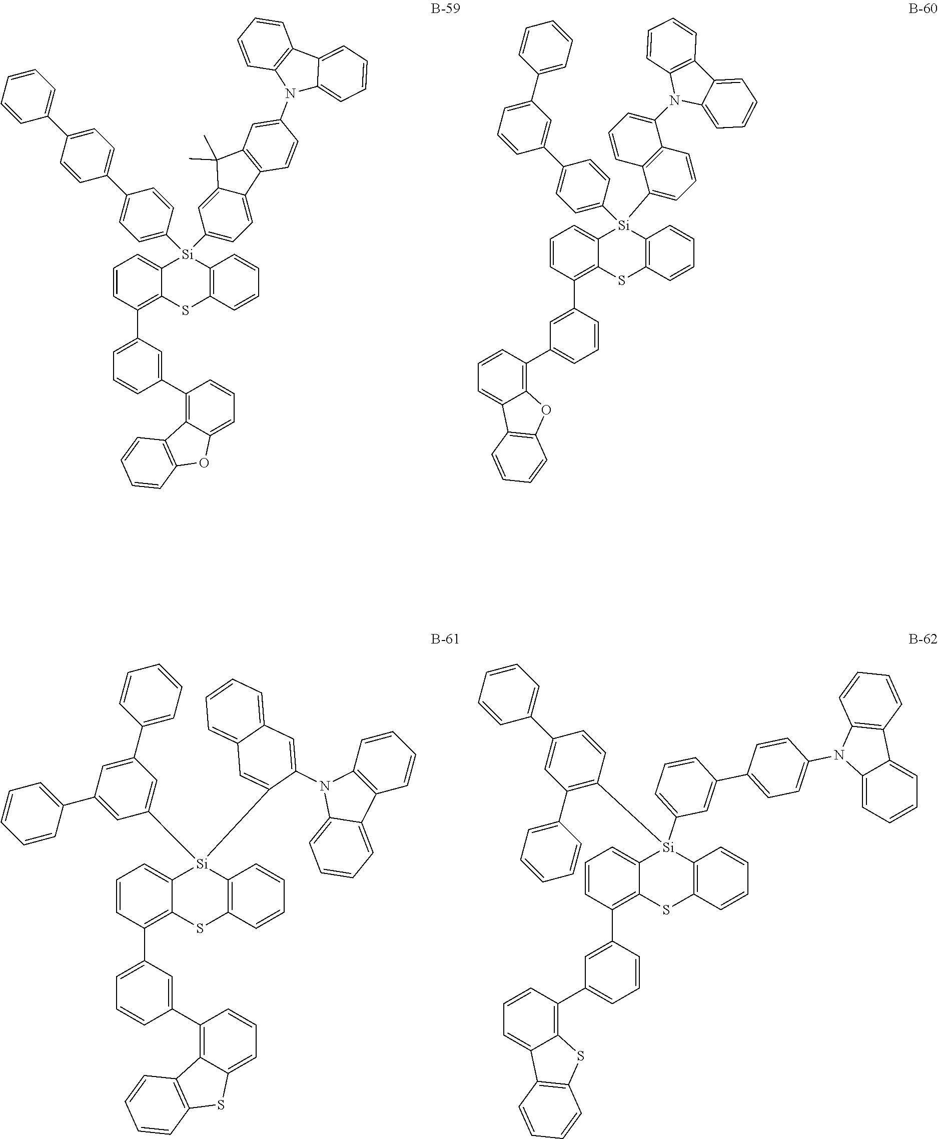

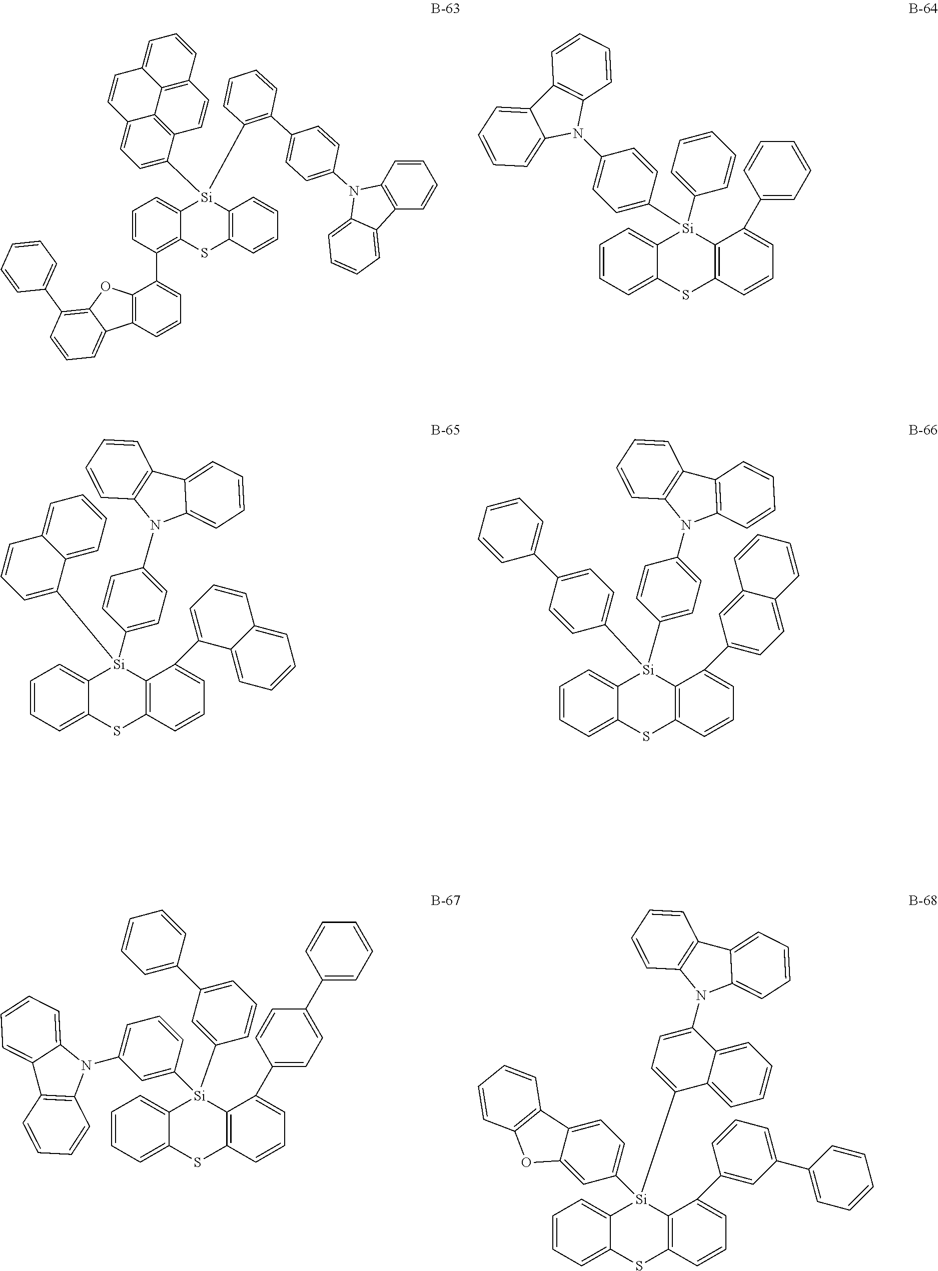

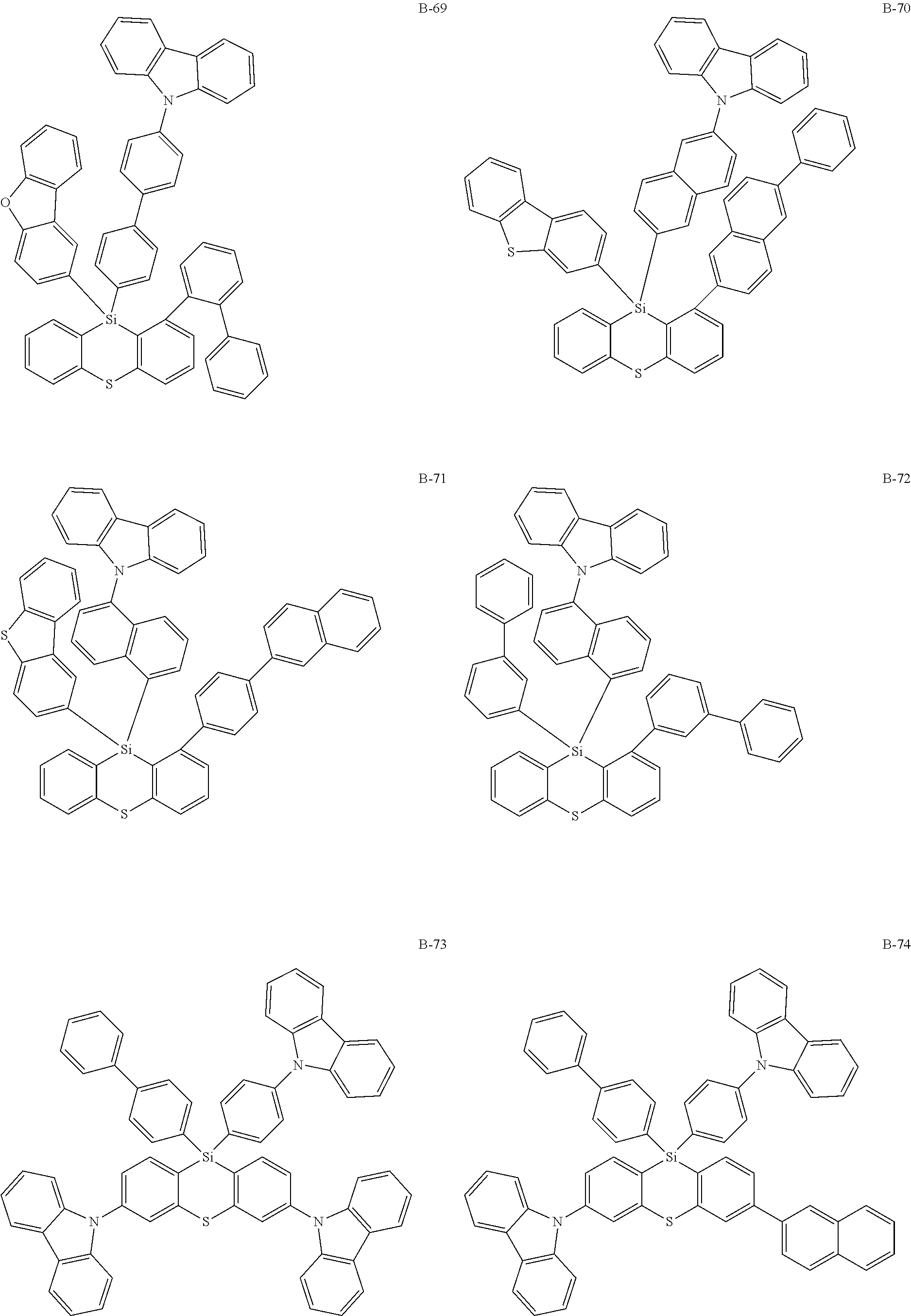

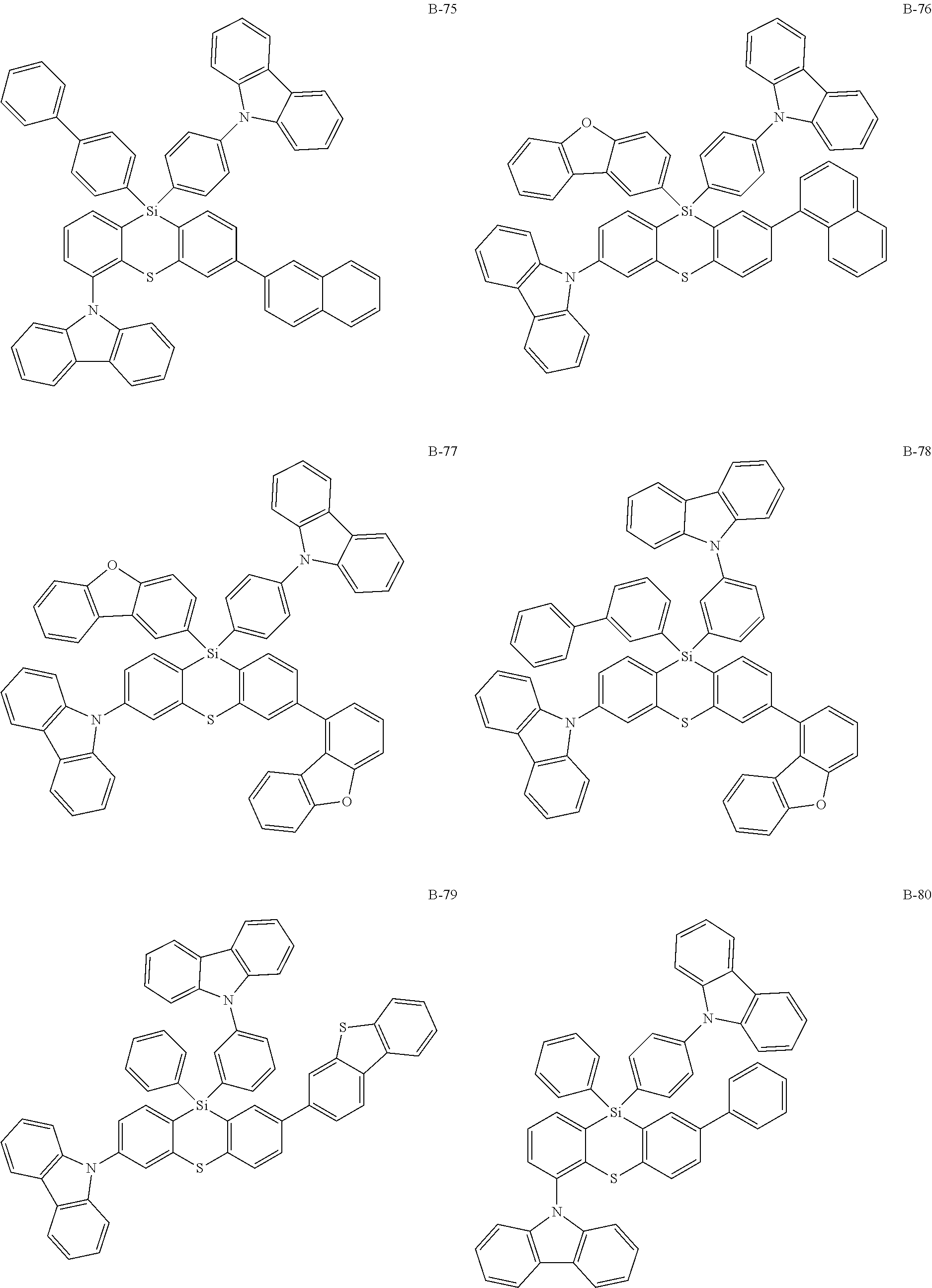

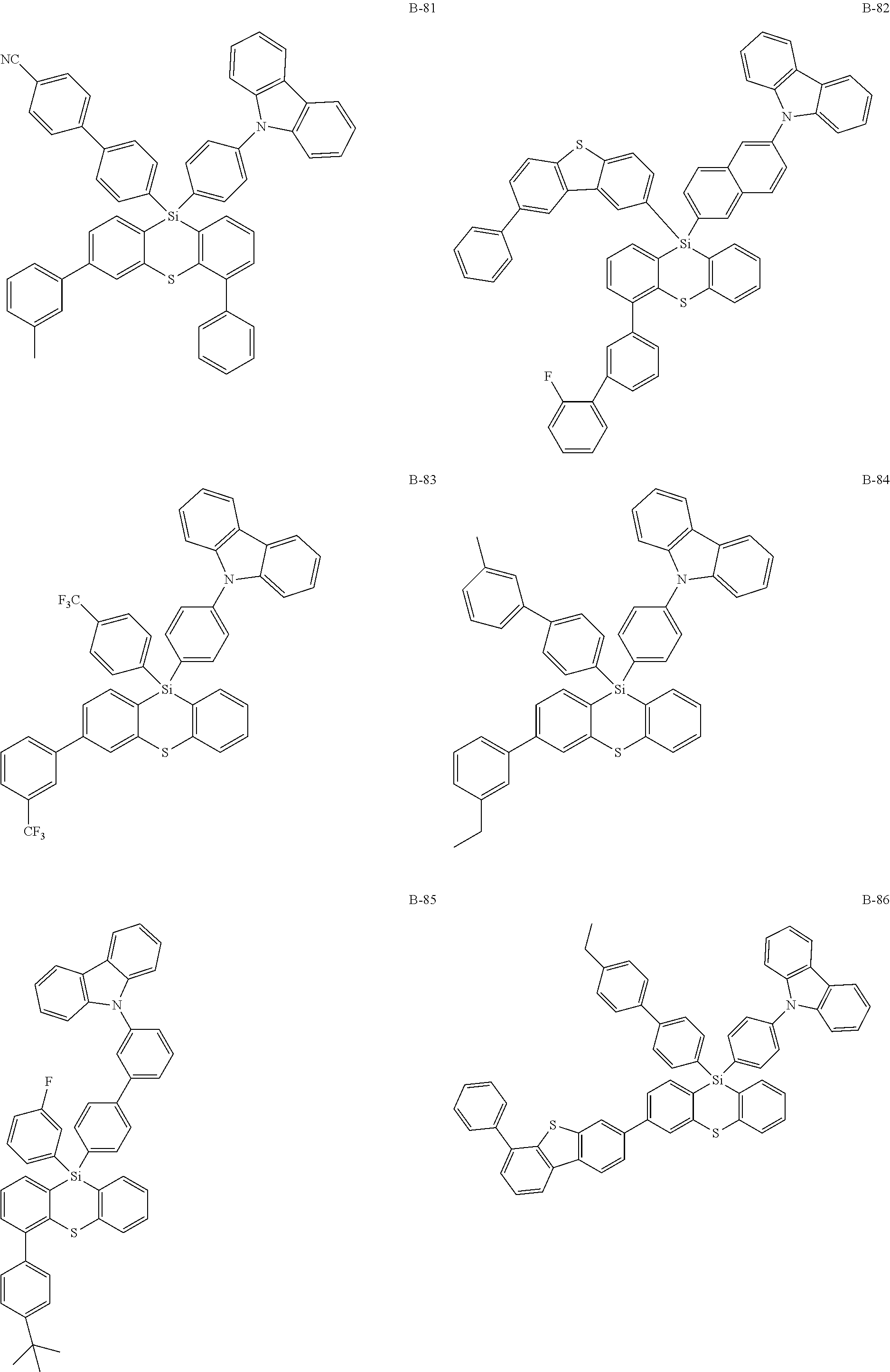

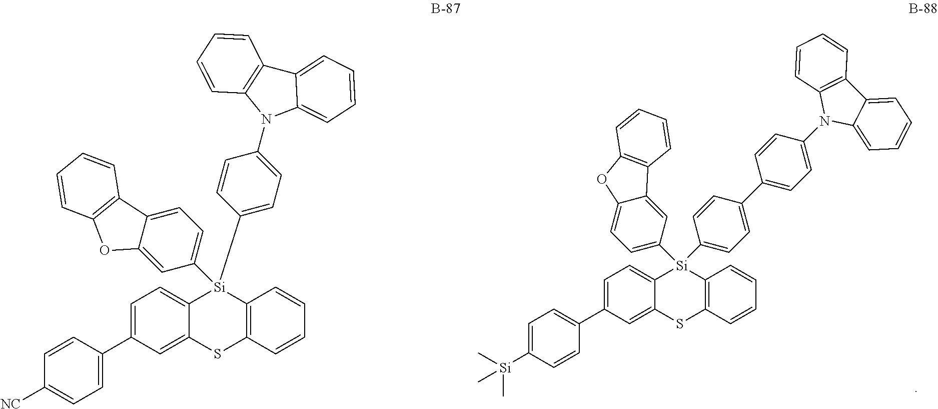 [SMILES: N#Cc1ccc(-c2ccc3c(c2)Sc2ccccc2[Si]3(c2ccc(-n3c4ccccc4c4ccccc43)cc2)c2ccc3c(c2)oc2ccccc23)cc1 ; C[Si](C)(C)c1ccc(-c2ccc3c(c2)Sc2ccccc2[Si]3(c2ccc(-c3ccc(-n4c5ccccc5c5ccccc54)cc3)cc2)c2ccc3oc4ccccc4c3c2)cc1]

In a second aspect, the present application provides an electronic element, comprising an anode and a cathode disposed opposite to each other, and a functional layer disposed between the anode and the cathode; the functional layer contains the organic compound of the present application.

Optionally, the electronic element is an organic electroluminescent device.

Optionally, the functional layer comprises an organic light-emitting layer, which contains the organic compound of the present application.

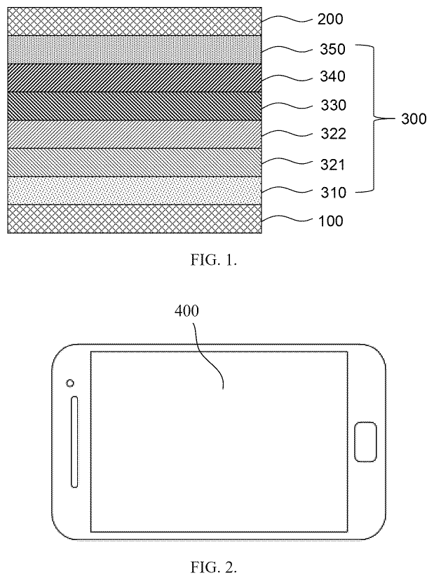

In one embodiment, the electronic element is an organic electroluminescent device. As shown in FIG. 1, the organic electroluminescent device may comprise an anode 100, a hole transport layer 321, an electron blocking layer 322, an organic light-emitting layer 330, an electron transport layer 340, and a cathode 200 that are stacked sequentially.

In a specific embodiment, the organic electroluminescent device is a blue organic electroluminescent device.

Optionally, the anode 100 comprises the following anode materials, which are alternatively a high work function material contributing to injection of holes into the functional layer. Specific examples of the anode material include: metals such as nickel, platinum, vanadium, chromium, copper, zinc, and gold, or alloys thereof; metal oxides such as zinc oxide, indium oxide, indium tin oxide (ITO), and indium zinc oxide (IZO); combinations of metals and oxides, such as ZnO:Al or SnO₂:Sb; or conductive polymers such as poly(3-methylthiophene), poly[3,4-(ethylene-1,2-dioxy)thiophene](PEDT), polypyrrole, and polyaniline, but are not limited thereto. Preferably, a transparent electrode comprising indium tin oxide (ITO) is included as the anode.

Optionally, the hole transport layer 321 includes one or more hole transport material(s). The hole transport materials may be selected from carbazole multimers, carbazole-linked triarylamine based compounds, and other types of compounds. Those skilled in the art may make a selection with reference to the prior art. For example, the material of the hole transport layer is selected from the group consisting of the following compounds:

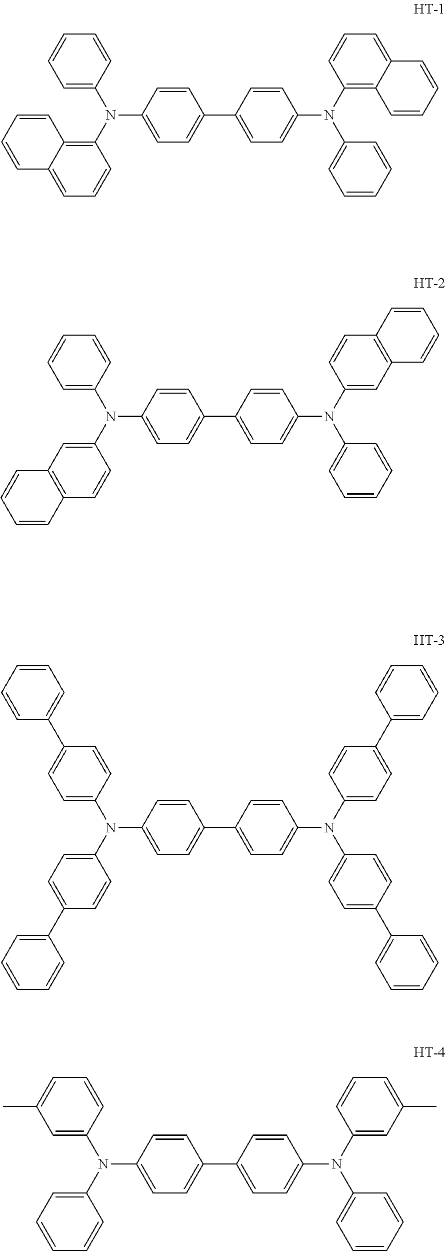

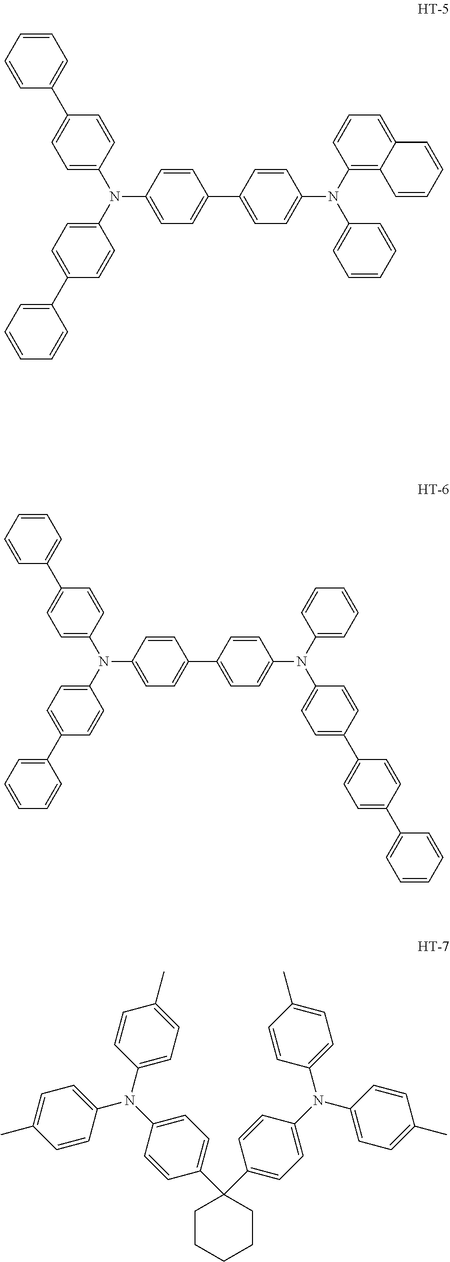

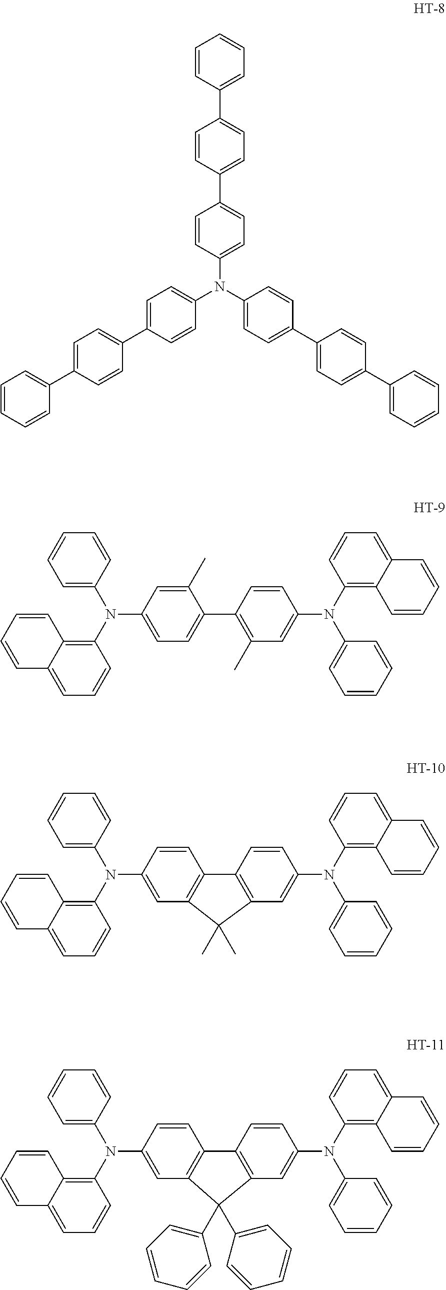 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; Cc1cc(N(c2ccccc2)c2cccc3ccccc23)ccc1-c1ccc(N(c2ccccc2)c2cccc3ccccc23)cc1C ; CC1(C)c2cc(N(c3ccccc3)c3cccc4ccccc34)ccc2-c2ccc(N(c3ccccc3)c3cccc4ccccc34)cc21 ; c1ccc(N(c2ccc3c(c2)C(c2ccccc2)(c2ccccc2)c2cc(N(c4ccccc4)c4cccc5ccccc45)ccc2-3)c2cccc3ccccc23)cc1]

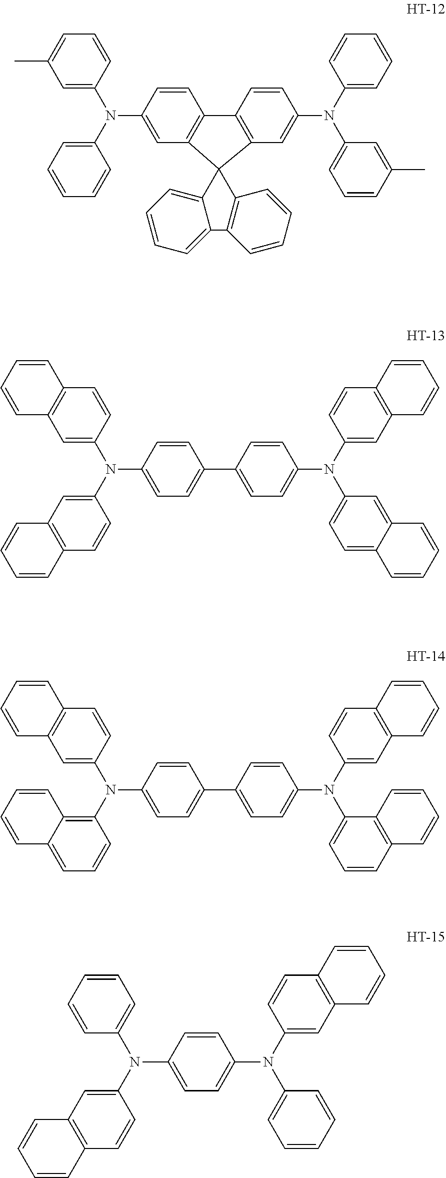

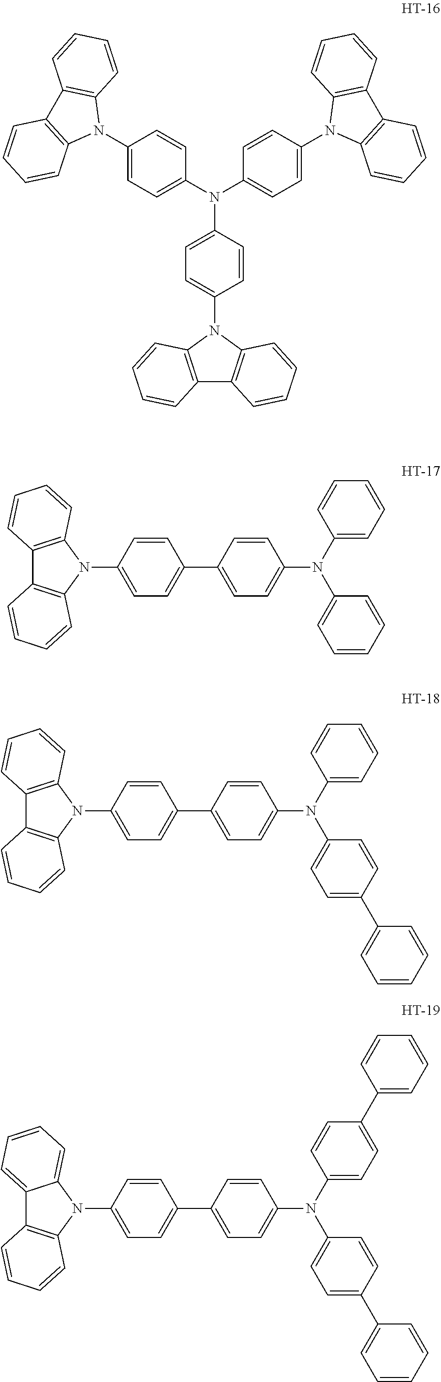 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

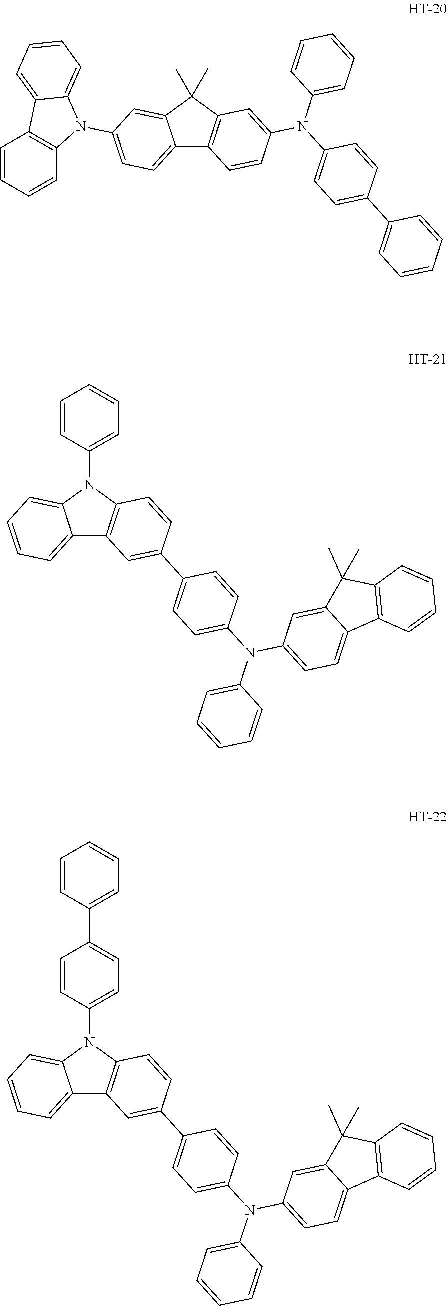 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

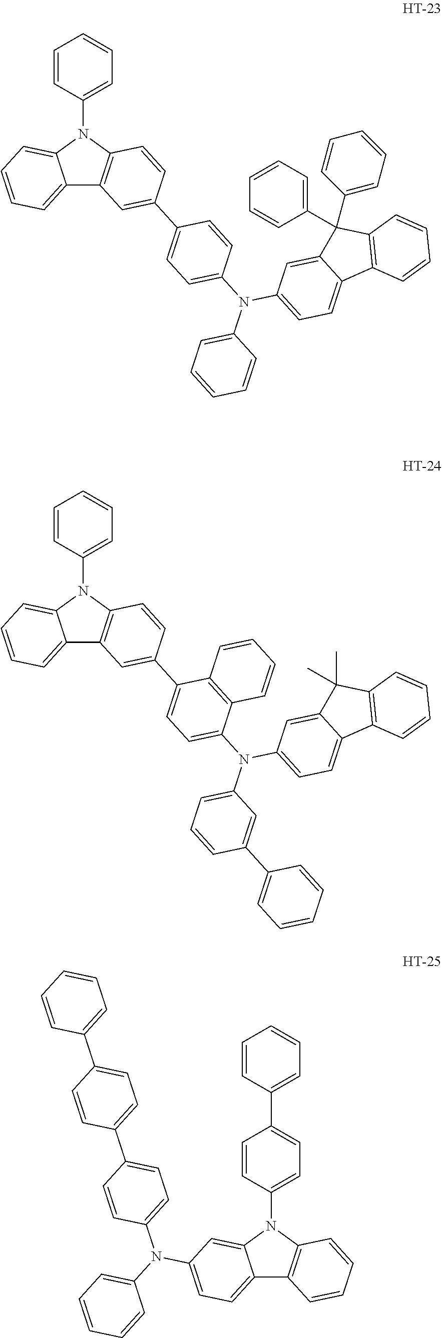 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; c1ccc(-c2ccc(-c3ccc(N(c4ccccc4)c4ccc5c6ccccc6n(-c6ccc(-c7ccccc7)cc6)c5c4)cc3)cc2)cc1]

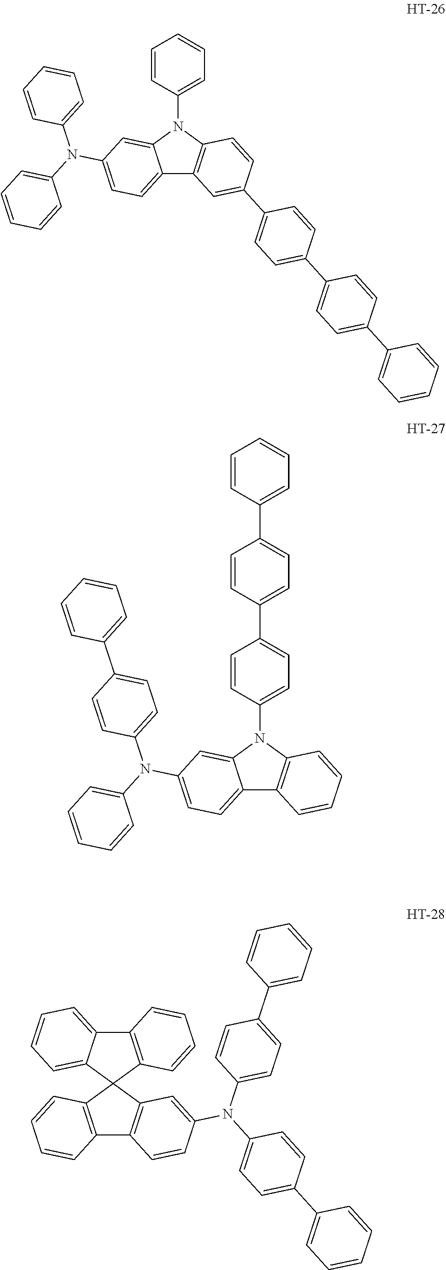 [SMILES: c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1]

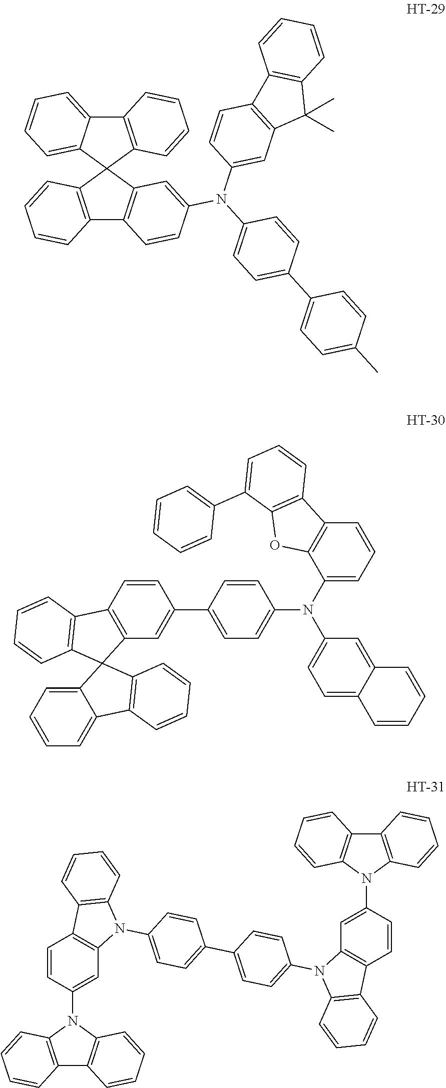 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1]

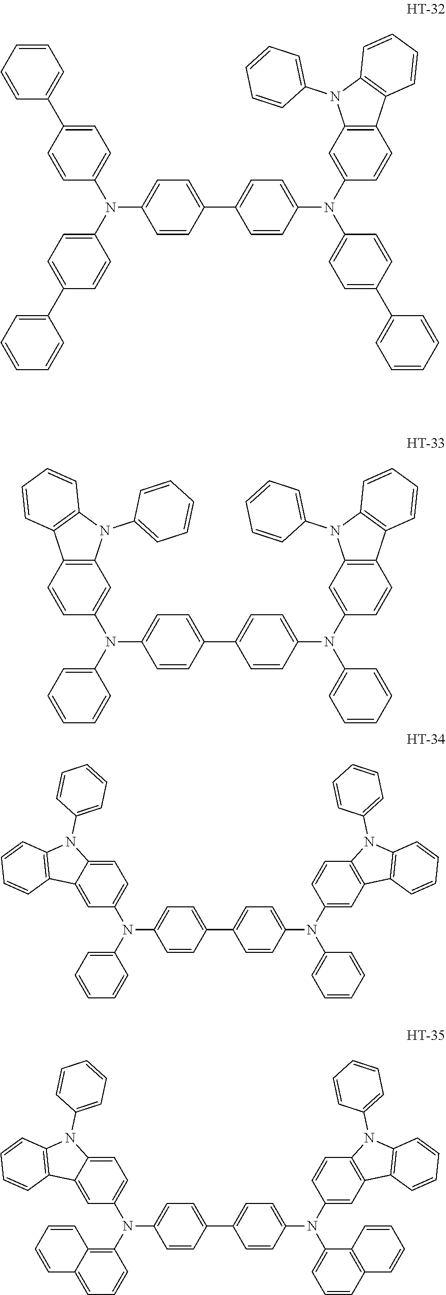

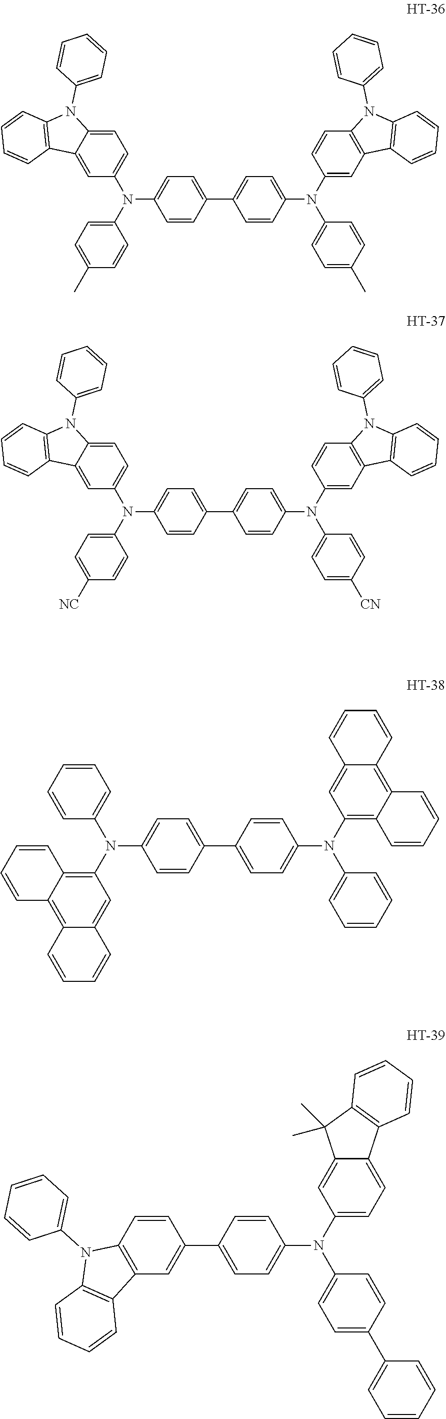 [SMILES: Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(N(c2ccc(-c3ccc(N(c4ccccc4)c4cc5ccccc5c5ccccc45)cc3)cc2)c2cc3ccccc3c3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

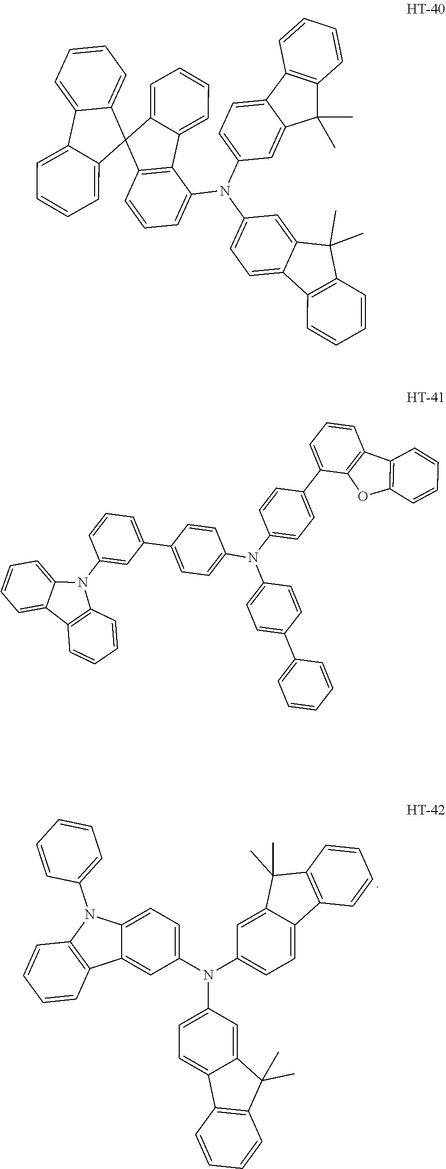 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1 ; CC1(C)c2ccccc2-c2ccc(N(c3ccc4c(c3)C(C)(C)c3ccccc3-4)c3ccc4c(c3)c3ccccc3n4-c3ccccc3)cc21]

In one specific embodiment, the hole transport layer 321 is HT-42.

Optionally, the electron blocking layer 322 includes one or more electron blocking material(s), which may be selected from carbazole multimers or other types of compounds. It is not particularly limited in the present application. In one specific embodiment, the electron blocking layer 322 is SiCzCz.

Optionally, the organic light-emitting layer 330 may be composed of a single luminescent layer material or may comprise a host material and a doping material. Optionally, the organic light-emitting layer 330 is composed of a host material and a doping material. The holes injected into the organic light-emitting layer 330 and the electrons injected into the organic light-emitting layer 330 can recombine in the organic light-emitting layer 330 to form excitons. The excitons transmit energy to the host material, and the host material transmits the energy to the doping material, thereby enabling the doping material to emit light.

The host material of the organic light-emitting layer 330 may be a metal chelating compound, a stilbene-based derivative, an aromatic amine derivative, a dibenzofuran derivative, or other types of materials. It is not particularly limited in the present application. The host material may be a single host material, or a mixed host material.

In one embodiment of the present application, the host material of the organic light-emitting layer 330 is BH-N and the organic compound of the present application.

The doping material of the organic light-emitting layer 330 can be selected based on the prior art, and for example, may be selected from an iridium (III) organometallic complex, a platinum (II) organometallic complex, and a ruthenium (II) complex, etc. The specific examples of the doping material include but are not limited to

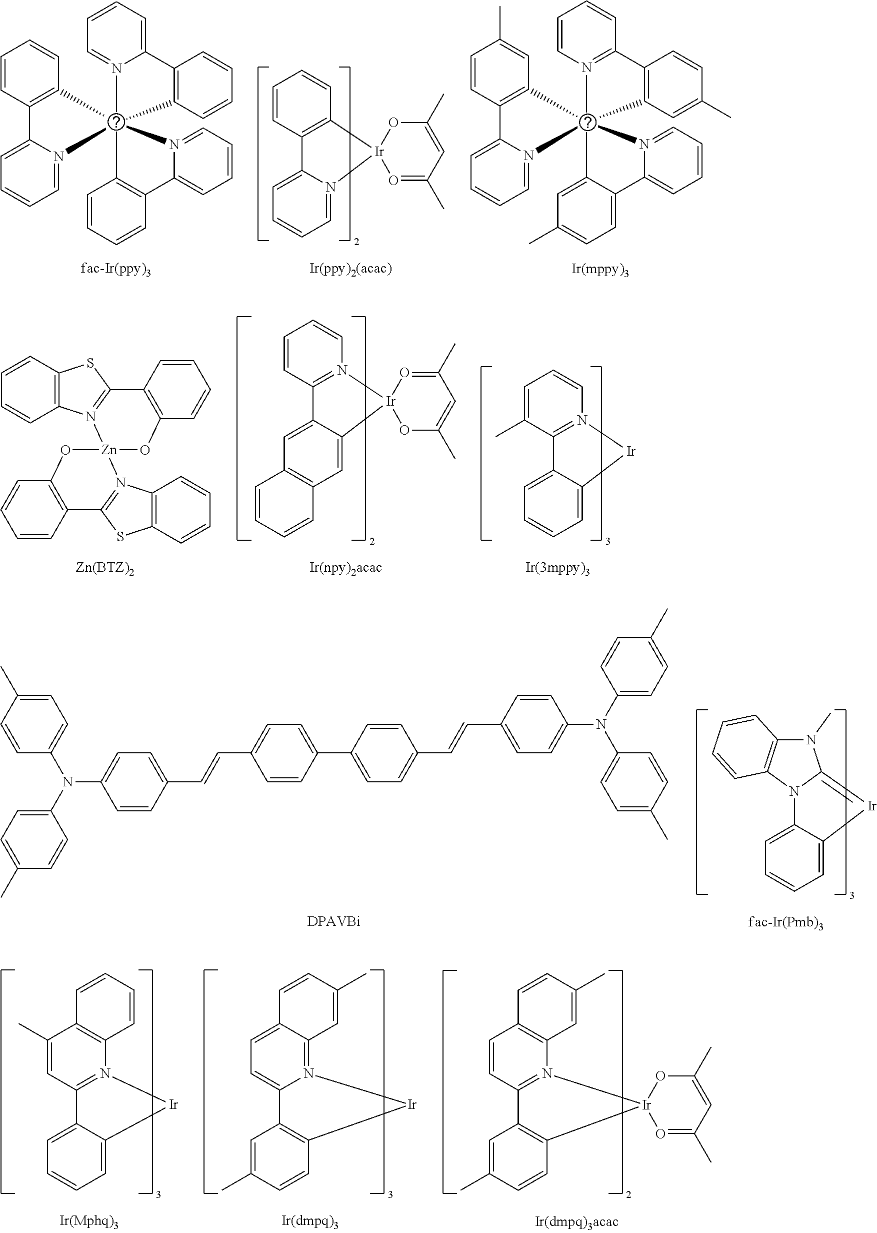

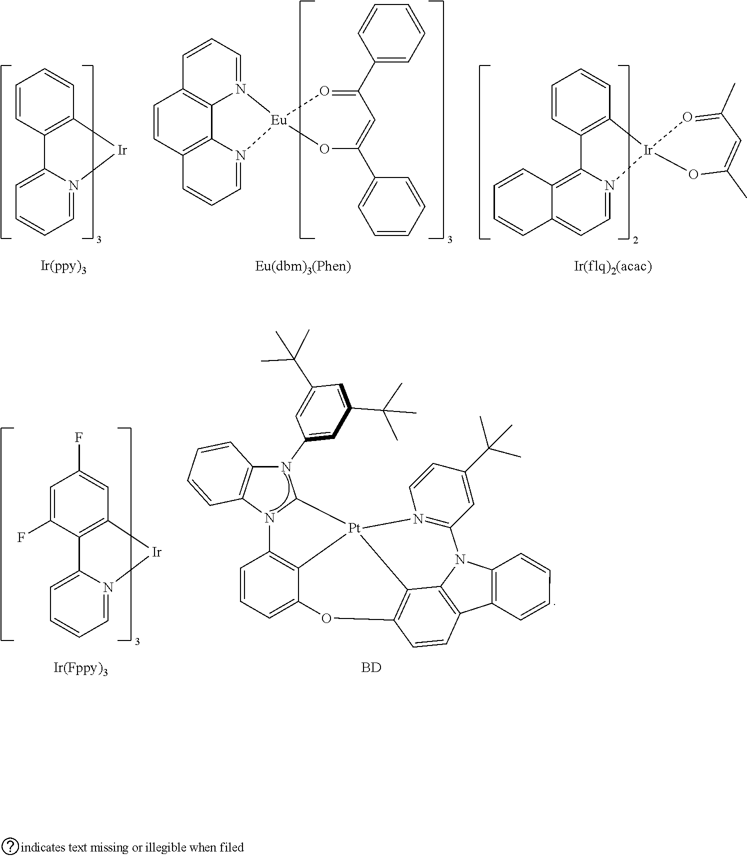

In one embodiment of the present application, the doping material of the organic light-emitting layer 330 is BD.

Optionally, the electron transport layer 340 may be either a single-layer structure or a multi-layer structure and may comprise one or more electron transport material(s). The electron transport material may typically include a metal complex or a nitrogen-containing heterocyclic derivative, in which the metal complex material may be, for example, selected from LiQ, Alq₃, and Bepq₂, etc; the nitrogen-containing heterocyclic derivative may be an aromatic ring compound with a nitrogen-containing 5-membered or 6-membered skeleton, a fused aromatic ring compound with a nitrogen-containing 5-membered or 6-membered skeleton, etc. Specific examples include but are not limited to 1,10-phenanthroline based compounds such as ET-21, Bphen, Nbphen, DBimiBphen, BimiBphen, or anthracene-based compounds, triazine based compounds, or pyrimidine-based compounds with nitrogen-containing heteroaryl as shown below. In one embodiment of the present application, the electron transport layer 340 is composed of ET-21 and LiQ.

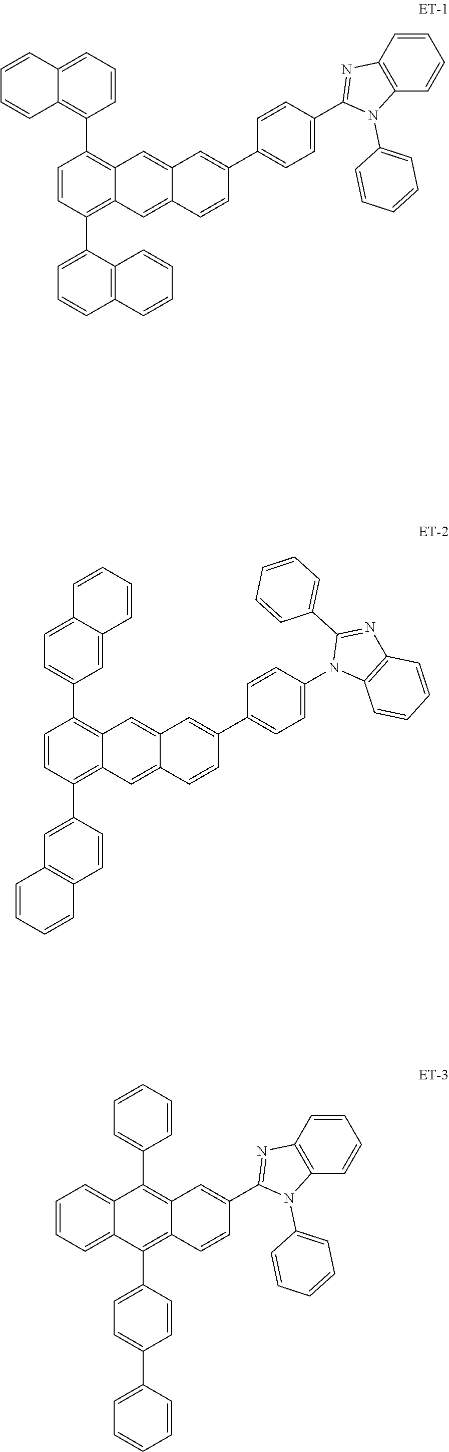 [SMILES: c1ccc(-n2c(-c3ccc(-c4ccc5cc6c(-c7cccc8ccccc78)ccc(-c7cccc8ccccc78)c6cc5c4)cc3)nc3ccccc32)cc1 ; c1ccc(-c2nc3ccccc3n2-c2ccc(-c3ccc4cc5c(-c6ccc7ccccc7c6)ccc(-c6ccc7ccccc7c6)c5cc4c3)cc2)cc1 ; c1ccc(-c2ccc(-c3c4ccccc4c(-c4ccccc4)c4cc(-c5nc6ccccc6n5-c5ccccc5)ccc34)cc2)cc1]

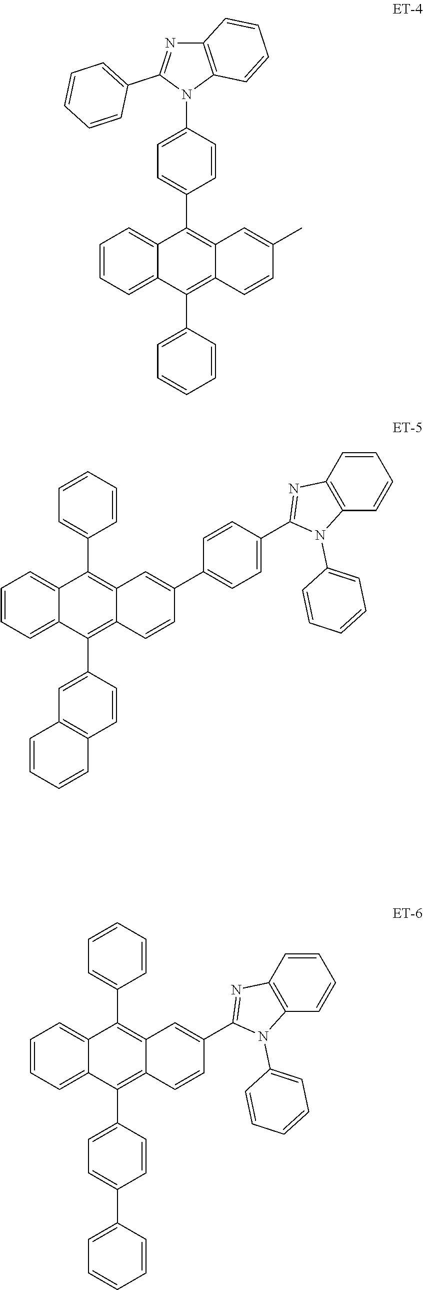 [SMILES: Cc1ccc2c(-c3ccccc3)c3ccccc3c(-c3ccc(-n4c(-c5ccccc5)nc5ccccc54)cc3)c2c1 ; c1ccc(-c2c3ccccc3c(-c3ccc4ccccc4c3)c3ccc(-c4ccc(-c5nc6ccccc6n5-c5ccccc5)cc4)cc23)cc1 ; c1ccc(-c2ccc(-c3c4ccccc4c(-c4ccccc4)c4cc(-c5nc6ccccc6n5-c5ccccc5)ccc34)cc2)cc1]

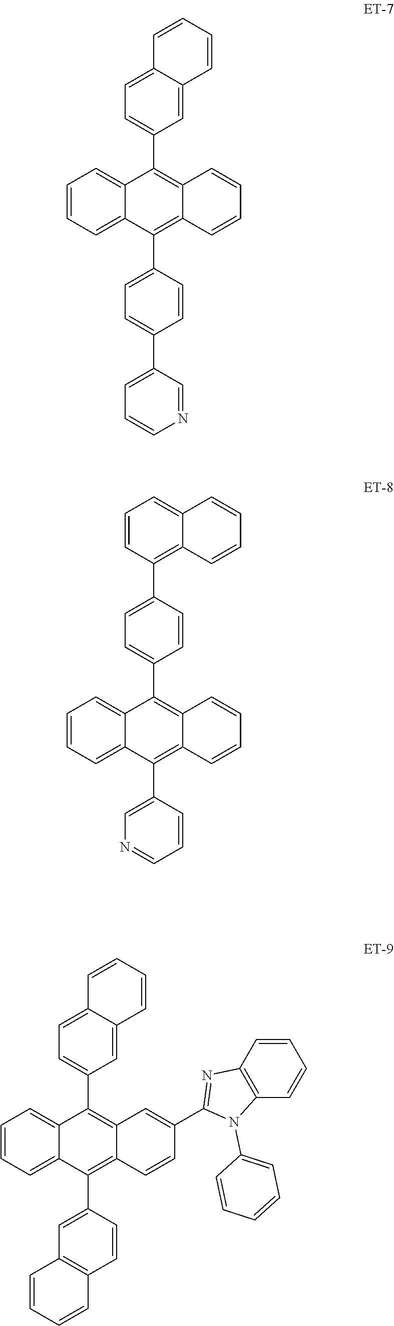 [SMILES: c1cncc(-c2ccc(-c3c4ccccc4c(-c4ccc5ccccc5c4)c4ccccc34)cc2)c1 ; c1cncc(-c2c3ccccc3c(-c3ccc(-c4cccc5ccccc45)cc3)c3ccccc23)c1 ; c1ccc(-n2c(-c3ccc4c(-c5ccc6ccccc6c5)c5ccccc5c(-c5ccc6ccccc6c5)c4c3)nc3ccccc32)cc1]

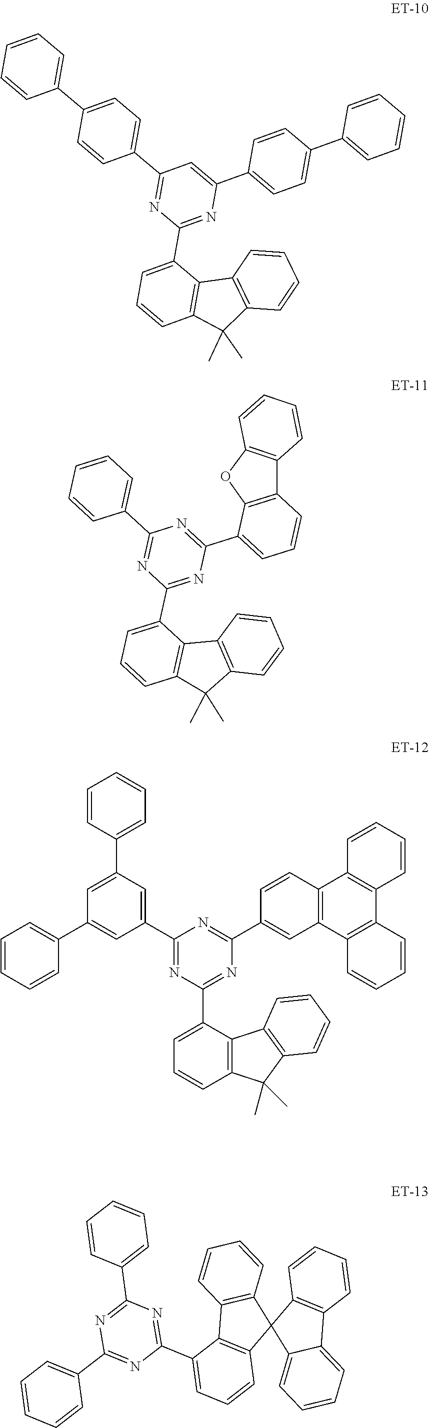

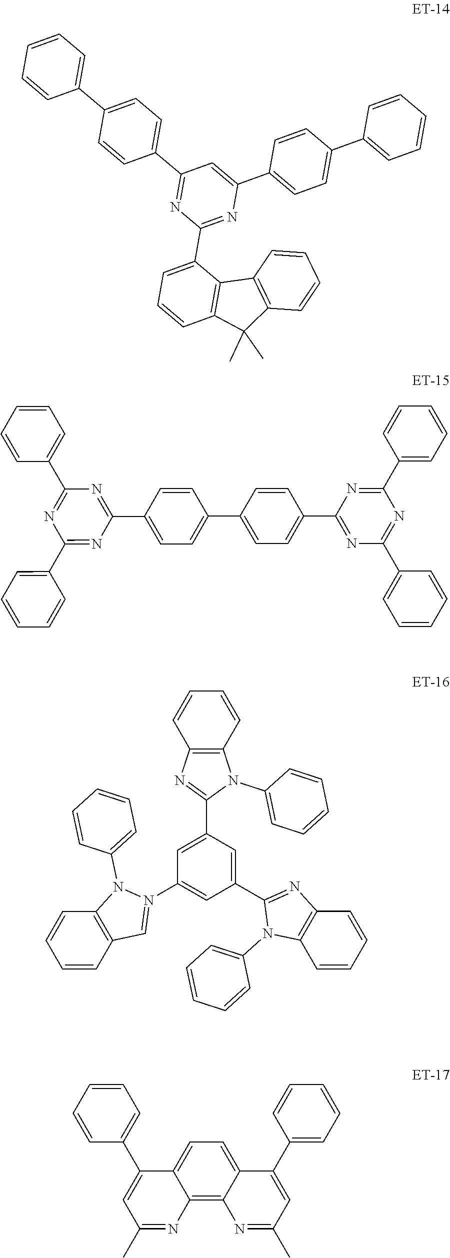

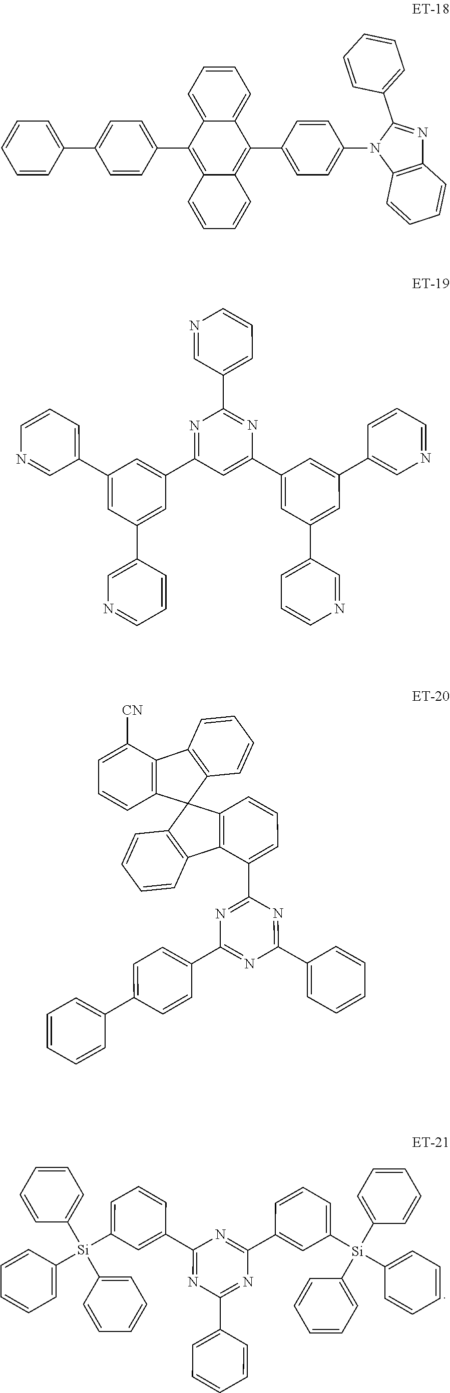 [SMILES: c1ccc(-c2ccc(-c3c4ccccc4c(-c4ccc(-n5c(-c6ccccc6)nc6ccccc65)cc4)c4ccccc34)cc2)cc1 ; c1cncc(-c2cc(-c3cccnc3)cc(-c3cc(-c4cc(-c5cccnc5)cc(-c5cccnc5)c4)nc(-c4cccnc4)n3)c2)c1 ; N#Cc1cccc2c1-c1ccccc1C21c2ccccc2-c2c(-c3nc(-c4ccccc4)nc(-c4ccc(-c5ccccc5)cc4)n3)cccc21 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

In the present application, the cathode 200 may comprise a cathode material, which is a low work function material contributing to injection of electrons into the functional layer. Specific examples of the cathode material include, but are not limited to, metals such as magnesium, calcium, sodium, potassium, titanium, indium, yttrium, lithium, gadolinium, aluminum, silver, tin, and lead, or alloys thereof; or multilayer materials such as LiF/Al, Liq/Al, LiO₂/Al, LiF/Ca, LiF/Al, and BaF₂/Ca. Preferably, a metal electrode comprising magnesium and silver as the cathode is included.

Optionally, as shown in FIG. 1, a hole injection layer 310 may be further provided between the anode 100 and the hole transport layer 321 to enhance the ability to inject holes into the hole transport layer 321. The hole injection layer 310 may choose to use a benzidine derivative, a starburst arylamine-based compound, a phthalocyanine derivative, and other materials. It is not particularly limited in the present application. For example, the compound contained in the hole injection layer 310 is selected from the group consisting of the following compounds.

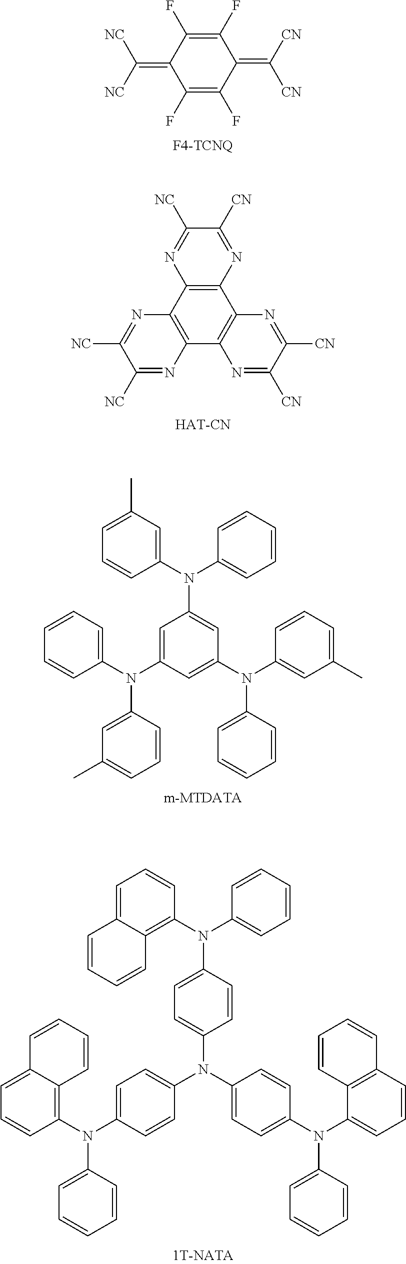 [SMILES: N#CC(C#N)=c1c(F)c(F)c(=C(C#N)C#N)c(F)c1F ; N#Cc1nc2c3nc(C#N)c(C#N)nc3c3nc(C#N)c(C#N)nc3c2nc1C#N ; Cc1cccc(N(c2ccccc2)c2cc(N(c3ccccc3)c3cccc(C)c3)cc(N(c3ccccc3)c3cccc(C)c3)c2)c1 ; c1ccc(N(c2ccc(N(c3ccc(N(c4ccccc4)c4cccc5ccccc45)cc3)c3ccc(N(c4ccccc4)c4cccc5ccccc45)cc3)cc2)c2cccc3ccccc23)cc1]

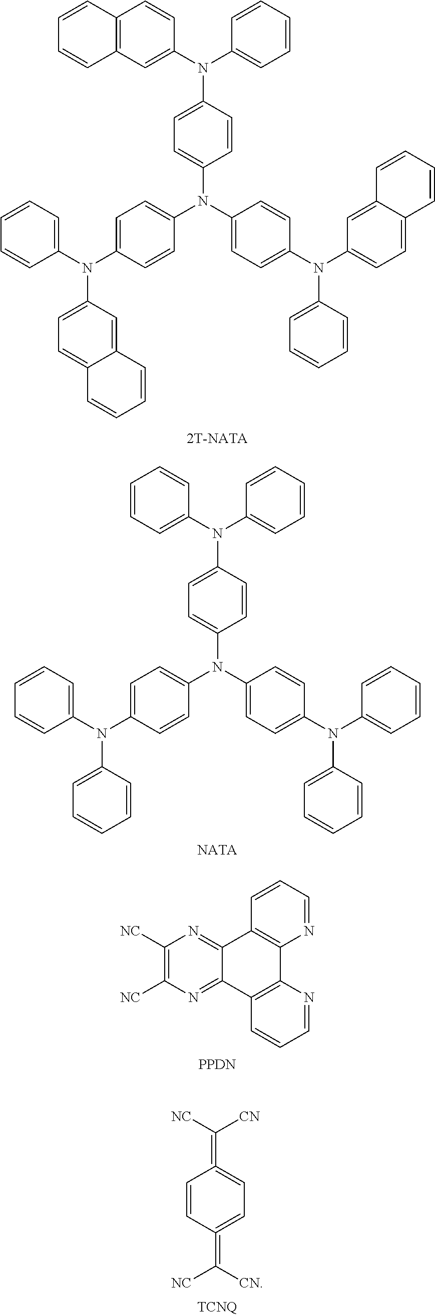

In one specific embodiment of the present application, the hole injection layer 310 is HAT-CN and HT-42.

Optionally, as shown in FIG. 1, an electron injection layer 350 is further provided between the cathode 200 and the electron transport layer 340 to enhance the ability to inject electrons into the electron transport layer 340. The electron injection layer 350 may comprise an inorganic material such as an alkali metal sulfide and an alkali metal halide or may comprise a complex of an alkali metal and an organic compound. In one specific embodiment of the present application, the electron injection layer 350 is Yb.

In a third aspect, the present application provides an electronic apparatus, comprising the electronic element described in the second aspect.

According to one embodiment, as shown in FIG. 2, the electronic apparatus is an electronic apparatus 400 comprising the above-described organic electroluminescent device. The electronic apparatus 400 may be a display apparatus, a lighting apparatus, an optical communication apparatus, or other type of electronic apparatus, examples of which may include, for example but be not limited to, computer screens, mobile phone screens, televisions, electronic paper, emergency lamps, and optical modules, etc.

The synthesis method of the organic compound in the present application will be demonstrated in detail with the following synthesis examples, but the present application is not limited in any way by this.

The compounds of which the synthetic methods not mentioned in the present application are all raw material products commercially available.

### Synthesis Example

### 1. Synthesis of IM a-1

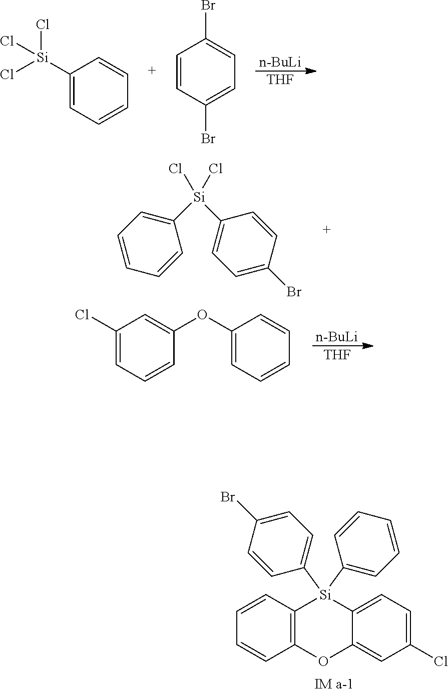

1,4-dibromobenzene (100 g, 423.9 mmol) was dissolved in dried THF (800 mL) in a reaction flask 1 and the resulting solution was cooled to −78° C., followed by addition of (2M) n-butyllithium (n-BuLi) (211.9 mL) dropwise. After the dropwise addition was completed, the resulting solution was maintained at −78° C. and added with trichlorophenylsilane (89.6 g, 423.9 mmol) dropwise in 30 minutes, followed by 1 hour of reaction maintained at that temperature. Meanwhile, 3-chlorodiphenyl ether (86.7 g, 423.9 mmol) was dissolved in dried tetrahydrofuran (THF) (450 mL) in a reaction flask 2, and the resulting solution was cooled to −78° C., followed by addition of (2M) n-butyllithium (423 mL) dropwise. After the dropwise addition was completed, the resulting solution was maintained at that temperature for 1 hour of reaction. The reaction solution obtained from the reaction flask 1 and the reaction solution in the reaction flask 2 were mixed for 2 hours of reaction maintained at that temperature. Then the reaction solution was allowed to naturally warm to room temperature with stirring for another 2 hours, then the reaction was completed. The reaction solution was quenched with water, extracted with dichloromethane, dried over anhydrous magnesium sulfate to remove water, followed by the removal of the solvent under reduced pressure to yield a crude product. The crude product was purified via silica gel chromatography using a mixed solvent of dichloromethane and n-heptane to yield IM a-1 as a white solid (127.8 g; yield 650%).

IM a-x listed in Table 1 were synthesized using the same method as that for IM a-1, except that Raw material 1 was used instead of trichlorophenylsilane, and Raw material 2 was used instead of 1,4-dibromobenzene, and Raw material 3 was used instead of 3-chlorodiphenyl ether. The main raw materials used, the synthesized IM a-x, and final yields thereof are shown in Table 1.

TABLE 1

| Raw material 1 | Raw material 2 | Raw material 3 | IM a-x | Yield/% |
|---|---|---|---|---|
| 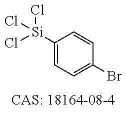 [SMILES: Cl[Si](Cl)(Cl)c1ccc(Br)cc1] | 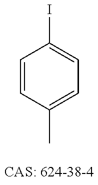 | 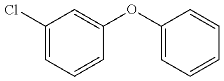 [SMILES: Clc1cccc(Oc2ccccc2)c1] | 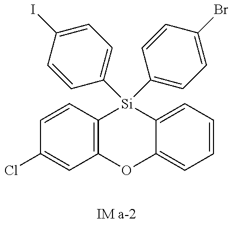 [SMILES: Clc1ccc2c(c1)Oc1ccccc1[Si]2(c1ccc(Br)cc1)c1ccc(I)cc1] | 67 |
| 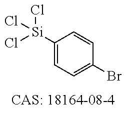 [SMILES: Cl[Si](Cl)(Cl)c1ccc(Br)cc1] | 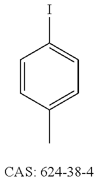 | 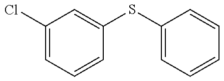 [SMILES: Clc1cccc(Sc2ccccc2)c1] | 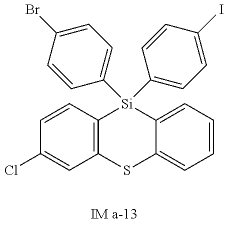 [SMILES: Clc1ccc2c(c1)Sc1ccccc1[Si]2(c1ccc(Br)cc1)c1ccc(I)cc1] | 58 |
| 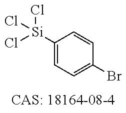 [SMILES: Cl[Si](Cl)(Cl)c1ccc(Br)cc1] | 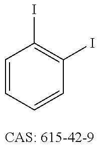 | 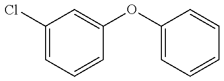 [SMILES: Clc1cccc(Oc2ccccc2)c1] | 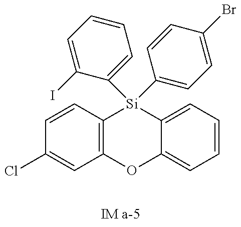 [SMILES: Clc1ccc2c(c1)Oc1ccccc1[Si]2(c1ccc(Br)cc1)c1ccccc1I] | 47 |
| 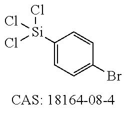 [SMILES: Cl[Si](Cl)(Cl)c1ccc(Br)cc1] | 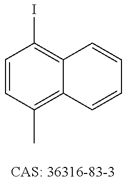 | 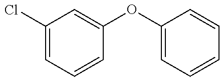 [SMILES: Clc1cccc(Oc2ccccc2)c1] | 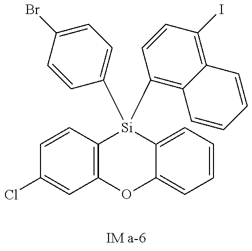 [SMILES: Clc1ccc2c(c1)Oc1ccccc1[Si]2(c1ccc(Br)cc1)c1ccc(I)c2ccccc12] | 52 |
| 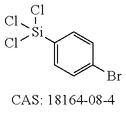 [SMILES: Cl[Si](Cl)(Cl)c1ccc(Br)cc1] | 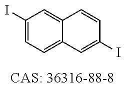 [SMILES: Ic1ccc2cc(I)ccc2c1] | 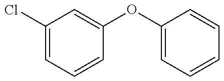 [SMILES: Clc1cccc(Oc2ccccc2)c1] | 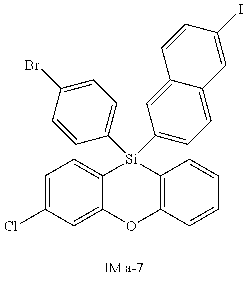 [SMILES: Clc1ccc2c(c1)Oc1ccccc1[Si]2(c1ccc(Br)cc1)c1ccc2cc(I)ccc2c1] | 55 |
| 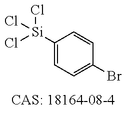 [SMILES: Cl[Si](Cl)(Cl)c1ccc(Br)cc1] | 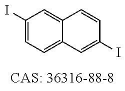 [SMILES: Ic1ccc2cc(I)ccc2c1] | 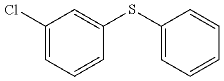 [SMILES: Clc1cccc(Sc2ccccc2)c1] | 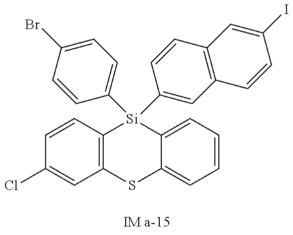 [SMILES: Clc1ccc2c(c1)Sc1ccccc1[Si]2(c1ccc(Br)cc1)c1ccc2cc(I)ccc2c1] | 54 |
| 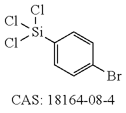 [SMILES: Cl[Si](Cl)(Cl)c1ccc(Br)cc1] | 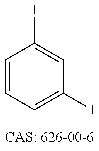 | 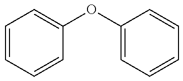 [SMILES: c1ccc(Oc2ccccc2)cc1] | 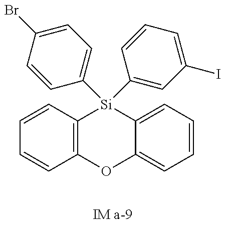 [SMILES: Brc1ccc([Si]2(c3cccc(I)c3)c3ccccc3Oc3ccccc32)cc1] | 58 |
| 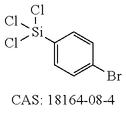 [SMILES: Cl[Si](Cl)(Cl)c1ccc(Br)cc1] | 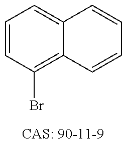 [SMILES: Brc1cccc2ccccc12] | 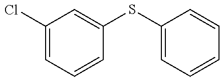 [SMILES: Clc1cccc(Sc2ccccc2)c1] | 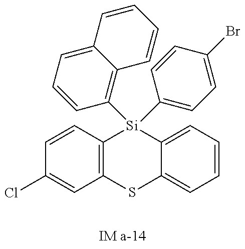 [SMILES: Clc1ccc2c(c1)Sc1ccccc1[Si]2(c1ccc(Br)cc1)c1cccc2ccccc12] | 55 |
| 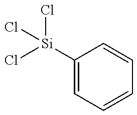 | 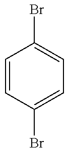 | 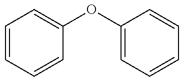 [SMILES: c1ccc(Oc2ccccc2)cc1] | 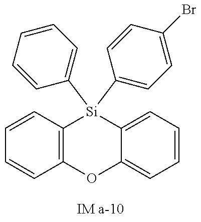 [SMILES: Brc1ccc([Si]2(c3ccccc3)c3ccccc3Oc3ccccc32)cc1] | 70 |
| 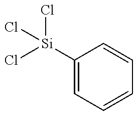 | 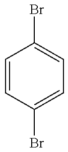 | 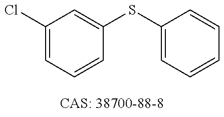 [SMILES: Clc1cccc(Sc2ccccc2)c1] | 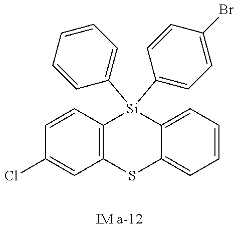 [SMILES: Clc1ccc2c(c1)Sc1ccccc1[Si]2(c1ccccc1)c1ccc(Br)cc1] | 60 |
| 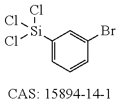 [SMILES: Cl[Si](Cl)(Cl)c1cccc(Br)c1] | 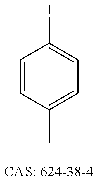 | 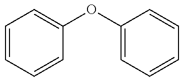 [SMILES: c1ccc(Oc2ccccc2)cc1] | 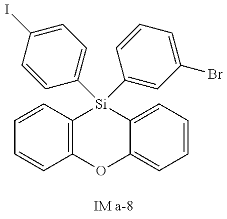 [SMILES: Brc1cccc([Si]2(c3ccc(I)cc3)c3ccccc3Oc3ccccc32)c1] | 52 |
| 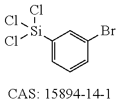 [SMILES: Cl[Si](Cl)(Cl)c1cccc(Br)c1] | 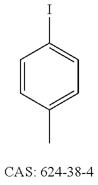 | 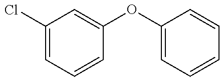 [SMILES: Clc1cccc(Oc2ccccc2)c1] | 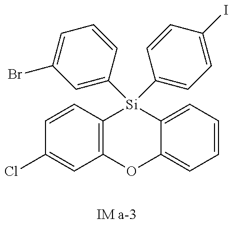 [SMILES: Clc1ccc2c(c1)Oc1ccccc1[Si]2(c1ccc(I)cc1)c1cccc(Br)c1] | 61 |
| 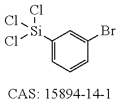 [SMILES: Cl[Si](Cl)(Cl)c1cccc(Br)c1] | 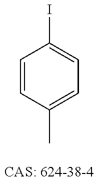 | 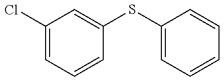 [SMILES: Clc1cccc(Sc2ccccc2)c1] | 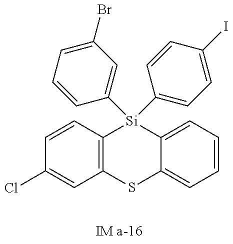 [SMILES: Clc1ccc2c(c1)Sc1ccccc1[Si]2(c1ccc(I)cc1)c1cccc(Br)c1] | 50 |
| 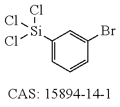 [SMILES: Cl[Si](Cl)(Cl)c1cccc(Br)c1] | 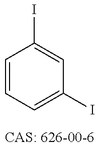 | 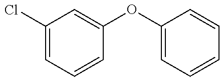 [SMILES: Clc1cccc(Oc2ccccc2)c1] | 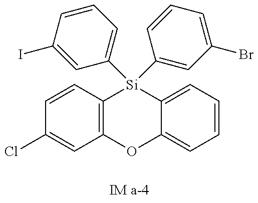 [SMILES: Clc1ccc2c(c1)Oc1ccccc1[Si]2(c1cccc(Br)c1)c1cccc(I)c1] | 50 |
| 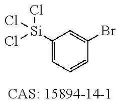 [SMILES: Cl[Si](Cl)(Cl)c1cccc(Br)c1] | 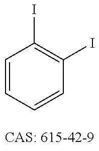 | 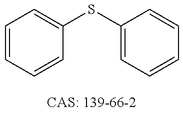 [SMILES: c1ccc(Sc2ccccc2)cc1] | 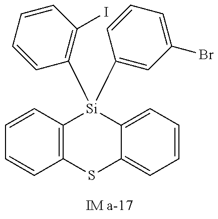 [SMILES: Brc1cccc([Si]2(c3ccccc3I)c3ccccc3Sc3ccccc32)c1] | 46 |

### 2. Synthesis of IM b-1

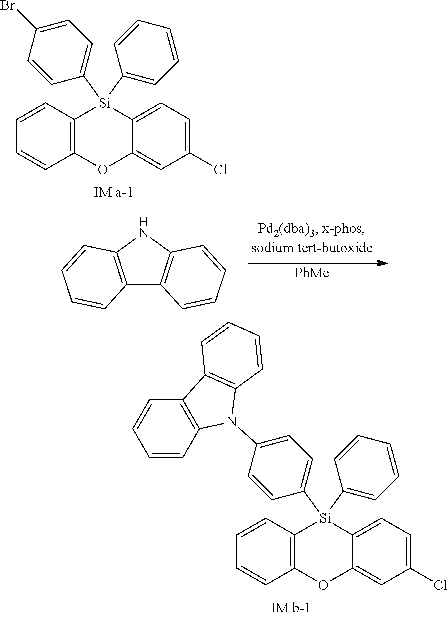

IM a-1 (20 g, 43.1 mmol), carbazole (7.2 g, 43.1 mmol), tris(dibenzylidene acetonate) dipalladium (Pd₂(dba)₃) (0.39 g, 0.43 mmol), 2-dicyclohexylphosphino-2′,4′,6′-triisopropylbiphenyl (x-phos) (0.41 g, 0.86 mmol), sodium tert-butoxide (6.3 g, 64.7 mmol), and toluene (PhMe) (200 mL) were added into a flask, and then the resulting solution was heated to 110° C. for 4 hours of reaction. After the reaction was completed, the reaction solution was cooled to room temperature, and extracted with dichloromethane and water to separate the organic phase. The organic phase was dried over anhydrous magnesium sulfate to remove water, and then concentrated under reduced pressure to yield a grayish-black crude product. The crude product was purified via silica gel column chromatography using a mixed solvent of dichloromethane/n-heptane as the mobile phase, to yield IM b-1 (15.6 g; yield 66%).

IM b-x listed in Table 2 were synthesized using the same method as that for IM b-1, except that Raw material 4 was used instead of IM a-1. The main raw materials used, the synthesized intermediates, and yields thereof are shown in Table 2.

TABLE 2

| Raw material 4 | IM b-x | Yield/% |
|---|---|---|
| 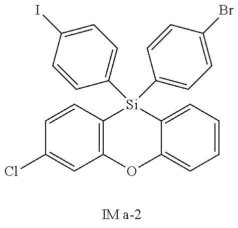 [SMILES: Clc1ccc2c(c1)Oc1ccccc1[Si]2(c1ccc(Br)cc1)c1ccc(I)cc1] | 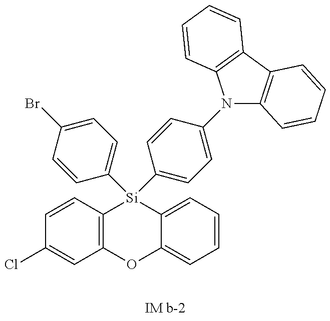 [SMILES: Clc1ccc2c(c1)Oc1ccccc1[Si]2(c1ccc(Br)cc1)c1ccc(-n2c3ccccc3c3ccccc32)cc1] | 64 |
| 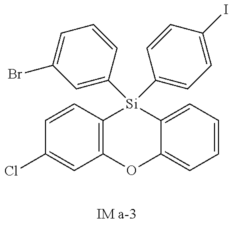 [SMILES: Clc1ccc2c(c1)Oc1ccccc1[Si]2(c1ccc(I)cc1)c1cccc(Br)c1] | 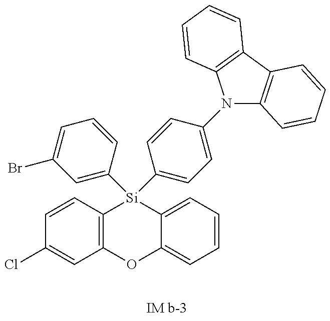 [SMILES: Clc1ccc2c(c1)Oc1ccccc1[Si]2(c1ccc(-n2c3ccccc3c3ccccc32)cc1)c1cccc(Br)c1] | 76 |
| 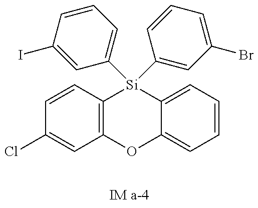 [SMILES: Clc1ccc2c(c1)Oc1ccccc1[Si]2(c1cccc(Br)c1)c1cccc(I)c1] | 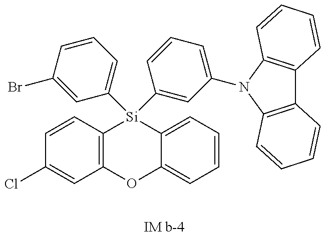 [SMILES: Clc1ccc2c(c1)Oc1ccccc1[Si]2(c1cccc(Br)c1)c1cccc(-n2c3ccccc3c3ccccc32)c1] | 64 |
| 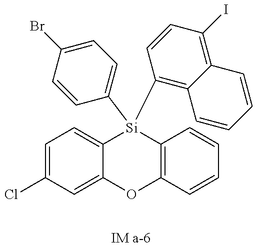 [SMILES: Clc1ccc2c(c1)Oc1ccccc1[Si]2(c1ccc(Br)cc1)c1ccc(I)c2ccccc12] | 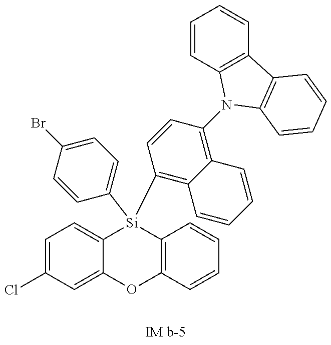 [SMILES: Clc1ccc2c(c1)Oc1ccccc1[Si]2(c1ccc(Br)cc1)c1ccc(-n2c3ccccc3c3ccccc32)c2ccccc12] | 62 |
| 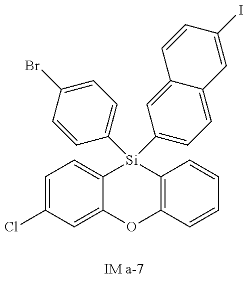 [SMILES: Clc1ccc2c(c1)Oc1ccccc1[Si]2(c1ccc(Br)cc1)c1ccc2cc(I)ccc2c1] | 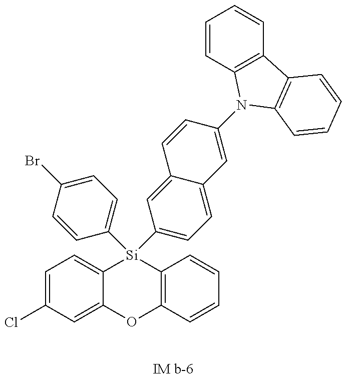 [SMILES: Clc1ccc2c(c1)Oc1ccccc1[Si]2(c1ccc(Br)cc1)c1ccc2cc(-n3c4ccccc4c4ccccc43)ccc2c1] | 68 |
| 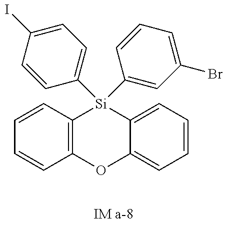 [SMILES: Brc1cccc([Si]2(c3ccc(I)cc3)c3ccccc3Oc3ccccc32)c1] | 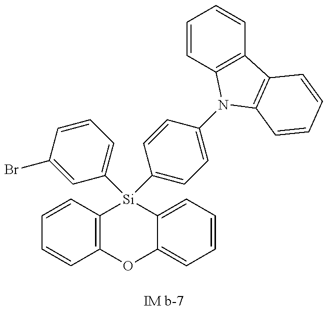 [SMILES: Brc1cccc([Si]2(c3ccc(-n4c5ccccc5c5ccccc54)cc3)c3ccccc3Oc3ccccc32)c1] | 74 |
| 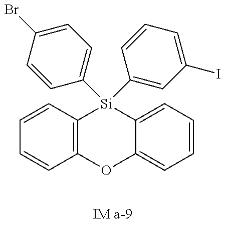 [SMILES: Brc1ccc([Si]2(c3cccc(I)c3)c3ccccc3Oc3ccccc32)cc1] | 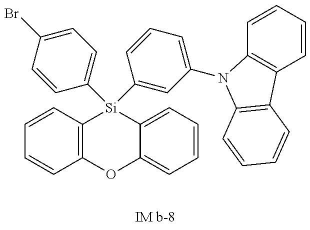 [SMILES: Brc1ccc([Si]2(c3cccc(-n4c5ccccc5c5ccccc54)c3)c3ccccc3Oc3ccccc32)cc1] | 72 |
| 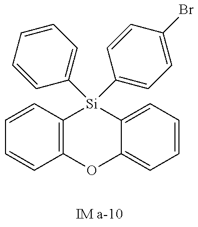 [SMILES: Brc1ccc([Si]2(c3ccccc3)c3ccccc3Oc3ccccc32)cc1] | 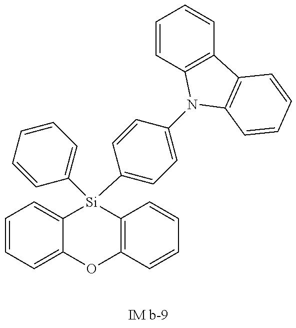 [SMILES: c1ccc([Si]2(c3ccc(-n4c5ccccc5c5ccccc54)cc3)c3ccccc3Oc3ccccc32)cc1] | 70 |
| 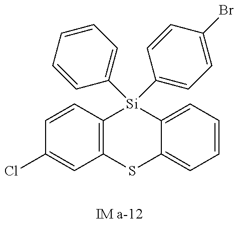 [SMILES: Clc1ccc2c(c1)Sc1ccccc1[Si]2(c1ccccc1)c1ccc(Br)cc1] | 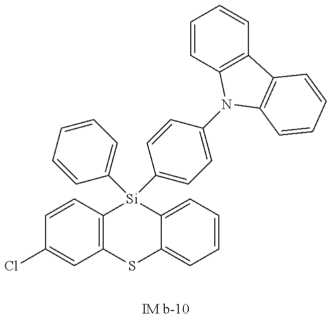 [SMILES: Clc1ccc2c(c1)Sc1ccccc1[Si]2(c1ccccc1)c1ccc(-n2c3ccccc3c3ccccc32)cc1] | 79 |
| 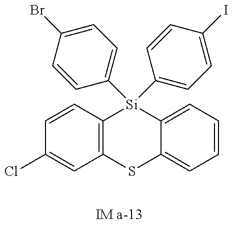 [SMILES: Clc1ccc2c(c1)Sc1ccccc1[Si]2(c1ccc(Br)cc1)c1ccc(I)cc1] | 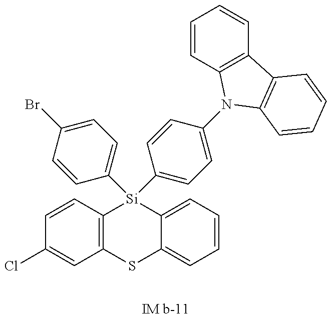 [SMILES: Clc1ccc2c(c1)Sc1ccccc1[Si]2(c1ccc(Br)cc1)c1ccc(-n2c3ccccc3c3ccccc32)cc1] | 75 |
| 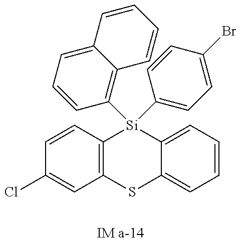 [SMILES: Clc1ccc2c(c1)Sc1ccccc1[Si]2(c1ccc(Br)cc1)c1cccc2ccccc12] | 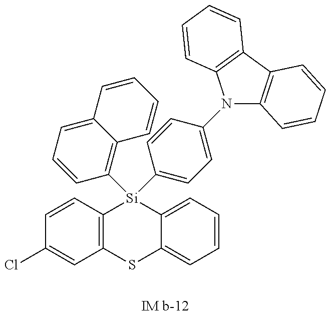 [SMILES: Clc1ccc2c(c1)Sc1ccccc1[Si]2(c1ccc(-n2c3ccccc3c3ccccc32)cc1)c1cccc2ccccc12] | 68 |
| 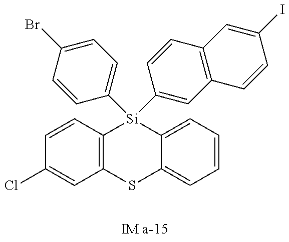 [SMILES: Clc1ccc2c(c1)Sc1ccccc1[Si]2(c1ccc(Br)cc1)c1ccc2cc(I)ccc2c1] | 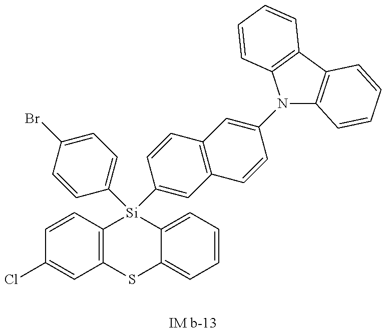 [SMILES: Clc1ccc2c(c1)Sc1ccccc1[Si]2(c1ccc(Br)cc1)c1ccc2cc(-n3c4ccccc4c4ccccc43)ccc2c1] | 65 |

### 3. Synthesis of IM b-14

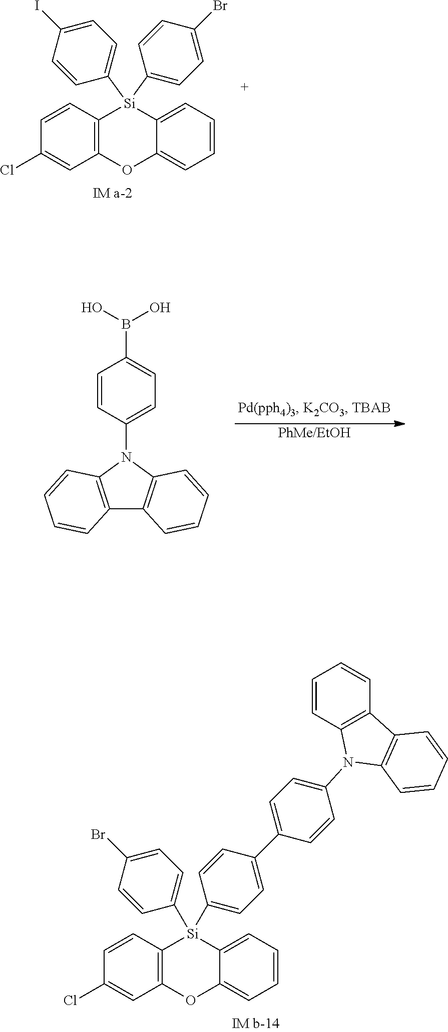 [SMILES: Clc1ccc2c(c1)Oc1ccccc1[Si]2(c1ccc(Br)cc1)c1ccc(I)cc1 ; OB(O)c1ccc(-n2c3ccccc3c3ccccc32)cc1 ; "PhMe/EtOH" ; Clc1ccc2c(c1)Oc1ccccc1[Si]2(c1ccc(Br)cc1)c1ccc(-c2ccc(-n3c4ccccc4c4ccccc43)cc2)cc1]

IM a-2 (20 g, 33.9 mmol), 4-(9H-carbazol-9-yl) phenylboronic acid (9.7 g, 33.9 mmol), tetrakis(triphenylphosphine) palladium (0.39 g, 0.34 mmol), potassium carbonate (10.3 g, 74.6 mmol), and tetrabutylammonium bromide (2.2 g, 6.8 mmol) were added into a flask, followed by the addition of a mixed solvent of toluene (160 mL), ethanol (EtOH) (80 mL), and water (40 mL). Under a nitrogen atmosphere, the resulting solution was heated to 78° C. and maintained at that temperature with stirring for 8 hours of reaction. Upon cooling to room temperature and cessation of stirring, the reaction solution was washed with water and the organic phase was separated. The organic phase was dried over anhydrous magnesium sulfate and the solvent was removed under reduced pressure to yield a crude product. The crude product was purified via silica gel chromatography using a mixed solvent of dichloromethane and n-heptane as the mobile phase, to yield IM b-14 as a white solid (17.9 g; yield 75%).

The Intermediate listed in Table 3 were synthesized using the same method as that for IM b-14, except that Raw material 5 was used instead of IM a-2, and Raw material 6 was used instead of 4-(9H-carbazol-9-yl) phenylboronic acid. The main raw materials used, the synthesized Intermediates, and yields thereof are shown in Table 3.

TABLE 3

| Raw material 5 | Raw material 6 | Intermediate structure | Yield/% |
|---|---|---|---|
| 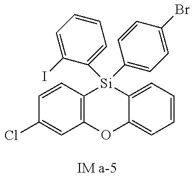 [SMILES: Clc1ccc2c(c1)Oc1ccccc1[Si]2(c1ccc(Br)cc1)c1ccccc1I] | 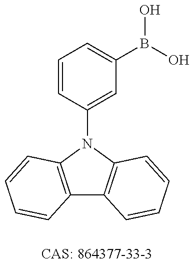 [SMILES: OB(O)c1cccc(-n2c3ccccc3c3ccccc32)c1] | 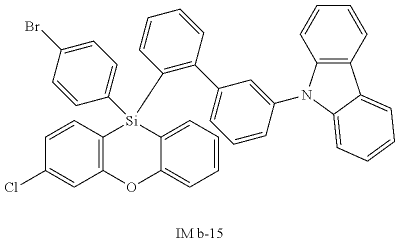 [SMILES: Clc1ccc2c(c1)Oc1ccccc1[Si]2(c1ccc(Br)cc1)c1ccccc1-c1cccc(-n2c3ccccc3c3ccccc32)c1] | 70 |
| 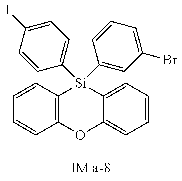 [SMILES: Brc1cccc([Si]2(c3ccc(I)cc3)c3ccccc3Oc3ccccc32)c1] | 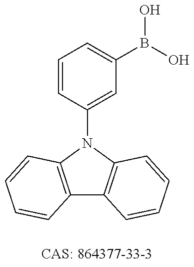 [SMILES: OB(O)c1cccc(-n2c3ccccc3c3ccccc32)c1] | 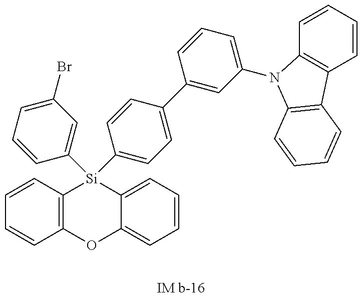 [SMILES: Brc1cccc([Si]2(c3ccc(-c4cccc(-n5c6ccccc6c6ccccc65)c4)cc3)c3ccccc3Oc3ccccc32)c1] | 75 |
| 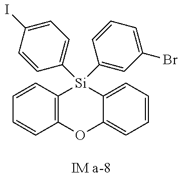 [SMILES: Brc1cccc([Si]2(c3ccc(I)cc3)c3ccccc3Oc3ccccc32)c1] | 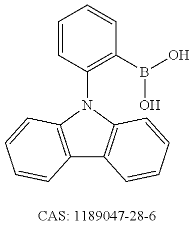 [SMILES: OB(O)c1ccccc1-n1c2ccccc2c2ccccc21] | 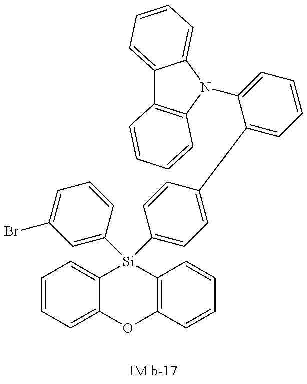 [SMILES: Brc1cccc([Si]2(c3ccc(-c4ccccc4-n4c5ccccc5c5ccccc54)cc3)c3ccccc3Oc3ccccc32)c1] | 68 |
| 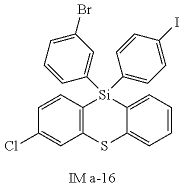 [SMILES: Clc1ccc2c(c1)Sc1ccccc1[Si]2(c1ccc(I)cc1)c1cccc(Br)c1] | 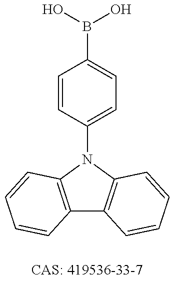 [SMILES: OB(O)c1ccc(-n2c3ccccc3c3ccccc32)cc1] | 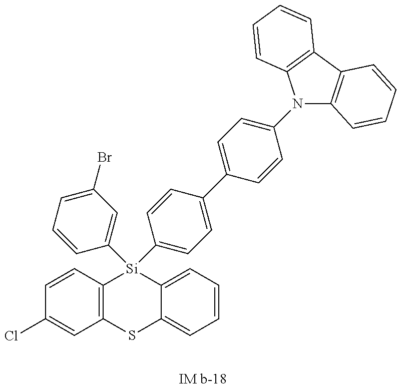 [SMILES: Clc1ccc2c(c1)Sc1ccccc1[Si]2(c1ccc(-c2ccc(-n3c4ccccc4c4ccccc43)cc2)cc1)c1cccc(Br)c1] | 70 |
| 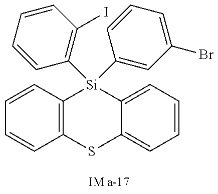 [SMILES: Brc1cccc([Si]2(c3ccccc3I)c3ccccc3Sc3ccccc32)c1] | 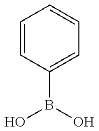 | 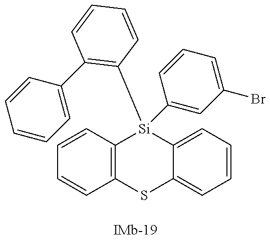 [SMILES: Brc1cccc([Si]2(c3ccccc3-c3ccccc3)c3ccccc3Sc3ccccc32)c1] | 71 |

### 4. Synthesis of IM c-1

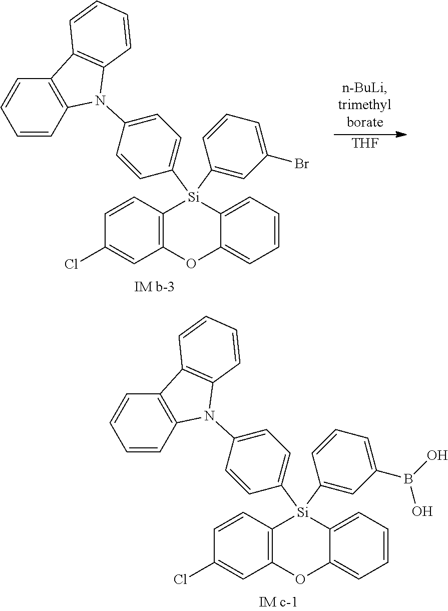 [SMILES: Clc1ccc2c(c1)Oc1ccccc1[Si]2(c1ccc(-n2c3ccccc3c3ccccc32)cc1)c1cccc(Br)c1 ; OB(O)c1cccc([Si]2(c3ccc(-n4c5ccccc5c5ccccc54)cc3)c3ccccc3Oc3cc(Cl)ccc32)c1 ; "THF"]

IM b-3 (15 g, 23.8 mmol) and dried tetrahydrofuran (120 mL) were added into a flask. Under a nitrogen atmosphere, the resulting solution was cooled to −80° C. With stirring, a solution of n-butyllithium in tetrahydrofuran (2.5M) (13 mL, 26.2 mmol) was added dropwise. Following the completion of the drop wise addition, the resulting solution was maintained at that temperature with stirring for 1 hour. Trimethyl borate (3.0 g, 28.6 mmol) was added dropwise with the temperature being maintained at −80° C. for 1 hour before being warmed to room temperature and stirred for 24 hours. A solution of dilute hydrochloric acid (2M, 15 mL) was added to the reaction solution, which was stirred for 1 hour and separated into aqueous and organic phases. The organic phase was washed with water until neutral, dried over anhydrous magnesium sulfate, followed by the removal of the solvent under reduced pressure to yield a crude product. The crude product was purified via silica gel chromatography using a dichloromethane/n-heptane system, to yield IM c-1 as a white solid (9.9 g, yield 70%).

IM c-2 was synthesized using the same method as that for the synthesis of IM c-1, except that IM b-4 was used instead of IM b-3. The main materials utilized, the synthesized IM c-2, and yield thereof are shown in Table 4.

TABLE 4

| IM b-4 | IM c-2 | Yield/% |
|---|---|---|
| 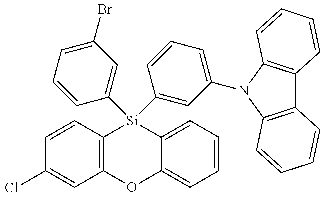 [SMILES: Clc1ccc2c(c1)Oc1ccccc1[Si]2(c1cccc(Br)c1)c1cccc(-n2c3ccccc3c3ccccc32)c1] | 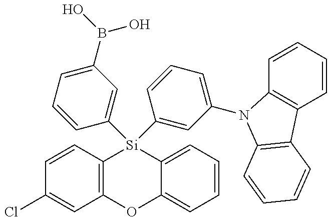 [SMILES: OB(O)c1cccc([Si]2(c3cccc(-n4c5ccccc5c5ccccc54)c3)c3ccccc3Oc3cc(Cl)ccc32)c1] | 68 |

### 5. Synthesis of IM d-1

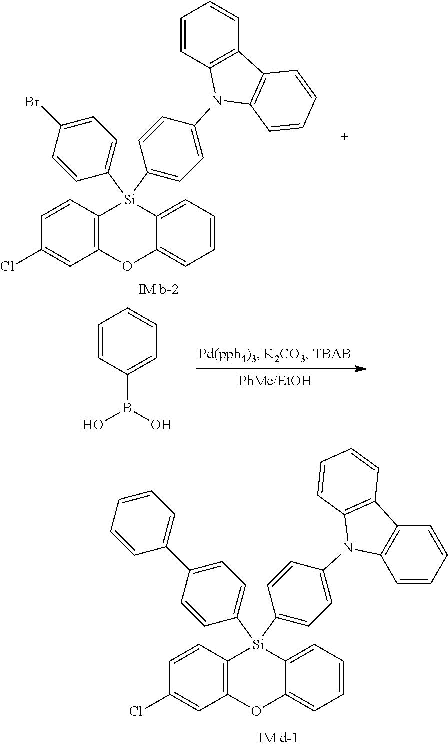

IM b-2 (15 g, 23.8 mmol), phenylboronic acid (3.1 g, 25.0 mmol), tetrakis (triphenylphosphine) palladium (0.27 g, 0.24 mmol), potassium carbonate (7.3 g, 52.5 mmol), and tetrabutylammonium bromide (1.5 g, 4.8 mmol) were added into a flask, followed by the addition of a mixed solvent of toluene (120 mL), ethanol (60 mL), and water (30 mL). Under a nitrogen atmosphere, the resulting solution was heated to 78° C. and maintained at that temperature with stirring for 8 hours. Upon cooling to room temperature and cessation of stirring, the reaction solution was washed with water to separate an organic phase, and the organic phase was dried over anhydrous magnesium sulfate, followed by the removal of the solvent under reduced pressure to yield a crude product. The crude product was purified via silica gel chromatography using a mixed solvent of dichloromethane and n-heptane as the mobile phase, to yield a product IM d-1 as a white solid (11.6 g; yield 78%).

IM d-x listed in Table 5 were synthesized using the same method as that for the synthesis of IM d-1, except that Raw material 7 was used instead of IM b-2 and Raw material 8 was used instead of phenylboronic acid. The main raw materials used, the synthesized intermediates, and yields thereof are shown in Table 5.

TABLE 5

| Raw material 7 | Raw material 8 | IM d-x | Yield/% |
|---|---|---|---|
| 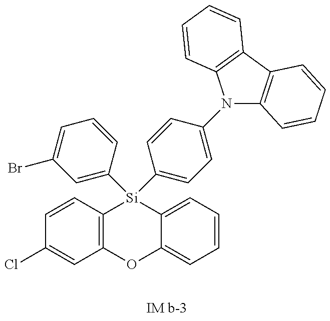 [SMILES: Clc1ccc2c(c1)Oc1ccccc1[Si]2(c1ccc(-n2c3ccccc3c3ccccc32)cc1)c1cccc(Br)c1] | 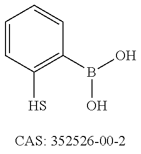 | 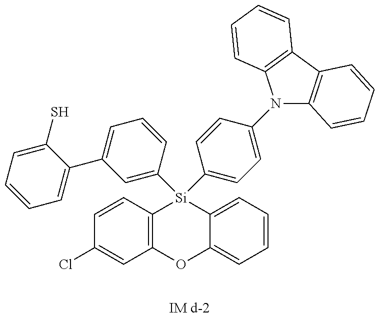 [SMILES: Sc1ccccc1-c1cccc([Si]2(c3ccc(-n4c5ccccc5c5ccccc54)cc3)c3ccccc3Oc3cc(Cl)ccc32)c1] | 72 |
| 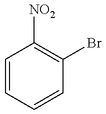 | 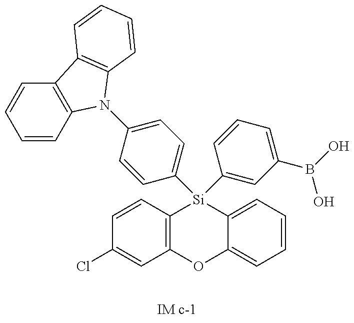 [SMILES: OB(O)c1cccc([Si]2(c3ccc(-n4c5ccccc5c5ccccc54)cc3)c3ccccc3Oc3cc(Cl)ccc32)c1] | 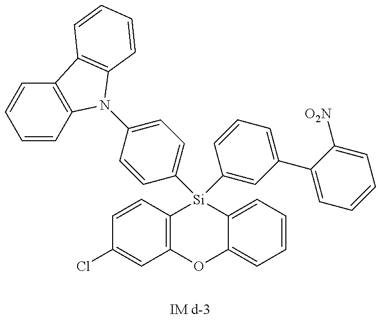 [SMILES: O=[N+]([O-])c1ccccc1-c1cccc([Si]2(c3ccc(-n4c5ccccc5c5ccccc54)cc3)c3ccccc3Oc3cc(Cl)ccc32)c1] | 77 |
| 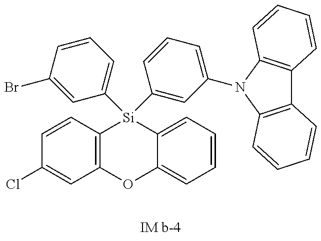 [SMILES: Clc1ccc2c(c1)Oc1ccccc1[Si]2(c1cccc(Br)c1)c1cccc(-n2c3ccccc3c3ccccc32)c1] | 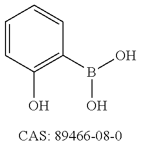 | 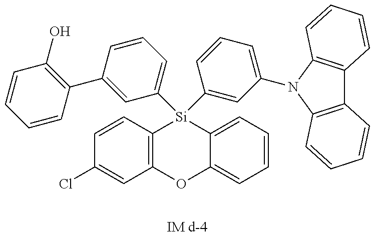 [SMILES: Oc1ccccc1-c1cccc([Si]2(c3cccc(-n4c5ccccc5c5ccccc54)c3)c3ccccc3Oc3cc(Cl)ccc32)c1] | 78 |
| 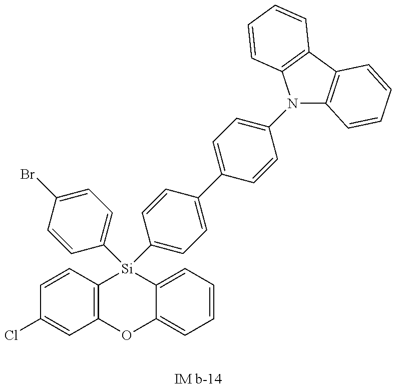 [SMILES: Clc1ccc2c(c1)Oc1ccccc1[Si]2(c1ccc(Br)cc1)c1ccc(-c2ccc(-n3c4ccccc4c4ccccc43)cc2)cc1] | 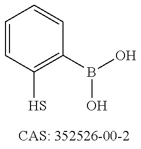 | 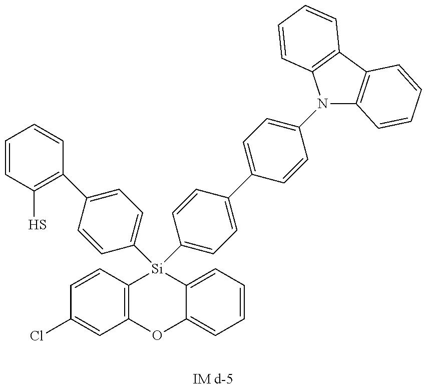 [SMILES: Sc1ccccc1-c1ccc([Si]2(c3ccc(-c4ccc(-n5c6ccccc6c6ccccc65)cc4)cc3)c3ccccc3Oc3cc(Cl)ccc32)cc1] | 69 |
| 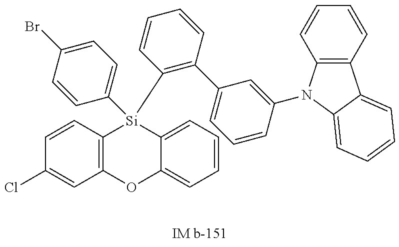 [SMILES: Clc1ccc2c(c1)Oc1ccccc1[Si]2(c1ccc(Br)cc1)c1ccccc1-c1cccc(-n2c3ccccc3c3ccccc32)c1] | 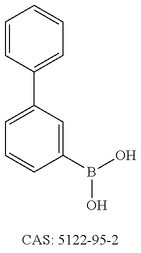 [SMILES: OB(O)c1cccc(-c2ccccc2)c1] | 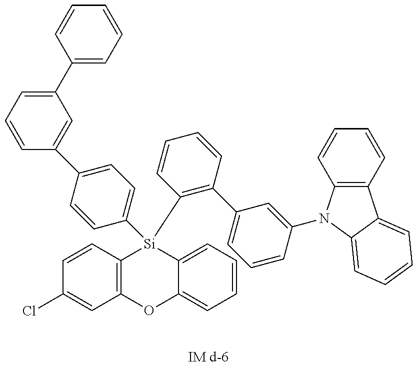 [SMILES: Clc1ccc2c(c1)Oc1ccccc1[Si]2(c1ccc(-c2cccc(-c3ccccc3)c2)cc1)c1ccccc1-c1cccc(-n2c3ccccc3c3ccccc32)c1] | 71 |
| 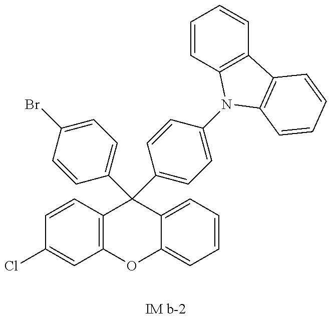 [SMILES: Clc1ccc2c(c1)Oc1ccccc1C2(c1ccc(Br)cc1)c1ccc(-n2c3ccccc3c3ccccc32)cc1] | 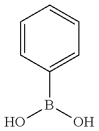 | 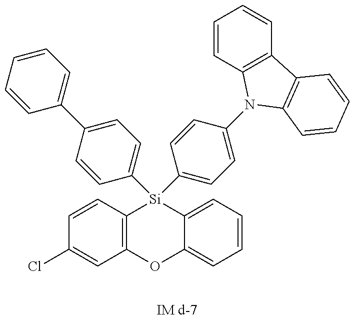 [SMILES: Clc1ccc2c(c1)Oc1ccccc1[Si]2(c1ccc(-c2ccccc2)cc1)c1ccc(-n2c3ccccc3c3ccccc32)cc1] | 70 |
| 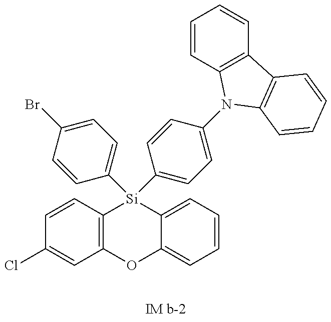 [SMILES: Clc1ccc2c(c1)Oc1ccccc1[Si]2(c1ccc(Br)cc1)c1ccc(-n2c3ccccc3c3ccccc32)cc1] | 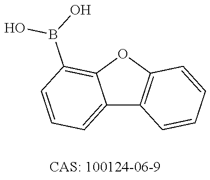 [SMILES: OB(O)c1cccc2c1oc1ccccc12] | 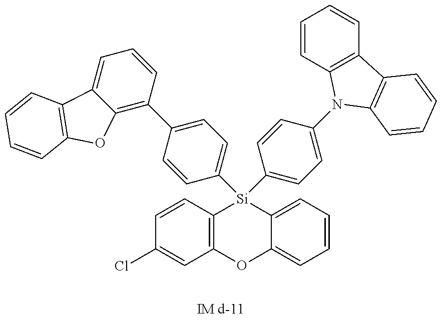 [SMILES: Clc1ccc2c(c1)Oc1ccccc1[Si]2(c1ccc(-c2cccc3c2oc2ccccc23)cc1)c1ccc(-n2c3ccccc3c3ccccc32)cc1] | 73 |
| 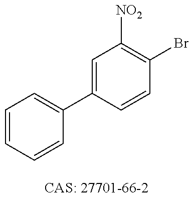 [SMILES: O=[N+]([O-])c1cc(-c2ccccc2)ccc1Br] | 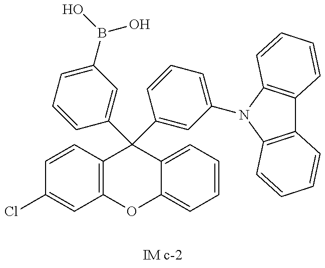 [SMILES: OB(O)c1cccc(C2(c3cccc(-n4c5ccccc5c5ccccc54)c3)c3ccccc3Oc3cc(Cl)ccc32)c1] | 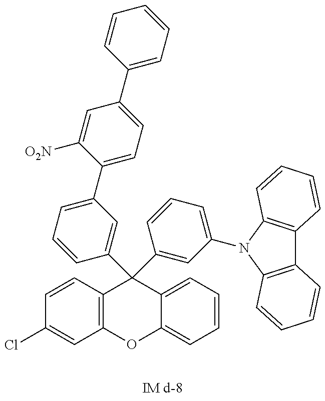 [SMILES: O=[N+]([O-])c1cc(-c2ccccc2)ccc1-c1cccc(C2(c3cccc(-n4c5ccccc5c5ccccc54)c3)c3ccccc3Oc3cc(Cl)ccc32)c1] | 80 |
| 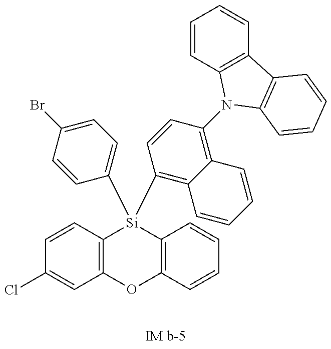 [SMILES: Clc1ccc2c(c1)Oc1ccccc1[Si]2(c1ccc(Br)cc1)c1ccc(-n2c3ccccc3c3ccccc32)c2ccccc12] | 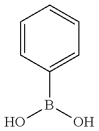 | 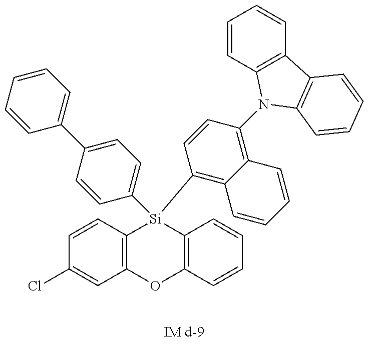 [SMILES: Clc1ccc2c(c1)Oc1ccccc1[Si]2(c1ccc(-c2ccccc2)cc1)c1ccc(-n2c3ccccc3c3ccccc32)c2ccccc12] | 74 |
| 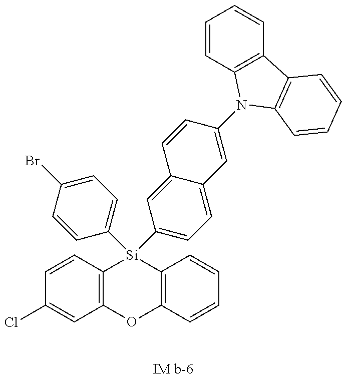 [SMILES: Clc1ccc2c(c1)Oc1ccccc1[Si]2(c1ccc(Br)cc1)c1ccc2cc(-n3c4ccccc4c4ccccc43)ccc2c1] | 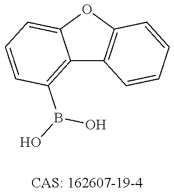 [SMILES: OB(O)c1cccc2oc3ccccc3c12] | 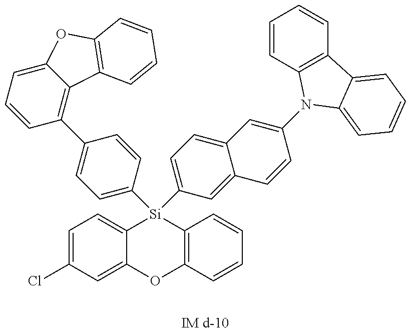 [SMILES: Clc1ccc2c(c1)Oc1ccccc1[Si]2(c1ccc(-c2cccc3oc4ccccc4c23)cc1)c1ccc2cc(-n3c4ccccc4c4ccccc43)ccc2c1] | 70 |
| 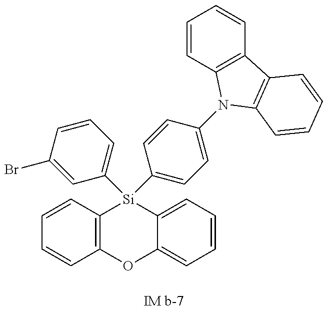 [SMILES: Brc1cccc([Si]2(c3ccc(-n4c5ccccc5c5ccccc54)cc3)c3ccccc3Oc3ccccc32)c1] | 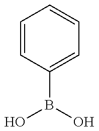 | 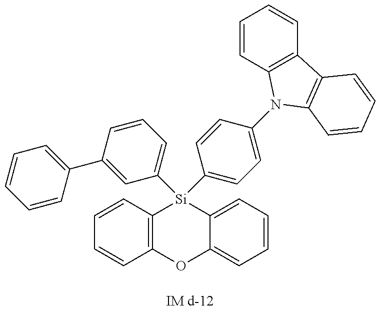 [SMILES: c1ccc(-c2cccc([Si]3(c4ccc(-n5c6ccccc6c6ccccc65)cc4)c4ccccc4Oc4ccccc43)c2)cc1] | 75 |
| 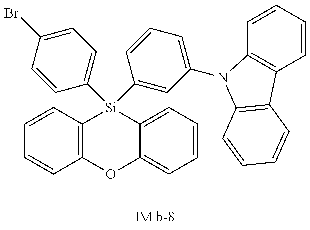 [SMILES: Brc1ccc([Si]2(c3cccc(-n4c5ccccc5c5ccccc54)c3)c3ccccc3Oc3ccccc32)cc1] | 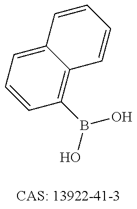 [SMILES: OB(O)c1cccc2ccccc12] | 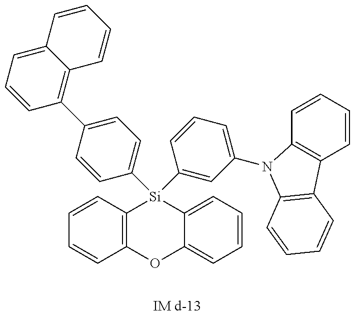 [SMILES: c1cc(-n2c3ccccc3c3ccccc32)cc([Si]2(c3ccc(-c4cccc5ccccc45)cc3)c3ccccc3Oc3ccccc32)c1] | 65 |
| 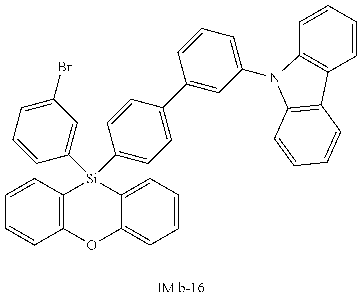 [SMILES: Brc1cccc([Si]2(c3ccc(-c4cccc(-n5c6ccccc6c6ccccc65)c4)cc3)c3ccccc3Oc3ccccc32)c1] | 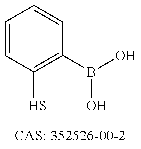 | 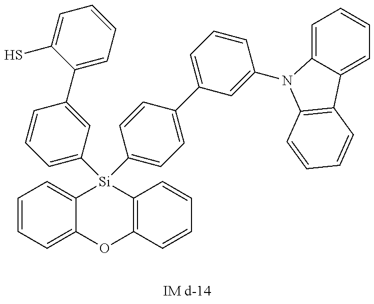 [SMILES: Sc1ccccc1-c1cccc([Si]2(c3ccc(-c4cccc(-n5c6ccccc6c6ccccc65)c4)cc3)c3ccccc3Oc3ccccc32)c1] | 67 |
| 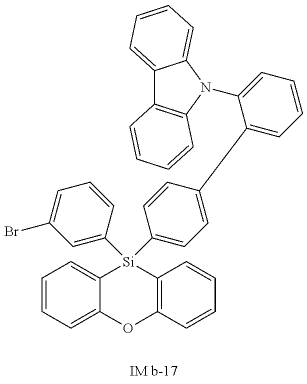 [SMILES: Brc1cccc([Si]2(c3ccc(-c4ccccc4-n4c5ccccc5c5ccccc54)cc3)c3ccccc3Oc3ccccc32)c1] | 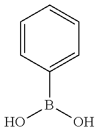 | 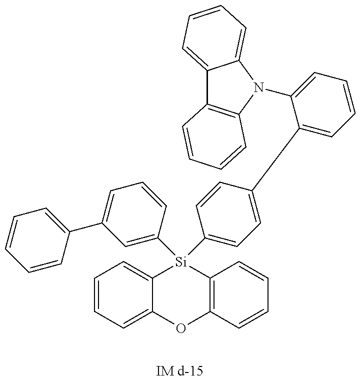 [SMILES: c1ccc(-c2cccc([Si]3(c4ccc(-c5ccccc5-n5c6ccccc6c6ccccc65)cc4)c4ccccc4Oc4ccccc43)c2)cc1] | 72 |
| 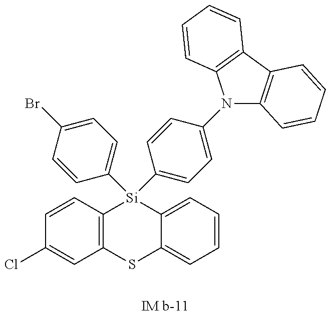 [SMILES: Clc1ccc2c(c1)Sc1ccccc1[Si]2(c1ccc(Br)cc1)c1ccc(-n2c3ccccc3c3ccccc32)cc1] | 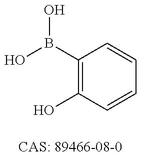 | 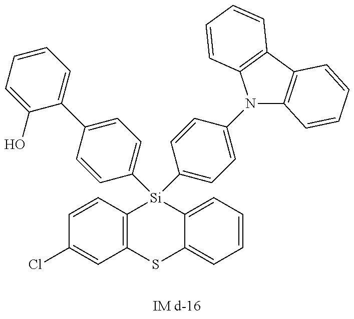 [SMILES: Oc1ccccc1-c1ccc([Si]2(c3ccc(-n4c5ccccc5c5ccccc54)cc3)c3ccccc3Sc3cc(Cl)ccc32)cc1] | 71 |
| 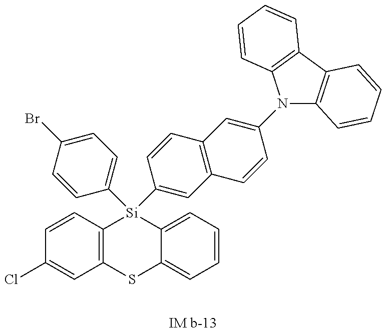 [SMILES: Clc1ccc2c(c1)Sc1ccccc1[Si]2(c1ccc(Br)cc1)c1ccc2cc(-n3c4ccccc4c4ccccc43)ccc2c1] | 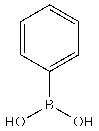 | 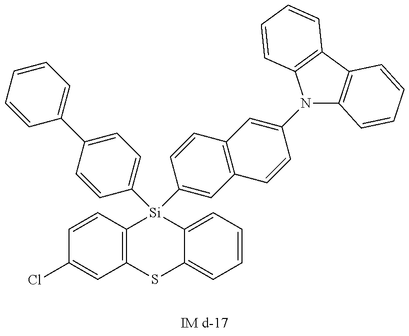 [SMILES: Clc1ccc2c(c1)Sc1ccccc1[Si]2(c1ccc(-c2ccccc2)cc1)c1ccc2cc(-n3c4ccccc4c4ccccc43)ccc2c1] | 78 |
| 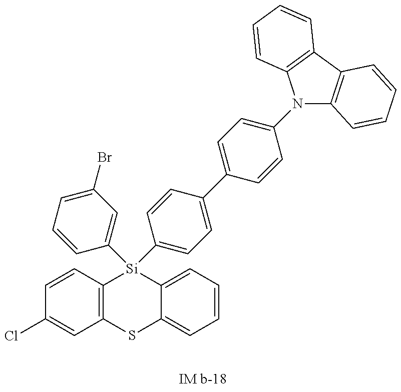 [SMILES: Clc1ccc2c(c1)Sc1ccccc1[Si]2(c1ccc(-c2ccc(-n3c4ccccc4c4ccccc43)cc2)cc1)c1cccc(Br)c1] | 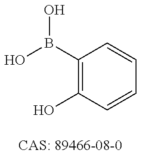 | 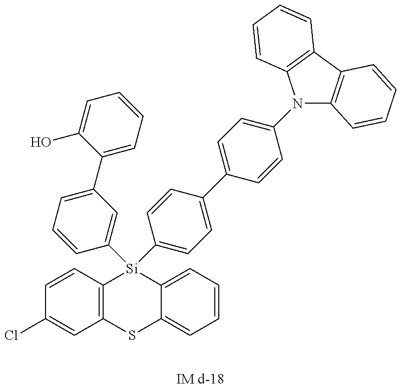 [SMILES: Oc1ccccc1-c1cccc([Si]2(c3ccc(-c4ccc(-n5c6ccccc6c6ccccc65)cc4)cc3)c3ccccc3Sc3cc(Cl)ccc32)c1] | 70 |

### 6. Synthesis of IM d-19

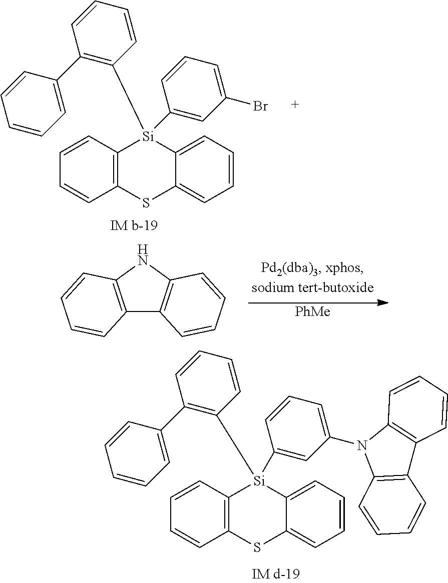

IM b-19 (15 g, 28.8 mmol), carbazole (4.8 g, 28.8 mmol), tris(dibenzylidene acetonate) dipalladium (0.26 g, 0.29 mmol), 2-dicyclohexylphosphino-2′,4′,6′-triisopropylbiphenyl (x-phos) (0.27 g, 0.57 mmol), sodium tert-butoxide (4.1 g, 43.1 mmol), and toluene (150 mL) were added into a flask, and then the resulting solution was heated to 110° C. for 4 hours of reaction. After the reaction was completed, the reaction solution was cooled to room temperature, and extracted with dichloromethane and water to separate the organic phase. The organic phase was dried over anhydrous magnesium sulfate to remove water and concentrated under reduced pressure to yield a grayish-black crude product. The crude product was purified via silica gel column chromatography using a mixed solvent of dichloromethane/n-heptane as the mobile phase, to yield IM d-19 (12.2 g; yield 70%).

### 7. Synthesis of IM e-1

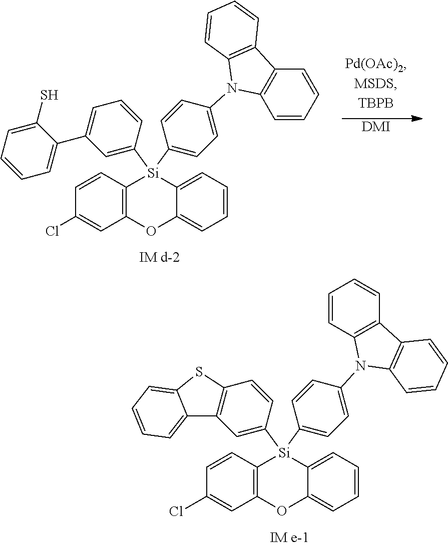

IM d-2 (10 g, 15.2 mmol), 3-nitropyridine (MSDS) (0.04 g, 0.30 mmol), tert-butyl peroxybenzoate (TBPB) (8.8 g, 45 mmol), palladium acetate (Pd(OAc)₂) (0.02 g, 0.15 mmol), and 1,3-dimethyl-2-imidazolidinone (DMI) (80 mL) were added into a flask, and the resulting solution was then heated to 130° C. for 8 hours of reaction. After the reaction was completed, the reaction solution was cooled to room temperature and was extracted with dichloromethane and water to separate the organic phase. The organic phase was dried over anhydrous magnesium sulfate to remove water and concentrated under reduced pressure to yield a grayish-black crude product. The crude product was purified via silica gel column chromatography using a mixed solvent of dichloromethane/n-heptane as the mobile phase, to yield IM e-1 (5.0 g; yield 50%).

IM e-x listed in Table 6 were synthesized using the same method as that for synthesis of IM e-1, except that Raw material 9 was used instead of IM d-2. The main raw materials used, the synthesized intermediates, and their yields thereof are shown in Table 6.

TABLE 6

| Raw material 9 | IM e-x | Yield/% |
|---|---|---|
| 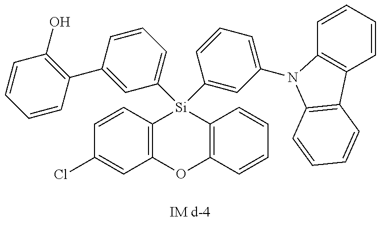 [SMILES: Oc1ccccc1-c1cccc([Si]2(c3cccc(-n4c5ccccc5c5ccccc54)c3)c3ccccc3Oc3cc(Cl)ccc32)c1] | 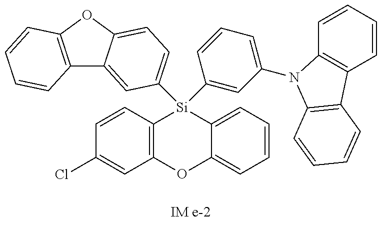 [SMILES: Clc1ccc2c(c1)Oc1ccccc1[Si]2(c1cccc(-n2c3ccccc3c3ccccc32)c1)c1ccc2oc3ccccc3c2c1] | 47 |
| 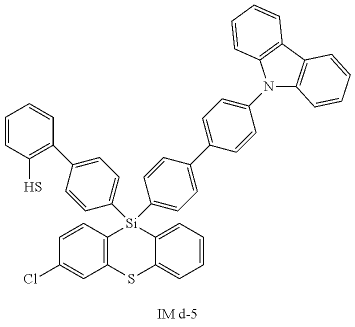 [SMILES: Sc1ccccc1-c1ccc([Si]2(c3ccc(-c4ccc(-n5c6ccccc6c6ccccc65)cc4)cc3)c3ccccc3Sc3cc(Cl)ccc32)cc1] | 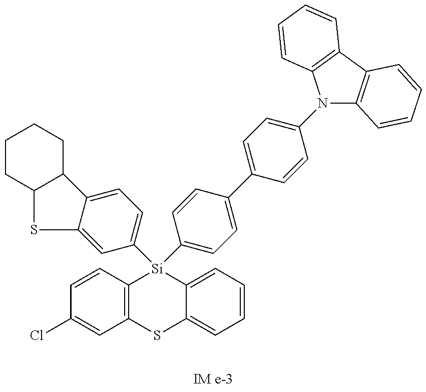 [SMILES: Clc1ccc2c(c1)Sc1ccccc1[Si]2(c1ccc(-c2ccc(-n3c4ccccc4c4ccccc43)cc2)cc1)c1ccc2c(c1)SC1CCCCC21] | 48 |
| 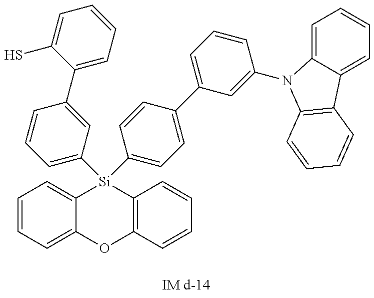 [SMILES: Sc1ccccc1-c1cccc([Si]2(c3ccc(-c4cccc(-n5c6ccccc6c6ccccc65)c4)cc3)c3ccccc3Oc3ccccc32)c1] | 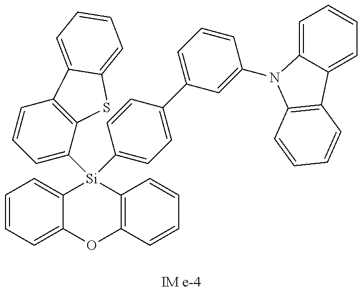 [SMILES: c1cc(-c2ccc([Si]3(c4cccc5c4sc4ccccc45)c4ccccc4Oc4ccccc43)cc2)cc(-n2c3ccccc3c3ccccc32)c1] | 53 |
| 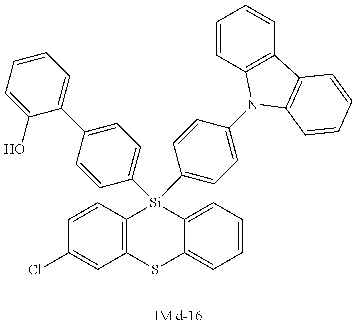 [SMILES: Oc1ccccc1-c1ccc([Si]2(c3ccc(-n4c5ccccc5c5ccccc54)cc3)c3ccccc3Sc3cc(Cl)ccc32)cc1] | 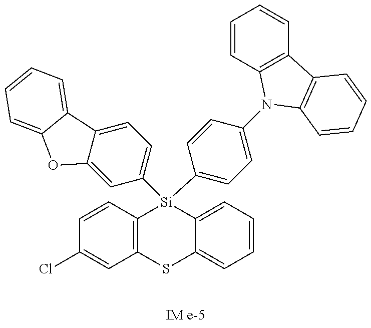 [SMILES: Clc1ccc2c(c1)Sc1ccccc1[Si]2(c1ccc(-n2c3ccccc3c3ccccc32)cc1)c1ccc2c(c1)oc1ccccc12] | 45 |
| 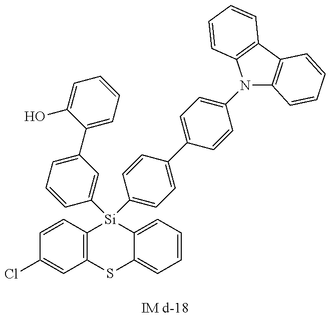 [SMILES: Oc1ccccc1-c1cccc([Si]2(c3ccc(-c4ccc(-n5c6ccccc6c6ccccc65)cc4)cc3)c3ccccc3Sc3cc(Cl)ccc32)c1] | 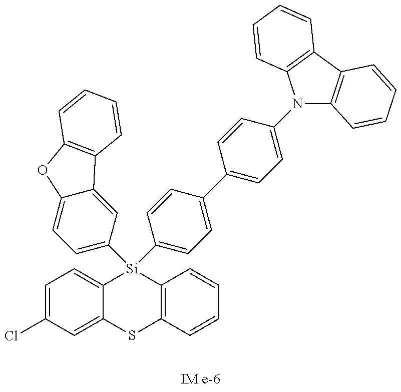 [SMILES: Clc1ccc2c(c1)Sc1ccccc1[Si]2(c1ccc(-c2ccc(-n3c4ccccc4c4ccccc43)cc2)cc1)c1ccc2oc3ccccc3c2c1] | 51 |

### 8. Synthesis of IM f-1

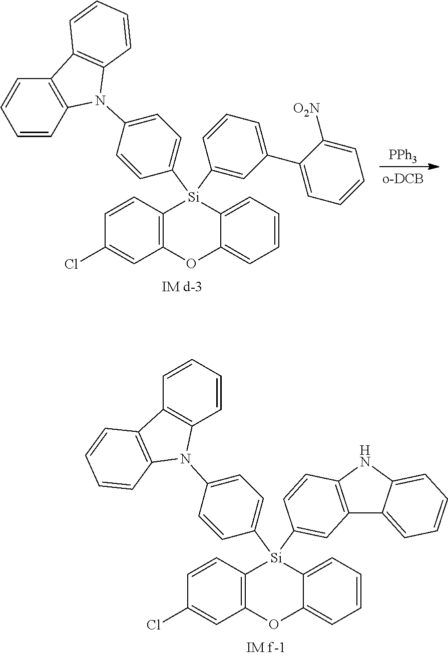 [SMILES: O=[N+]([O-])c1ccccc1-c1cccc([Si]2(c3ccc(-n4c5ccccc5c5ccccc54)cc3)c3ccccc3Oc3cc(Cl)ccc32)c1 ; Clc1ccc2c(c1)Oc1ccccc1[Si]2(c1ccc(-n2c3ccccc3c3ccccc32)cc1)c1ccc2[nH]c3ccccc3c2c1 ; "PPh3"]

IM d-3 (10 g, 14.9 mmol), triphenylphosphine (PPh₃) (9.7 g, 37.2 mmol), and o-dichlorobenzene (o-DCB) (100 mL) were added into a flask, and the resulting solution was then heated to 178° C. under a nitrogen atmosphere with stirring for 10 hours. Upon cooling to room temperature, and the reaction solution was washed with water, separated into aqueous and organic phases, and the organic phase was washed with water and dried over anhydrous magnesium sulfate, followed by concentration under reduced pressure to yield a crude product. The crude product was purified via silica gel chromatography using an ethyl acetate/n-heptane system, to yield IM f-1 (5.7 g, yield 60%).

IM f-2 listed in Table 7 was synthesized using the same method as that for synthesis of IM f-1, except that IM d-8 was used instead of IM d-3. The main raw materials used, the synthesized intermediate, and yield thereof are shown in Table 7.

TABLE 7

| IM d-8 | IM f-2 | Yield/% |
|---|---|---|
| 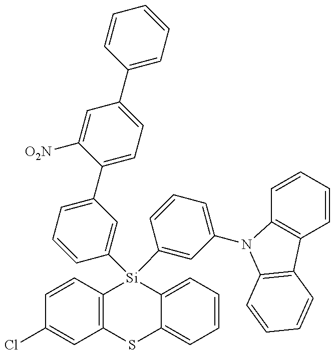 [SMILES: O=[N+]([O-])c1cc(-c2ccccc2)ccc1-c1cccc([Si]2(c3cccc(-n4c5ccccc5c5ccccc54)c3)c3ccccc3Sc3cc(Cl)ccc32)c1] | 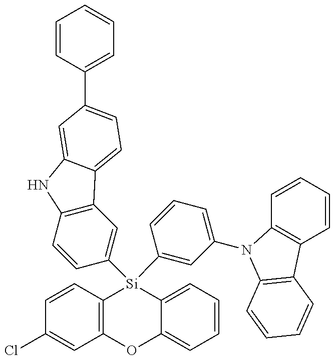 [SMILES: Clc1ccc2c(c1)Oc1ccccc1[Si]2(c1cccc(-n2c3ccccc3c3ccccc32)c1)c1ccc2[nH]c3cc(-c4ccccc4)ccc3c2c1] | 62 |

### 9. Synthesis of IM g-1

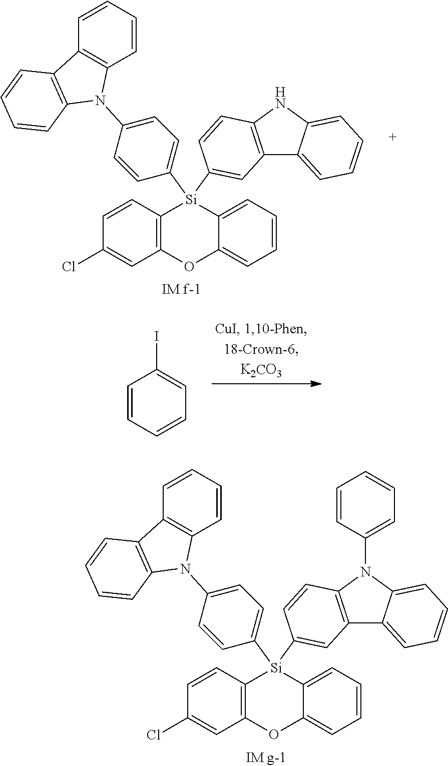 [SMILES: Clc1ccc2c(c1)Oc1ccccc1[Si]2(c1ccc(-n2c3ccccc3c3ccccc32)cc1)c1ccc2[nH]c3ccccc3c2c1 ; Ic1ccccc1 ; Clc1ccc2c(c1)Oc1ccccc1[Si]2(c1ccc(-n2c3ccccc3c3ccccc32)cc1)c1ccc2c(c1)c1ccccc1n2-c1ccccc1]

IM f-1 (5.7 g, 8.9 mmol), iodobenzene (2.2 g, 10.7 mmol), copper iodide (CuI) (0.17 g, 0.89 mmol), 1,10-phenanthroline (1,10-Phen) (0.3 g, 1.8 mmol), 18-Crown-6 (0.23 g, 0.9 mmol), potassium carbonate (2.7 g, 19.6 mmol), and DMF (50 mL) were added into a flask, and the resulting solution was heated to 150° C. under a nitrogen atmosphere, with stirring for 8 hours; upon cooling to room temperature, the reaction solution was washed with water, separated into aqueous and organic phases, and the organic phase was washed with water and dried over anhydrous magnesium sulfate, followed by concentration under reduced pressure to yield a crude product; the crude product was purified via silica gel chromatography using a dichloromethane/n-heptane system, to yield IM g-1 (5.1 g, yield 80%).

IM g-2 was synthesized using the same method as that for synthesis of IM g-1, except that IM f-2 was used instead of IM f-1. The main raw materials used, the synthesized intermediate, and its yield thereof are shown in Table 8.

TABLE 8

| IM f-2 | IM g-2 | Yield/% |
|---|---|---|
| 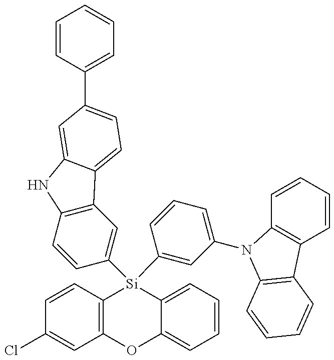 [SMILES: Clc1ccc2c(c1)Oc1ccccc1[Si]2(c1cccc(-n2c3ccccc3c3ccccc32)c1)c1ccc2[nH]c3cc(-c4ccccc4)ccc3c2c1] | 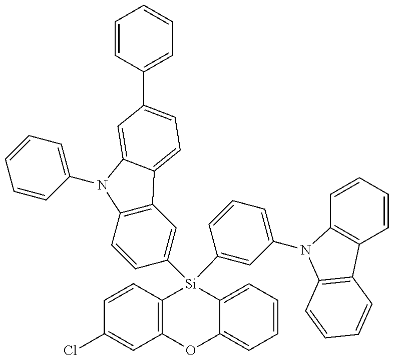 [SMILES: Clc1ccc2c(c1)Oc1ccccc1[Si]2(c1cccc(-n2c3ccccc3c3ccccc32)c1)c1ccc2c(c1)c1ccc(-c3ccccc3)cc1n2-c1ccccc1] | 78 |

### 10. Synthesis of IM h-1

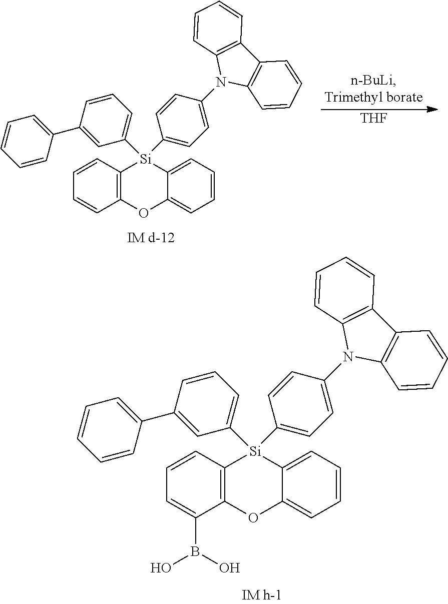 [SMILES: c1ccc(-c2cccc([Si]3(c4ccc(-n5c6ccccc6c6ccccc65)cc4)c4ccccc4Oc4ccccc43)c2)cc1 ; OB(O)c1cccc2c1Oc1ccccc1[Si]2(c1ccc(-n2c3ccccc3c3ccccc32)cc1)c1cccc(-c2ccccc2)c1 ; "THF"]

IM d-12 (10 g, 16.9 mmol) and dried tetrahydrofuran (100 mL) were added into a flask. Under a nitrogen atmosphere, the resulting solution was cooled to −80° C., and a solution of n-butyllithium in tetrahydrofuran (2M) (10.1 mL, 20.3 mmol) was added dropwise with stirring. Upon the completion of the dropwise addition, the resulting solution was maintained at −80° C. with stirring for 1 hour. Trimethyl borate (2.3 g, 21.9 mmol) was added dropwise with the temperature being maintained at −80° C. for 1 hour before being warmed to room temperature and stirred for 24 hours. A solution of dilute hydrochloric acid (2M, 10.1 mL) was added to the reaction solution, stirred for 1 hour, and the reaction solution was separated into aqueous and organic phases. The organic phase was washed with water until neutral, separated out, dried over anhydrous magnesium sulfate, and concentrated under reduced pressure to yield a crude product. The crude product was purified via silica gel chromatography using a dichloromethane/n-heptane system, to yield IM h-1 as a white solid (8.0 g, yield: 75%).

IM h-x listed in Table 9 were synthesized using the same method as that for synthesis of IM h-1, except that Raw material 10 was used instead of IM d-12. The main raw materials used, the synthesized intermediates, and yields thereof are shown in Table 9.

TABLE 9

| Raw material 10 | IM h-x | Yield/% |
|---|---|---|
| 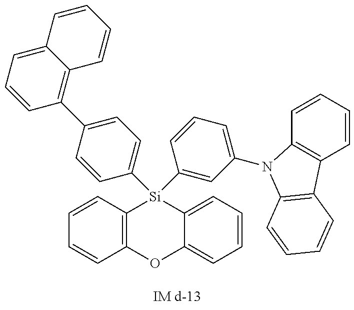 [SMILES: c1cc(-n2c3ccccc3c3ccccc32)cc([Si]2(c3ccc(-c4cccc5ccccc45)cc3)c3ccccc3Oc3ccccc32)c1] | 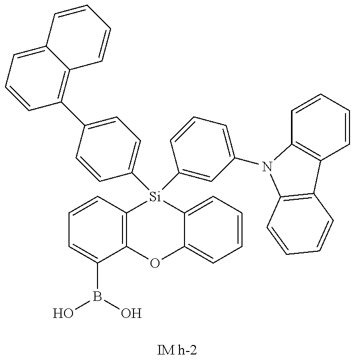 [SMILES: OB(O)c1cccc2c1Oc1ccccc1[Si]2(c1ccc(-c2cccc3ccccc23)cc1)c1cccc(-n2c3ccccc3c3ccccc32)c1] | 72 |
| 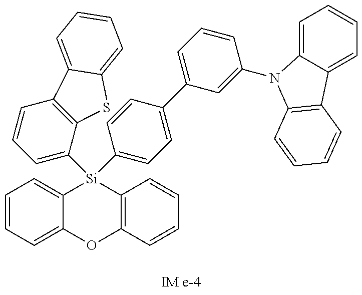 [SMILES: c1cc(-c2ccc([Si]3(c4cccc5c4sc4ccccc45)c4ccccc4Oc4ccccc43)cc2)cc(-n2c3ccccc3c3ccccc32)c1] | 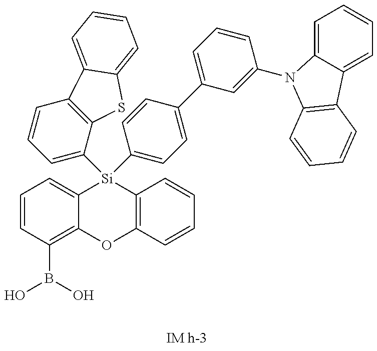 [SMILES: OB(O)c1cccc2c1Oc1ccccc1[Si]2(c1ccc(-c2cccc(-n3c4ccccc4c4ccccc43)c2)cc1)c1cccc2c1sc1ccccc12] | 70 |
| 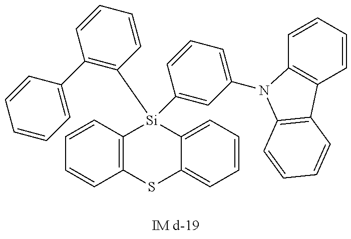 [SMILES: c1ccc(-c2ccccc2[Si]2(c3cccc(-n4c5ccccc5c5ccccc54)c3)c3ccccc3Sc3ccccc32)cc1] | 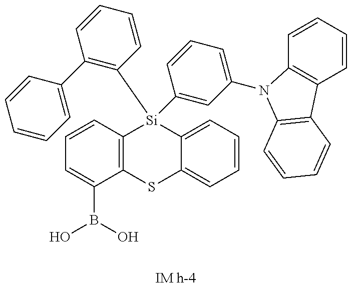 [SMILES: OB(O)c1cccc2c1Sc1ccccc1[Si]2(c1cccc(-n2c3ccccc3c3ccccc32)c1)c1ccccc1-c1ccccc1] | 70 |

### 11. Synthesis of IM i-1

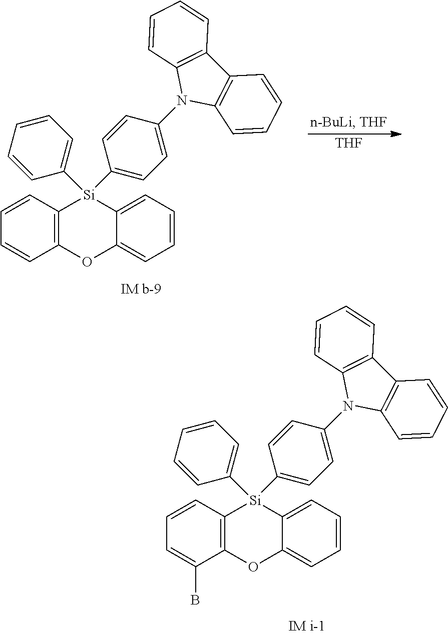

IM b-9 (10 g, 16.9 mmol) and dried tetrahydrofuran (100 mL) were added into a flask. Under a nitrogen atmosphere, the resulting solution was cooled to −60° C., and a solution of n-butyllithium in tetrahydrofuran (2.5M) (13 mL, 25.3 mmol) was added dropwise with stirring. After the dropwise addition was completed, the reaction solution was allowed to gradually warm to room temperature and then to 60° C., and then stirred for 10 hours. The reaction solution was cooled to −60° C., and 1,2-dibromoethane (DBE) (3.3 g, 33.8 mmol) dissolved in THF (10 mL) were added dropwise. After the dropwise addition was completed, the reaction solution was warmed to −50° C., and maintained at that temperature for 1 hour, and then naturally warmed to room temperature, with stirring for 10 hours. The organic phase was washed with water, separated, and dried over anhydrous magnesium sulfate, followed by the removal of the solvent under reduced pressure to yield a crude product. The crude product was purified via silica gel chromatography using a dichloromethane/n-heptane system, to yield IM i-1 as a solid (6.0 g, yield: 60%).

IM i-2 was synthesized using the same method as that for synthesis of IM i-1, except that IM d-15 was used instead of IM b-9. The main raw materials used, the synthesized intermediate, and yield thereof are shown in Table 10.

TABLE 10

| IM d-15 | IM i-2 | Yield/% |
|---|---|---|
| 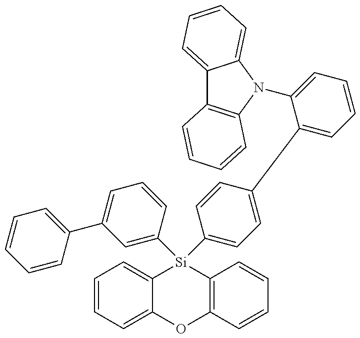 [SMILES: c1ccc(-c2cccc([Si]3(c4ccc(-c5ccccc5-n5c6ccccc6c6ccccc65)cc4)c4ccccc4Oc4ccccc43)c2)cc1] | 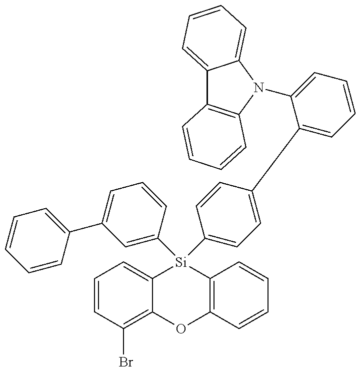 [SMILES: Brc1cccc2c1Oc1ccccc1[Si]2(c1ccc(-c2ccccc2-n2c3ccccc3c3ccccc32)cc1)c1cccc(-c2ccccc2)c1] | 55 |

### 12. Synthesis of Compound A-1

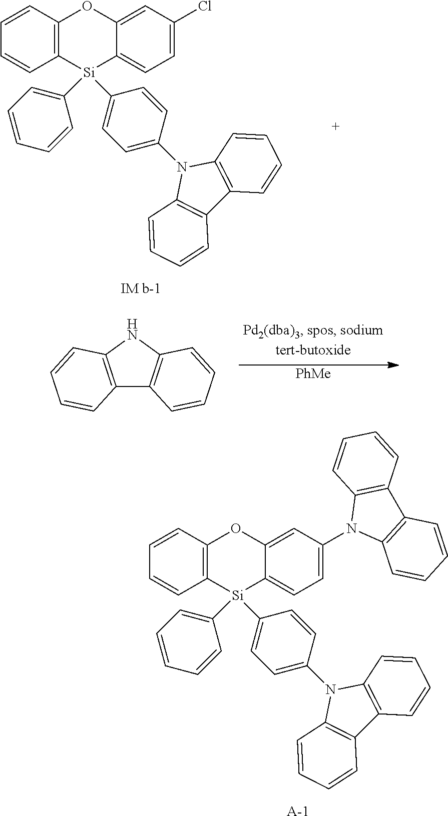

IM b-1 (5 g, 9.1 mmol), carbazole (1.5 g, 9.1 mmol), tris(dibenzylidene acetone) dipalladium (0.08 g, 0.09 mmol), 2-dicyclohexylphosphino-2′,6′-dimethoxy-biphenyl (sphos) (0.07 g, 0.18 mmol), sodium tert-butoxide (1.3 g, 13.6 mmol), and toluene (50 mL) were added into a flask, and the resulting solution was then heated to 110° C. for 8 hours of reaction. After the reaction was completed, the reaction solution was cooled to room temperature, and was extracted with water to separate the organic phase. The organic phase was dried over anhydrous magnesium sulfate to remove water and concentrated under reduced pressure to yield a grayish-black crude product. The crude product was purified via silica gel column chromatography using a mixed solvent of dichloromethane/n-heptane as the mobile phase, to yield Compound A-1 (4.0 g; yield 65%), Mass spectra (m/z)=681.2[M+H]⁺.

Compounds listed in Table 11 were synthesized using the same method as that for synthesis of Compound A-1, except that Raw material 11 was used instead of IM b-1. The main raw materials used, the synthesized intermediates, and yields thereof are shown in Table

TABLE 11

| | | | Mass |
|---|---|---|---|
| | | | Spectra |
| | | Yield/ | (m/z)/ |
| Raw material 11 | Compound | % | [M + H]⁺ |
| 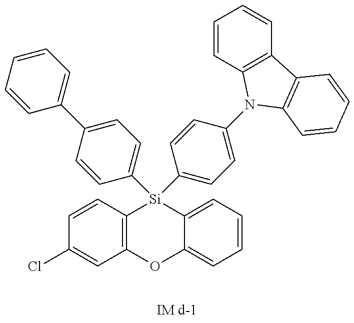 [SMILES: Clc1ccc2c(c1)Oc1ccccc1[Si]2(c1ccc(-c2ccccc2)cc1)c1ccc(-n2c3ccccc3c3ccccc32)cc1] | 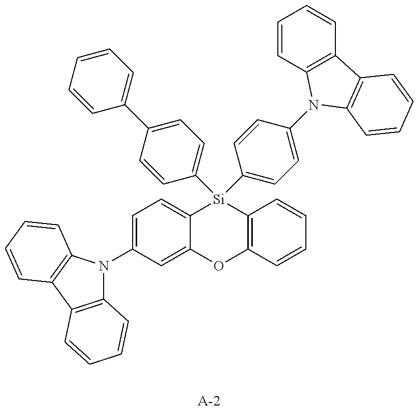 [SMILES: c1ccc(-c2ccc([Si]3(c4ccc(-n5c6ccccc6c6ccccc65)cc4)c4ccccc4Oc4cc(-n5c6ccccc6c6ccccc65)ccc43)cc2)cc1 ; "A-2"] | 60 | 757.3 |
| 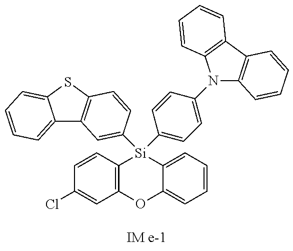 [SMILES: Clc1ccc2c(c1)Oc1ccccc1[Si]2(c1ccc(-n2c3ccccc3c3ccccc32)cc1)c1ccc2sc3ccccc3c2c1] | 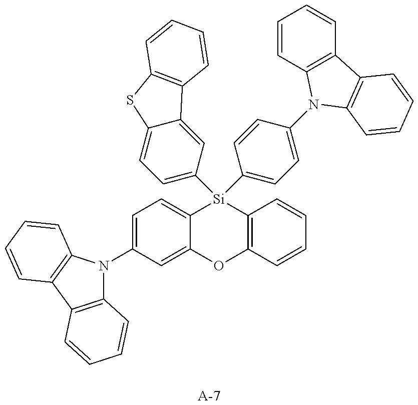 [SMILES: c1ccc2c(c1)Oc1cc(-n3c4ccccc4c4ccccc43)ccc1[Si]2(c1ccc(-n2c3ccccc3c3ccccc32)cc1)c1ccc2sc3ccccc3c2c1 ; "A-7"] | 66 | 863.3 |
| 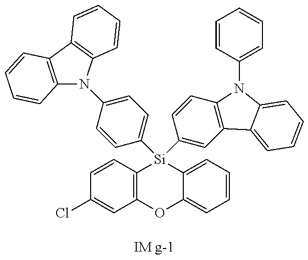 [SMILES: Clc1ccc2c(c1)Oc1ccccc1[Si]2(c1ccc(-n2c3ccccc3c3ccccc32)cc1)c1ccc2c(c1)c1ccccc1n2-c1ccccc1] | 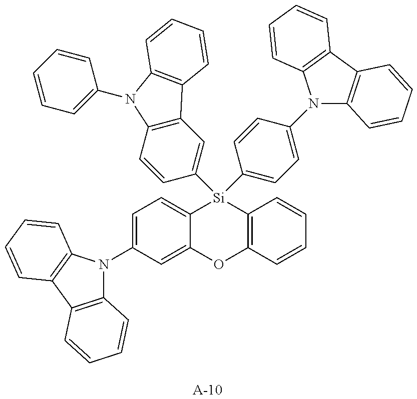 [SMILES: c1ccc(-n2c3ccccc3c3cc([Si]4(c5ccc(-n6c7ccccc7c7ccccc76)cc5)c5ccccc5Oc5cc(-n6c7ccccc7c7ccccc76)ccc54)ccc32)cc1 ; "A-10"] | 72 | 846.3 |
| 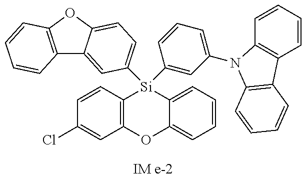 [SMILES: Clc1ccc2c(c1)Oc1ccccc1[Si]2(c1cccc(-n2c3ccccc3c3ccccc32)c1)c1ccc2oc3ccccc3c2c1] | 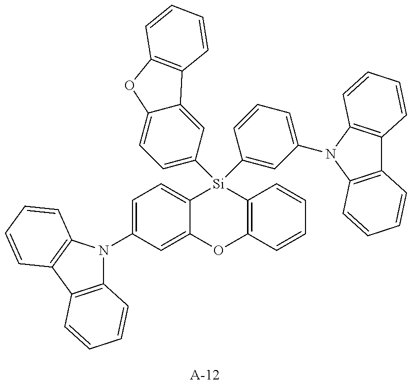 [SMILES: c1cc(-n2c3ccccc3c3ccccc32)cc([Si]2(c3ccc4oc5ccccc5c4c3)c3ccccc3Oc3cc(-n4c5ccccc5c5ccccc54)ccc32)c1 ; "A-12"] | 75 | 771.2 |
| 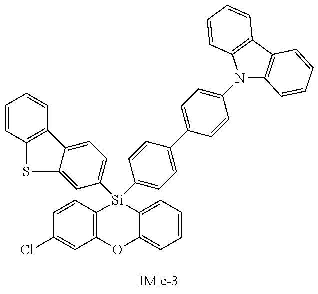 [SMILES: Clc1ccc2c(c1)Oc1ccccc1[Si]2(c1ccc(-c2ccc(-n3c4ccccc4c4ccccc43)cc2)cc1)c1ccc2c(c1)sc1ccccc12] | 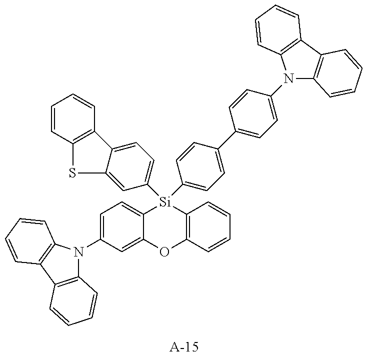 [SMILES: c1ccc2c(c1)Oc1cc(-n3c4ccccc4c4ccccc43)ccc1[Si]2(c1ccc(-c2ccc(-n3c4ccccc4c4ccccc43)cc2)cc1)c1ccc2c(c1)sc1ccccc12 ; "A-15"] | 71 | 863.3 |
| 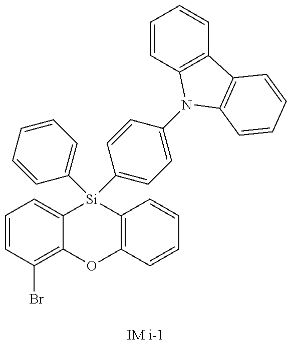 [SMILES: Brc1cccc2c1Oc1ccccc1[Si]2(c1ccccc1)c1ccc(-n2c3ccccc3c3ccccc32)cc1] | 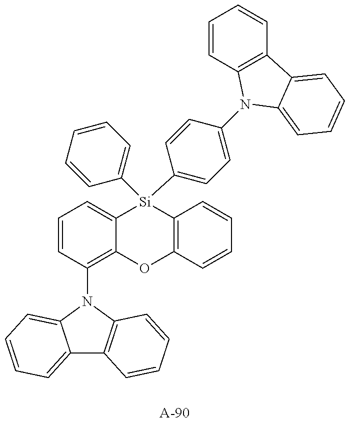 | 75 | 681.2 |
| 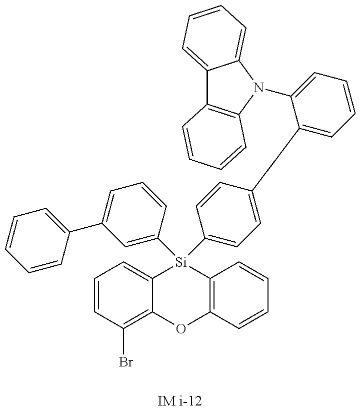 [SMILES: Brc1cccc2c1Oc1ccccc1[Si]2(c1ccc(-c2ccccc2-n2c3ccccc3c3ccccc32)cc1)c1cccc(-c2ccccc2)c1] | 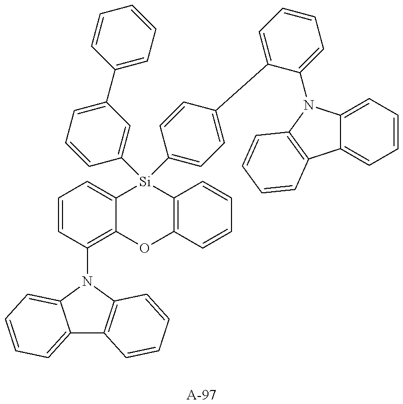 [SMILES: c1ccc(-c2cccc([Si]3(c4ccc(-c5ccccc5-n5c6ccccc6c6ccccc65)cc4)c4ccccc4Oc4c(-n5c6ccccc6c6ccccc65)cccc43)c2)cc1 ; "A-97"] | 67 | 833.3 |
| 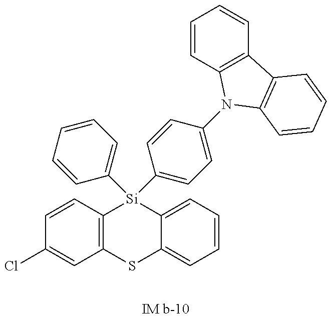 [SMILES: Clc1ccc2c(c1)Sc1ccccc1[Si]2(c1ccccc1)c1ccc(-n2c3ccccc3c3ccccc32)cc1] | 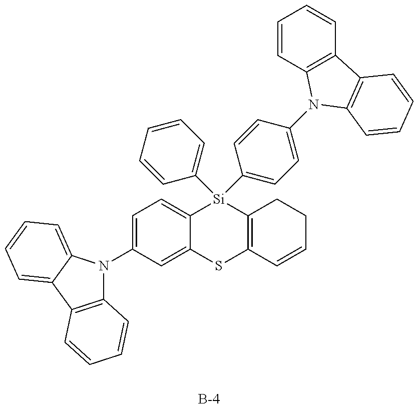 | 65 | 697.2 |

### 13. Synthesis of Compound A-28

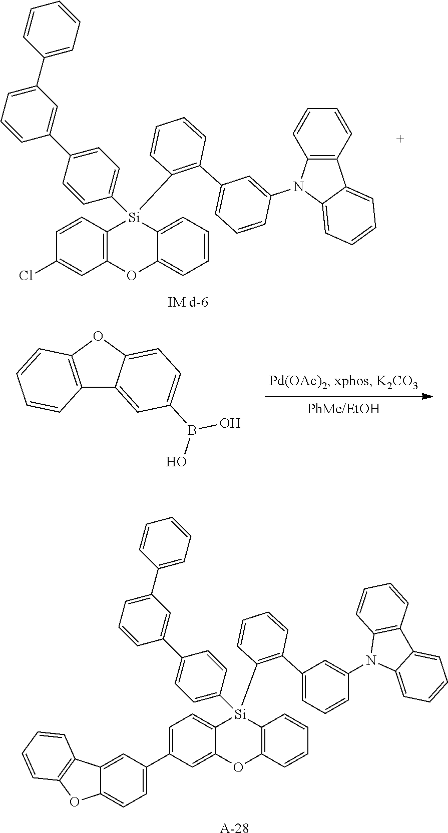 [SMILES: Clc1ccc2c(c1)Oc1ccccc1[Si]2(c1ccc(-c2cccc(-c3ccccc3)c2)cc1)c1ccccc1-c1cccc(-n2c3ccccc3c3ccccc32)c1 ; OB(O)c1ccc2oc3ccccc3c2c1 ; c1ccc(-c2cccc(-c3ccc([Si]4(c5ccccc5-c5cccc(-n6c7ccccc7c7ccccc76)c5)c5ccccc5Oc5cc(-c6ccc7oc8ccccc8c7c6)ccc54)cc3)c2)cc1 ; "A-28"]

IM d-6 (5 g, 6.4 mmol), dibenzofuran-2-boronic acid (1.4 g, 6.6 mmol), palladium acetate (0.01 g, 0.06 mmol), 2-dicyclohexylphosphino-2′,4′,6′-triisopropylbiphenyl (0.06 g, 0.13 mmol), potassium carbonate (1.9 g, 14.1 mmol), and tetrabutylammonium bromide (0.4 g, 1.3 mmol) were added into a flask, followed by the addition of a mixed solvent of toluene (40 mL), ethanol (20 mL), and water (10 mL). Under a nitrogen atmosphere, the resulting solution was heated to 80° C. and maintained at that temperature with stirring for 8 hours. Upon cooling to room temperature and cessation of stirring, the reaction solution was washed with water to separate the organic phase. The organic phase was then dried over anhydrous magnesium sulfate, followed by the removal of the solvent under reduced pressure to yield a crude product. The crude was purified via silica gel column chromatography using n-heptane as mobile phase, to yield Compound A-28 (4.1 g; yield 70%); Mass Spectra (m/z)=910.3[M+H]⁺.

Compounds listed in Table 12 were synthesized using the same method as that for synthesis of Compound A-28, except that Raw material 12 was used instead of IM d-6, and Raw material 13 was used instead of dibenzofuran-2-boronic acid. The main raw materials used, the synthesized intermediates, and yields thereof are shown in Table 12.

TABLE 12

| | | | | Mass |
|---|---|---|---|---|
| | | | | Spectra |
| | | | | (m/z)/ |
| | | | Yield/ | [M + |
| Raw material 12 | Raw material 13 | Compound | % | H]⁺ |
| 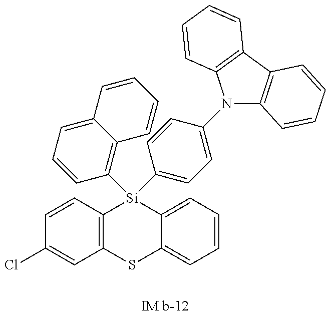 [SMILES: Clc1ccc2c(c1)Sc1ccccc1[Si]2(c1ccc(-n2c3ccccc3c3ccccc32)cc1)c1cccc2ccccc12] | 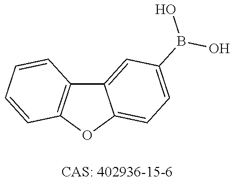 [SMILES: OB(O)c1ccc2oc3ccccc3c2c1] | 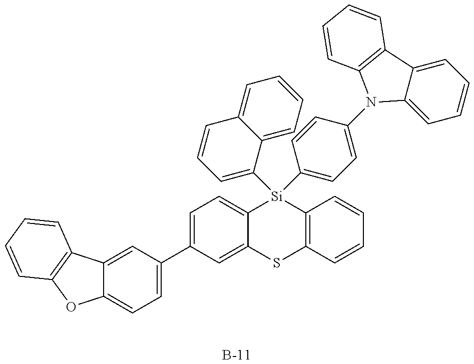 | 76 | 748.2 |
| 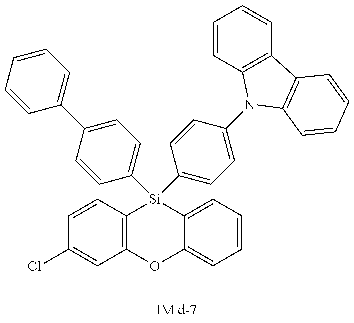 [SMILES: Clc1ccc2c(c1)Oc1ccccc1[Si]2(c1ccc(-c2ccccc2)cc1)c1ccc(-n2c3ccccc3c3ccccc32)cc1] | 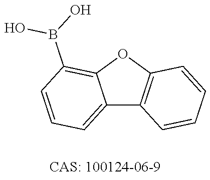 [SMILES: OB(O)c1cccc2c1oc1ccccc12] | 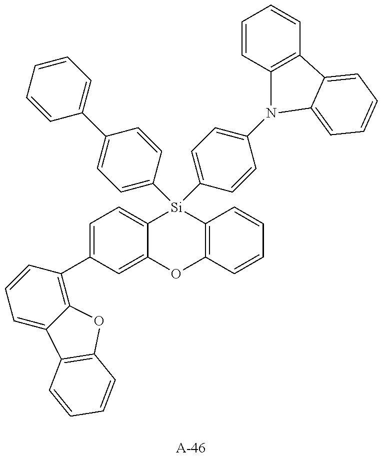 [SMILES: c1ccc(-c2ccc([Si]3(c4ccc(-n5c6ccccc6c6ccccc65)cc4)c4ccccc4Oc4cc(-c5cccc6c5oc5ccccc56)ccc43)cc2)cc1 ; "A-46"] | 68 | 758.2 |
| 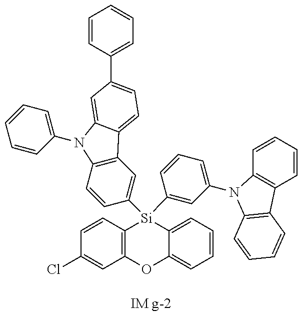 [SMILES: Clc1ccc2c(c1)Oc1ccccc1[Si]2(c1cccc(-n2c3ccccc3c3ccccc32)c1)c1ccc2c(c1)c1ccc(-c3ccccc3)cc1n2-c1ccccc1] | 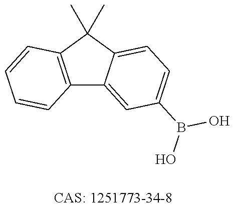 [SMILES: CC1(C)c2ccccc2-c2cc(B(O)O)ccc21] | 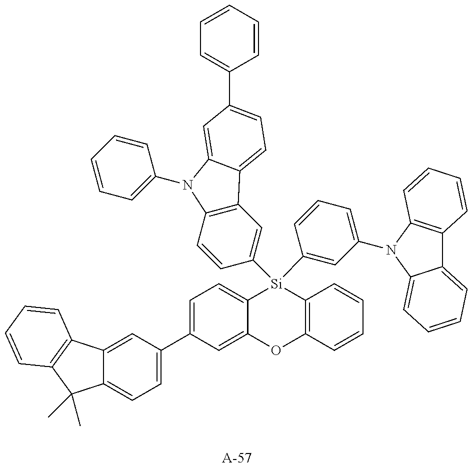 [SMILES: CC1(C)c2ccccc2-c2cc(-c3ccc4c(c3)Oc3ccccc3[Si]4(c3cccc(-n4c5ccccc5c5ccccc54)c3)c3ccc4c(c3)c3ccc(-c5ccccc5)cc3n4-c3ccccc3)ccc21 ; "A-57"] | 77 | 949.3 |
| 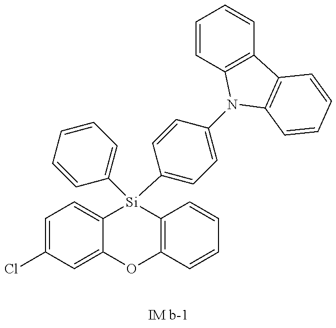 [SMILES: Clc1ccc2c(c1)Oc1ccccc1[Si]2(c1ccccc1)c1ccc(-n2c3ccccc3c3ccccc32)cc1] | 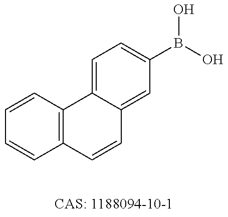 [SMILES: OB(O)c1ccc2c(ccc3ccccc32)c1] | 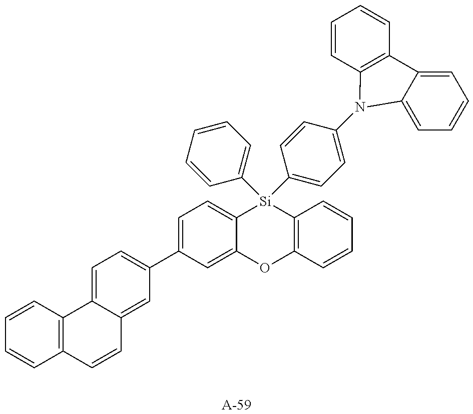 [SMILES: c1ccc([Si]2(c3ccc(-n4c5ccccc5c5ccccc54)cc3)c3ccccc3Oc3cc(-c4ccc5c(ccc6ccccc65)c4)ccc32)cc1 ; "A-59"] | 67 | 692.2 |
| 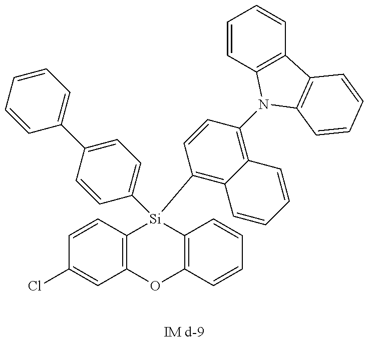 [SMILES: Clc1ccc2c(c1)Oc1ccccc1[Si]2(c1ccc(-c2ccccc2)cc1)c1ccc(-n2c3ccccc3c3ccccc32)c2ccccc12] | 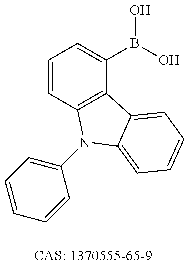 [SMILES: OB(O)c1cccc2c1c1ccccc1n2-c1ccccc1] | 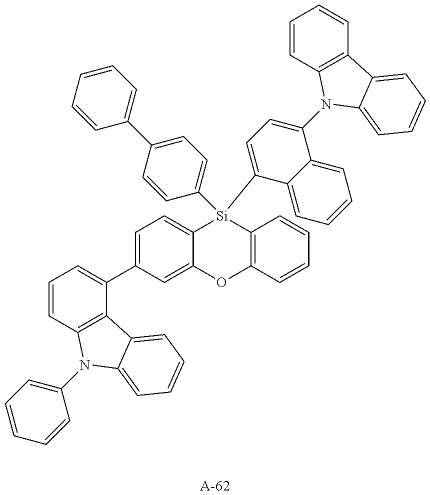 [SMILES: c1ccc(-c2ccc([Si]3(c4ccc(-n5c6ccccc6c6ccccc65)c5ccccc45)c4ccccc4Oc4cc(-c5cccc6c5c5ccccc5n6-c5ccccc5)ccc43)cc2)cc1 ; "A-62"] | 78 | 883.3 |
| 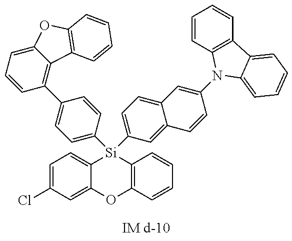 [SMILES: Clc1ccc2c(c1)Oc1ccccc1[Si]2(c1ccc(-c2cccc3oc4ccccc4c23)cc1)c1ccc2cc(-n3c4ccccc4c4ccccc43)ccc2c1] | 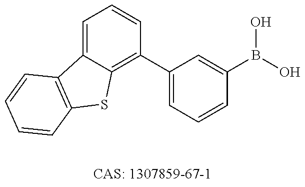 [SMILES: OB(O)c1cccc(-c2cccc3c2sc2ccccc23)c1] | 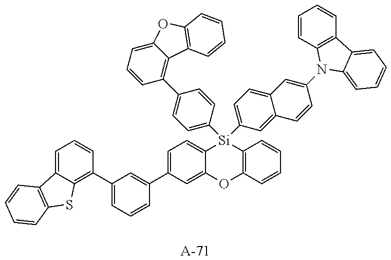 [SMILES: c1cc(-c2ccc3c(c2)Oc2ccccc2[Si]3(c2ccc(-c3cccc4oc5ccccc5c34)cc2)c2ccc3cc(-n4c5ccccc5c5ccccc54)ccc3c2)cc(-c2cccc3c2sc2ccccc23)c1 ; "A-71"] | 72 | 990.3 |
| 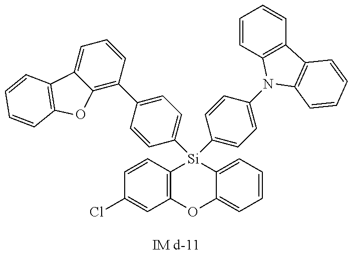 [SMILES: Clc1ccc2c(c1)Oc1ccccc1[Si]2(c1ccc(-c2cccc3c2oc2ccccc23)cc1)c1ccc(-n2c3ccccc3c3ccccc32)cc1] | 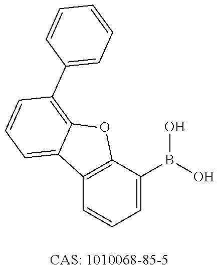 [SMILES: OB(O)c1cccc2c1oc1c(-c3ccccc3)cccc12] | 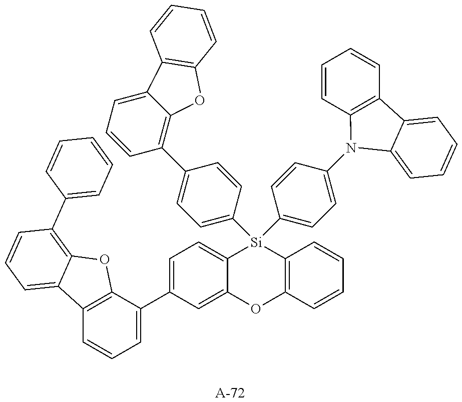 [SMILES: c1ccc(-c2cccc3c2oc2c(-c4ccc5c(c4)Oc4ccccc4[Si]5(c4ccc(-c5cccc6c5oc5ccccc56)cc4)c4ccc(-n5c6ccccc6c6ccccc65)cc4)cccc23)cc1 ; "A-72"] | 66 | 924.3 |
| 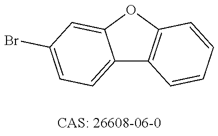 [SMILES: Brc1ccc2c(c1)oc1ccccc12] | 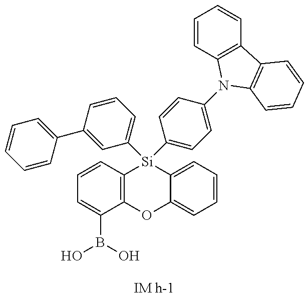 [SMILES: OB(O)c1cccc2c1Oc1ccccc1[Si]2(c1ccc(-n2c3ccccc3c3ccccc32)cc1)c1cccc(-c2ccccc2)c1] | 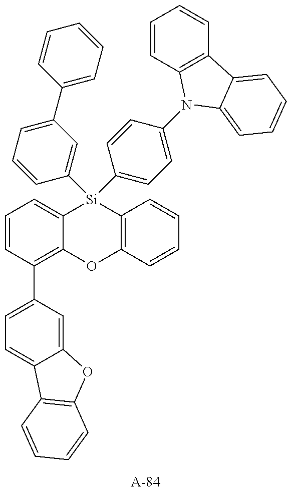 [SMILES: c1ccc(-c2cccc([Si]3(c4ccc(-n5c6ccccc6c6ccccc65)cc4)c4ccccc4Oc4c(-c5ccc6c(c5)oc5ccccc56)cccc43)c2)cc1 ; "A-84"] | 79 | 758.2 |
| 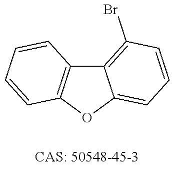 [SMILES: Brc1cccc2oc3ccccc3c12] | 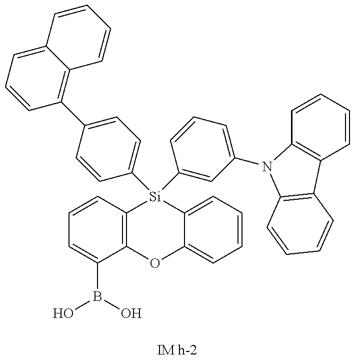 [SMILES: OB(O)c1cccc2c1Oc1ccccc1[Si]2(c1ccc(-c2cccc3ccccc23)cc1)c1cccc(-n2c3ccccc3c3ccccc32)c1] | 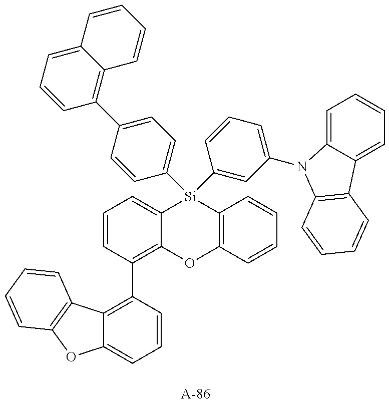 [SMILES: c1cc(-n2c3ccccc3c3ccccc32)cc([Si]2(c3ccc(-c4cccc5ccccc45)cc3)c3ccccc3Oc3c(-c4cccc5oc6ccccc6c45)cccc32)c1 ; "A-86"] | 69 | 808.3 |
| 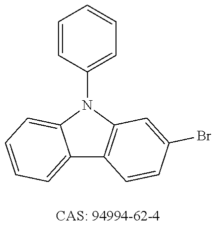 [SMILES: Brc1ccc2c3ccccc3n(-c3ccccc3)c2c1] | 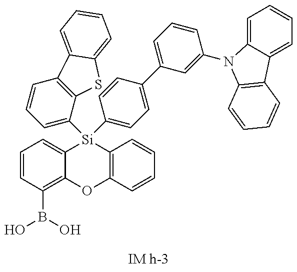 [SMILES: OB(O)c1cccc2c1Oc1ccccc1[Si]2(c1ccc(-c2cccc(-n3c4ccccc4c4ccccc43)c2)cc1)c1cccc2c1sc1ccccc12] | 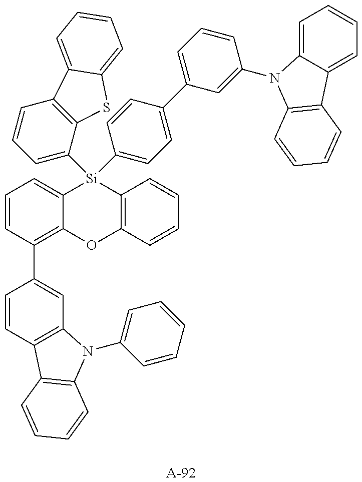 [SMILES: c1ccc(-n2c3ccccc3c3ccc(-c4cccc5c4Oc4ccccc4[Si]5(c4ccc(-c5cccc(-n6c7ccccc7c7ccccc76)c5)cc4)c4cccc5c4sc4ccccc45)cc32)cc1 ; "A-92"] | 76 | 939.3 |
| 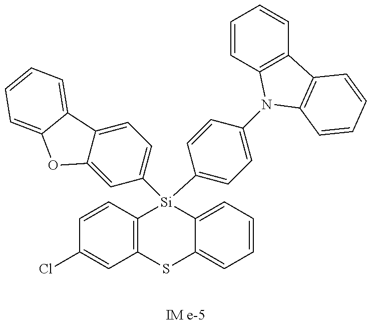 [SMILES: Clc1ccc2c(c1)Sc1ccccc1[Si]2(c1ccc(-n2c3ccccc3c3ccccc32)cc1)c1ccc2c(c1)oc1ccccc12] | 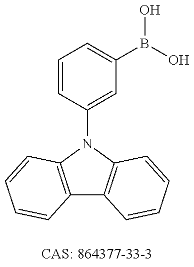 [SMILES: OB(O)c1cccc(-n2c3ccccc3c3ccccc32)c1] | 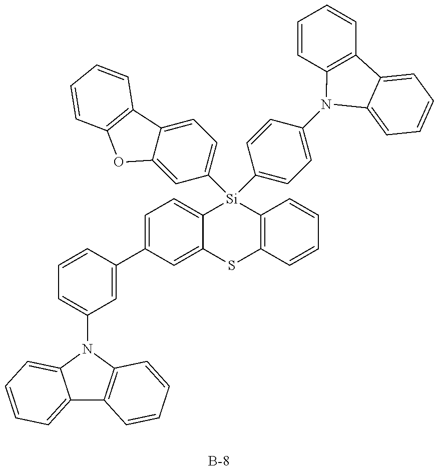 | 70 | 863.3 |
| 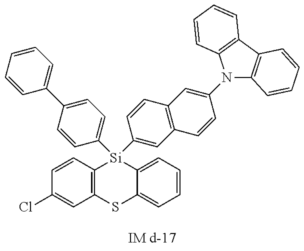 [SMILES: Clc1ccc2c(c1)Sc1ccccc1[Si]2(c1ccc(-c2ccccc2)cc1)c1ccc2cc(-n3c4ccccc4c4ccccc43)ccc2c1] | 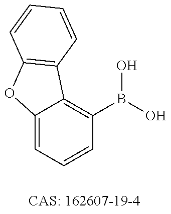 [SMILES: OB(O)c1cccc2oc3ccccc3c12] | 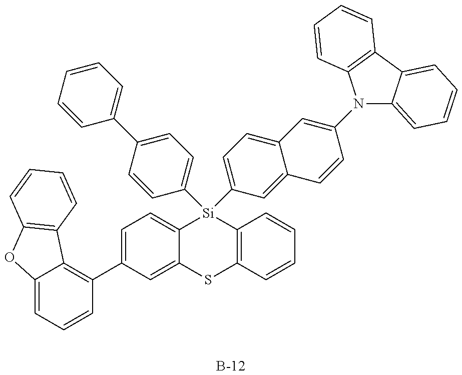 | 75 | 824.2 |
| 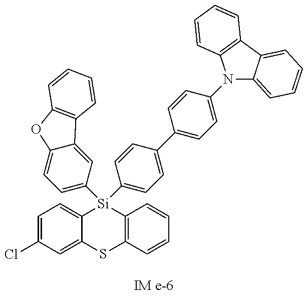 [SMILES: Clc1ccc2c(c1)Sc1ccccc1[Si]2(c1ccc(-c2ccc(-n3c4ccccc4c4ccccc43)cc2)cc1)c1ccc2oc3ccccc3c2c1] | 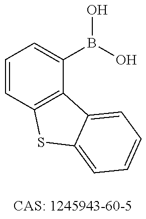 [SMILES: OB(O)c1cccc2sc3ccccc3c12] | 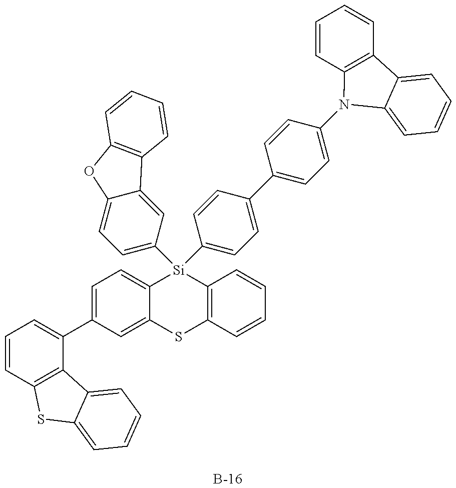 | 71 | 880.2 |
| 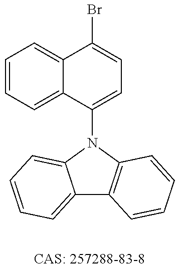 [SMILES: Brc1ccc(-n2c3ccccc3c3ccccc32)c2ccccc12] | 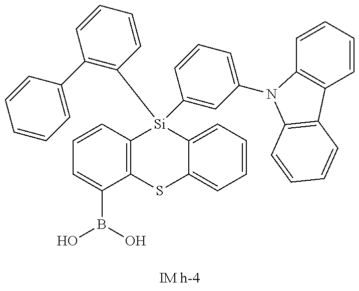 [SMILES: OB(O)c1cccc2c1Sc1ccccc1[Si]2(c1cccc(-n2c3ccccc3c3ccccc32)c1)c1ccccc1-c1ccccc1] | 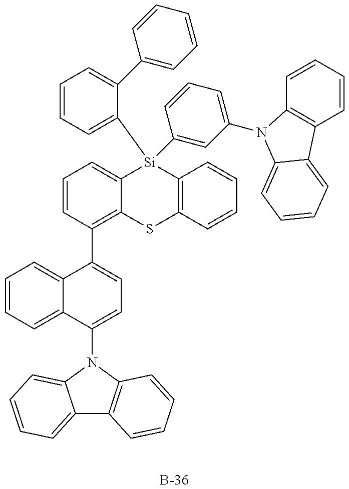 | 70 | 899.3 |

NMR data of some Compounds are shown in Table 13 below:

TABLE 13

| Compound | NMR data |
|---|---|
| Compound | ¹H-NMR (CD₂Cl₂, 400 MHz): 8.08(d, 1H), 7.93(d, 2H), 7.89(d, 2H), 7.67(m, 3H), |
| A-1 | 7.59-7.53(m, 4H), 7.43-7.30(m, 12H), 7.29(d, 1H), 7.25-7.17(m, 5H), 6.96(t, 1H), |
| | 6.16(s, 1H). |
| Compound | ¹H-NMR (CD₂Cl₂, 400 MHz): 8.10(d, 1H), 8.00(d, 2H), 7.90(d, 2H), 7.79(d, 2H), |
| A-90 | 7.55-7.52(m, 3H), 7.76-7.30(m, 15H), 7.28-7.20(m, 5H), 7.09(d, 1H), 6.94(t, 1H). |
| Compound | ¹H-NMR (CD₂Cl₂, 400 MHz): 8.13(d, 1H), 8.09(d, 1H), 7.95(d, 1H), 7.90(d, 2H), |
| B-11 | 7.87(s, 1H), 7.82(d, 1H), 7.69(d, 1H), 7.65(d, 1H), 7.62(d, 1H), 7.55-7.45(m, 9H), |
| | 7.43-7.30(m, 6H), 7.27-7.16(m, 6H), 6.85(d, 1H), 6.70(s, 1H). |

### Fabrication and Performance Evaluation of Organic Electroluminescent Device

### Example 1

An ITO substrate with a thickness of 1200 Å was cut into dimensions of 40 mm (length)×40 mm (width)×0.7 mm (height), and prepared into an experimental substrate having cathode, anode, and insulation layer patterns with photolithography process. A surface treatment was performed using ultraviolet ozone and O₂:N₂ plasma to remove surface floating debris and improve the anode work function of the substrate.

First, on the experimental substrate (anode), Compound HAT-CN and Compound HT-42 were co-deposited at a vapor deposition rate ratio of 2%:98% to form a hole injection layer with a thickness of 100 Å.

On the hole injection layer, Compound HT-42 was deposited to form a hole transport layer with a thickness of 980 Å.

On the hole transport layer, Compound SiCzCz was deposited to form an electron blocking layer with a thickness of 50 Å.

On the electron blocking layer, Compound BH-N, Compound A-1, and Compound BD were co-deposited at a vapor deposition rate ratio of 27%:60%:13% to form an organic light-emitting layer with a thickness of 350 Å.

On the organic light-emitting layer, Compound ET-21 and LiQ were deposited at a vapor deposition rate of 1:1 to form an electron transport layer with a thickness of 350 Å.

On the electron transport layer, Yb was deposited to form an electron injection layer with a thickness of 10 Å, and then aluminum (Al) was deposited by vacuum evaporation on the electron injection layer to form a cathode with a thickness of 800 Å. Thereby, a blue organic light-emitting device was fabricated.

### Examples 2 to 24

Organic electroluminescent devices were fabricated using the same method as that in Example 1, except that Compounds X shown in Table 15 were used instead of Compound A-1 during the formation of the organic light-emitting layer.

### Comparative Examples 1 to 4

Organic electroluminescent devices were fabricated using the same method as that in Example 1, except that the compounds A, B, C, and D shown in Table 14 were used instead of Compound A-1 during the formation of the organic light-emitting layer.

The main material structures used in the above examples and comparative examples are shown in Table 14 below:

TABLE 14

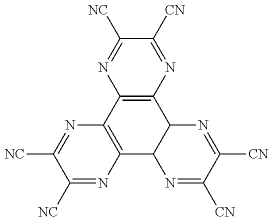 [SMILES: N#CC1=NC2c3nc(C#N)c(C#N)nc3-c3nc(C#N)c(C#N)nc3C2N=C1C#N]

HAT-CN

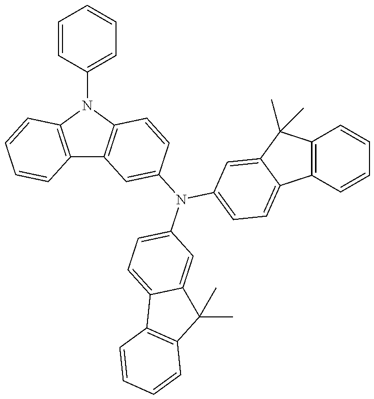 [SMILES: CC1(C)c2ccccc2-c2ccc(N(c3ccc4c(c3)C(C)(C)c3ccccc3-4)c3ccc4c(c3)c3ccccc3n4-c3ccccc3)cc21]

HT-42

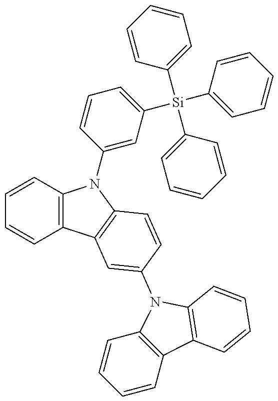 [SMILES: c1ccc([Si](c2ccccc2)(c2ccccc2)c2cccc(-n3c4ccccc4c4cc(-n5c6ccccc6c6ccccc65)ccc43)c2)cc1]

SiCzCz

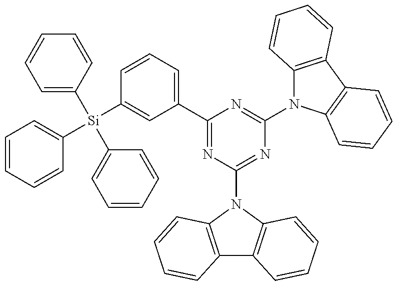 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

BH-N

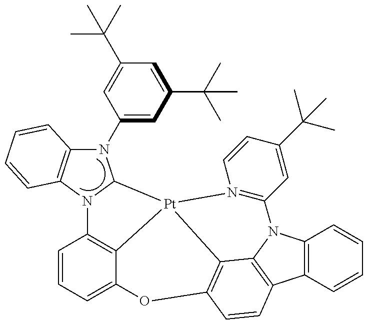

BD

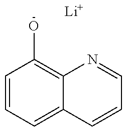 [SMILES: [Li+] ; Oc1cccc2cccnc12]

LiQ

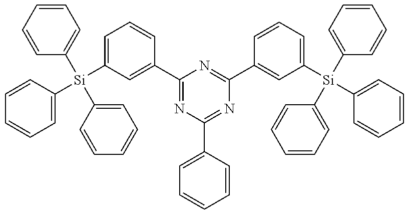 [SMILES: c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

ET-21

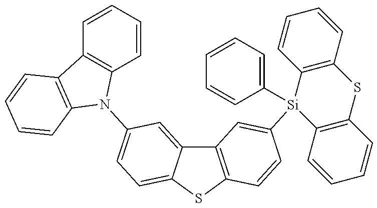 [SMILES: c1ccc([Si]2(c3ccc4sc5ccc(-n6c7ccccc7c7ccccc76)cc5c4c3)c3ccccc3Sc3ccccc32)cc1]

Compound A

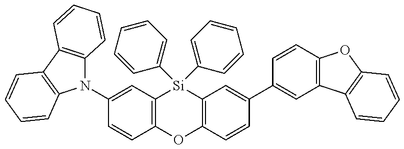 [SMILES: c1ccc([Si]2(c3ccccc3)c3cc(-c4ccc5oc6ccccc6c5c4)ccc3Oc3ccc(-n4c5ccccc5c5ccccc54)cc32)cc1]

Compound B

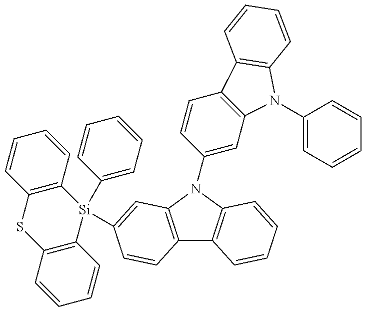 [SMILES: c1ccc(-n2c3ccccc3c3ccc(-n4c5ccccc5c5ccc([Si]6(c7ccccc7)c7ccccc7Sc7ccccc76)cc54)cc32)cc1]

Compound C

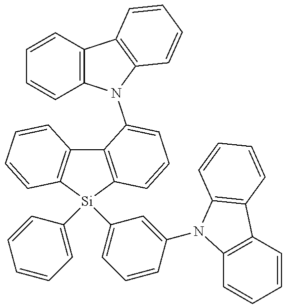 [SMILES: c1ccc([Si]2(c3cccc(-n4c5ccccc5c5ccccc54)c3)c3ccccc3-c3c(-n4c5ccccc5c5ccccc54)cccc32)cc1]

Compound D

The performances of the devices fabricated in Examples and Comparative Examples were tested, and the IVL (driving voltage, current efficiency, and color coordinates) and lifetime characteristics were evaluated at a luminance of 1000 nit. The results are presented in Table 15.

TABLE 15

| | Organic | | | | |
|---|---|---|---|---|---|
| | light-emitting layer | | Current | Color | |
| | BH-N:Compound | Driving | Efficiency | coordinates | T95 |
| Example No. | X:BD | Voltage (V) | (Cd/A) | CIEx, CIEy | lifetime(hrs) |
| Example 1 | Compound A-1 | 6.18 | 27.68 | 0.140, 0.140 | 213 |
| Example 2 | Compound A-2 | 6.16 | 27.57 | 0.140, 0.140 | 228 |
| Example 3 | Compound A-7 | 6.19 | 27.37 | 0.140, 0.140 | 214 |
| Example 4 | Compound A-10 | 6.21 | 27.86 | 0.140, 0.140 | 219 |
| Example 5 | Compound A-12 | 6.12 | 27.33 | 0.140, 0.140 | 226 |
| Example 6 | Compound A-15 | 6.16 | 27.76 | 0.140, 0.140 | 218 |
| Example 7 | Compound A-90 | 6.14 | 28.32 | 0.140, 0.140 | 212 |
| Example 8 | Compound A-97 | 6.22 | 28.23 | 0.140, 0.140 | 224 |
| Example 9 | Compound B-4 | 6.11 | 27.79 | 0.140, 0.140 | 225 |
| Example 10 | Compound A-28 | 6.22 | 27.27 | 0.140, 0.140 | 227 |
| Example 11 | Compound A-46 | 6.15 | 27.34 | 0.140, 0.140 | 215 |
| Example 12 | Compound A-57 | 6.18 | 28.35 | 0.140, 0.140 | 220 |
| Example 13 | Compound A-59 | 6.20 | 27.49 | 0.140, 0.140 | 207 |
| Example 14 | Compound A-62 | 6.13 | 27.89 | 0.140, 0.140 | 222 |
| Example 15 | Compound A-71 | 6.20 | 28.55 | 0.140, 0.140 | 211 |
| Example 16 | Compound A-72 | 6.14 | 28.46 | 0.140, 0.140 | 216 |
| Example 17 | Compound A-84 | 6.10 | 28.44 | 0.140, 0.140 | 208 |
| Example 18 | Compound A-86 | 6.17 | 27.58 | 0.140, 0.140 | 205 |
| Example 19 | Compound A-92 | 6.15 | 28.11 | 0.140, 0.140 | 223 |
| Example 20 | Compound B-8 | 6.13 | 27.46 | 0.140, 0.140 | 209 |
| Example 21 | Compound B-11 | 6.19 | 28.27 | 0.140, 0.140 | 206 |
| Example 22 | Compound B-12 | 6.11 | 27.38 | 0.140, 0.140 | 217 |
| Example 23 | Compound B-16 | 6.17 | 28.16 | 0.140, 0.140 | 210 |
| Example 24 | Compound B-36 | 6.10 | 28.06 | 0.140, 0.140 | 221 |
| Comparative | Compound A | 6.29 | 22.79 | 0.140, 0.140 | 165 |
| Example 1 | | | | | |
| Comparative | Compound B | 6.43 | 20.53 | 0.140, 0.140 | 158 |
| Example 2 | | | | | |
| Comparative | Compound C | 6.35 | 21.21 | 0.140, 0.140 | 161 |
| Example 3 | | | | | |
| Comparative | Compound D | 6.25 | 23.67 | 0.140, 0.140 | 170 |
| Example 4 | | | | | |

It can be seen from the results presented in Table 15 that, comparing Examples 1 to 24 with Comparative Examples 1 to 4, when the organic compounds according to the present application were used as the host material in the light-emitting layer, the current efficiency (Cd/A) was improved by at least 15.2% and the lifetime was improved by at least 20.6%.

The preferred embodiments of the present application are described in detail above in conjunction with the accompanying drawings. However, the present application is not limited to the specific details of the above embodiments. Within the scope of the technical concept of the present application, various simple modifications can be made to the technical solutions of the present application, and all these simple modifications fall within the protection scope of the present application.

Furthermore, it should be noted that the specific technical features described in the above embodiments can be combined in any suitable way without contradiction. To avoid unnecessary repetition, the present application will not separately explain various possible combination methods.

1. An organic compound, having a structure shown in a Formula I: 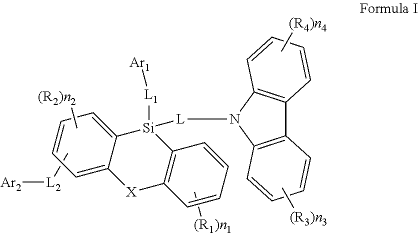
wherein, X is selected from O or S;
Ar₁ and Ar₂ are the same or different, and are each independently selected from a substituted or unsubstituted aryl having 6 to 40 carbon atoms, or a substituted or unsubstituted heteroaryl having 3 to 40 carbon atoms;
L₁ and L₂ are the same or different, and are each independently selected from a single bond, a substituted or unsubstituted arylene having 6 to 30 carbon atoms, or a substituted or unsubstituted heteroarylene having 3 to 30 carbon atoms;
L is selected from a substituted or unsubstituted arylene having 6 to 30 carbon atoms, or a substituted or unsubstituted heteroarylene having 3 to 30 carbon atoms;
the substituent(s) of Ar₁, Ar₂, L₁, L₂ and L are the same or different, and are each independently selected from a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, an aryl having 6 to 20 carbon atoms, or a heteroaryl having 3 to 20 carbon atoms;
R₁, R₂, R₃ and R₄ are the same or different, and are each independently selected from a hydrogen, a deuterium, a halogen group, a cyano, an alkyl having 1 to 10 carbon atoms, a trialkylsilyl having 3 to 12 carbon atoms, a haloalkyl having 1 to 10 carbon atoms, a cycloalkyl having 3 to 10 carbon atoms, a substituted or unsubstituted aryl having 6 to 20 carbon atoms, or a substituted or unsubstituted heteroaryl having 3 to 20 carbon atoms;
n₁ represents the number of R₁, and n₁ is selected from 1, 2, 3, or 4; when n₁ is greater than 1, any two R₁ are the same or different;
n₂ represents the number of R₂, and n₂ is selected from 1, 2, or 3; when n₂ is greater than 1, any two R₂ are the same or different;
n₃ represents the number of R₃, and n₃ is selected from 1, 2, 3, or 4; when n₃ is greater than 1, any two R₃ are the same or different;
n₄ represents the number of R₄, and n₄ is selected from 1, 2, 3, or 4; when n₄ is greater than 1, any two R₄ are the same or different;
the substituent(s) of R₁, R₂, R₃ and R₄ are the same or different, and are each independently selected from a deuterium, a halogen group, a cyano, an alkyl having 1 to 5 carbon atoms, an aryl having 6 to 12 carbon atoms, or a heteroaryl having 3 to 12 carbon atoms.

2. The organic compound according to claim 1, wherein L is selected from a substituted or unsubstituted phenylene, a substituted or unsubstituted naphthylene, a substituted or unsubstituted biphenylene, a substituted or unsubstituted terphenylene, a substituted or unsubstituted fluorenylene, a substituted or unsubstituted phenanthrylene, a substituted or unsubstituted pyridylene, a substituted or unsubstituted dibenzofuranylene, or a substituted or unsubstituted dibenzothienylene;
optionally, the substituent(s) of L are each independently selected from a deuterium, a fluorine, a cyano, a methyl, an ethyl, an isopropyl, a tert-butyl, a phenyl, a naphthyl, or a biphenyl.

3. The organic compound according to claim 1, wherein Ar₁ and Ar₂ are each independently selected from a substituted or unsubstituted phenyl, a substituted or unsubstituted naphthyl, a substituted or unsubstituted biphenyl, a substituted or unsubstituted terphenyl, a substituted or unsubstituted fluorenyl, a substituted or unsubstituted phenanthryl, a substituted or unsubstituted anthryl, a substituted or unsubstituted pyridyl, a substituted or unsubstituted quinolyl, a substituted or unsubstituted dibenzofuranyl, a substituted or unsubstituted dibenzothienyl, a substituted or unsubstituted carbazolyl, a substituted or unsubstituted spirobifluorenyl, a substituted or unsubstituted pyrenyl, or a substituted or unsubstituted triphenylene;
optionally, the substituent(s) of Ar₁ and Ar₂ are each independently selected from a deuterium, a fluorine, a cyano, a methyl, an ethyl, an isopropyl, a tert-butyl, a trimethylsilyl, a trifluoromethyl, a cyclopentane, a cyclohexane, an adamantane, a phenyl, a naphthyl, a biphenyl, a dibenzofuranyl, a dibenzothienyl, or a carbazolyl.

4. The organic compound according to claim 1, wherein L₁ and L₂ are each independently selected from a single bond, a substituted or unsubstituted phenylene, a substituted or unsubstituted naphthylene, a substituted or unsubstituted biphenylene, a substituted or unsubstituted anthrylene, a substituted or unsubstituted fluorenylene, a substituted or unsubstituted dibenzothienylene, a substituted or unsubstituted dibenzofuranylene, or a substituted or unsubstituted carbazolylene;
optionally, the substituent(s) of L₁ and L₂ are each independently selected from a deuterium, a fluorine, a cyano, a trimethylsilyl, a trifluoromethyl, a methyl, an ethyl, an isopropyl, a tert-butyl, a phenyl, a naphthyl, or a biphenyl.

5. The organic compound according to claim 1, wherein Ar₁ is selected from the group consisting of the following groups:

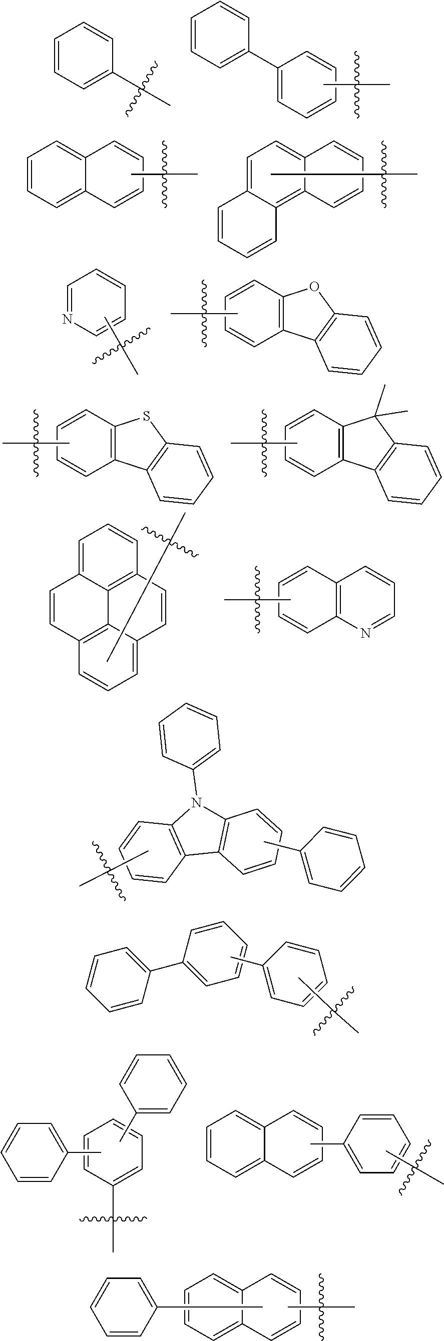

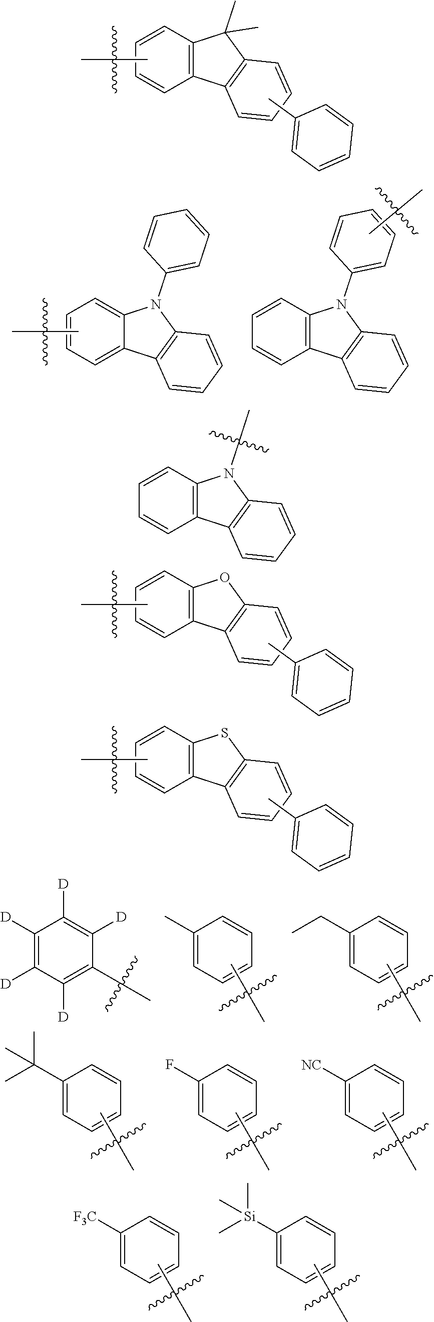

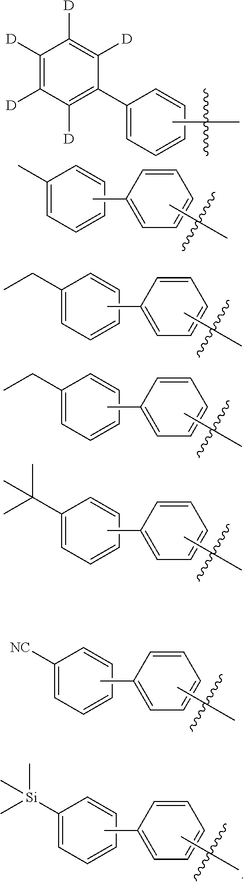

6. The organic compound according to claim 1, wherein 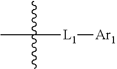
is selected from the group consisting of the following groups:

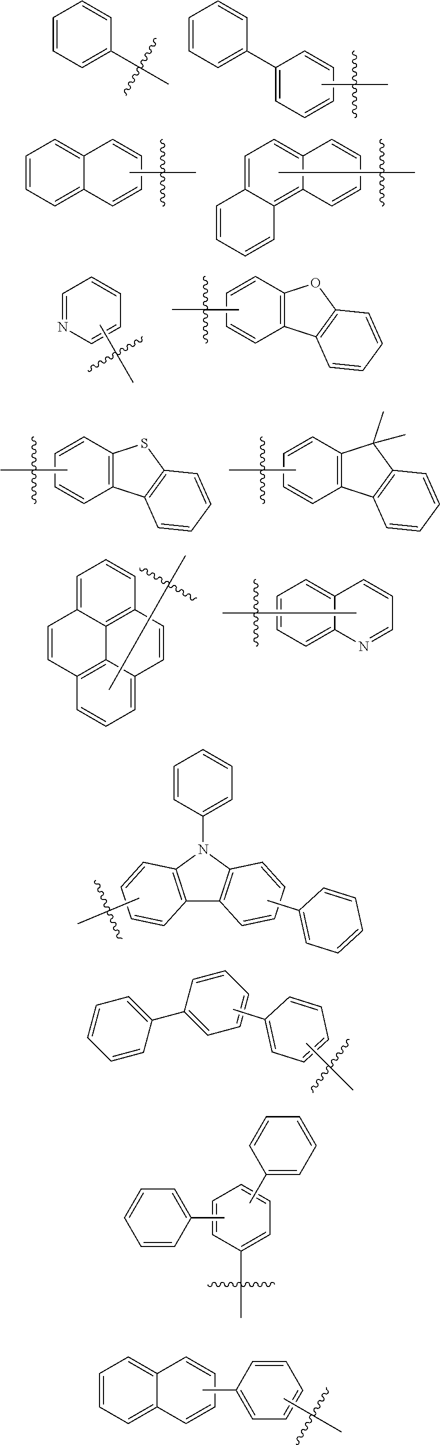

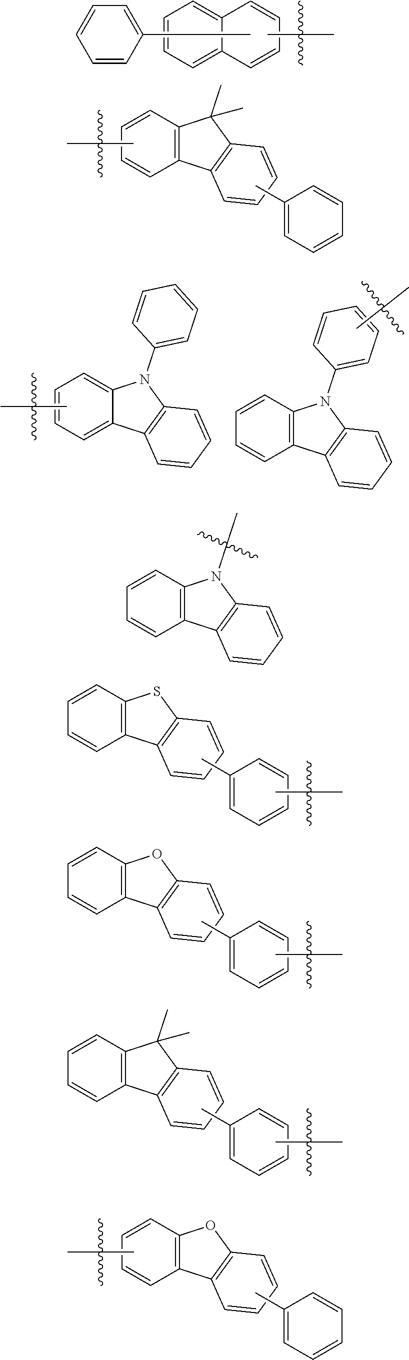

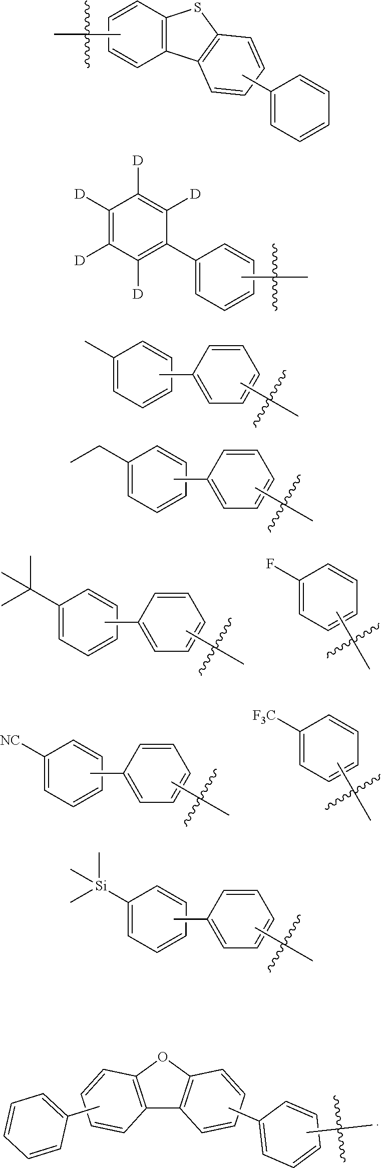

7. The organic compound according to claim 1, wherein Ar₂ is selected from the group consisting of the following groups:

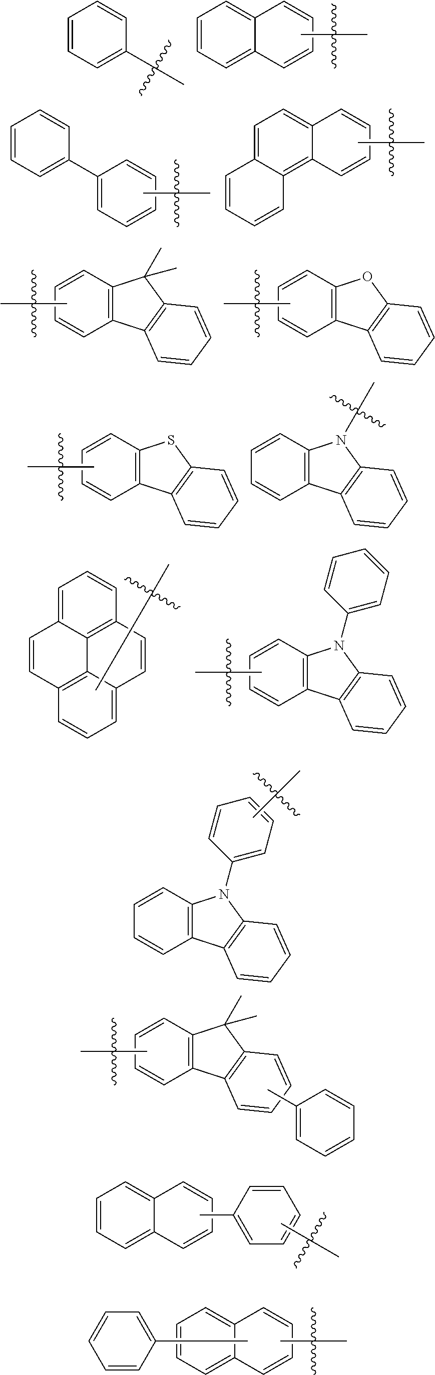

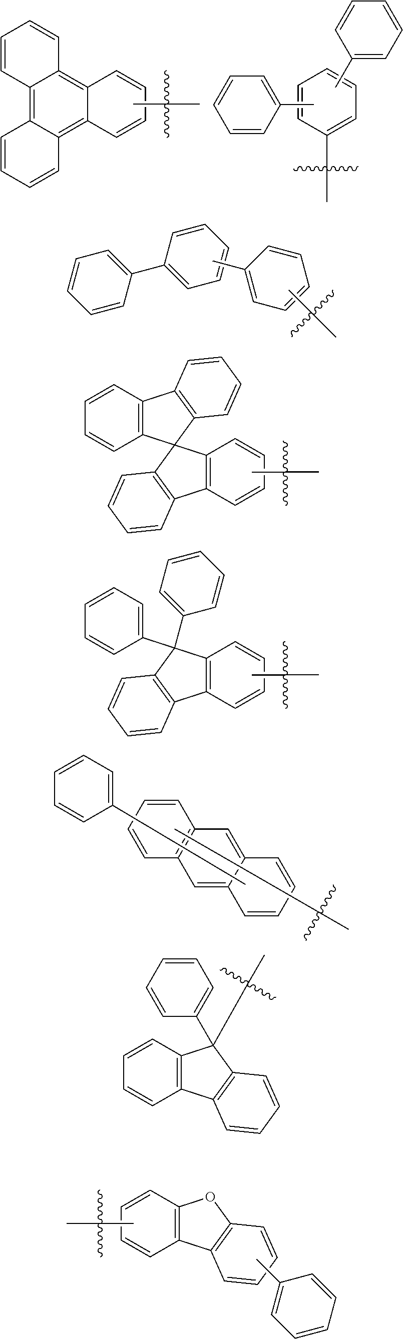

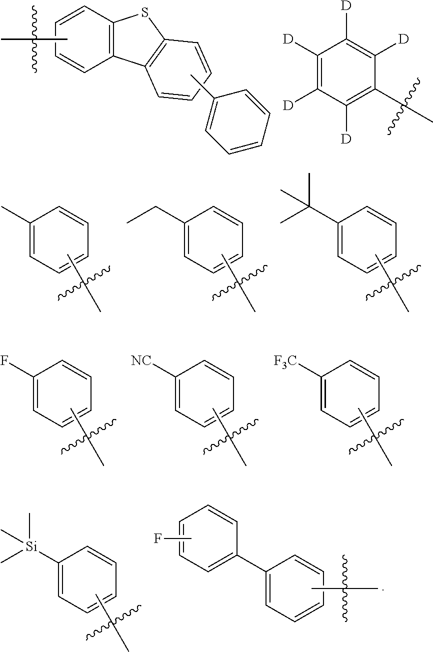

8. The organic compound according to claim 1, wherein 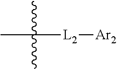
is selected from the group consisting of the following groups:

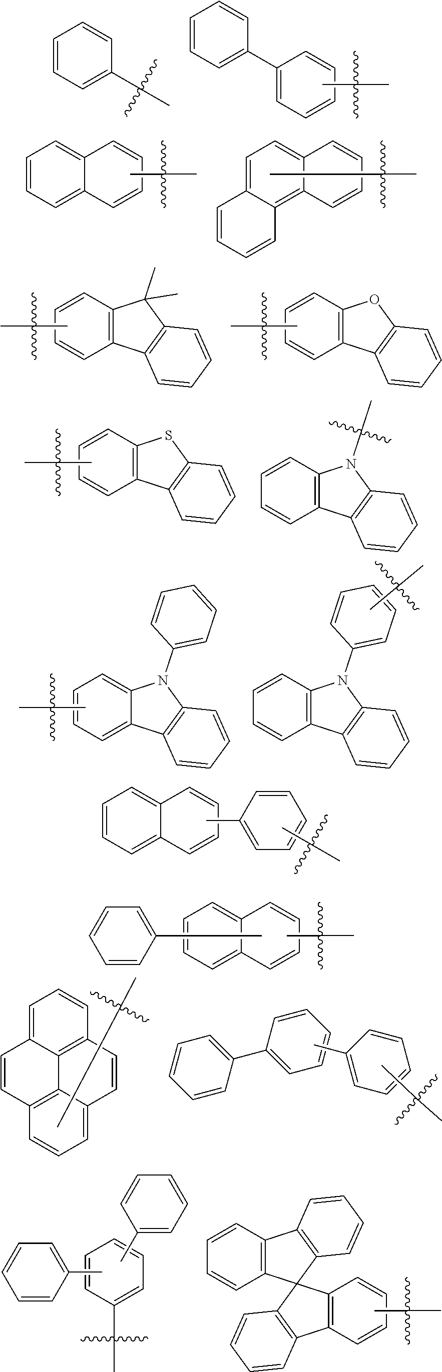

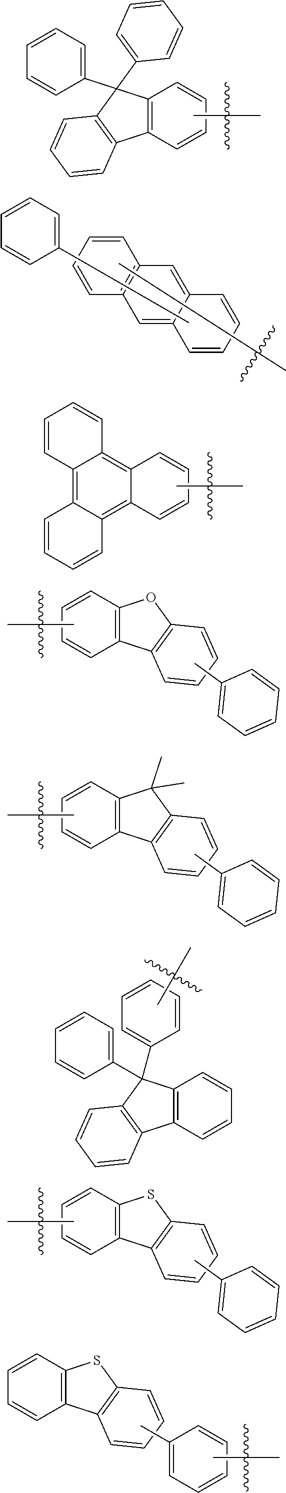

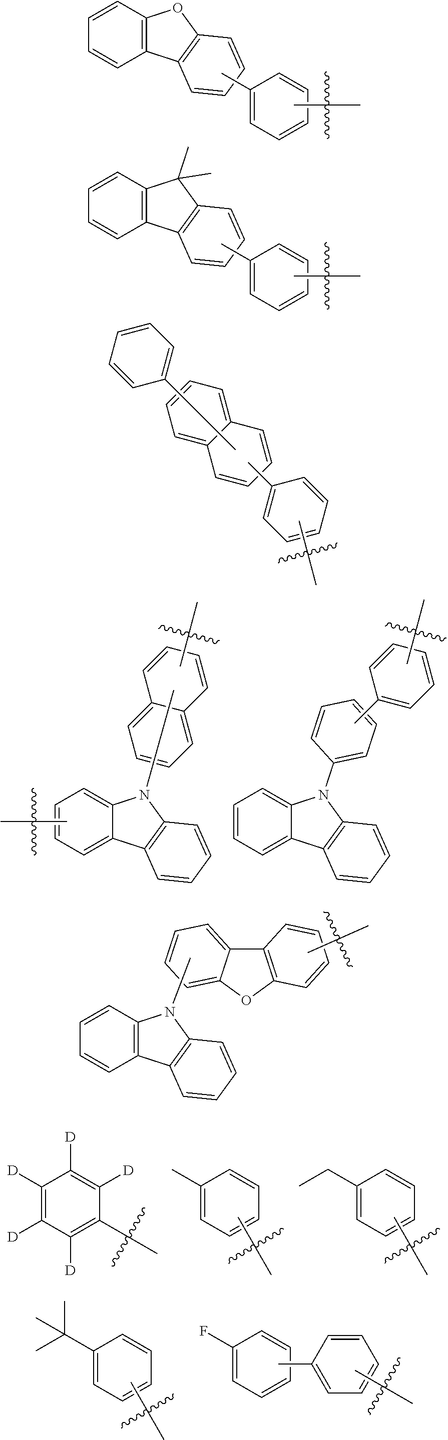

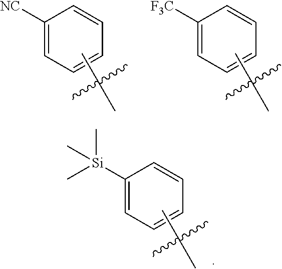

9. The organic compound according to claim 1, wherein R₁, R₂, R₃ and R₄ are each independently selected from a hydrogen, a deuterium, a fluorine, a cyano, a methyl, an ethyl, an isopropyl, a tert-butyl, a trimethylsilyl, a trifluoromethyl, a cyclopentane, a cyclohexane, an adamantane, a deuterated phenyl, a phenyl, a naphthyl, a biphenyl, a phenanthryl, a pyridyl, a quinolyl, a 9,9-dimethylfluorenyl, a dibenzofuranyl, a dibenzothienyl, N-carbazolyl, or N-phenylcarbazolyl.

10. The organic compound according to claim 1, wherein the organic compound is selected from the group consisting of the following compounds:

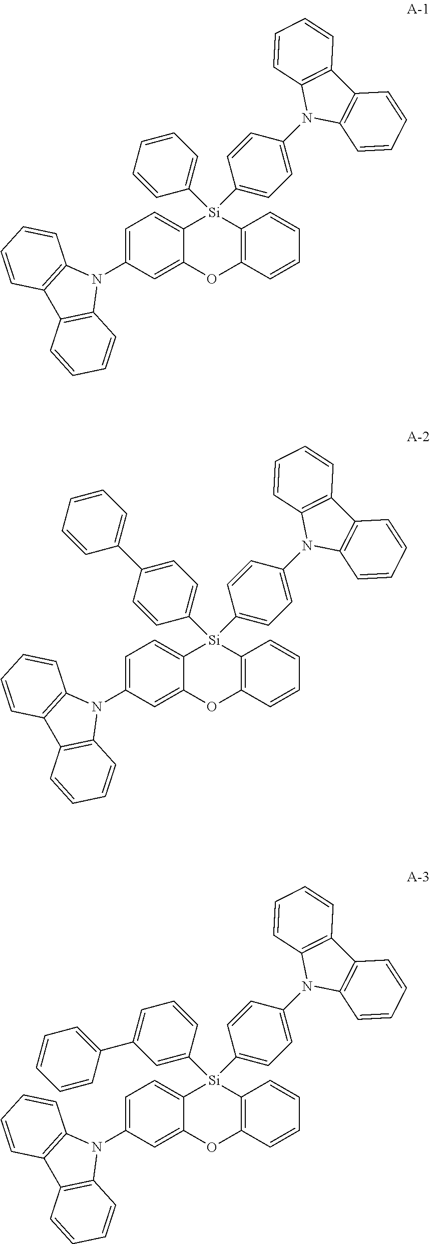 [SMILES: c1ccc([Si]2(c3ccc(-n4c5ccccc5c5ccccc54)cc3)c3ccccc3Oc3cc(-n4c5ccccc5c5ccccc54)ccc32)cc1 ; c1ccc(-c2ccc([Si]3(c4ccc(-n5c6ccccc6c6ccccc65)cc4)c4ccccc4Oc4cc(-n5c6ccccc6c6ccccc65)ccc43)cc2)cc1 ; c1ccc(-c2cccc([Si]3(c4ccc(-n5c6ccccc6c6ccccc65)cc4)c4ccccc4Oc4cc(-n5c6ccccc6c6ccccc65)ccc43)c2)cc1]

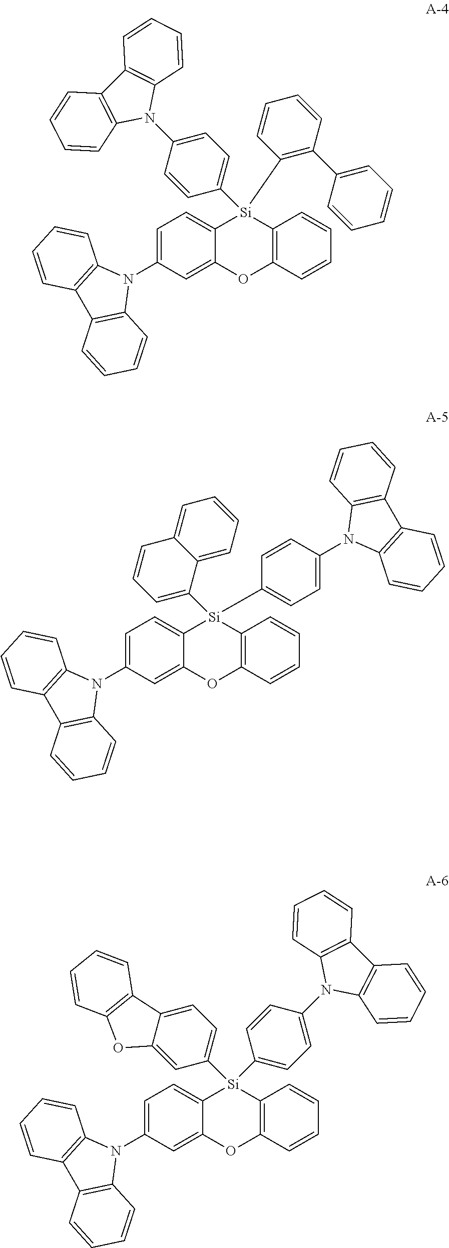 [SMILES: c1ccc(-c2ccccc2[Si]2(c3ccc(-n4c5ccccc5c5ccccc54)cc3)c3ccccc3Oc3cc(-n4c5ccccc5c5ccccc54)ccc32)cc1 ; c1ccc2c(c1)Oc1cc(-n3c4ccccc4c4ccccc43)ccc1[Si]2(c1ccc(-n2c3ccccc3c3ccccc32)cc1)c1cccc2ccccc12 ; c1ccc2c(c1)Oc1cc(-n3c4ccccc4c4ccccc43)ccc1[Si]2(c1ccc(-n2c3ccccc3c3ccccc32)cc1)c1ccc2c(c1)oc1ccccc12]

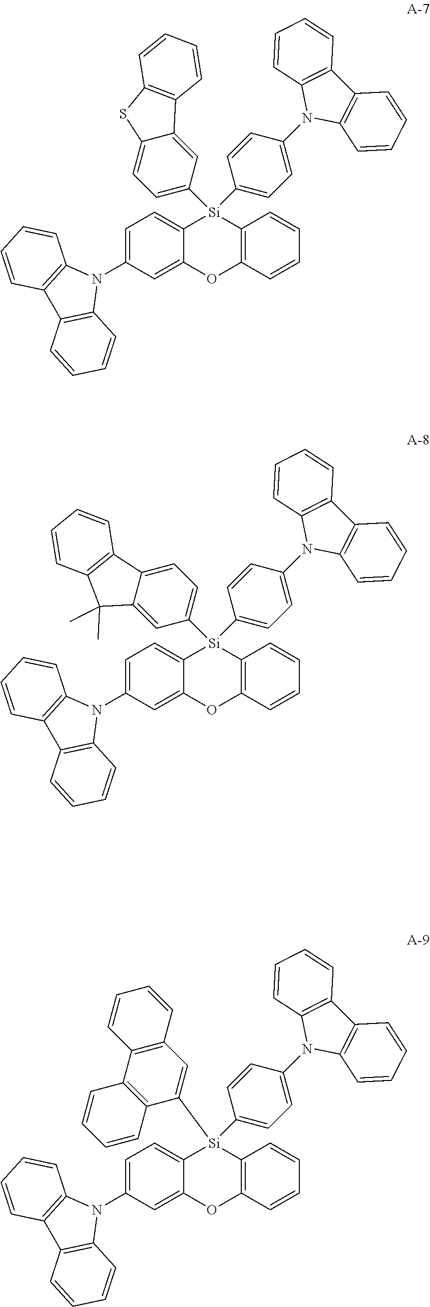 [SMILES: c1ccc2c(c1)Oc1cc(-n3c4ccccc4c4ccccc43)ccc1[Si]2(c1ccc(-n2c3ccccc3c3ccccc32)cc1)c1ccc2sc3ccccc3c2c1 ; CC1(C)c2ccccc2-c2ccc([Si]3(c4ccc(-n5c6ccccc6c6ccccc65)cc4)c4ccccc4Oc4cc(-n5c6ccccc6c6ccccc65)ccc43)cc21 ; c1ccc2c(c1)Oc1cc(-n3c4ccccc4c4ccccc43)ccc1[Si]2(c1ccc(-n2c3ccccc3c3ccccc32)cc1)c1cc2ccccc2c2ccccc12]

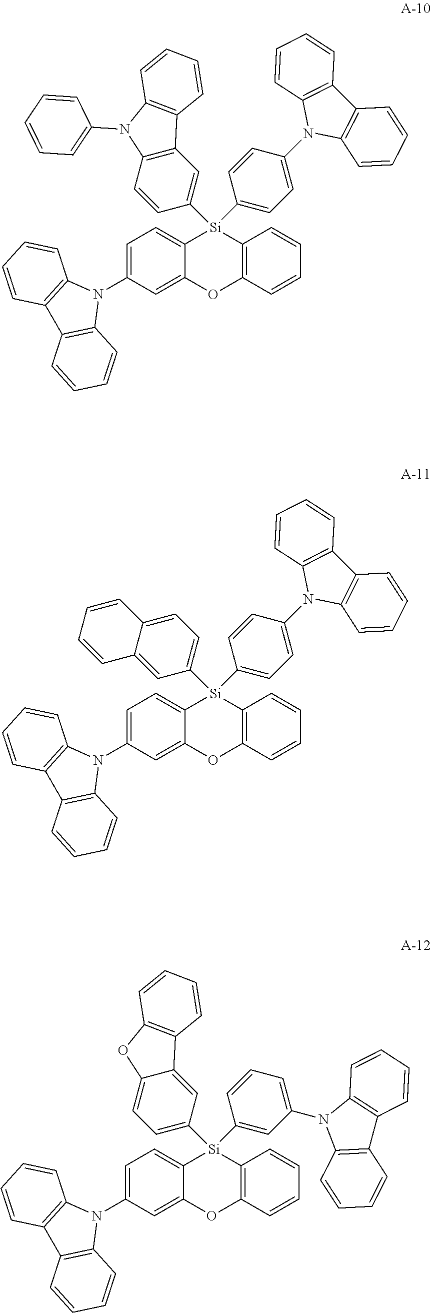 [SMILES: c1ccc(-n2c3ccccc3c3cc([Si]4(c5ccc(-n6c7ccccc7c7ccccc76)cc5)c5ccccc5Oc5cc(-n6c7ccccc7c7ccccc76)ccc54)ccc32)cc1 ; c1ccc2c(c1)Oc1cc(-n3c4ccccc4c4ccccc43)ccc1[Si]2(c1ccc(-n2c3ccccc3c3ccccc32)cc1)c1ccc2ccccc2c1 ; c1cc(-n2c3ccccc3c3ccccc32)cc([Si]2(c3ccc4oc5ccccc5c4c3)c3ccccc3Oc3cc(-n4c5ccccc5c5ccccc54)ccc32)c1]

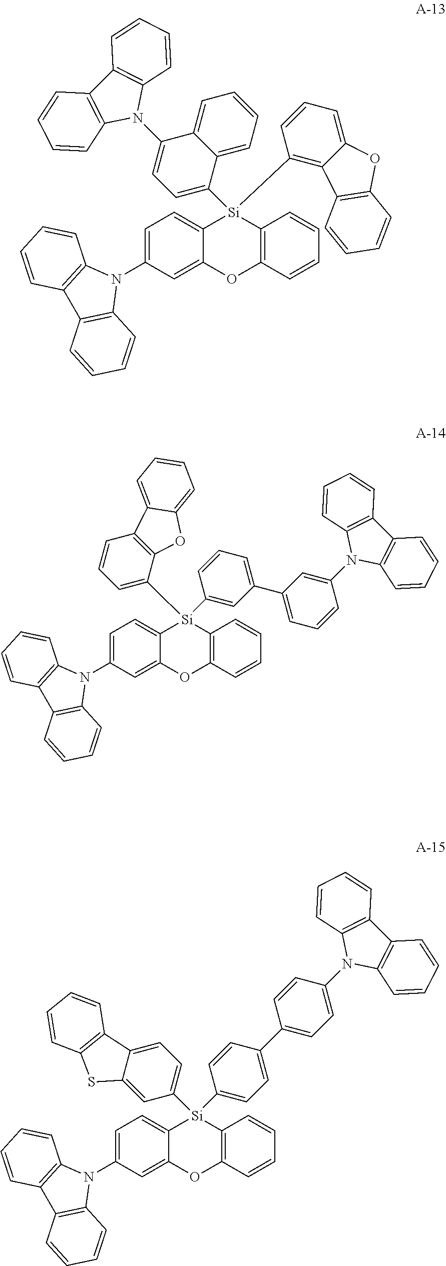 [SMILES: c1ccc2c(c1)Oc1cc(-n3c4ccccc4c4ccccc43)ccc1[Si]2(c1ccc(-n2c3ccccc3c3ccccc32)c2ccccc12)c1cccc2oc3ccccc3c12 ; c1cc(-c2cccc([Si]3(c4cccc5c4oc4ccccc45)c4ccccc4Oc4cc(-n5c6ccccc6c6ccccc65)ccc43)c2)cc(-n2c3ccccc3c3ccccc32)c1 ; c1ccc2c(c1)Oc1cc(-n3c4ccccc4c4ccccc43)ccc1[Si]2(c1ccc(-c2ccc(-n3c4ccccc4c4ccccc43)cc2)cc1)c1ccc2c(c1)sc1ccccc12]

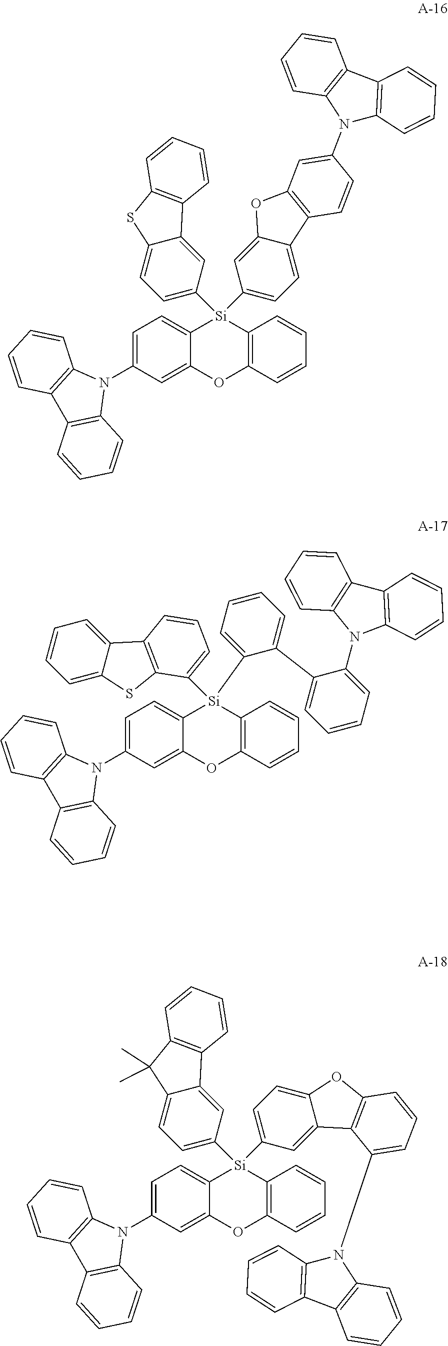 [SMILES: c1ccc2c(c1)Oc1cc(-n3c4ccccc4c4ccccc43)ccc1[Si]2(c1ccc2c(c1)oc1cc(-n3c4ccccc4c4ccccc43)ccc12)c1ccc2sc3ccccc3c2c1 ; c1ccc2c(c1)Oc1cc(-n3c4ccccc4c4ccccc43)ccc1[Si]2(c1ccccc1-c1ccccc1-n1c2ccccc2c2ccccc21)c1cccc2c1sc1ccccc12 ; CC1(C)c2ccccc2-c2cc([Si]3(c4ccc5oc6cccc(-n7c8ccccc8c8ccccc87)c6c5c4)c4ccccc4Oc4cc(-n5c6ccccc6c6ccccc65)ccc43)ccc21]

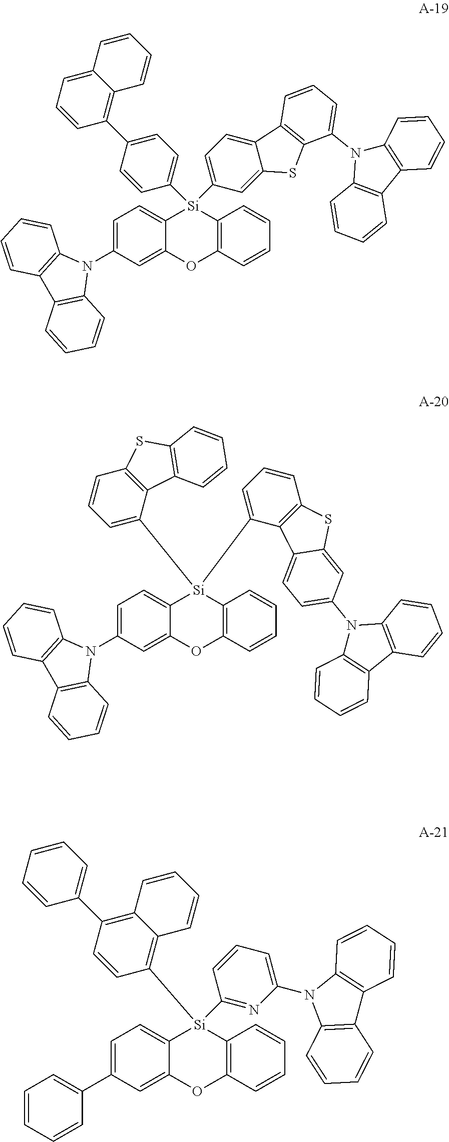 [SMILES: c1ccc2c(c1)Oc1cc(-n3c4ccccc4c4ccccc43)ccc1[Si]2(c1ccc(-c2cccc3ccccc23)cc1)c1ccc2c(c1)sc1c(-n3c4ccccc4c4ccccc43)cccc12 ; c1ccc2c(c1)Oc1cc(-n3c4ccccc4c4ccccc43)ccc1[Si]2(c1cccc2sc3ccccc3c12)c1cccc2sc3cc(-n4c5ccccc5c5ccccc54)ccc3c12 ; c1ccc(-c2ccc3c(c2)Oc2ccccc2[Si]3(c2cccc(-n3c4ccccc4c4ccccc43)n2)c2ccc(-c3ccccc3)c3ccccc23)cc1]

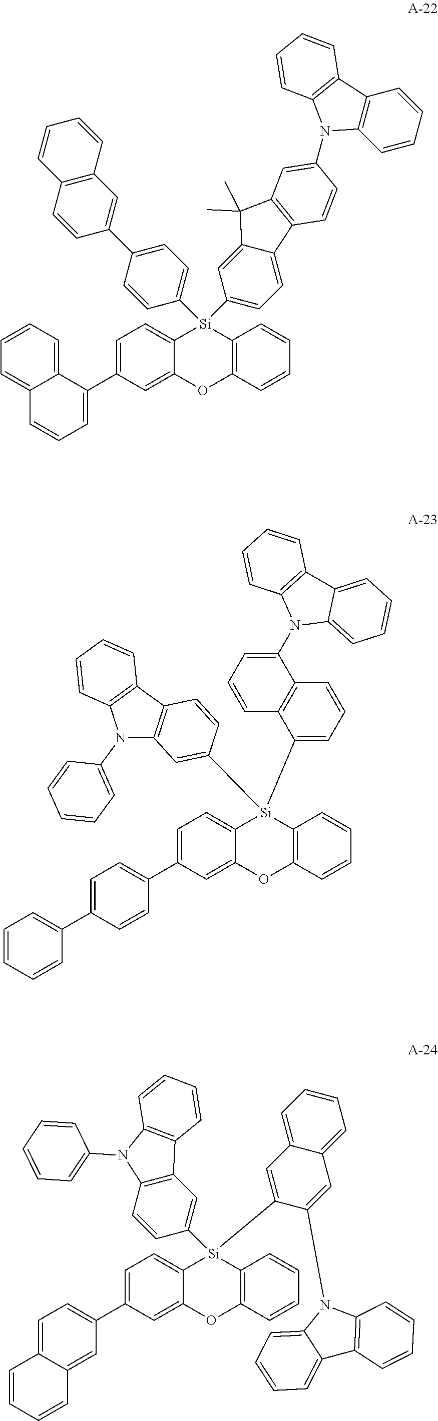 [SMILES: CC1(C)c2cc(-n3c4ccccc4c4ccccc43)ccc2-c2ccc([Si]3(c4ccc(-c5ccc6ccccc6c5)cc4)c4ccccc4Oc4cc(-c5cccc6ccccc56)ccc43)cc21 ; c1ccc(-c2ccc(-c3ccc4c(c3)Oc3ccccc3[Si]4(c3ccc4c5ccccc5n(-c5ccccc5)c4c3)c3cccc4c(-n5c6ccccc6c6ccccc65)cccc34)cc2)cc1 ; c1ccc(-n2c3ccccc3c3cc([Si]4(c5cc6ccccc6cc5-n5c6ccccc6c6ccccc65)c5ccccc5Oc5cc(-c6ccc7ccccc7c6)ccc54)ccc32)cc1]

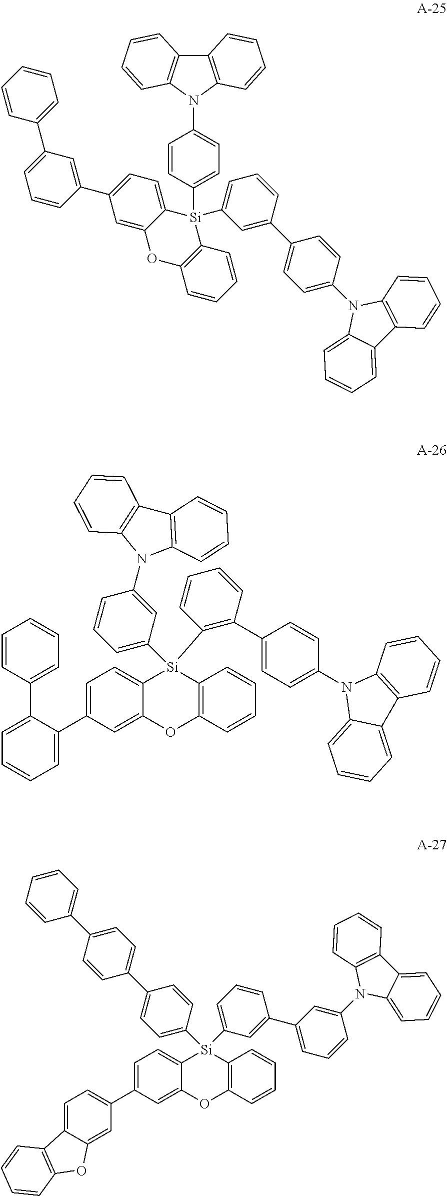 [SMILES: c1ccc(-c2cccc(-c3ccc4c(c3)Oc3ccccc3[Si]4(c3ccc(-n4c5ccccc5c5ccccc54)cc3)c3cccc(-c4ccc(-n5c6ccccc6c6ccccc65)cc4)c3)c2)cc1 ; c1ccc(-c2ccccc2-c2ccc3c(c2)Oc2ccccc2[Si]3(c2cccc(-n3c4ccccc4c4ccccc43)c2)c2ccccc2-c2ccc(-n3c4ccccc4c4ccccc43)cc2)cc1 ; c1ccc(-c2ccc(-c3ccc([Si]4(c5cccc(-c6cccc(-n7c8ccccc8c8ccccc87)c6)c5)c5ccccc5Oc5cc(-c6ccc7c(c6)oc6ccccc67)ccc54)cc3)cc2)cc1]

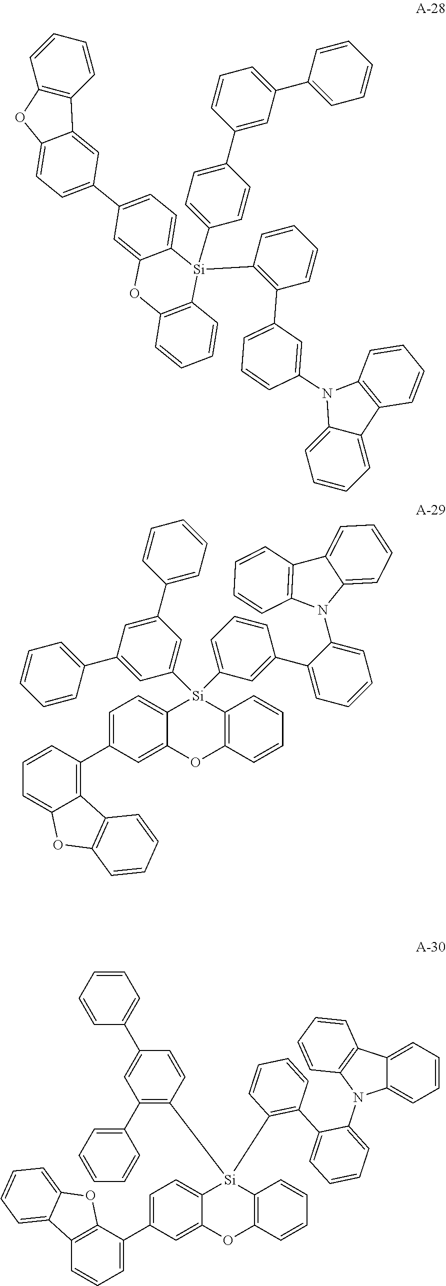

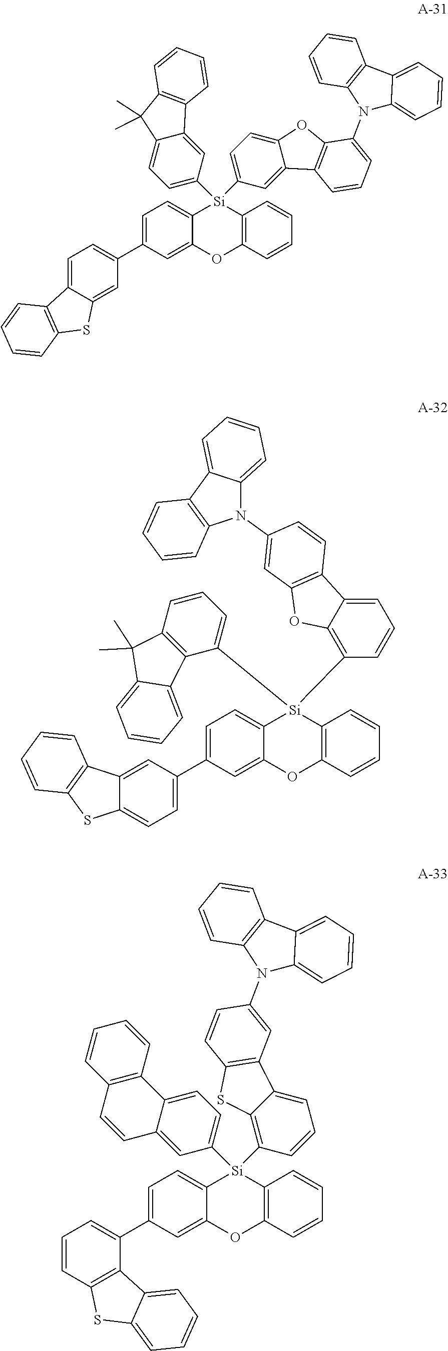 [SMILES: CC1(C)c2ccccc2-c2cc([Si]3(c4ccc5oc6c(-n7c8ccccc8c8ccccc87)cccc6c5c4)c4ccccc4Oc4cc(-c5ccc6c(c5)sc5ccccc56)ccc43)ccc21 ; CC1(C)c2ccccc2-c2c1cccc2[Si]1(c2cccc3c2oc2cc(-n4c5ccccc5c5ccccc54)ccc23)c2ccccc2Oc2cc(-c3ccc4sc5ccccc5c4c3)ccc21 ; c1ccc2c(c1)Oc1cc(-c3cccc4sc5ccccc5c34)ccc1[Si]2(c1ccc2c(ccc3ccccc32)c1)c1cccc2c1sc1ccc(-n3c4ccccc4c4ccccc43)cc12]

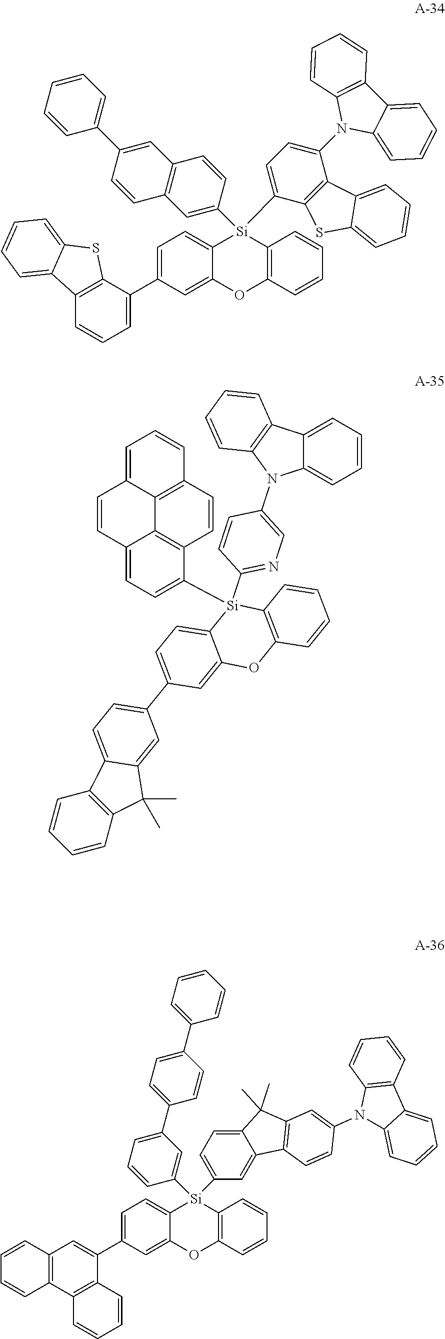 [SMILES: c1ccc(-c2ccc3cc([Si]4(c5ccc(-n6c7ccccc7c7ccccc76)c6c5sc5ccccc56)c5ccccc5Oc5cc(-c6cccc7c6sc6ccccc67)ccc54)ccc3c2)cc1 ; CC1(C)c2ccccc2-c2ccc(-c3ccc4c(c3)Oc3ccccc3[Si]4(c3ccc(-n4c5ccccc5c5ccccc54)cn3)c3ccc4ccc5cccc6ccc3c4c56)cc21 ; CC1(C)c2ccc([Si]3(c4cccc(-c5ccc(-c6ccccc6)cc5)c4)c4ccccc4Oc4cc(-c5cc6ccccc6c6ccccc56)ccc43)cc2-c2ccc(-n3c4ccccc4c4ccccc43)cc21]

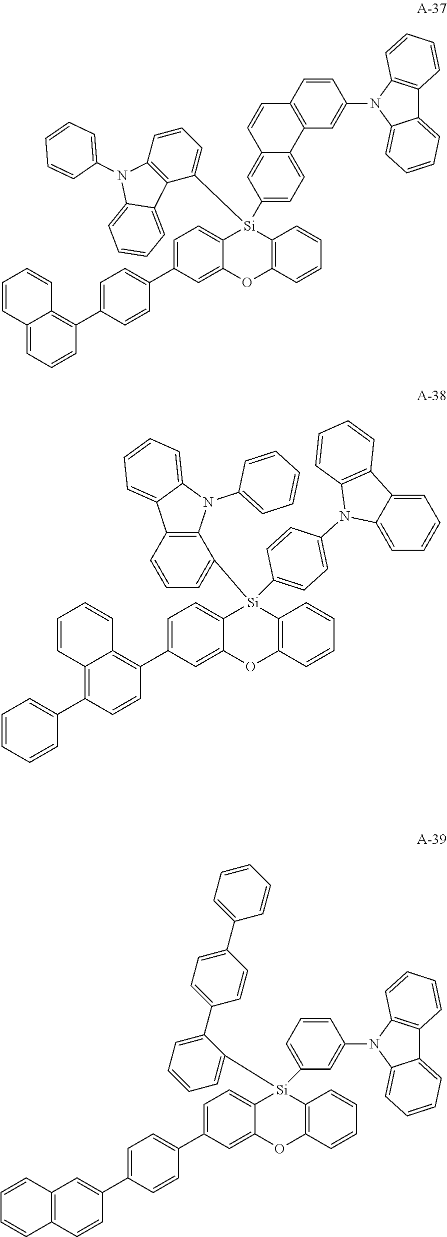 [SMILES: c1ccc(-n2c3ccccc3c3c([Si]4(c5ccc6c(ccc7ccc(-n8c9ccccc9c9ccccc98)cc76)c5)c5ccccc5Oc5cc(-c6ccc(-c7cccc8ccccc78)cc6)ccc54)cccc32)cc1 ; c1ccc(-c2ccc(-c3ccc4c(c3)Oc3ccccc3[Si]4(c3ccc(-n4c5ccccc5c5ccccc54)cc3)c3cccc4c5ccccc5n(-c5ccccc5)c34)c3ccccc23)cc1 ; c1ccc(-c2ccc(-c3ccccc3[Si]3(c4cccc(-n5c6ccccc6c6ccccc65)c4)c4ccccc4Oc4cc(-c5ccc(-c6ccc7ccccc7c6)cc5)ccc43)cc2)cc1]

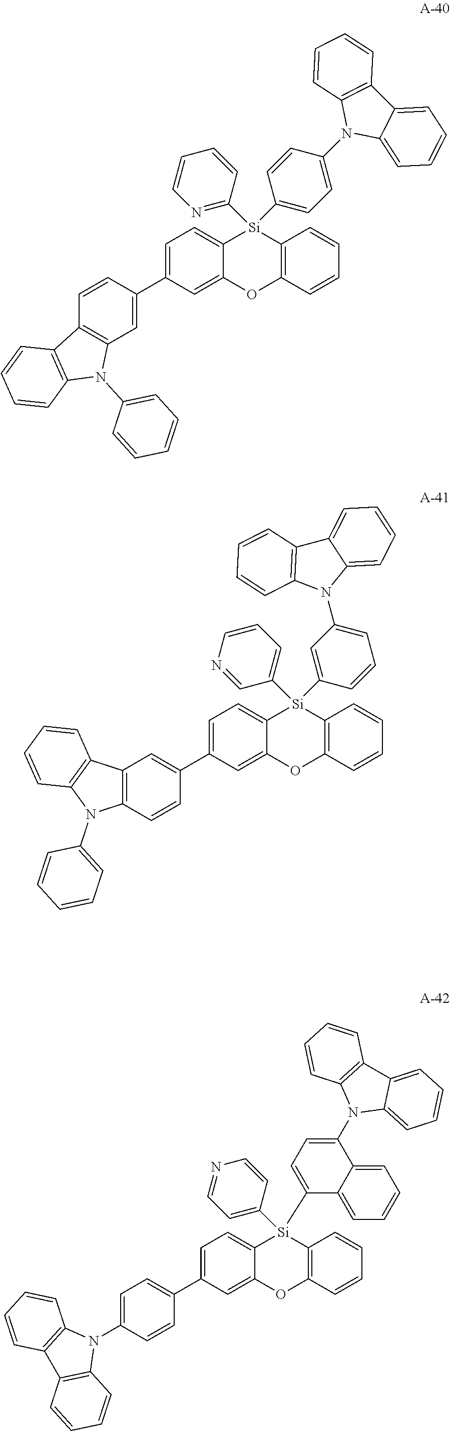 [SMILES: c1ccc(-n2c3ccccc3c3ccc(-c4ccc5c(c4)Oc4ccccc4[Si]5(c4ccc(-n5c6ccccc6c6ccccc65)cc4)c4ccccn4)cc32)cc1 ; c1ccc(-n2c3ccccc3c3cc(-c4ccc5c(c4)Oc4ccccc4[Si]5(c4cccnc4)c4cccc(-n5c6ccccc6c6ccccc65)c4)ccc32)cc1 ; c1ccc2c(c1)Oc1cc(-c3ccc(-n4c5ccccc5c5ccccc54)cc3)ccc1[Si]2(c1ccncc1)c1ccc(-n2c3ccccc3c3ccccc32)c2ccccc12]

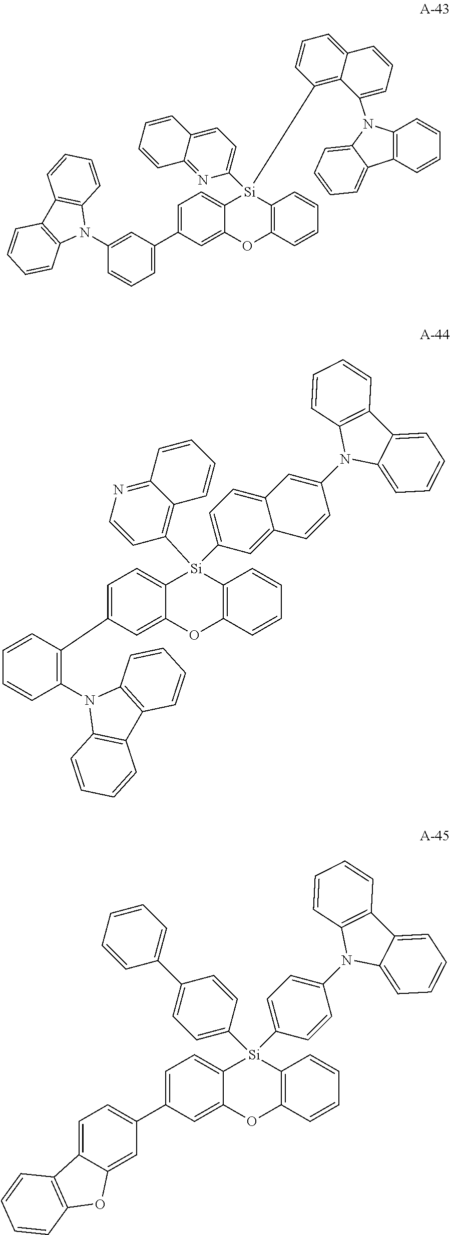 [SMILES: c1cc(-c2ccc3c(c2)Oc2ccccc2[Si]3(c2ccc3ccccc3n2)c2cccc3cccc(-n4c5ccccc5c5ccccc54)c23)cc(-n2c3ccccc3c3ccccc32)c1 ; c1ccc2c(c1)Oc1cc(-c3ccccc3-n3c4ccccc4c4ccccc43)ccc1[Si]2(c1ccc2cc(-n3c4ccccc4c4ccccc43)ccc2c1)c1ccnc2ccccc12 ; c1ccc(-c2ccc([Si]3(c4ccc(-n5c6ccccc6c6ccccc65)cc4)c4ccccc4Oc4cc(-c5ccc6c(c5)oc5ccccc56)ccc43)cc2)cc1]

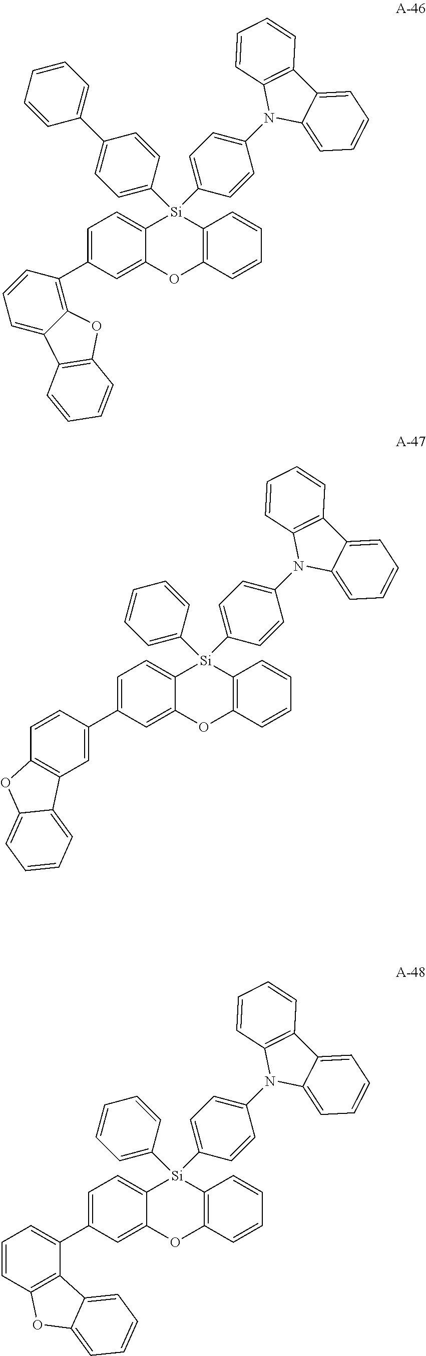 [SMILES: c1ccc(-c2ccc([Si]3(c4ccc(-n5c6ccccc6c6ccccc65)cc4)c4ccccc4Oc4cc(-c5cccc6c5oc5ccccc56)ccc43)cc2)cc1 ; c1ccc([Si]2(c3ccc(-n4c5ccccc5c5ccccc54)cc3)c3ccccc3Oc3cc(-c4ccc5oc6ccccc6c5c4)ccc32)cc1 ; c1ccc([Si]2(c3ccc(-n4c5ccccc5c5ccccc54)cc3)c3ccccc3Oc3cc(-c4cccc5oc6ccccc6c45)ccc32)cc1]

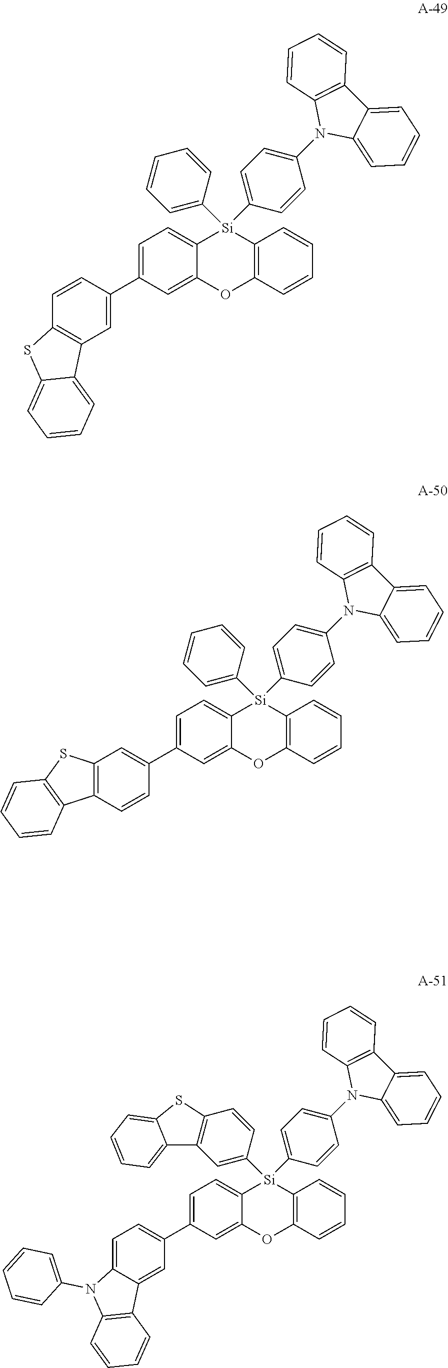 [SMILES: c1ccc([Si]2(c3ccc(-n4c5ccccc5c5ccccc54)cc3)c3ccccc3Oc3cc(-c4ccc5sc6ccccc6c5c4)ccc32)cc1 ; c1ccc([Si]2(c3ccc(-n4c5ccccc5c5ccccc54)cc3)c3ccccc3Oc3cc(-c4ccc5c(c4)sc4ccccc45)ccc32)cc1 ; c1ccc(-n2c3ccccc3c3cc(-c4ccc5c(c4)Oc4ccccc4[Si]5(c4ccc(-n5c6ccccc6c6ccccc65)cc4)c4ccc5sc6ccccc6c5c4)ccc32)cc1]

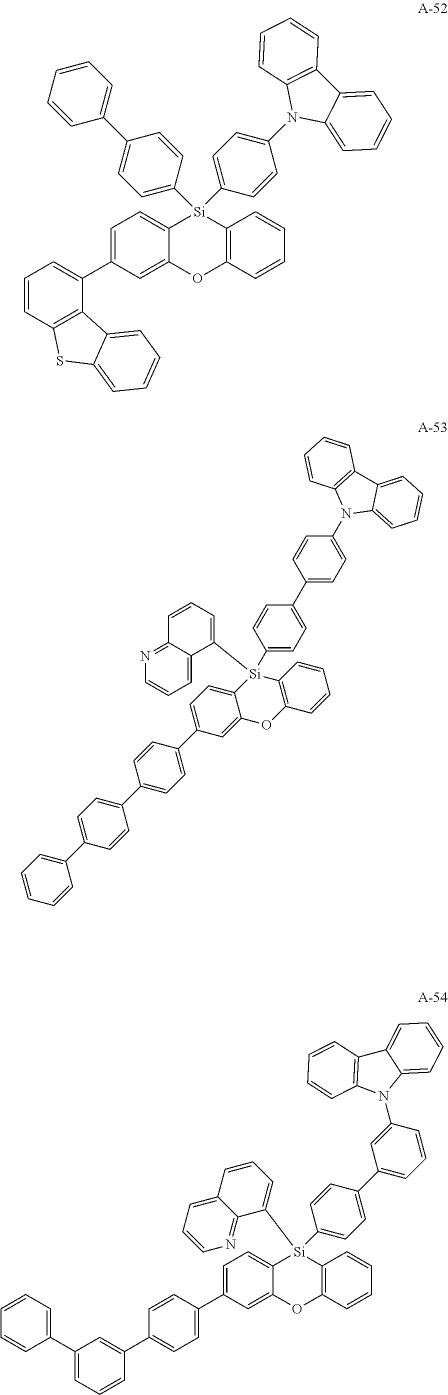 [SMILES: c1ccc(-c2ccc([Si]3(c4ccc(-n5c6ccccc6c6ccccc65)cc4)c4ccccc4Oc4cc(-c5cccc6sc7ccccc7c56)ccc43)cc2)cc1 ; c1ccc(-c2ccc(-c3ccc(-c4ccc5c(c4)Oc4ccccc4[Si]5(c4ccc(-c5ccc(-n6c7ccccc7c7ccccc76)cc5)cc4)c4cccc5ncccc45)cc3)cc2)cc1 ; c1ccc(-c2cccc(-c3ccc(-c4ccc5c(c4)Oc4ccccc4[Si]5(c4ccc(-c5cccc(-n6c7ccccc7c7ccccc76)c5)cc4)c4cccc5cccnc45)cc3)c2)cc1]

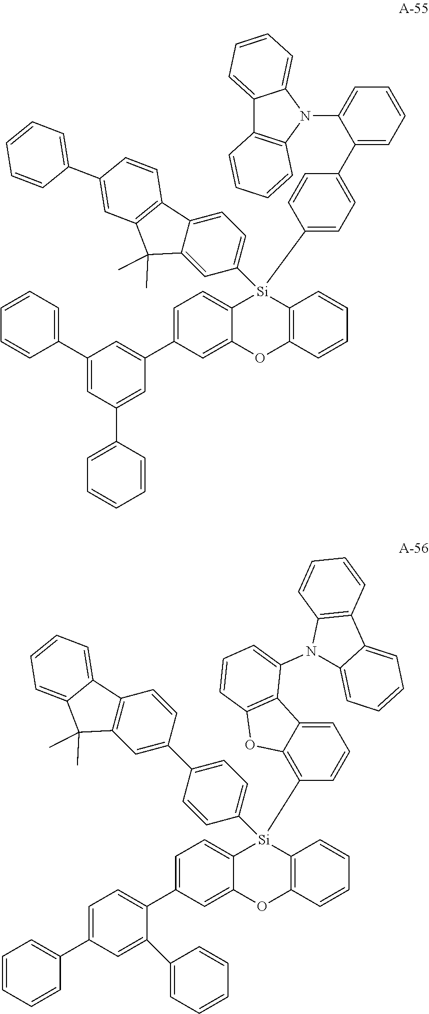 [SMILES: CC1(C)c2cc(-c3ccccc3)ccc2-c2ccc([Si]3(c4ccc(-c5ccccc5-n5c6ccccc6c6ccccc65)cc4)c4ccccc4Oc4cc(-c5cc(-c6ccccc6)cc(-c6ccccc6)c5)ccc43)cc21 ; CC1(C)c2ccccc2-c2ccc(-c3ccc([Si]4(c5cccc6c5oc5cccc(-n7c8ccccc8c8ccccc87)c56)c5ccccc5Oc5cc(-c6ccc(-c7ccccc7)cc6-c6ccccc6)ccc54)cc3)cc21]

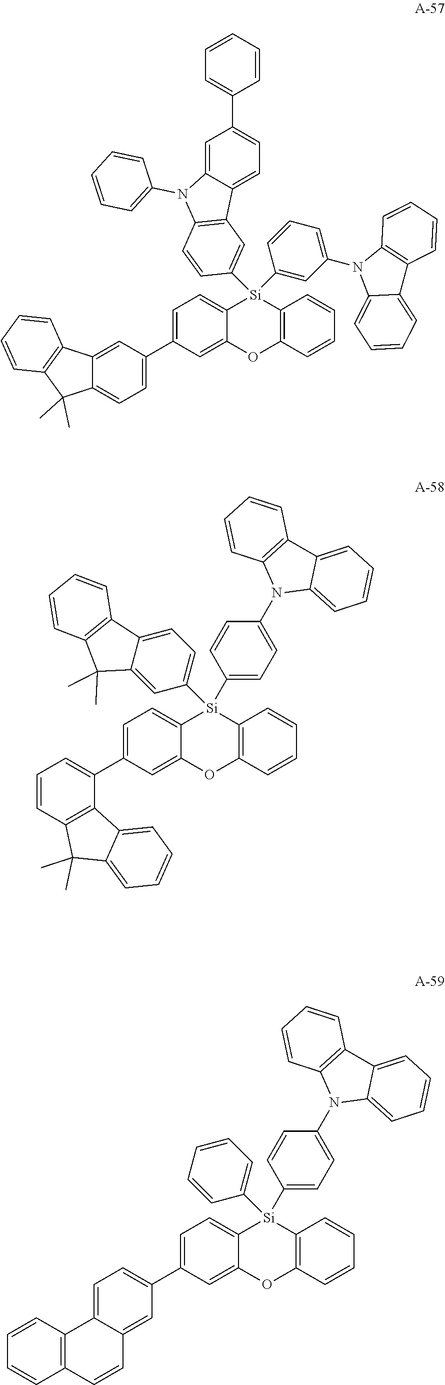 [SMILES: CC1(C)c2ccccc2-c2cc(-c3ccc4c(c3)Oc3ccccc3[Si]4(c3cccc(-n4c5ccccc5c5ccccc54)c3)c3ccc4c(c3)c3ccc(-c5ccccc5)cc3n4-c3ccccc3)ccc21 ; CC1(C)c2ccccc2-c2ccc([Si]3(c4ccc(-n5c6ccccc6c6ccccc65)cc4)c4ccccc4Oc4cc(-c5cccc6c5-c5ccccc5C6(C)C)ccc43)cc21 ; c1ccc([Si]2(c3ccc(-n4c5ccccc5c5ccccc54)cc3)c3ccccc3Oc3cc(-c4ccc5c(ccc6ccccc65)c4)ccc32)cc1]

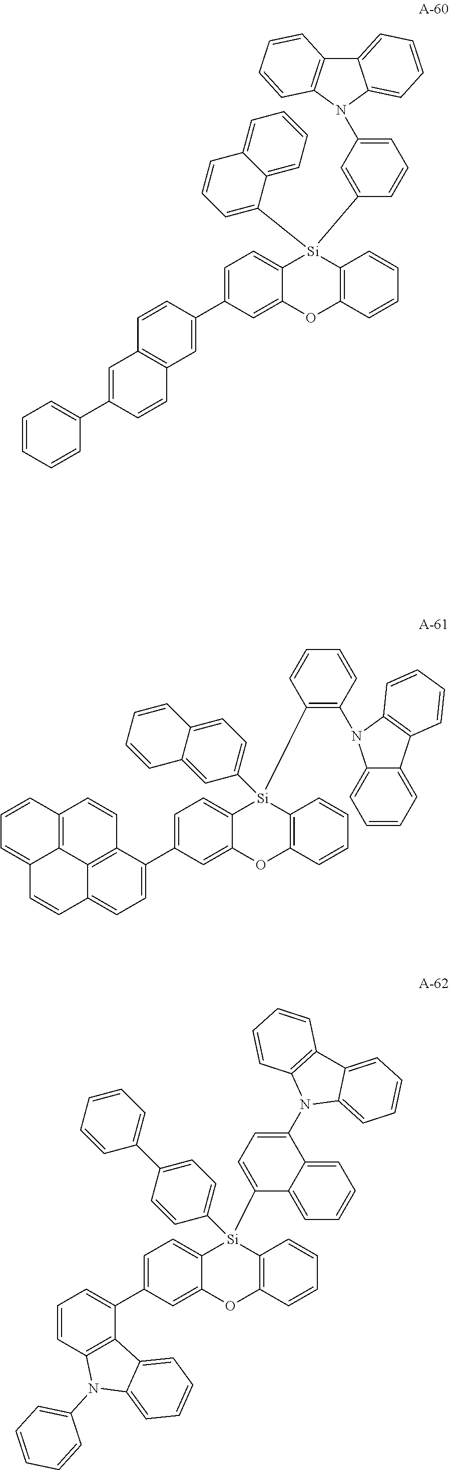 [SMILES: c1ccc(-c2ccc3cc(-c4ccc5c(c4)Oc4ccccc4[Si]5(c4cccc(-n5c6ccccc6c6ccccc65)c4)c4cccc5ccccc45)ccc3c2)cc1 ; c1ccc2c(c1)Oc1cc(-c3ccc4ccc5cccc6ccc3c4c56)ccc1[Si]2(c1ccc2ccccc2c1)c1ccccc1-n1c2ccccc2c2ccccc21 ; c1ccc(-c2ccc([Si]3(c4ccc(-n5c6ccccc6c6ccccc65)c5ccccc45)c4ccccc4Oc4cc(-c5cccc6c5c5ccccc5n6-c5ccccc5)ccc43)cc2)cc1]

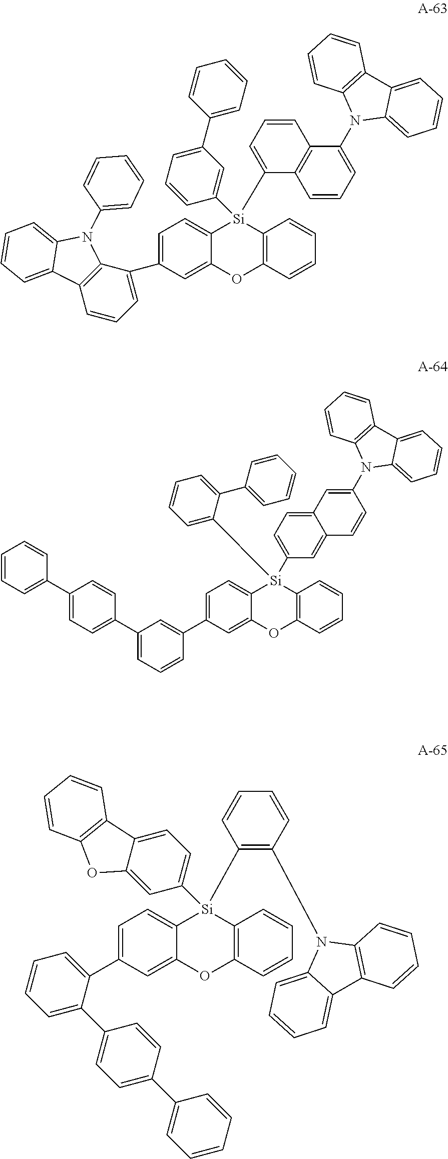

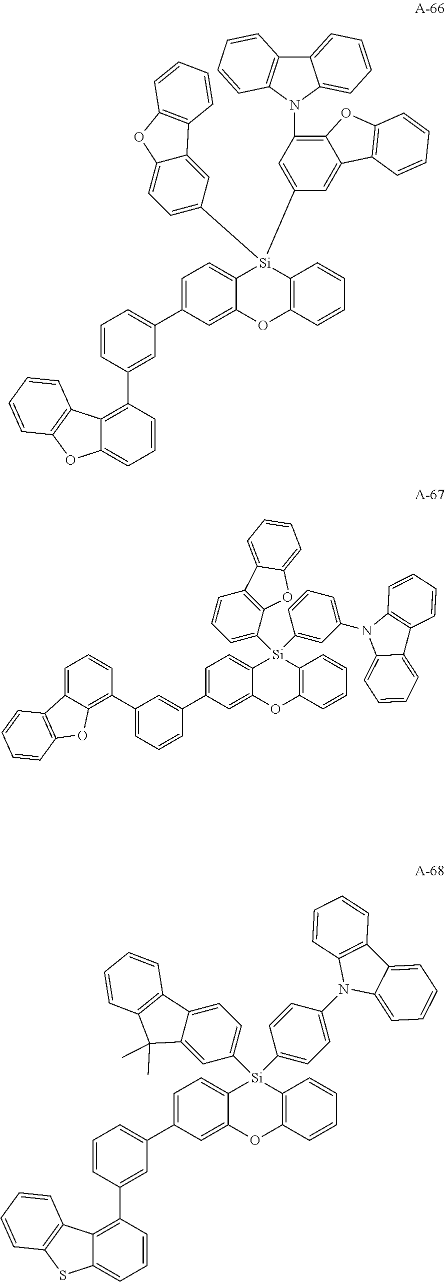 [SMILES: c1cc(-c2ccc3c(c2)Oc2ccccc2[Si]3(c2ccc3oc4ccccc4c3c2)c2cc(-n3c4ccccc4c4ccccc43)c3oc4ccccc4c3c2)cc(-c2cccc3oc4ccccc4c23)c1 ; c1cc(-c2ccc3c(c2)Oc2ccccc2[Si]3(c2cccc(-n3c4ccccc4c4ccccc43)c2)c2cccc3c2oc2ccccc23)cc(-c2cccc3c2oc2ccccc23)c1 ; CC1(C)c2ccccc2-c2ccc([Si]3(c4ccc(-n5c6ccccc6c6ccccc65)cc4)c4ccccc4Oc4cc(-c5cccc(-c6cccc7sc8ccccc8c67)c5)ccc43)cc21]

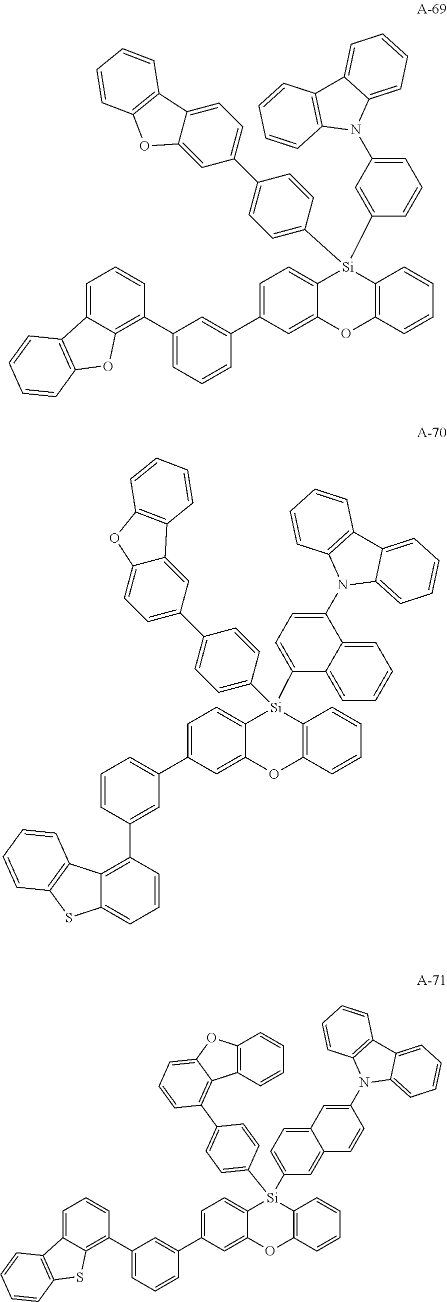 [SMILES: c1cc(-c2ccc3c(c2)Oc2ccccc2[Si]3(c2ccc(-c3ccc4c(c3)oc3ccccc34)cc2)c2cccc(-n3c4ccccc4c4ccccc43)c2)cc(-c2cccc3c2oc2ccccc23)c1 ; c1cc(-c2ccc3c(c2)Oc2ccccc2[Si]3(c2ccc(-c3ccc4oc5ccccc5c4c3)cc2)c2ccc(-n3c4ccccc4c4ccccc43)c3ccccc23)cc(-c2cccc3sc4ccccc4c23)c1 ; c1cc(-c2ccc3c(c2)Oc2ccccc2[Si]3(c2ccc(-c3cccc4oc5ccccc5c34)cc2)c2ccc3cc(-n4c5ccccc5c5ccccc54)ccc3c2)cc(-c2cccc3c2sc2ccccc23)c1]

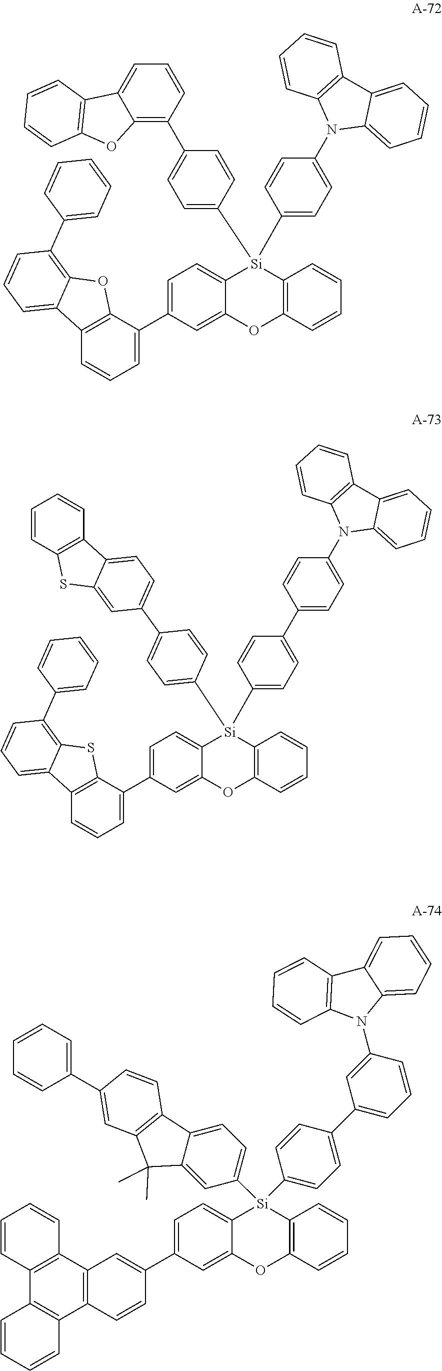 [SMILES: c1ccc(-c2cccc3c2oc2c(-c4ccc5c(c4)Oc4ccccc4[Si]5(c4ccc(-c5cccc6c5oc5ccccc56)cc4)c4ccc(-n5c6ccccc6c6ccccc65)cc4)cccc23)cc1 ; c1ccc(-c2cccc3c2sc2c(-c4ccc5c(c4)Oc4ccccc4[Si]5(c4ccc(-c5ccc(-n6c7ccccc7c7ccccc76)cc5)cc4)c4ccc(-c5ccc6c(c5)sc5ccccc56)cc4)cccc23)cc1 ; CC1(C)c2cc(-c3ccccc3)ccc2-c2ccc([Si]3(c4ccc(-c5cccc(-n6c7ccccc7c7ccccc76)c5)cc4)c4ccccc4Oc4cc(-c5ccc6c7ccccc7c7ccccc7c6c5)ccc43)cc21]

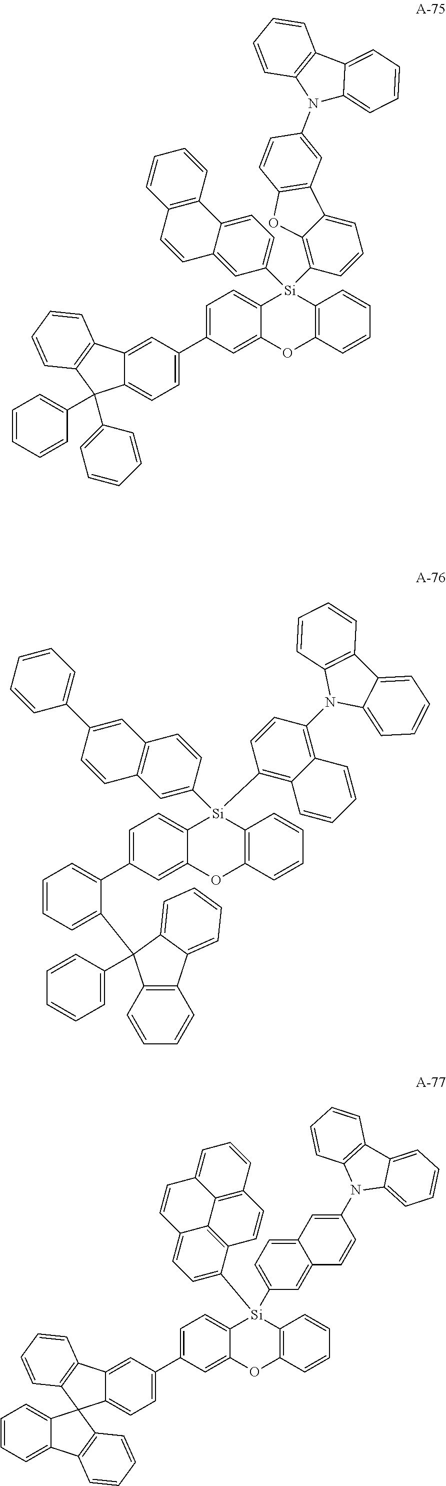 [SMILES: c1ccc(C2(c3ccccc3)c3ccccc3-c3cc(-c4ccc5c(c4)Oc4ccccc4[Si]5(c4ccc5c(ccc6ccccc65)c4)c4cccc5c4oc4ccc(-n6c7ccccc7c7ccccc76)cc45)ccc32)cc1 ; c1ccc(-c2ccc3cc([Si]4(c5ccc(-n6c7ccccc7c7ccccc76)c6ccccc56)c5ccccc5Oc5cc(-c6ccccc6C6(c7ccccc7)c7ccccc7-c7ccccc76)ccc54)ccc3c2)cc1 ; c1ccc2c(c1)Oc1cc(-c3ccc4c(c3)-c3ccccc3C43c4ccccc4-c4ccccc43)ccc1[Si]2(c1ccc2cc(-n3c4ccccc4c4ccccc43)ccc2c1)c1ccc2ccc3cccc4ccc1c2c34]

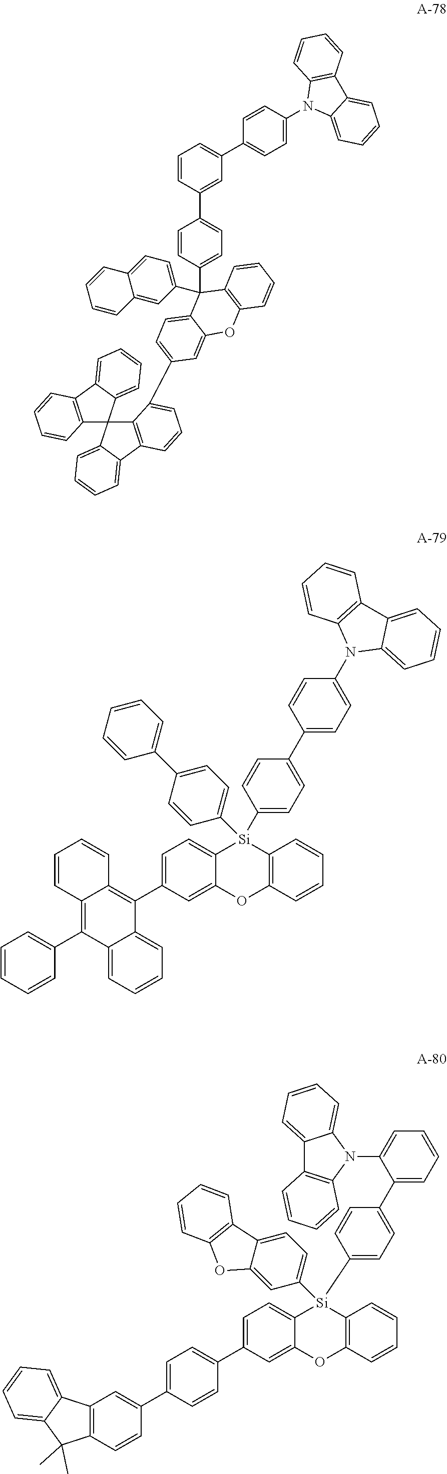 [SMILES: c1cc(-c2ccc(-n3c4ccccc4c4ccccc43)cc2)cc(-c2ccc(C3(c4ccc5ccccc5c4)c4ccccc4Oc4cc(-c5cccc6c5C5(c7ccccc7-c7ccccc75)c5ccccc5-6)ccc43)cc2)c1 ; c1ccc(-c2ccc([Si]3(c4ccc(-c5ccc(-n6c7ccccc7c7ccccc76)cc5)cc4)c4ccccc4Oc4cc(-c5c6ccccc6c(-c6ccccc6)c6ccccc56)ccc43)cc2)cc1 ; CC1(C)c2ccccc2-c2cc(-c3ccc(-c4ccc5c(c4)Oc4ccccc4[Si]5(c4ccc(-c5ccccc5-n5c6ccccc6c6ccccc65)cc4)c4ccc5c(c4)oc4ccccc45)cc3)ccc21]

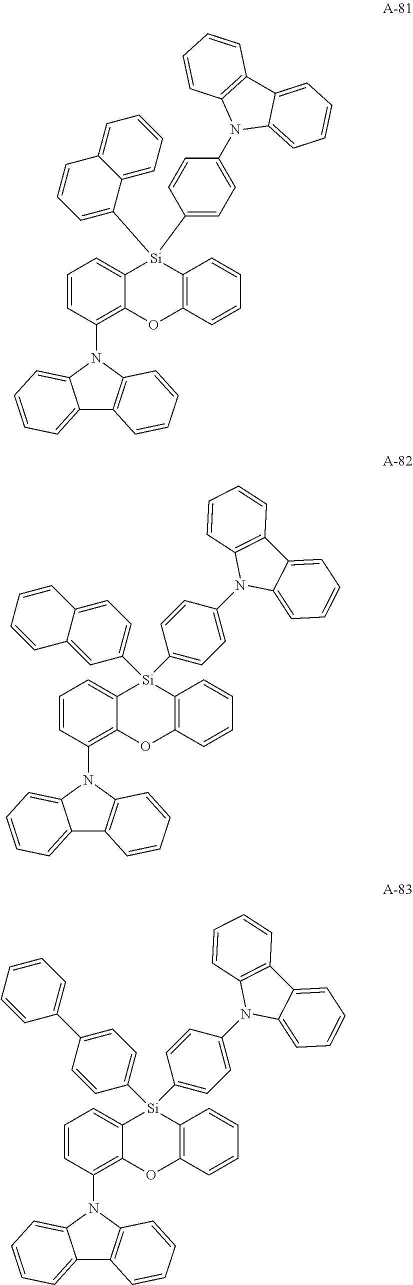 [SMILES: c1ccc2c(c1)Oc1c(-n3c4ccccc4c4ccccc43)cccc1[Si]2(c1ccc(-n2c3ccccc3c3ccccc32)cc1)c1cccc2ccccc12 ; c1ccc2c(c1)Oc1c(-n3c4ccccc4c4ccccc43)cccc1[Si]2(c1ccc(-n2c3ccccc3c3ccccc32)cc1)c1ccc2ccccc2c1 ; c1ccc(-c2ccc([Si]3(c4ccc(-n5c6ccccc6c6ccccc65)cc4)c4ccccc4Oc4c(-n5c6ccccc6c6ccccc65)cccc43)cc2)cc1]

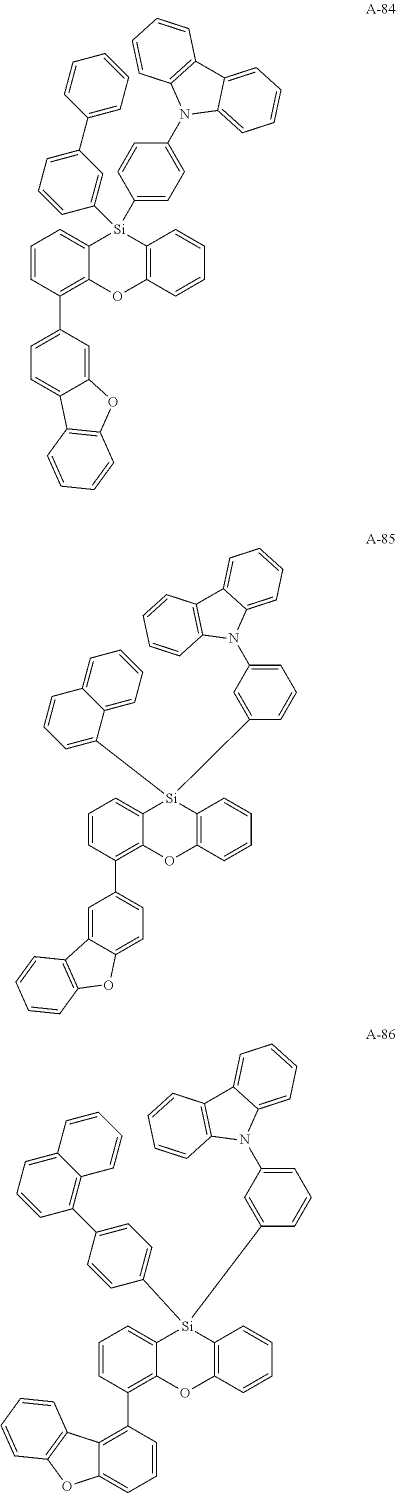 [SMILES: c1ccc(-c2cccc([Si]3(c4ccc(-n5c6ccccc6c6ccccc65)cc4)c4ccccc4Oc4c(-c5ccc6c(c5)oc5ccccc56)cccc43)c2)cc1 ; c1cc(-n2c3ccccc3c3ccccc32)cc([Si]2(c3cccc4ccccc34)c3ccccc3Oc3c(-c4ccc5oc6ccccc6c5c4)cccc32)c1 ; c1cc(-n2c3ccccc3c3ccccc32)cc([Si]2(c3ccc(-c4cccc5ccccc45)cc3)c3ccccc3Oc3c(-c4cccc5oc6ccccc6c45)cccc32)c1]

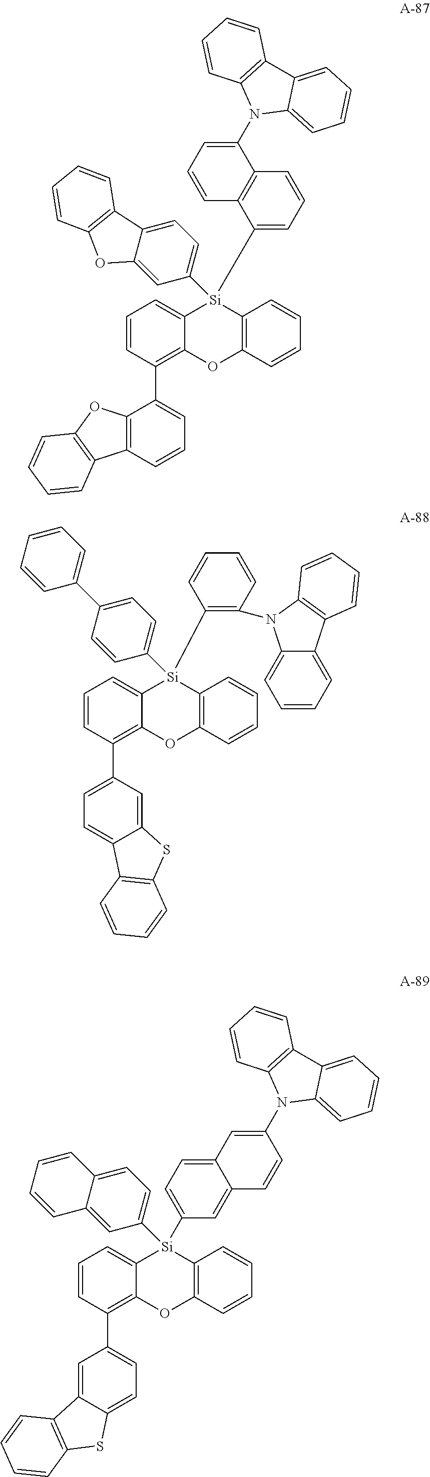

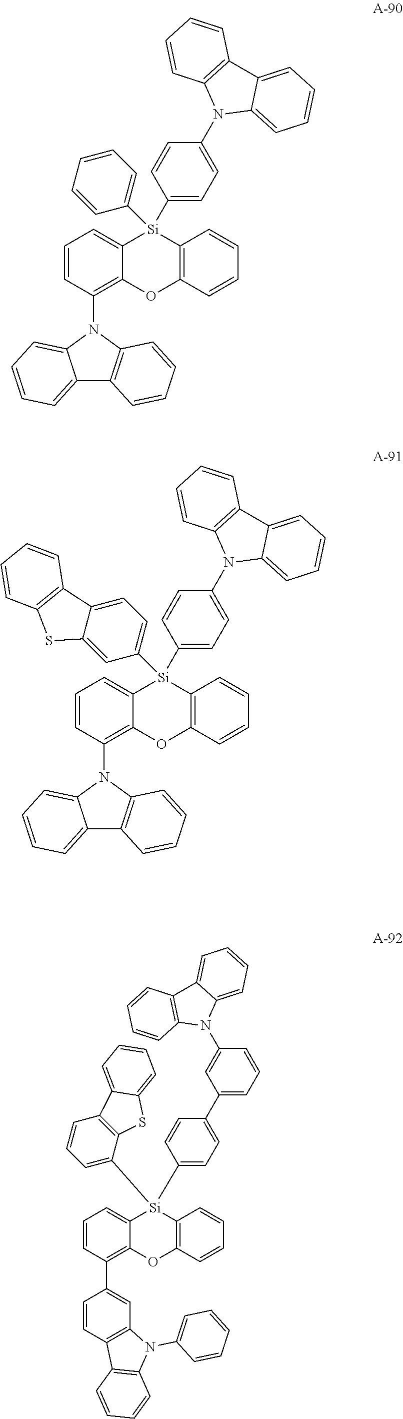 [SMILES: c1ccc([Si]2(c3ccc(-n4c5ccccc5c5ccccc54)cc3)c3ccccc3Oc3c(-n4c5ccccc5c5ccccc54)cccc32)cc1 ; c1ccc2c(c1)Oc1c(-n3c4ccccc4c4ccccc43)cccc1[Si]2(c1ccc(-n2c3ccccc3c3ccccc32)cc1)c1ccc2c(c1)sc1ccccc12 ; c1ccc(-n2c3ccccc3c3ccc(-c4cccc5c4Oc4ccccc4[Si]5(c4ccc(-c5cccc(-n6c7ccccc7c7ccccc76)c5)cc4)c4cccc5c4sc4ccccc45)cc32)cc1]

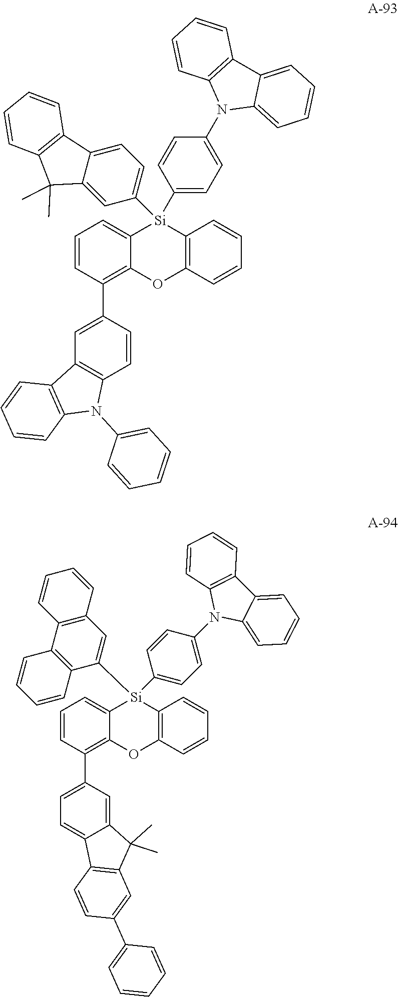 [SMILES: CC1(C)c2ccccc2-c2ccc([Si]3(c4ccc(-n5c6ccccc6c6ccccc65)cc4)c4ccccc4Oc4c(-c5ccc6c(c5)c5ccccc5n6-c5ccccc5)cccc43)cc21 ; CC1(C)c2cc(-c3ccccc3)ccc2-c2ccc(-c3cccc4c3Oc3ccccc3[Si]4(c3ccc(-n4c5ccccc5c5ccccc54)cc3)c3cc4ccccc4c4ccccc34)cc21]

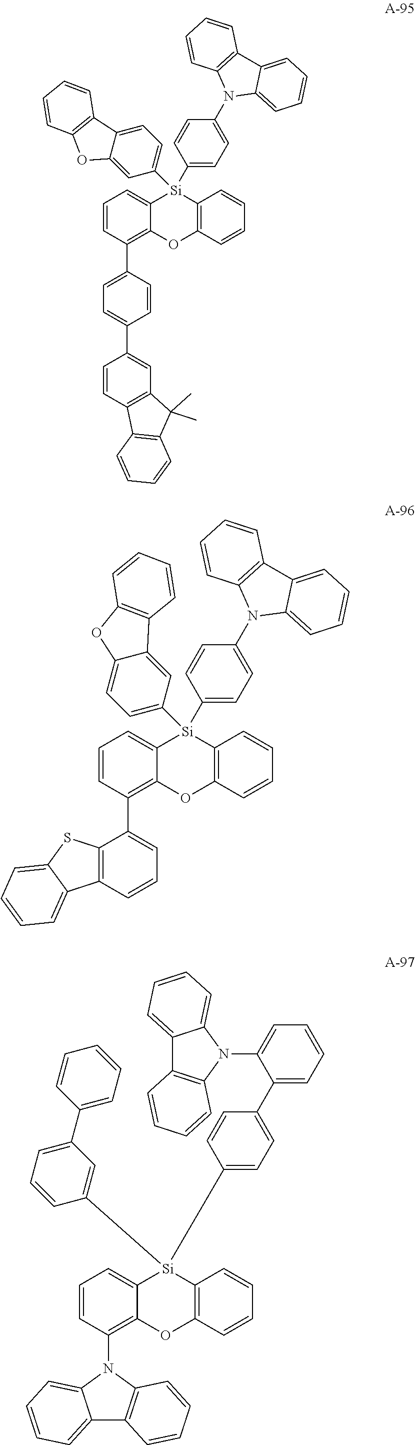 [SMILES: CC1(C)c2ccccc2-c2ccc(-c3ccc(-c4cccc5c4Oc4ccccc4[Si]5(c4ccc(-n5c6ccccc6c6ccccc65)cc4)c4ccc5c(c4)oc4ccccc45)cc3)cc21 ; c1ccc2c(c1)Oc1c(-c3cccc4c3sc3ccccc34)cccc1[Si]2(c1ccc(-n2c3ccccc3c3ccccc32)cc1)c1ccc2oc3ccccc3c2c1 ; c1ccc(-c2cccc([Si]3(c4ccc(-c5ccccc5-n5c6ccccc6c6ccccc65)cc4)c4ccccc4Oc4c(-n5c6ccccc6c6ccccc65)cccc43)c2)cc1]

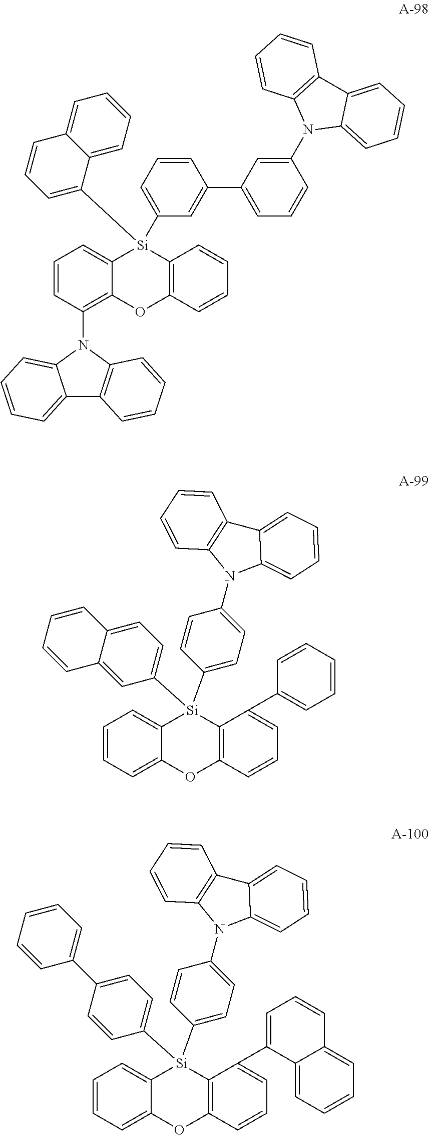 [SMILES: c1cc(-c2cccc([Si]3(c4cccc5ccccc45)c4ccccc4Oc4c(-n5c6ccccc6c6ccccc65)cccc43)c2)cc(-n2c3ccccc3c3ccccc32)c1 ; c1ccc(-c2cccc3c2[Si](c2ccc(-n4c5ccccc5c5ccccc54)cc2)(c2ccc4ccccc4c2)c2ccccc2O3)cc1 ; c1ccc(-c2ccc([Si]3(c4ccc(-n5c6ccccc6c6ccccc65)cc4)c4ccccc4Oc4cccc(-c5cccc6ccccc56)c43)cc2)cc1]

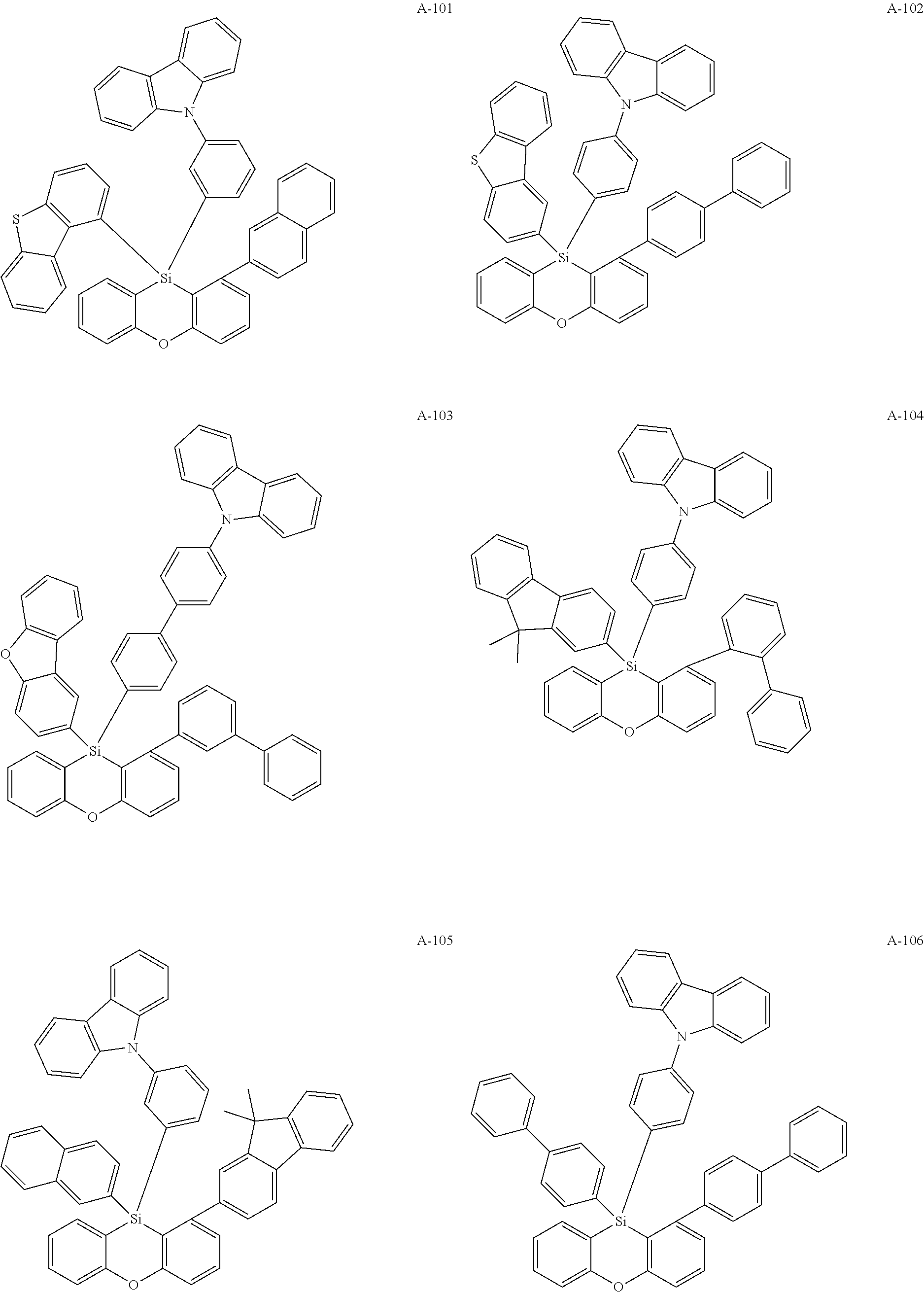

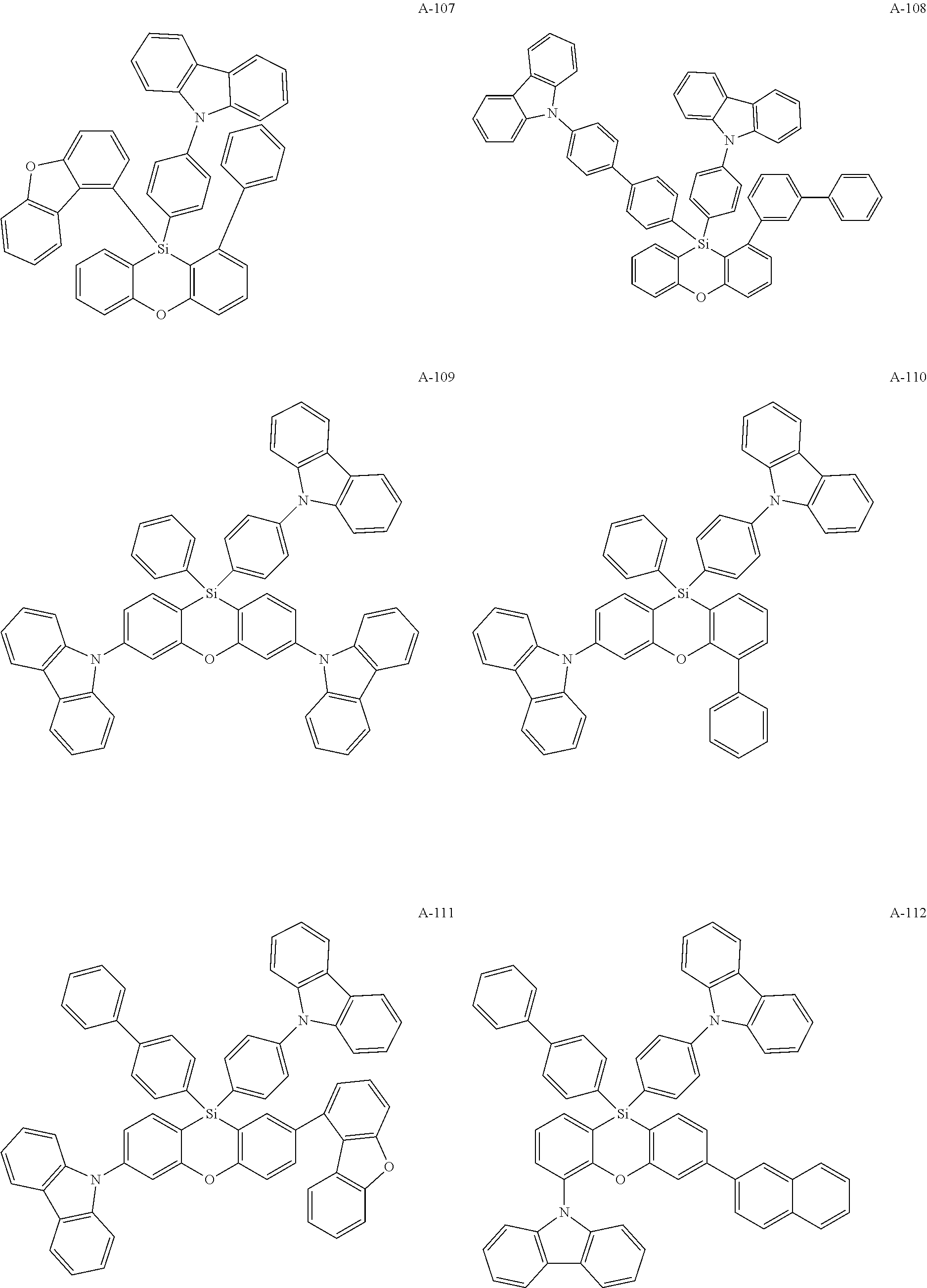

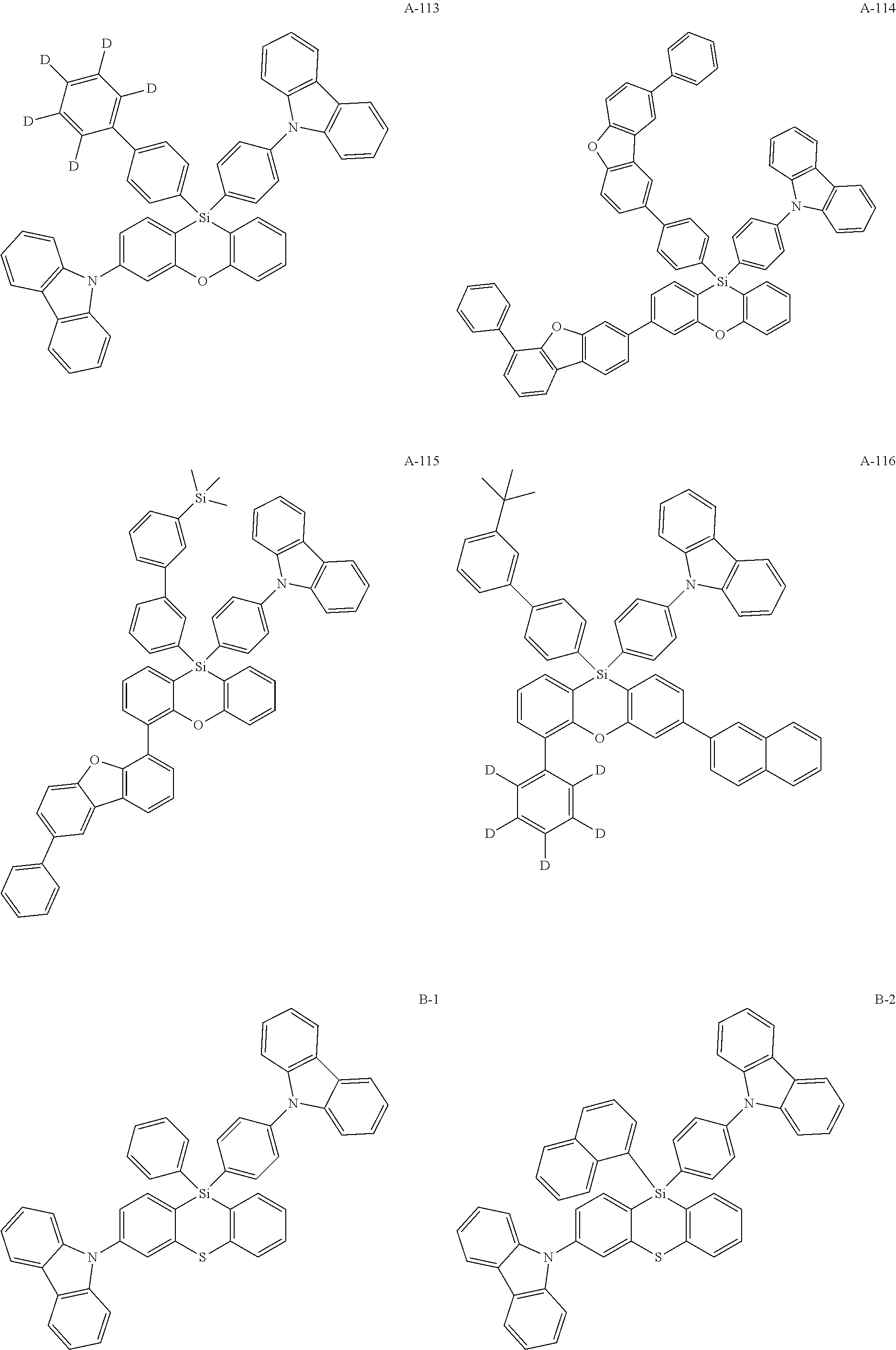

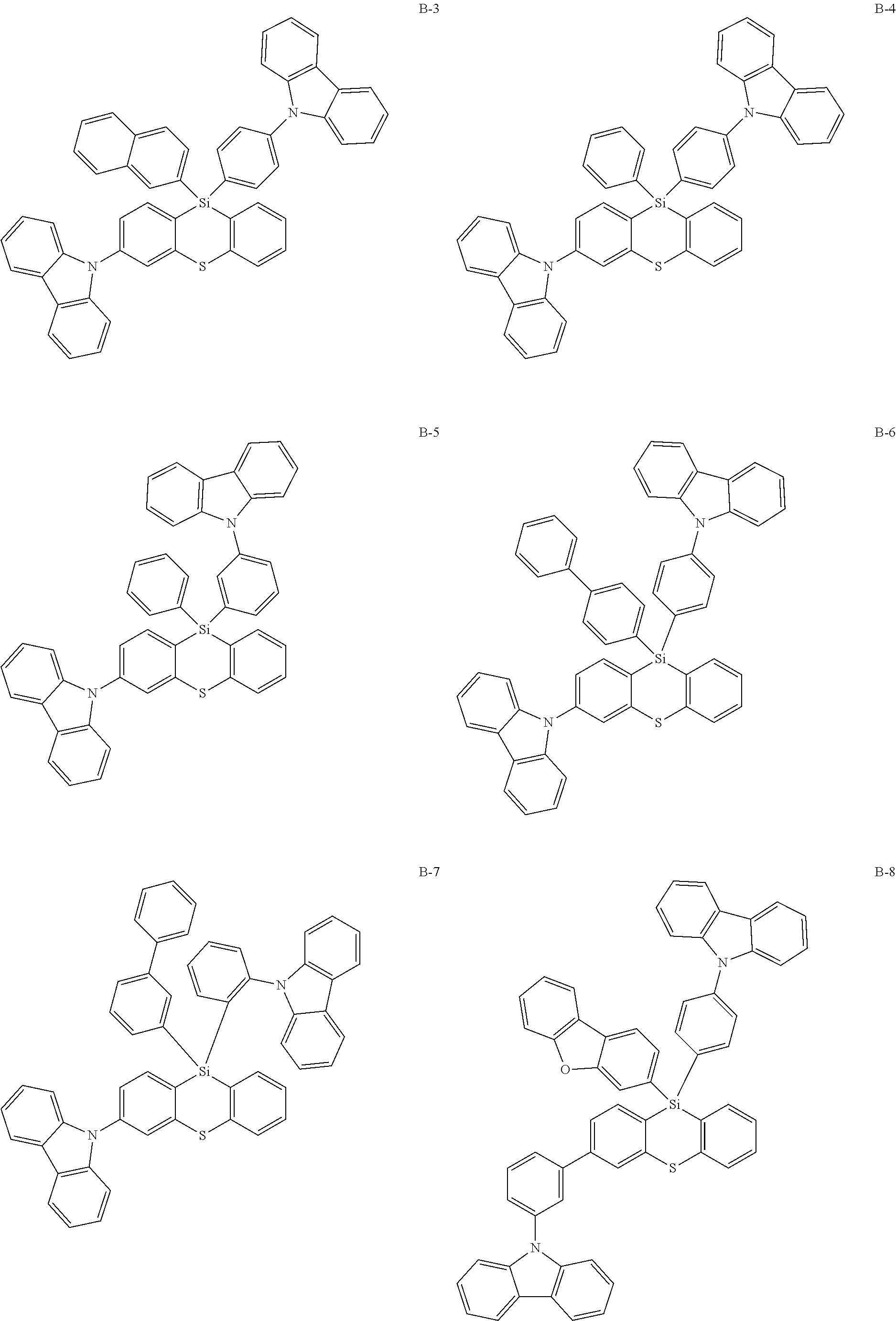

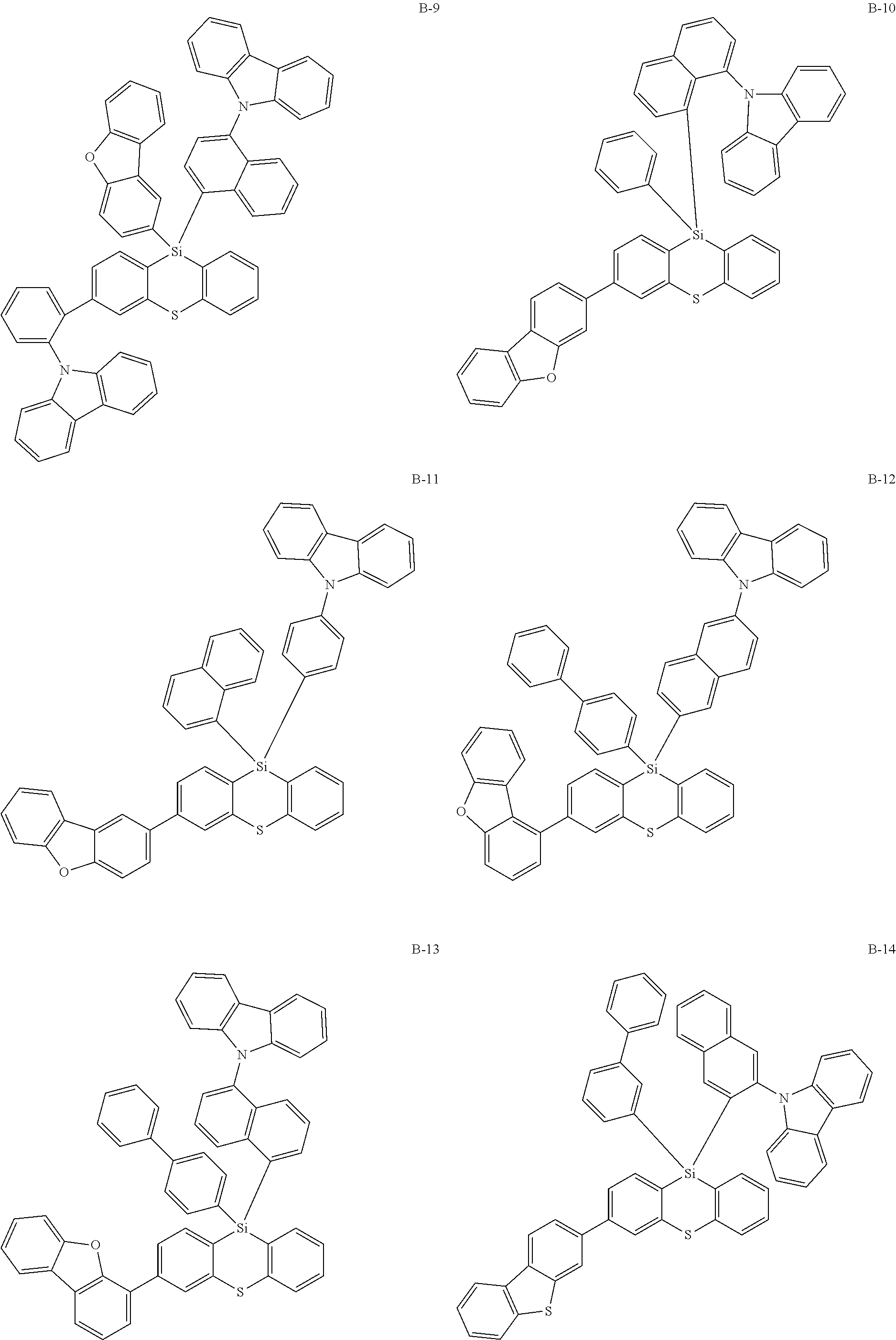

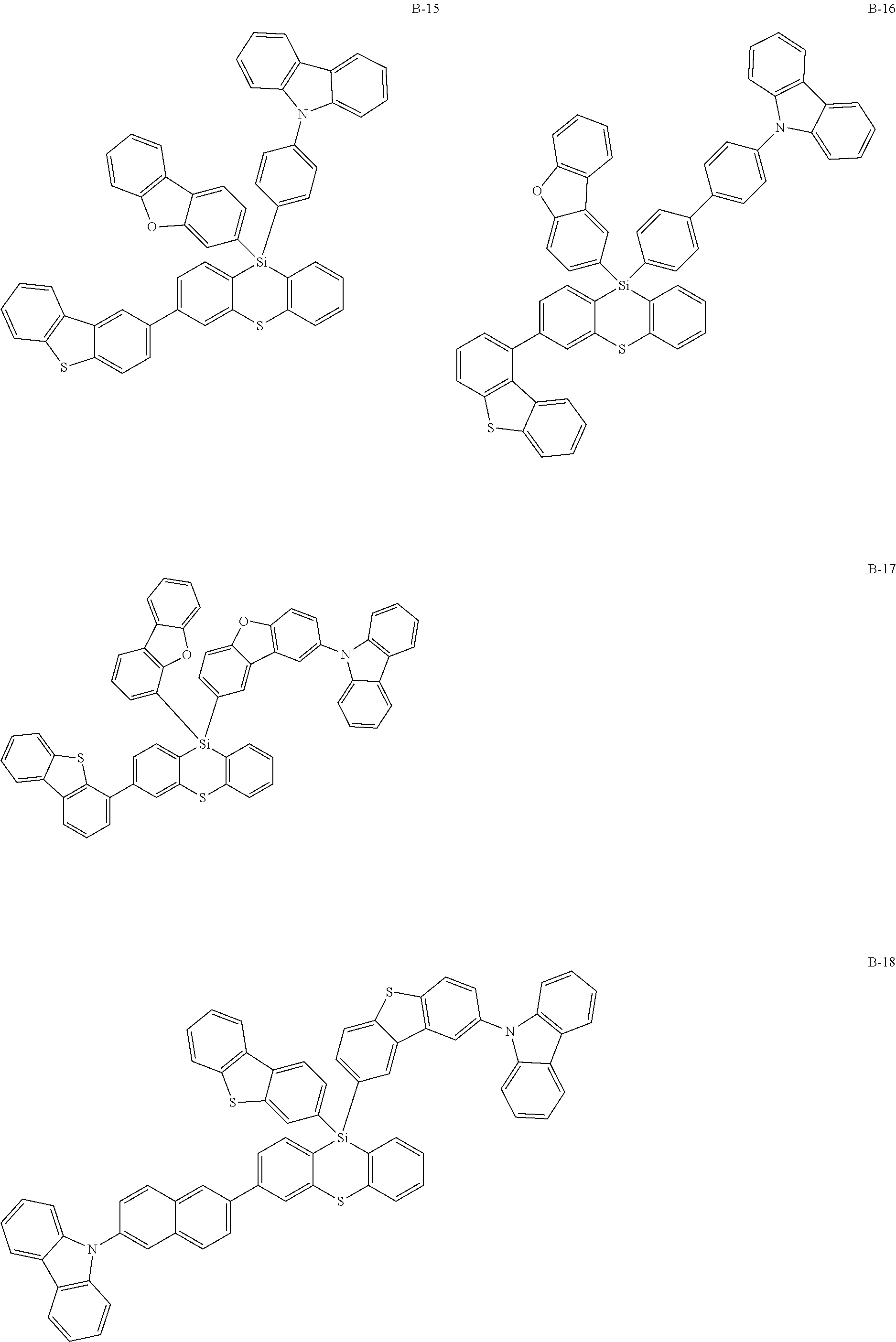 [SMILES: c1ccc2c(c1)Sc1cc(-c3ccc4sc5ccccc5c4c3)ccc1[Si]2(c1ccc(-n2c3ccccc3c3ccccc32)cc1)c1ccc2c(c1)oc1ccccc12 ; c1ccc2c(c1)Sc1cc(-c3cccc4sc5ccccc5c34)ccc1[Si]2(c1ccc(-c2ccc(-n3c4ccccc4c4ccccc43)cc2)cc1)c1ccc2oc3ccccc3c2c1 ; c1ccc2c(c1)Sc1cc(-c3cccc4c3sc3ccccc34)ccc1[Si]2(c1ccc2oc3ccc(-n4c5ccccc5c5ccccc54)cc3c2c1)c1cccc2c1oc1ccccc12 ; c1ccc2c(c1)Sc1cc(-c3ccc4cc(-n5c6ccccc6c6ccccc65)ccc4c3)ccc1[Si]2(c1ccc2c(c1)sc1ccccc12)c1ccc2sc3ccc(-n4c5ccccc5c5ccccc54)cc3c2c1]

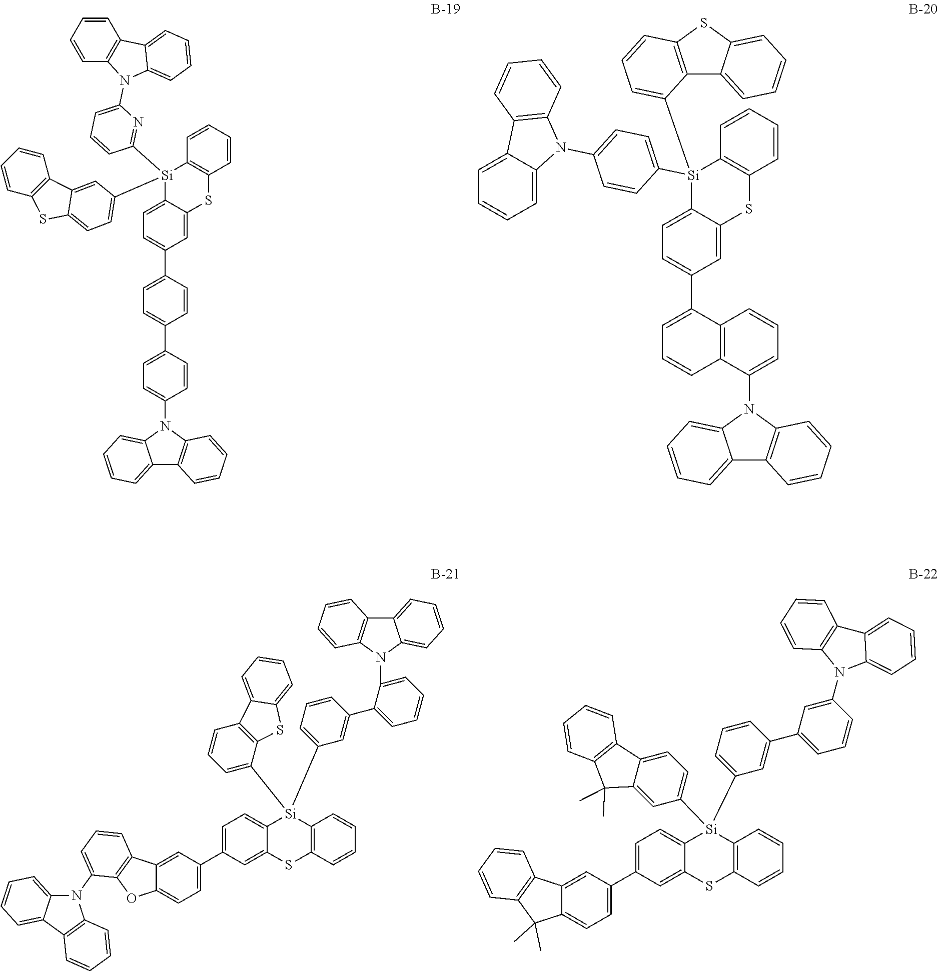 [SMILES: c1cc(-n2c3ccccc3c3ccccc32)nc([Si]2(c3ccc4sc5ccccc5c4c3)c3ccccc3Sc3cc(-c4ccc(-c5ccc(-n6c7ccccc7c7ccccc76)cc5)cc4)ccc32)c1 ; c1ccc2c(c1)Sc1cc(-c3cccc4c(-n5c6ccccc6c6ccccc65)cccc34)ccc1[Si]2(c1ccc(-n2c3ccccc3c3ccccc32)cc1)c1cccc2sc3ccccc3c12 ; c1cc(-c2ccccc2-n2c3ccccc3c3ccccc32)cc([Si]2(c3cccc4c3sc3ccccc34)c3ccccc3Sc3cc(-c4ccc5oc6c(-n7c8ccccc8c8ccccc87)cccc6c5c4)ccc32)c1 ; CC1(C)c2ccccc2-c2cc(-c3ccc4c(c3)Sc3ccccc3[Si]4(c3cccc(-c4cccc(-n5c6ccccc6c6ccccc65)c4)c3)c3ccc4c(c3)C(C)(C)c3ccccc3-4)ccc21]

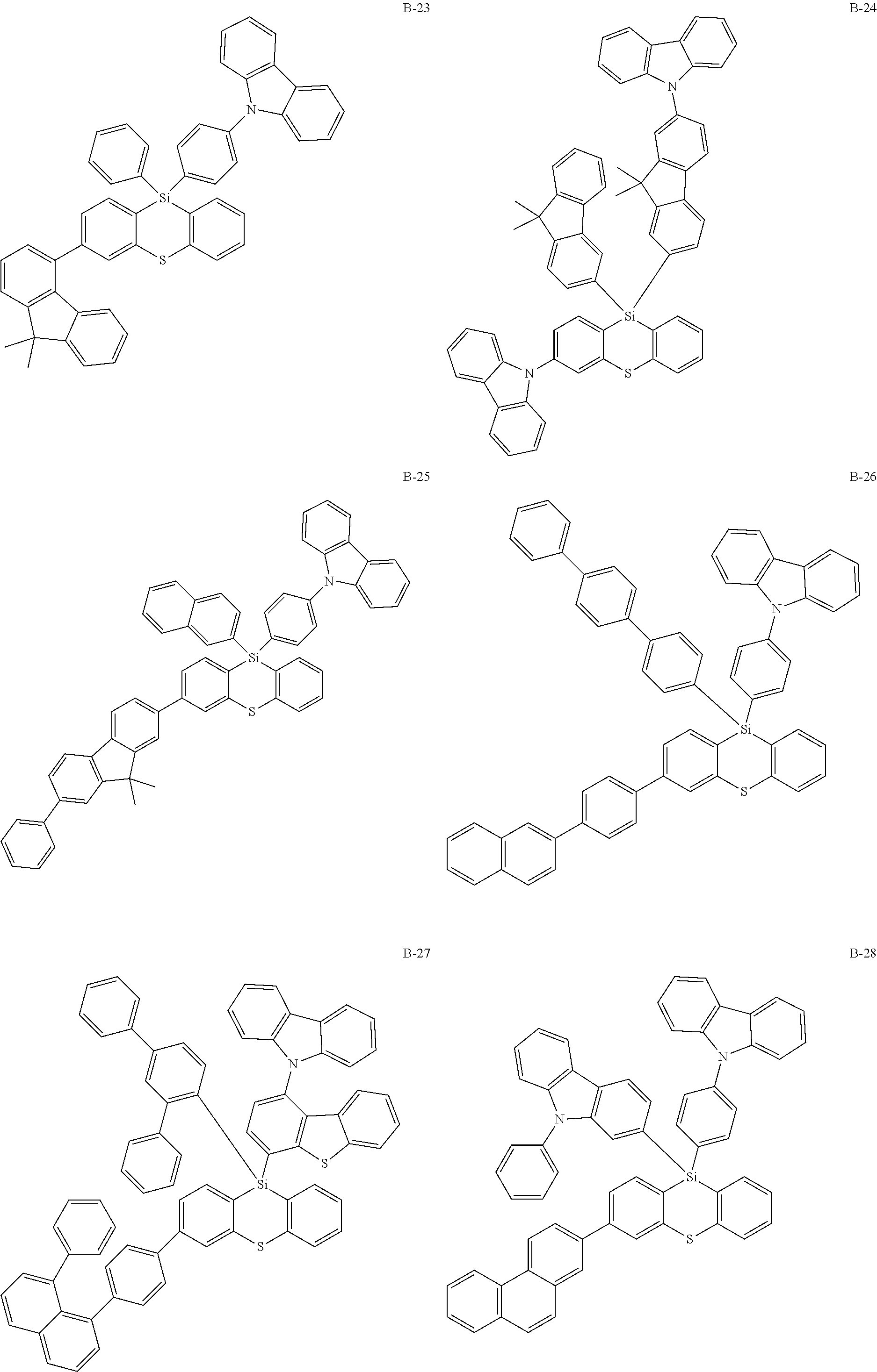

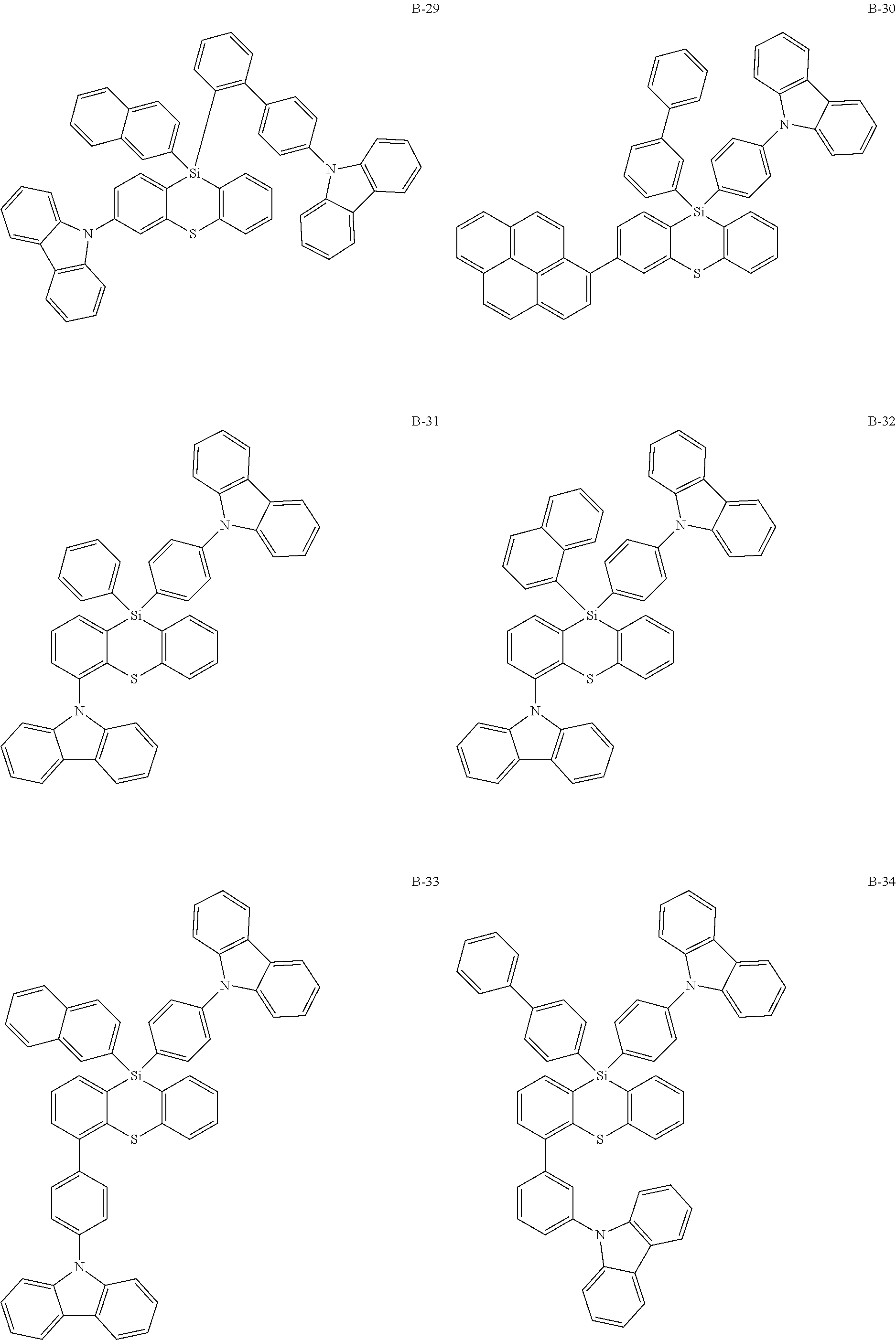

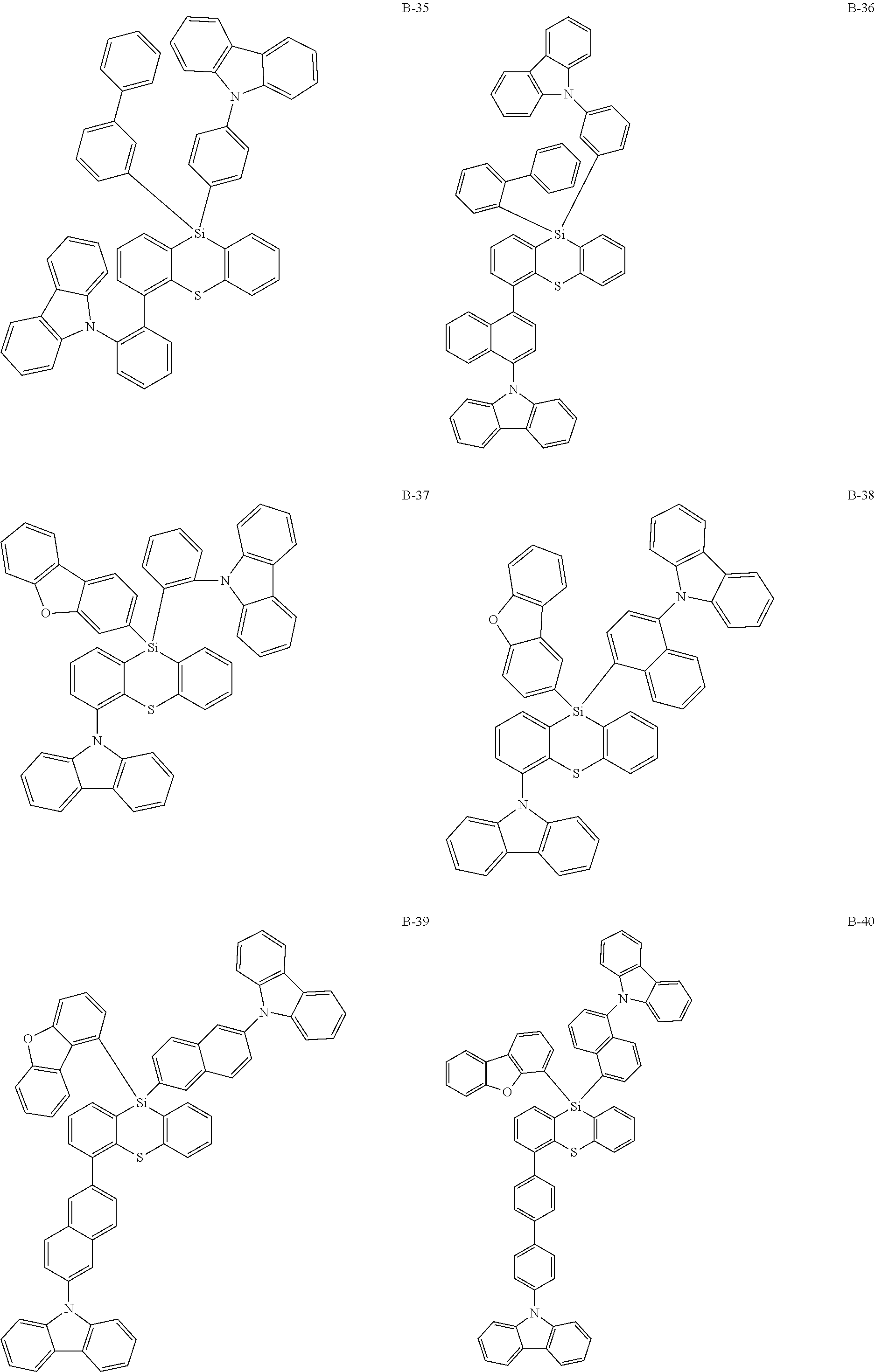

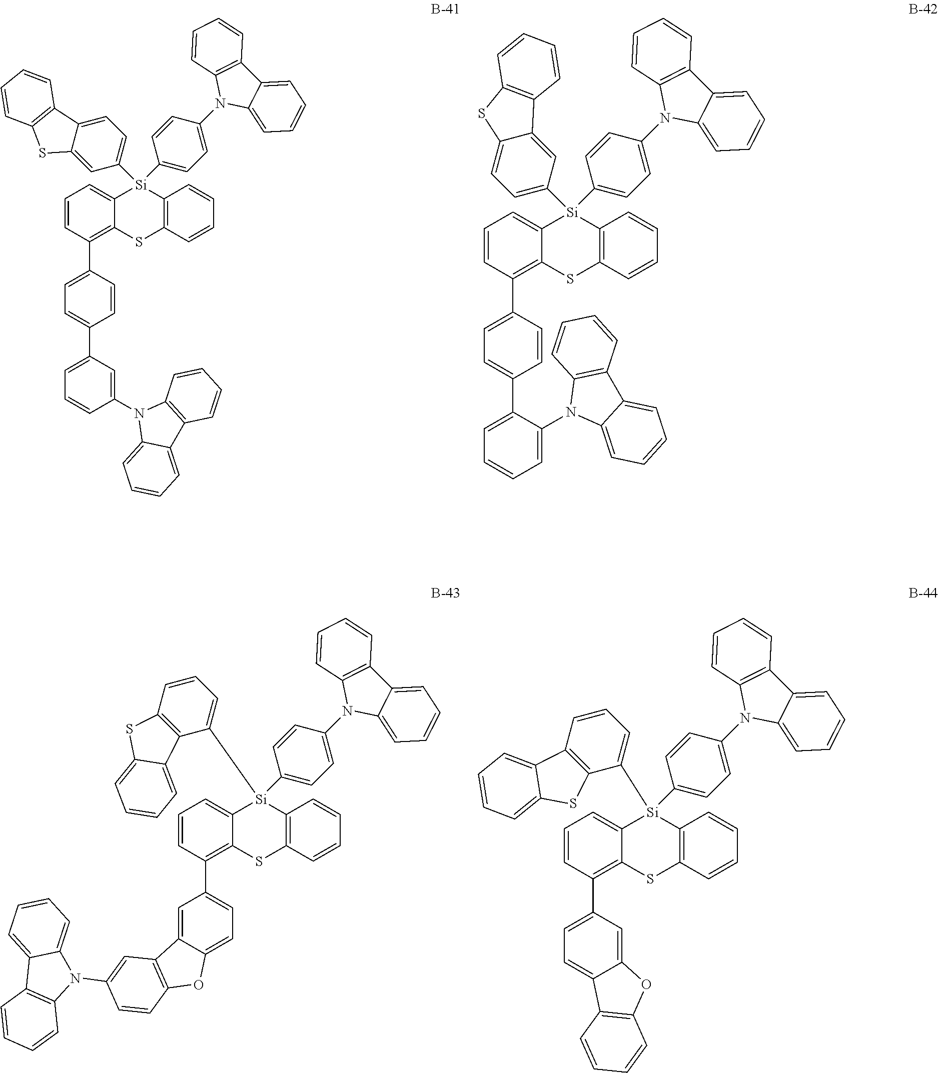 [SMILES: c1cc(-c2ccc(-c3cccc4c3Sc3ccccc3[Si]4(c3ccc(-n4c5ccccc5c5ccccc54)cc3)c3ccc4c(c3)sc3ccccc34)cc2)cc(-n2c3ccccc3c3ccccc32)c1 ; c1ccc2c(c1)Sc1c(-c3ccc(-c4ccccc4-n4c5ccccc5c5ccccc54)cc3)cccc1[Si]2(c1ccc(-n2c3ccccc3c3ccccc32)cc1)c1ccc2sc3ccccc3c2c1 ; c1ccc2c(c1)Sc1c(-c3ccc4oc5ccc(-n6c7ccccc7c7ccccc76)cc5c4c3)cccc1[Si]2(c1ccc(-n2c3ccccc3c3ccccc32)cc1)c1cccc2sc3ccccc3c12 ; c1ccc2c(c1)Sc1c(-c3ccc4c(c3)oc3ccccc34)cccc1[Si]2(c1ccc(-n2c3ccccc3c3ccccc32)cc1)c1cccc2c1sc1ccccc12]

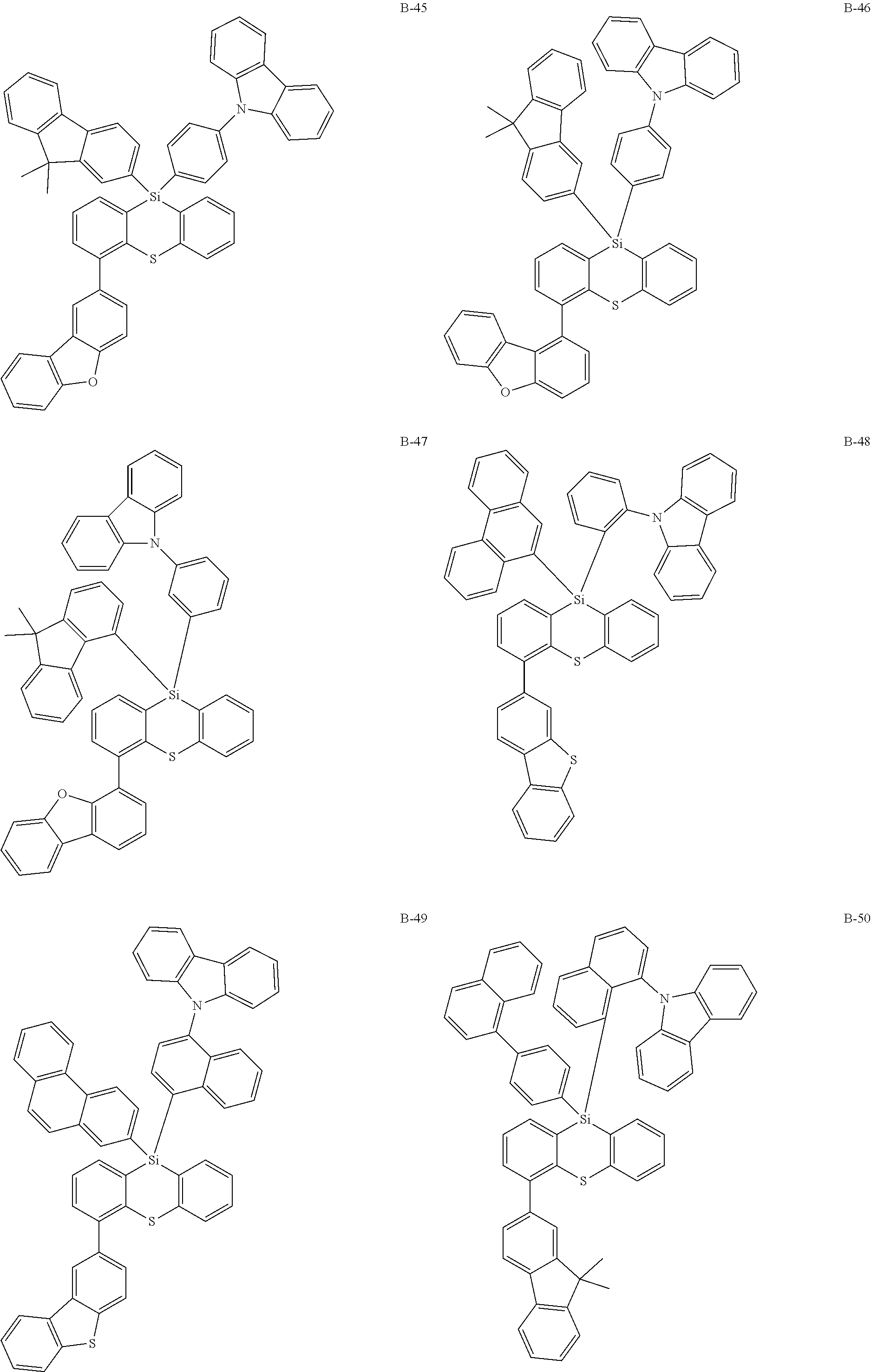

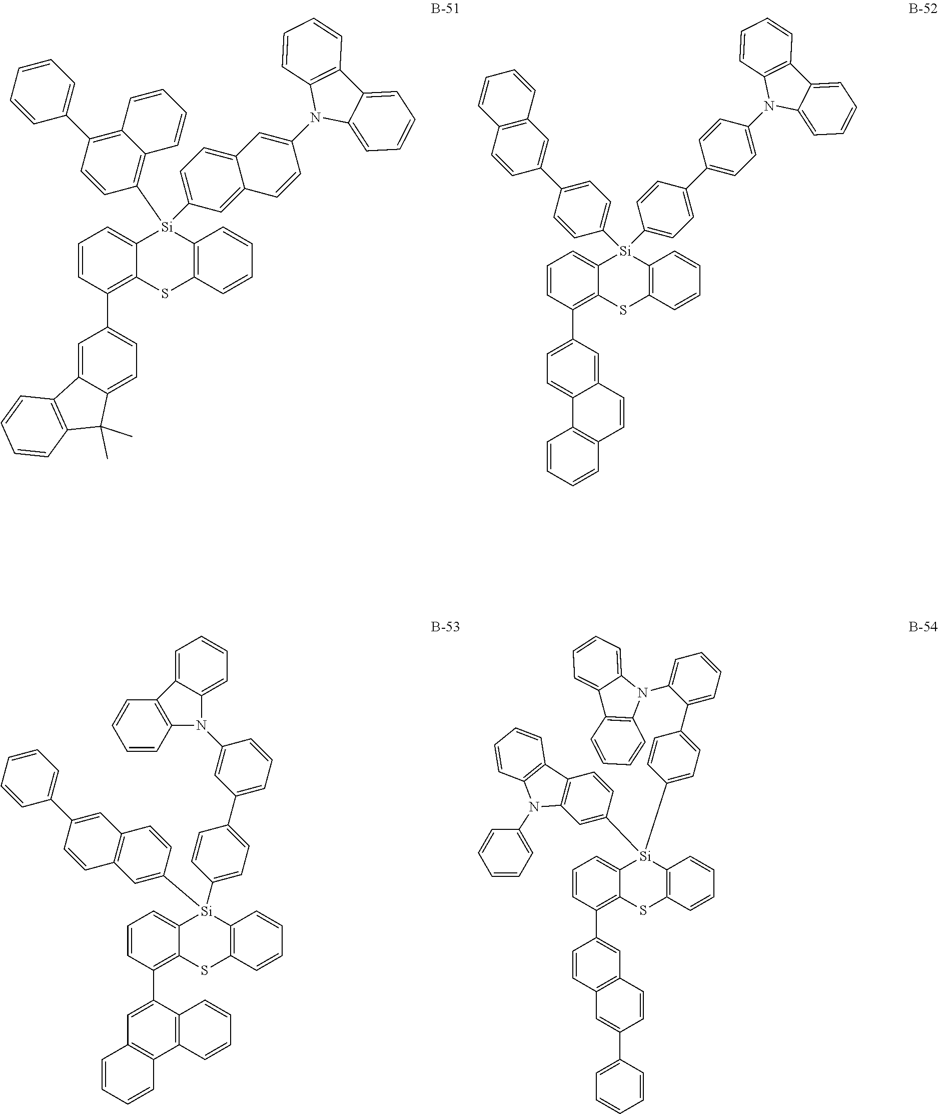 [SMILES: CC1(C)c2ccccc2-c2cc(-c3cccc4c3Sc3ccccc3[Si]4(c3ccc4cc(-n5c6ccccc6c6ccccc65)ccc4c3)c3ccc(-c4ccccc4)c4ccccc34)ccc21 ; c1ccc2c(c1)Sc1c(-c3ccc4c(ccc5ccccc54)c3)cccc1[Si]2(c1ccc(-c2ccc(-n3c4ccccc4c4ccccc43)cc2)cc1)c1ccc(-c2ccc3ccccc3c2)cc1 ; c1ccc(-c2ccc3cc([Si]4(c5ccc(-c6cccc(-n7c8ccccc8c8ccccc87)c6)cc5)c5ccccc5Sc5c(-c6cc7ccccc7c7ccccc67)cccc54)ccc3c2)cc1 ; c1ccc(-c2ccc3cc(-c4cccc5c4Sc4ccccc4[Si]5(c4ccc(-c5ccccc5-n5c6ccccc6c6ccccc65)cc4)c4ccc5c6ccccc6n(-c6ccccc6)c5c4)ccc3c2)cc1]

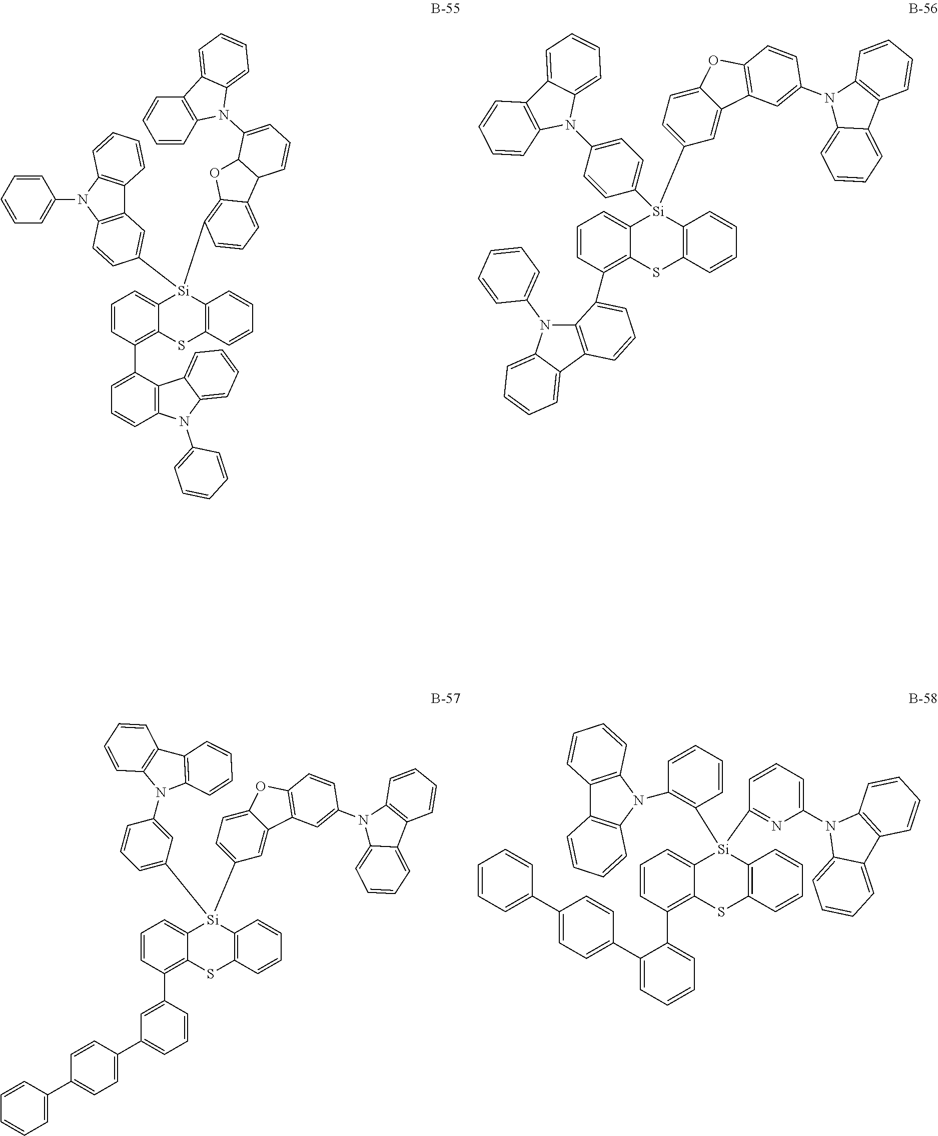

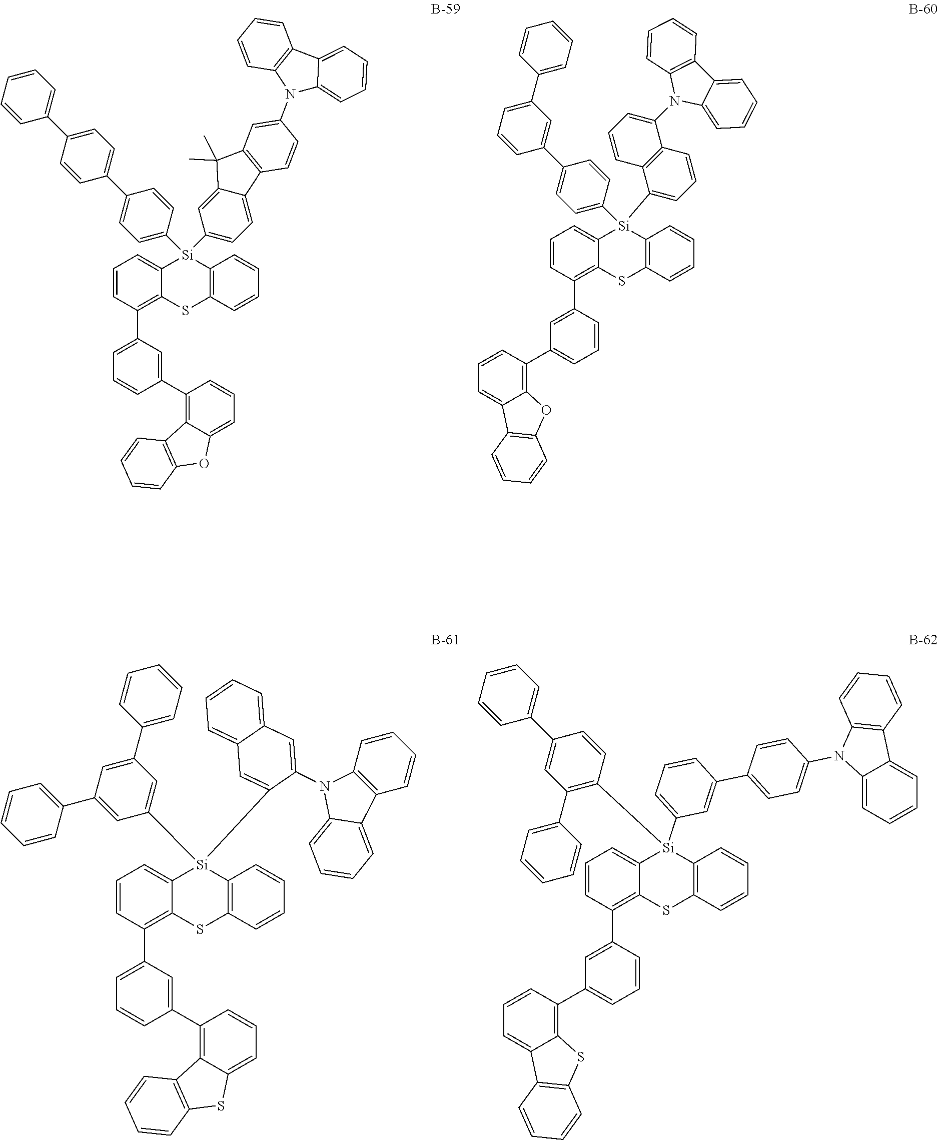

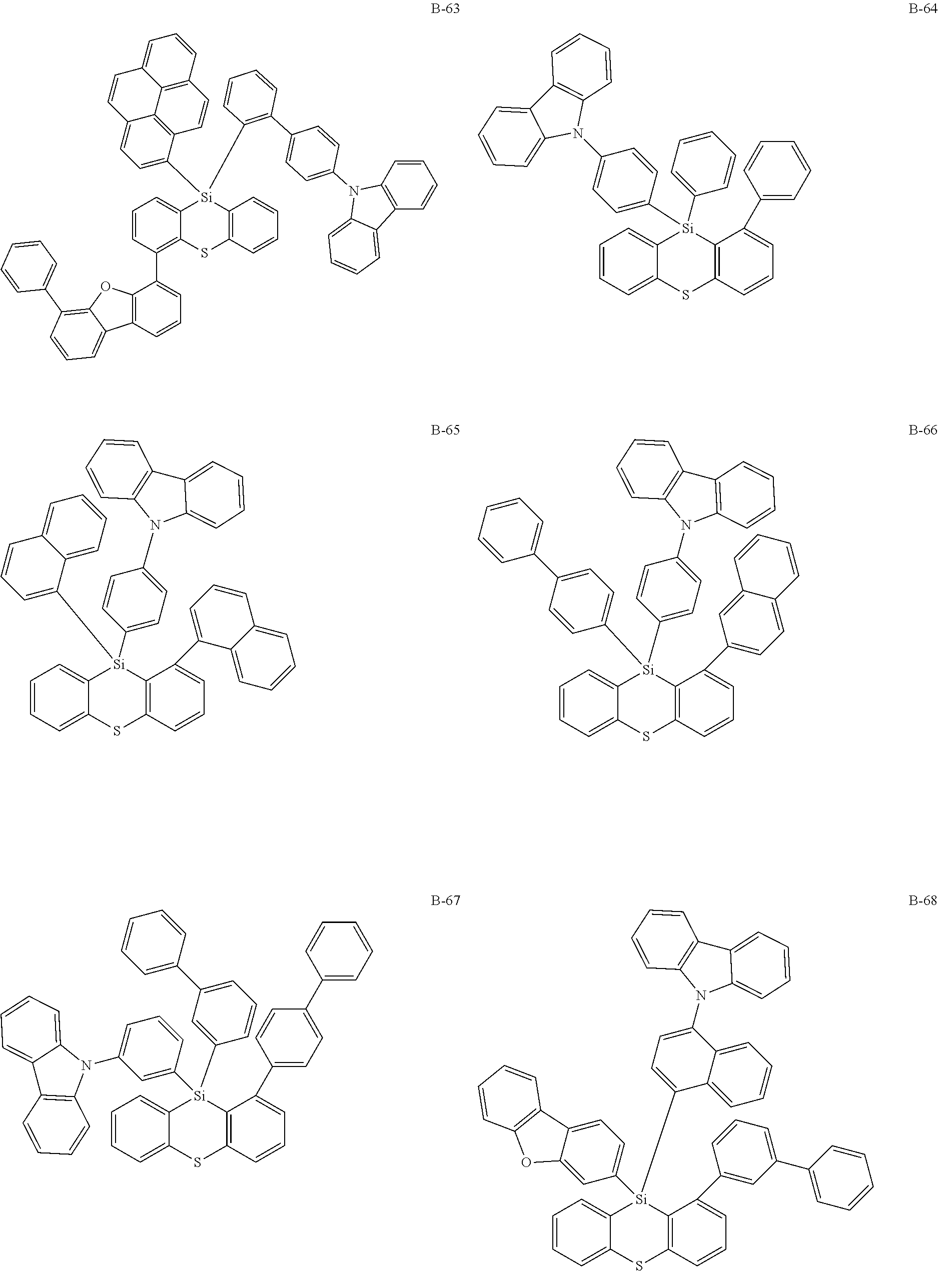

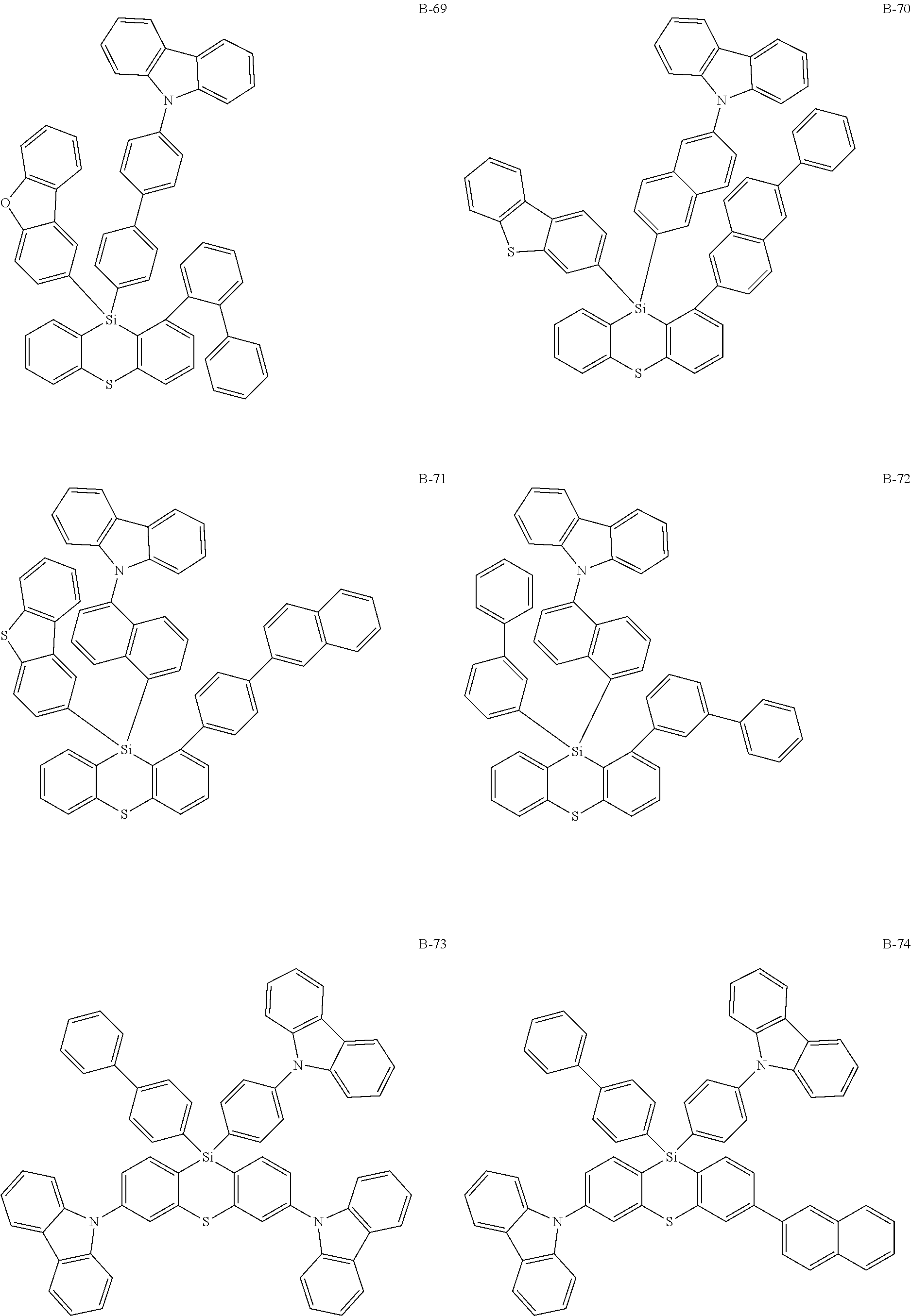

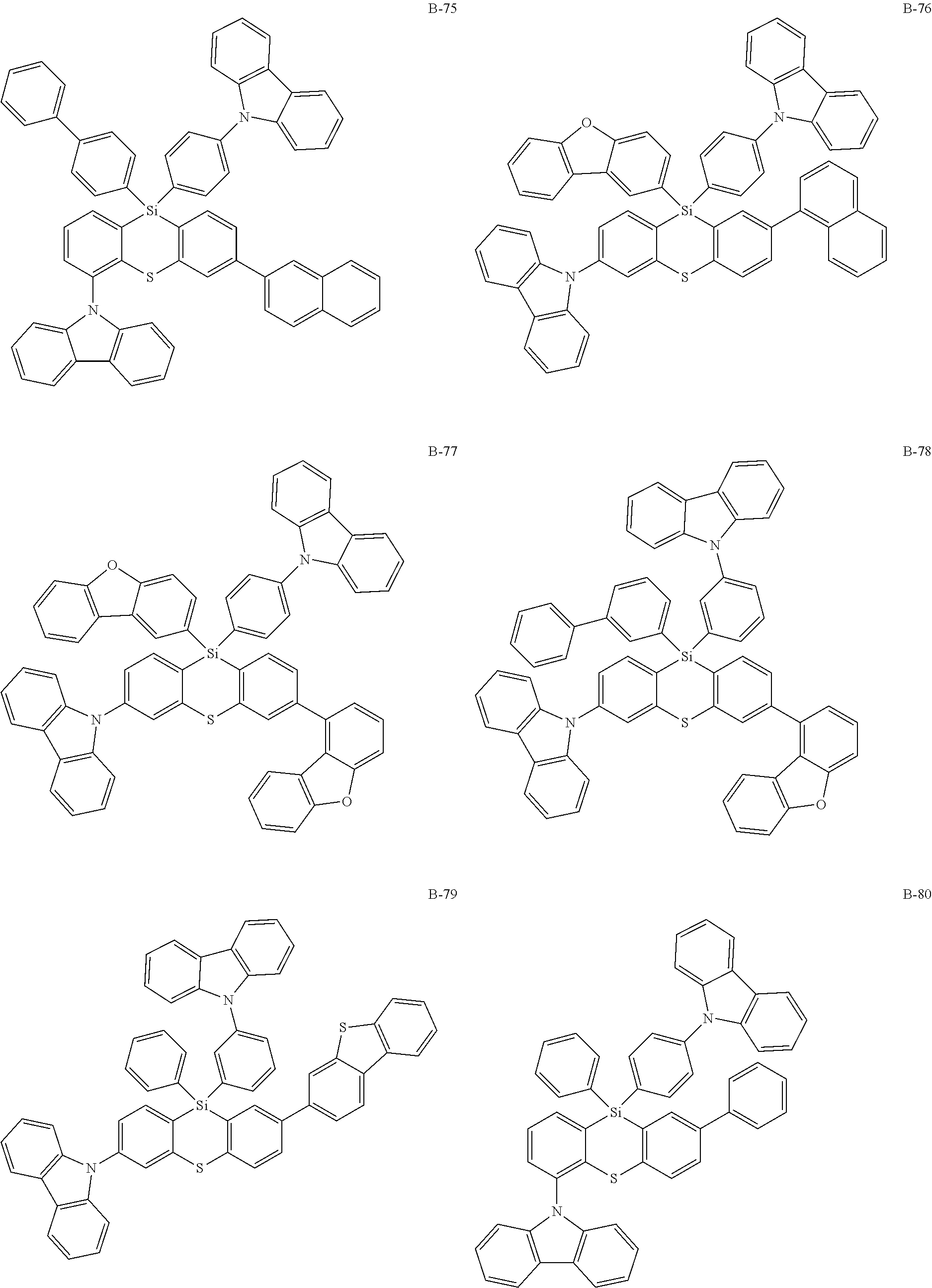

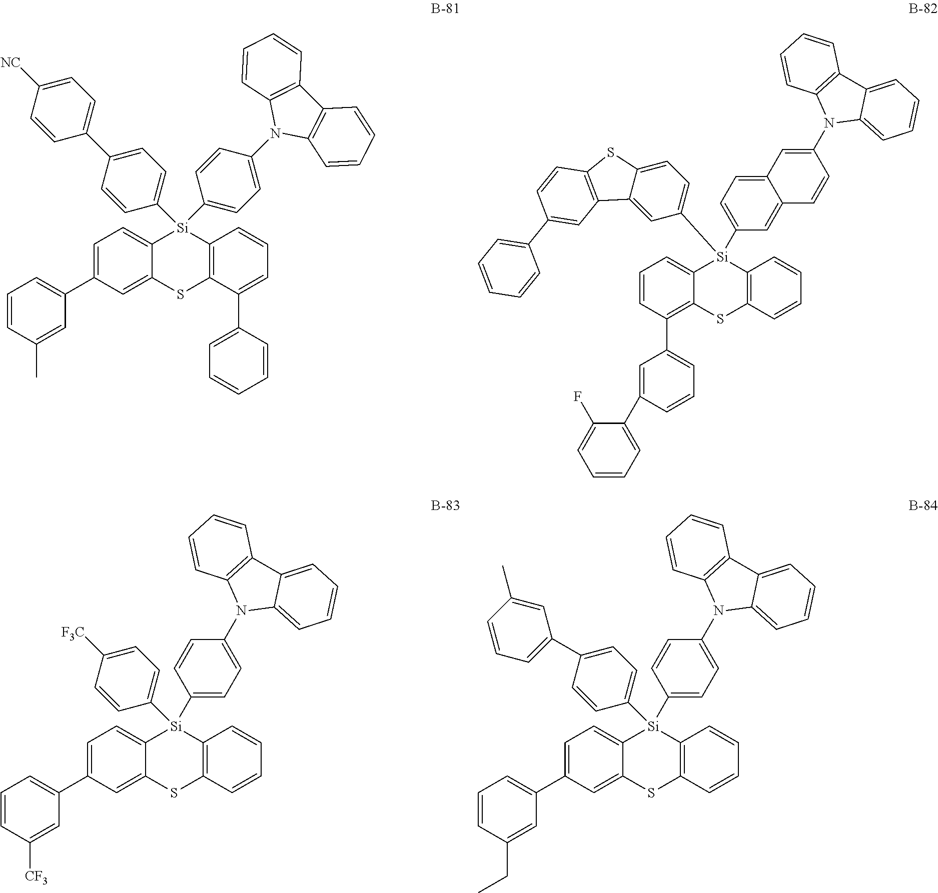 [SMILES: Cc1cccc(-c2ccc3c(c2)Sc2c(-c4ccccc4)cccc2[Si]3(c2ccc(-c3ccc(C#N)cc3)cc2)c2ccc(-n3c4ccccc4c4ccccc43)cc2)c1 ; Fc1ccccc1-c1cccc(-c2cccc3c2Sc2ccccc2[Si]3(c2ccc3cc(-n4c5ccccc5c5ccccc54)ccc3c2)c2ccc3sc4ccc(-c5ccccc5)cc4c3c2)c1 ; FC(F)(F)c1ccc([Si]2(c3ccc(-n4c5ccccc5c5ccccc54)cc3)c3ccccc3Sc3cc(-c4cccc(C(F)(F)F)c4)ccc32)cc1 ; CCc1cccc(-c2ccc3c(c2)Sc2ccccc2[Si]3(c2ccc(-c3cccc(C)c3)cc2)c2ccc(-n3c4ccccc4c4ccccc43)cc2)c1]

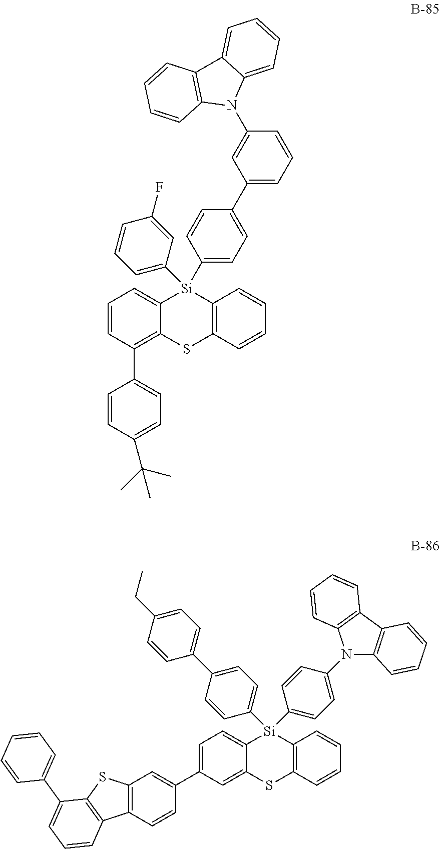 [SMILES: CC(C)(C)c1ccc(-c2cccc3c2Sc2ccccc2[Si]3(c2ccc(-c3cccc(-n4c5ccccc5c5ccccc54)c3)cc2)c2cccc(F)c2)cc1 ; CCc1ccc(-c2ccc([Si]3(c4ccc(-n5c6ccccc6c6ccccc65)cc4)c4ccccc4Sc4cc(-c5ccc6c(c5)sc5c(-c7ccccc7)cccc56)ccc43)cc2)cc1]

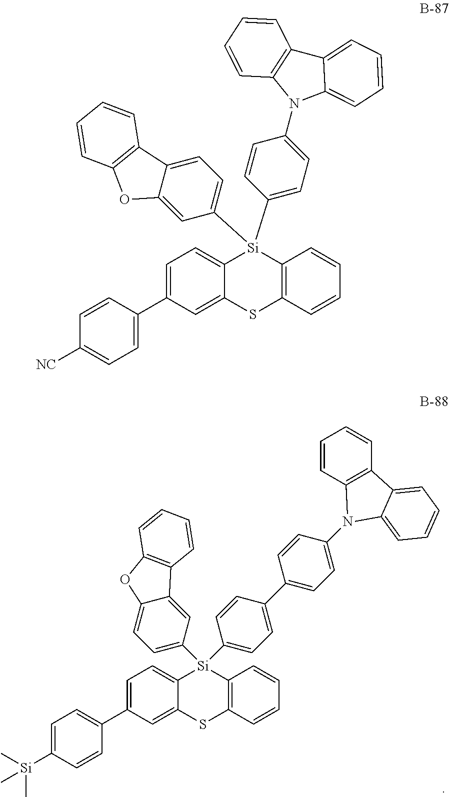 [SMILES: N#Cc1ccc(-c2ccc3c(c2)Sc2ccccc2[Si]3(c2ccc(-n3c4ccccc4c4ccccc43)cc2)c2ccc3c(c2)oc2ccccc23)cc1 ; C[Si](C)(C)c1ccc(-c2ccc3c(c2)Sc2ccccc2[Si]3(c2ccc(-c3ccc(-n4c5ccccc5c5ccccc54)cc3)cc2)c2ccc3oc4ccccc4c3c2)cc1]

11. An electronic element, comprising an anode and a cathode disposed opposite to each other, and a functional layer disposed between the anode and the cathode, wherein the functional layer comprises the organic compound of claim 1.

12. The electronic element according to claim 11, wherein the electronic element is an organic electroluminescent device, and the functional layer comprises an organic light-emitting layer, and the organic light-emitting layer comprises the organic compound.

13. An electronic apparatus, comprising the electronic element according to claim 11.
